(19) United States
(12) Patent Application Publication
(10) Pub. No.: US 2025/0089564 A1
(43) Pub. Date: Mar. 13, 2025

(54) LIGHT-EMITTING DEVICE, ELECTRONIC APPARATUS INCLUDING THE LIGHT-EMITTING DEVICE, AND CONDENSED CYCLIC COMPOUND

(71) Applicant: Samsung Electronics Co., Ltd., Suwon-si (KR)

(72) Inventors: Joonghee WON, Suwon-si (KR); Jong Soo KIM, Suwon-si (KR); Sungho NAM, Suwon-si (KR); Sangmo KIM, Suwon-si (KR); Joonghyuk KIM, Suwon-si (KR); Jiwhan KIM, Suwon-si (KR); Yusuke MARUYAMA, Suwon-si (KR); Yeonkyung LEE, Suwon-si (KR); Eunkyung LEE, Suwon-si (KR); Halim LEE, Suwon-si (KR); Sooghang IHN, Suwon-si (KR); Juhyung LIM, Suwon-si (KR); Soonok JEON, Suwon-si (KR); Daun JEONG, Suwon-si (KR); Yeon Sook CHUNG, Suwon-si (KR); Yongsik JUNG, Suwon-si (KR)

(21) Appl. No.: 18/818,813

(22) Filed: Aug. 29, 2024

(30) Foreign Application Priority Data
Sep. 1, 2023 (KR) 10-2023-0116270
Aug. 28, 2024 (KR) 10-2024-0115594

(51) Int. Cl. H10K 85/60; C09K 11/02; C09K 11/06; H10K 85/30; H10K 101/00

(52) U.S. Cl. CPC H10K 85/658; C09K 11/02; C09K 11/06; H10K 85/342; H10K 85/346; H10K 85/6572; H10K 2101/90

(57) ABSTRACT

A light-emitting device, an electronic apparatus including the light emitting device, and a condensed cyclic compound represented by Formula 1. The light-emitting device includes a first electrode, a second electrode facing the first electrode, and an interlayer arranged between the first electrode and the second electrode, the interlayer including an emission layer. The emission layer includes an emitter and one or more host(s) of number m1, m1 is an integer of 1 or more, and if m1 is 2 or more, two or more of the hosts are different from each other, the emitter and the host(s) m1 are different from each other, the emitter includes a condensed ring in which two or more monocyclic groups are condensed with each other, at least one of the monocyclic groups is a 6-membered ring including a boron atom, a nitrogen atom, and a carbon atom as ring-forming atoms, and at least one of the protection coefficient of the boron atom in the emitter is 0.7 or more. Formula 1 provided herein.

### CROSS-REFERENCE TO RELATED APPLICATION

This application claims priority to Korean Patent Applications Nos. 10-2023-0116270, filed on Sep. 1, 2023, and 10-2024-0115594, filed on Aug. 28, 2024, in the Korean Intellectual Property Office, and all the benefits accruing therefrom under 35 U.S.C. § 119, the disclosure of which in its entirety is incorporated by reference herein.

### BACKGROUND

### 1. Field

The disclosure relates to a light-emitting device, an electronic apparatus including the light-emitting device, a condensed cyclic compound and a method of evaluating a protection coefficient of an atom comprised in a compound.

### 2. Description of the Related Art

Organic light-emitting devices among light-emitting devices are self-emissive devices that, as compared with devices of the related art, have wide viewing angles, high contrast ratios, short response times, and excellent characteristics in terms of luminance, driving voltage, and response speed, and produce full-color images.

In an example, an organic light-emitting device includes an anode, a cathode, and an interlayer that is arranged between the anode and the cathode and includes an emission layer. A hole transport region may be provided between the anode and the emission layer, and an electron transport region may be provided between the emission layer and the cathode. Holes provided from the anode move toward the emission layer through the hole transport region, and electrons provided from the cathode move toward the emission layer through the electron transport region. The holes and the electrons recombine in the emission layer to produce excitons. The excitons transition from an excited state to a ground state, thereby generating light.

### SUMMARY

Provided are a light-emitting device with a long lifespan and an electronic apparatus including the light-emitting device. In addition, provided is a condensed cyclic compound capable of providing a light-emitting device with a long lifespan and a method of evaluating a protection coefficient of an atom comprised in a compound.

Additional aspects will be set forth in part in the description which follows and, in part, will be apparent from the description, or may be learned by practice of the presented embodiments of the disclosure.

According to an aspect of the disclosure, a light-emitting device includes
a first electrode and a second electrode facing the first electrode, and
an interlayer arranged between the first electrode and the second electrode, the interlayer including an emission layer,
wherein the emission layer may include an emitter and one or more hosts of number m1,
m1 may be an integer of 1 or more,
if m1 is 2 or more, two or more of the hosts may be different from each other,
the emitter and the one or more hosts of number m1 may be different from each other,
the emitter may include a condensed ring with two or more monocyclic groups condensed to the other, and at least one of the two or more monocyclic groups may be a 6-membered ring including a boron atom and a carbon atom as ring-forming atoms,
a protection coefficient of the boron atom in the emitter may be represented by Expression 1 and at least one of the protection coefficient of the boron atom may be 0.7 or more:

$$1 - ( {A}_{2} / {A}_{1} ) \qquad Expression 1$$

wherein, in Expression 1,
A₁ is a total surface area of a virtual sphere with a radial distance from the boron atom used in the determination of Expression 1 to an atom of the emitter furthest from the boron atom,
A₂ is an area of a region M2 at the surface of the virtual sphere, wherein the region M2 is a surface region defined by a plurality of projection lines from the boron atom without contacting a surface surrounding a virtual compound E having the same structure as the emitter except that the boron atom is not present in the virtual structure, and
A₁ and A₂ may each be evaluated by a density functional theory (DFT) calculation.

According to another aspect of the disclosure, an electronic apparatus includes the light-emitting device.

According to another aspect of the disclosure, provided is a condensed cyclic compound represented by Formula 1:

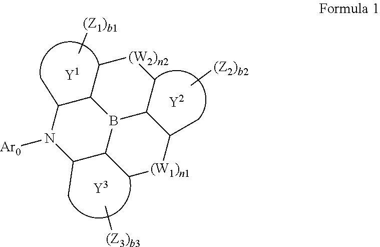

wherein, in Formula 1, Ar₀ may be a group represented by Formula 2,

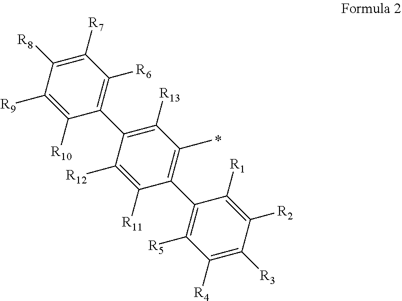

wherein, in Formulae 1 and 2,
ring Y₁, ring Y₂, and ring Y₃ may each independently be a C₅-C₆₀ carbocyclic group or a C₃-C₆₀ heterocyclic group,
W₁ may be a single bond, O, S, N(Ar₁), N(T₁₁), C(T₁₂)(T₁₃), or Si(T₁₂)(T₁₃),
W₂ may be a single bond, O, S, N(Ar₂), N(T₂₁), C(T₂₂)(T₂₃), or Si(T₂₂)(T₂₃),
n1 and n2 may each independently be 0 or 1,
when n1 is 0, *—(W₁)ₙ₁—*′ may not be present,
when n2 is 0, *—(W₂)ₙ₂—*′ may not be present,
the sum of n1 and n2 may be 1 or more,
Ar₁ and Ar₂ may each be a group represented by Formula 2,
R₁ to R₁₀ may each independently be
hydrogen, deuterium, —F, or a cyano group,
a C₁-C₆₀ alkyl group unsubstituted or substituted with deuterium, —F, a cyano group, or any combination thereof, or
a C₆-C₆₀ aryl group unsubstituted or substituted with deuterium, —F, a cyano group, a C₁-C₆₀ alkyl group, a C₆-C₆₀ aryl group, or any combination thereof,
R₁₁, R₁₂, and R₁₃ may each independently be
hydrogen, deuterium, —F, or a cyano group, or
a C₁-C₆₀ alkyl group unsubstituted or substituted with deuterium, —F, a cyano group, or any combination thereof,
* in Formula 2 indicates a binding site to Formula 1,
Z₁, Z₂, Z₃, T₁₁, T₁₂, T₁₃, T₂₁, T₂₂, and T₂₃ may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), —P(Q₈)(Q₉), or a group represented by Formula 2,
b1 to b3 may each independently be an integer from 0 to 10,
two or more of Z₁, Z₂, Z₃, T₁₁, T₁₂, T₁₃, T₂₁, T₂₂, and T₂₃ may optionally be linked to each other to form a substituted or unsubstituted C₅-C₃₀ carbocyclic group or a substituted or unsubstituted C₁-C₃₀ heterocyclic group,
at least one substituent of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group may each independently be
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group,
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or any combination thereof,
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or any combination thereof,
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉), or
any combination thereof, and
Q₁ to Q₉, Q₁₁ to Q₁₉, Q₂₁ to Q₂₉, and Q₃₁ to Q₃₉ may each independently be hydrogen, deuterium, —F, or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, a cyano group, a C₁-C₆₀ alkyl group, a C₆-C₆₀ aryl group, or any combination thereof.

According to another aspect of the disclosure, provided is a method of evaluating
a protection coefficient of an atom X comprised in a compound Y, comprising:
(a) evaluating A₁ by using a density functional theory calculation, wherein A₁ refers to total surface area of a virtual sphere with a radial distance from the atom X in compound Y to an atom furthest from atom X in the compound Y,
(b) evaluating A₂ by using a density functional theory calculation, wherein A₂ refers to an area of a region M2 at the surface of the virtual sphere and the region M2 is a region reached by a projection line from the atom X without contacting a surface surrounding a virtual compound YE having the same structure as the compound Y except that the atom X is not present, and
(c) evaluating 1−(A₂/A₁) to calculate the protection coefficient of the atom X.

### BRIEF DESCRIPTION OF THE DRAWINGS

The above and other aspects, features, and advantages of certain embodiments of the disclosure will be more apparent from the following description taken in conjunction with the accompanying drawings in which:

FIG. 1 is a schematic cross-sectional view of a light-emitting device according to an embodiment;

FIG. 2 is a schematic view of a virtual sphere 100 which is necessary for evaluating A₁ for Compound 3;

FIG. 3A is a schematic view two-dimensionally showing a surface surrounding a virtual Compound 3E 110, wherein Compound 3E has the same structure as Compound 3 except that the boron atom is not present;

FIG. 3B is a schematic view three-dimensionally showing the surface surrounding the virtual Compound 3E 110;

FIG. 4 is a schematic view showing i) Compound 3 and the virtual sphere 100 with the surface surrounding the virtual Compound 3E 110 and ii) a region M2 and a region M3 other than the region M2 in the virtual sphere 100; and

FIG. 5 is a schematic view three-dimensionally showing the region M2 and the region M3 for Compound 3.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Therefore, reference to “an” element in a claim followed by reference to “the” element is inclusive of one element as well as a plurality of the elements.

“At least one” is not to be construed as limiting “a” or “an.” “Or” means “and/or.” As used herein, the term “and/or” includes any and all combinations of one or more of the associated listed items.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10% or ±5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

A light-emitting device according to an embodiment may include a first electrode, a second electrode facing the first electrode, and an interlayer arranged between the first electrode and the second electrode.

The interlayer may include an emission layer.

The emission layer may include an emitter and one or more host(s) of number m1 where m1 may be an integer of 1 or more. If m1 is 2 or more, two or more hosts in the emission layer may be different from each other. For example, when m1 is 2 or more, the host of the emission layer may be a mixture of two or more different hosts. For example, m1 may be 2, the host may include a first host and a second host, and the first host and the second host may be different from each other. The emitter and the host(s) in the number of m1 may be different from each other. For example, the emitter may be a delayed fluorescence emitter.

In an embodiment, m1 may be 1, 2, 3, or 4.

In one or more embodiments, m1 may be 1 or 2.

When m1 is 2, a weight ratio between the two different hosts H1 and H2 included in the emission layer (H1:H2) may be in a range of about 1:9 to about 9:1, about 2:8 to about 8:2, about 3:7 to about 7:3, or about 4:6 to about 6:4. When the above weight ratios are satisfied, holes and electrons may move efficiently in the emission layer.

An emission ratio of fluorescent emission components emitted from the emitter to a total emission components emitted from the emission layer may be 70% or more, for example, in a range of about 70% to about 100%, about 70% to about 95%, about 70% to about 90%, about 70% to about 85%, or about 70% to about 80%.

The fluorescent emission components emitted from the emitter may be emission components that are emitted when excitons of a delayed fluorescence emitter transition from a singlet excited state to a ground state. Accordingly, the emission layer may be a fluorescent emission layer. The fluorescent emission layer is clearly distinguished from a phosphorescent emission layer including a phosphorescence emitter (e.g., an organometallic compound including a transition metal), wherein a ratio of phosphorescent emission components emitted from the phosphorescence emitter to the total emission components is 70% or more.

The emission layer may further include a sensitizer. When the emission layer further includes the sensitizer, excitation energy in the emission layer may be transferred from the sensitizer to the emitter, and the emitter may emit as fluorescence the excitation energy absorbed from the sensitizer. The emitter, the sensitizer, and the host(s) of number m1 in the emission layer may be different from each other.

For example, when the emission layer further includes the sensitizer, in the emission layer, singlet excitons generated at a ratio of 25% in the host may be transferred to the sensitizer through Förster energy transfer, and energy of triplet excitons generated at a ratio of 75% in the host may be transferred to singlet and triplet excited states of the sensitizer. Among these excitons, the triplet excitons transferred to the singlet and triplet excited states of the sensitizer may be transferred to a singlet excited state of the emitter through Förster energy transfer. As a result, the singlet excitons and the triplet excitons generated in the emission layer may all be transferred to the singlet excited state of the emitter and then undergo a radiative transition to a ground state, thereby emitting fluorescence with high luminescence efficiency, that is, hyper fluorescence.

A weight of the host(s) of number m1 in the emission layer may be greater than the weight of the emitter or the total weight of the emitter and the sensitizer. For example, the weight of the host(s) of number m1 in the emission layer may be in a range of about 60 wt % to about 99 wt %, about 70 wt % to about 97 wt %, about 80 wt % to about 96 wt %, or about 82 wt % to about 90 wt %, based on 100 wt % of the emission layer.

The emission layer may emit blue light (e.g., blue fluorescence).

In an embodiment, a full width at half maximum (FWHM) of fluorescence emitted from the emission layer may be in a range of about 5 nm to about 30 nm, for example, about 10 nm to about 30 nm, or about 20 nm to about 30 nm.

In one or more embodiments, an emission peak wavelength (maximum emission peak wavelength) of fluorescence emitted from the emission layer may be in a range of about 400 nm to about 500 nm, about 440 nm to about 470 nm, about 445 nm to about 470 nm, about 450 nm to about 470 nm, about 455 nm to about 470 nm, about 460 nm to about 470 nm, about 440 nm to about 465 nm, about 445 nm to about 465 nm, about 450 nm to about 465 nm, about 455 nm to about 465 nm, or about 460 nm to about 465 nm.

In one or more embodiments, a CIEy value of light emitted from the emission layer may be in a range of about 0.040 to about 0.170, about 0.050 to about 0.170, about 0.060 to about 0.170, about 0.040 to about 0.165, about 0.050 to about 0.165, or about 0.060 to about 0.165.

In an embodiment, the first electrode may be an anode, which is a hole injection electrode, and the second electrode may be a cathode, which is an electron injection electrode. In one or more embodiments, the first electrode may be a cathode, which is an electron injection electrode, and the second electrode may be an anode, which is a hole injection electrode.

In an embodiment, in the light-emitting device, the first electrode may be an anode, the second electrode may be a cathode, and the interlayer may further include a hole transport region arranged between the first electrode and the emission layer and an electron transport region arranged between the emission layer and the second electrode, wherein the hole transport region may include a hole injection layer, a hole transport layer, an electron-blocking layer, a buffer layer, or any combination thereof, and the electron transport region may include a buffer layer, a hole-blocking layer, an electron transport layer, an electron injection layer, or any combination thereof.

The term “interlayer” as used herein refers to a single layer and/or multiple layers arranged between the first electrode and the second electrode of the light-emitting device. The “interlayer” may include, in addition to an organic compound, an organometallic complex including metal.

The emitter may provide a radiative transition of excitation energy (or excitons) received from the host and/or the sensitizer to a ground state resulting in fluorescence emission.

The emitter may include a condensed ring in which two or more monocyclic groups are condensed to the other, and at least one of the monocyclic groups may be a 6-membered ring including a boron atom and a carbon atom as ring-forming atoms. The 6-membered ring may further include at least one of a nitrogen atom, an oxygen atom, a sulfur atom and a silicon atom as ring-forming atoms. For example, the 6-membered ring may include a boron atom, a nitrogen atom, and a carbon atom as ring-forming atoms. Accordingly, the emitter includes at least one boron atom. In one or more embodiments, a number of the 6-membered ring including a boron atom and a carbon atom as ring-forming atoms in the condensed ring of the emitter may be 1 and a number of the boron atom in the emitter may be 1. In one or more embodiments, a number of the 6-membered ring including a boron atom and a carbon atom as ring-forming atoms in the condensed ring of the emitter may be 2 or more (for example, 2, 3, 4 or 5) and a number of the boron atom in the emitter may be 2 or more (for example, 2, 3, 4 or 5), for example, as shown in Formulae 1-1, 1-2 and 1-3 described hereinafter. The condensed ring may be the same as described herein in connection with a condensed cyclic core of Formula 1.

A protection coefficient of the boron atom in the emitter may be represented by Expression 1 and at least one of the protection coefficient of the boron atom may be 0.7 or more.

As used herein, the protection coefficient of the boron atom comprised in the emitter refers to the protection coefficient of the boron atom in the 6-membered ring including a boron atom and a carbon atom as ring-forming atoms (for example, the 6-membered ring including a boron atom, a nitrogen atom, and a carbon atom as ring-forming atoms). When the number of the 6-membered ring including a boron atom and a carbon atom as ring-forming atoms in the condensed ring of the emitter is 2 or more, the protection coefficient of each boron atom may be calculated individually and the individually calculated protection coefficients of the boron atoms may be identical to or different from each other according to a molecular structure of the emitter.

In one or more embodiments, the emitter may include one boron atom and the protection coefficient of the boron atom may be 0.7 or more. In one or more embodiments, the emitter may include two boron atoms and the protection coefficient of one boron atom of the two boron atoms may be 0.7 or more. In one or more embodiments, the emitter may include two boron atoms and each of the protection coefficients of the two boron atoms may be 0.7 or more.

The protection coefficient may be represented by Expression 1:

$$1 - ( {A}_{2} / {A}_{1} ) \qquad Expression 1$$

wherein, in Expression 1,
A₁ refers to a total surface area of a virtual sphere defined by a radial distance from the boron atom used in the determination of Expression 1 to an atom of the emitter furthest from the boron atom,
A₂ refers to an area of a region M2 at the surface of the virtual sphere, wherein the region M2 is a surface region defined by a plurality of projection lines from the boron atom without contacting a surface surrounding a virtual compound E having the same structure as the emitter except that the boron atom is not present, and
A₁ and A₂ may each be evaluated by a density functional theory (DFT) calculation.

In an embodiment, the DFT calculation may be performed based on a molecular structure optimized through the B3LYP/6-31G(d,p) function.

In one or more embodiments, the DFT calculation may be performed using the Gaussian program (for example, Gaussian 16 program) or the like.

In one or more embodiments, the surface surrounding the virtual compound E may be a van der waals surface of the virtual compound E, a connolly surface of the virtual compound E, a solvent accessible surface of the virtual compound E etc. For example, the surface surrounding the virtual compound E may be the solvent accessible surface of the virtual compound E and the solvent accessible surface of the virtual compound E may be obtained using a solvent accessible surface area (SASA) method.

In the “virtual compound E having the same structure as the emitter except that the boron atom (the boron atom used in the determination of Expression 1) is not present”, no atom (for example, no hydrogen) is bonded to an atom (for example, a carbon atom), which was bonded to the boron atom removed from the emitter. Accordingly, spatial arrangement of atoms of the “virtual compound E having the same structure as the emitter except that the boron atom is not present” is the same as the spatial arrangement of atoms in the emitter other than the boron.

In one or more embodiments, the method of evaluating a protection coefficient of an atom X comprised in a compound Y may include:
(a) evaluating A₁ by using a density functional theory calculation, wherein A₁ refers to a total surface area of a virtual sphere with a radial distance from the atom X in the compound Y to an atom of compound Y furthest from the atom X,
(b) evaluating A₂ by using a density functional theory calculation, wherein A₂ refers to an area of a region M2 at the surface of the virtual sphere and the region M2 is a surface region defined by a plurality of projection lines from the atom X without contacting a surface surrounding a virtual compound YE having the same structure as the compound Y except that the atom X is not present, and
(c) evaluating 1−(A₂/A₁) to calculate the protection coefficient of the atom X.

In one or more embodiments, the method of evaluating a protection coefficient of the boron atom comprised in the emitter may include:
(a) evaluating A₁ by using a density functional theory calculation, wherein A₁ refers to the total surface area of a virtual sphere with a radial distance from the boron atom to an atom of the emitter furthest from the boron atom,
(b) evaluating A₂ by using a density functional theory calculation, wherein A₂ refers to an area of the region M2 at the surface of the virtual sphere and the region M2 is a surface region defined by a plurality of projection lines from the boron atom without contacting the surface surrounding the virtual compound E having the same structure as the emitter except that the boron atom is not present, and
(c) evaluating 1−(A₂/A₁) to calculate the protection coefficient of the boron atom.

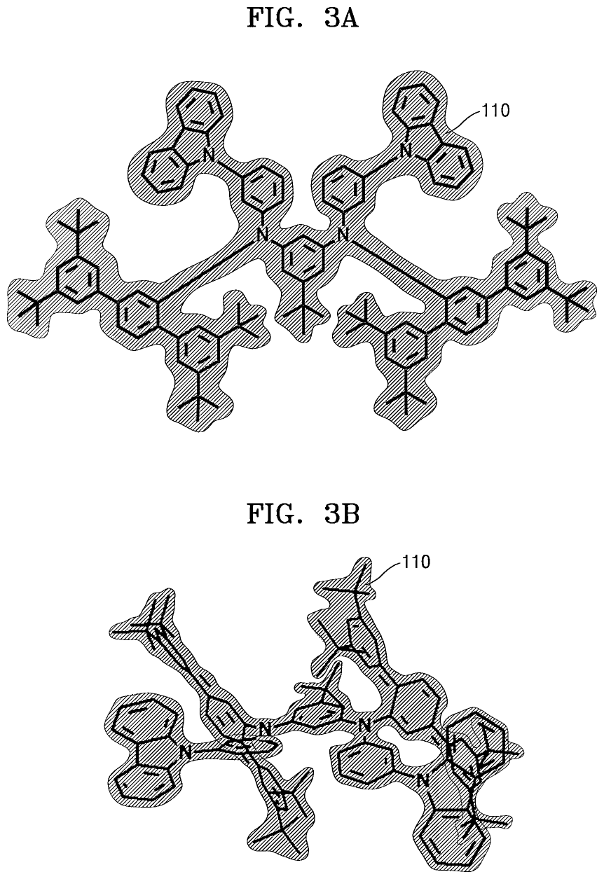

Hereinafter, the method of evaluating the protection coefficient of the boron atom comprised in Compound 3 according to an embodiment will be described with reference to FIGS. 2, 3A, 3B, 4 and 5.

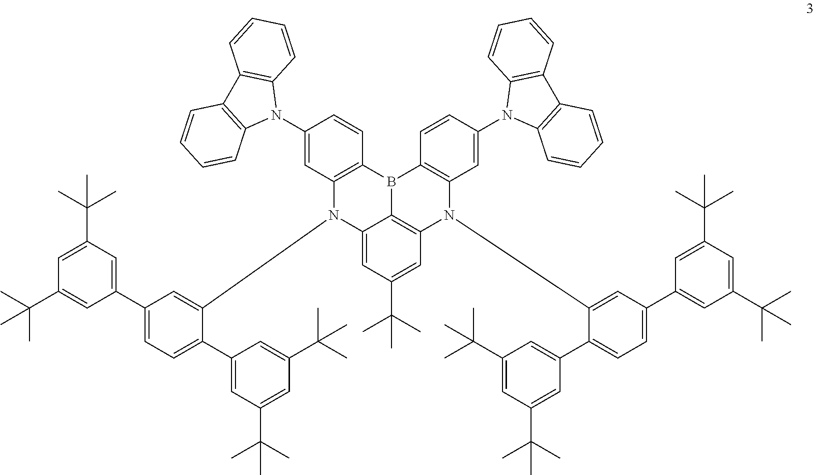 [SMILES: CC(C)(C)c1cc(-c2ccc(-c3cc(C(C)(C)C)cc(C(C)(C)C)c3)c(N3c4cc(-n5c6ccccc6c6ccccc65)ccc4B4c5ccc(-n6c7ccccc7c7ccccc76)cc5N(c5cc(-c6cc(C(C)(C)C)cc(C(C)(C)C)c6)ccc5-c5cc(C(C)(C)C)cc(C(C)(C)C)c5)c5cc(C(C)(C)C)cc3c54)c2)cc(C(C)(C)C)c1]

As shown in FIG. 2, A₁ may be evaluated by using a density functional theory calculation, wherein A₁ refers to a total surface area of a virtual sphere 100 having a radial distance from the boron atom in Compound 3 to an atom furthest from the boron atom among the atoms of Compound 3. For example, as indicated by compound 3 the virtual sphere is determined from a radial distance from the boron atom to a furtherest hydrogen atom on a methyl group of a t-butyl substituent on the terphenyl group.

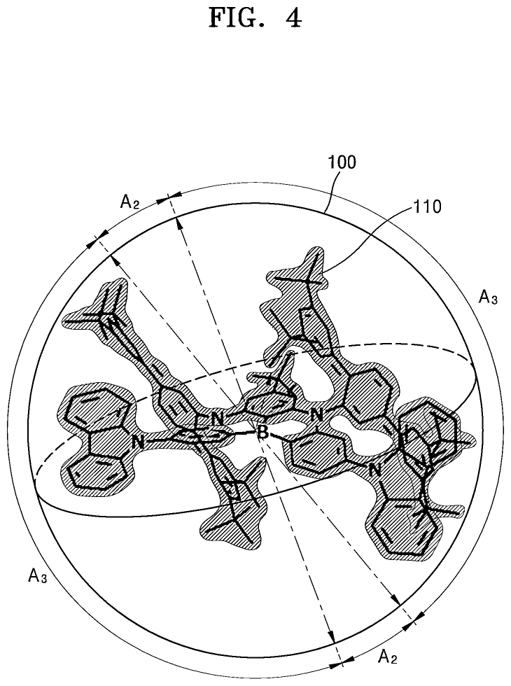

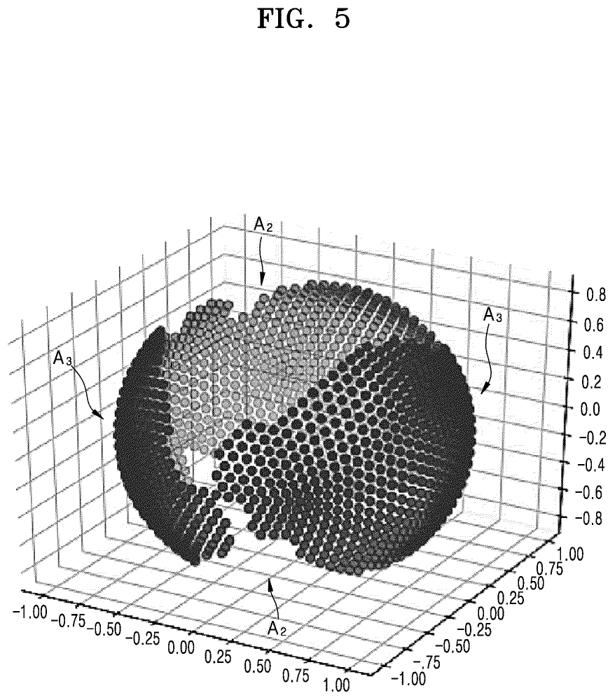

Next, as shown in FIG. 3A and FIG. 4, a surface surrounding a virtual Compound 3E 110 which has the same structure as Compound 3, except that the boron atom is not present, is projected and centered within the virtual sphere 100 of Compound 3, and A₂ may be evaluated by using a density functional theory calculation. A₂ refers to an area of a region M2 at the surface of the virtual sphere 100 and the region M2 is a surface region defined by a plurality of projection lines from the boron atom (indicated by an arrow from the boron atom in FIG. 4) to the surface of the virtual sphere without contacting the surface surrounding the virtual Compound 3E 110 (FIG. 3A). That is, for example, the region M2 may be a surface region obtained by defining a volumetric space in which the boron atom of Compound 3 is exposed to the outside surroundings without being blocked by other atoms of Compound 3, to the surface of the virtual sphere 100. In other words, the plurality of projection lines from the boron atom will provide a virtual volumetric cones to the surface of the virtual sphere. Accordingly, A₂ is a total surface area of region M2 defined by the intersection of the virtual cones with the surface of the virtual sphere. As represented in FIG. 5, a plurality of virtual cones, collectively, generates a surface region M2 as indicated by open access areas at the surface of the virtual sphere.

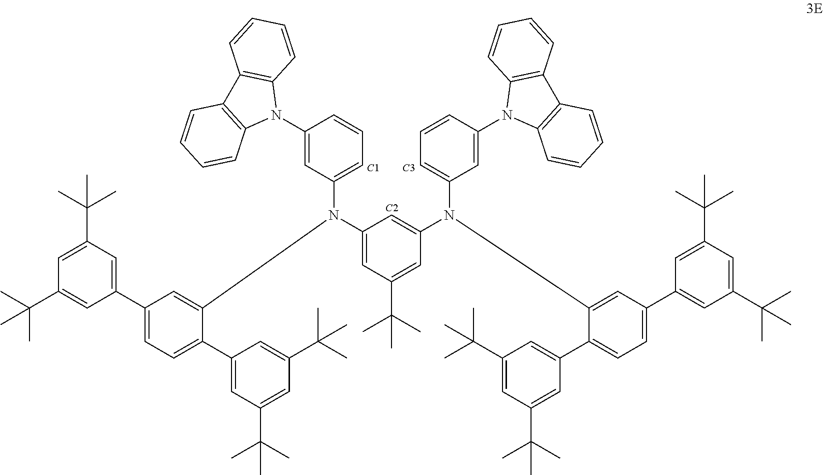

In the virtual Compound 3E, no atom (for example, no hydrogen) is bonded to each of three carbon atoms, which were bonded to the boron atom removed from Compound 3 and represented by “C1”, “C2” and “C3”, respectively. Accordingly, the spatial arrangement of atoms of the virtual Compound 3E is the same as spatial arrangement of atoms of Compound 3 other than the boron atom.

A schematic representation of a two-dimensional surface surrounding the virtual Compound 3E 110 is indicated in FIG. 3A, and a schematic representation of a three-dimensional surface surrounding virtual Compound 3E 110 is indicated in FIG. 3B.

The surface surrounding the virtual Compound 3E 110 may be a van der waals surface of the virtual Compound 3E, a connolly surface of the virtual Compound 3E, or a solvent accessible surface of the virtual Compound 3E. For example, the surface surrounding the virtual Compound 3E 110 may be the solvent accessible surface of the virtual Compound 3E and the solvent accessible surface of the virtual Compound 3E may be obtained using a solvent accessible surface area (SASA) method in which a probe radius is controlled in a range of 0.01 Å to 10 Å (for example, in a range of 0.1 Å to 1 Å).

In FIG. 4, a region M3 of the virtual sphere 100 is indicated separate from the region M2. For example, the region M3 may be a surface region in which the boron atom of Compound 3 is not exposed to the outside because other atoms of Compound 3 block the boron atom to the surface of the virtual sphere 100, i.e., a line from the boron atom in a direction toward the surface would be blocked by other atoms of Compound 3.

FIG. 5 is a schematic three-dimensional surface-dot representation of region M2 (open area) and the region M3 (blocked/surface-dot area) for a virtual sphere of Compound 3.

By calculating 1−(A₂/A₁) with the A₁ and A₂ evaluated as described above, a ratio of the region M3 to A₁ being the total area of the surface of the virtual sphere 100, that is the protection coefficient of the boron atom comprised in Compound 3, which means a protected level of the boron atom in Compound 3 by other atoms of Compound 3, may be evaluated.

In one or more embodiments, a method of evaluating the protection coefficient of the boron atom of the emitter and/or the atom X of the compound Y may be the same as described in Evaluation Example 2 provided below.

If at least one of the protection coefficient of the boron atom in the emitter is 0.7 or more (with a range of protection coefficients to follow), the boron atom may be effectively protected by the other atoms of the emitter. Without further limitation of the claimed subject matter, we believe that the protection of the boron atom provides an increase in stability and/or a robustness of the emitter. Accordingly, the light-emitting device including the emitter may exhibit an improvement in lifespan.

In an embodiment, at least one of the protection coefficient of the boron atom of the emitter may be in a range of about 0.7 to about 1.0, about 0.7 to about 0.99, about 0.7 to about 0.95, about 0.7 to about 0.9, about 0.7 to about 0.85, about 0.7 to about 0.845, about 0.72 to about 1.0, about 0.72 to about 0.99, about 0.72 to about 0.95, about 0.72 to about 0.9, about 0.72 to about 0.85, about 0.72 to about 0.845, about 0.739 to about 1.0, about 0.739 to about 0.99, about 0.739 to about 0.95, about 0.739 to about 0.9, about 0.739 to about 0.85, about 0.739 to about 0.845, about 0.8 to about 1.0, about 0.8 to about 0.99, about 0.8 to about 0.95, about 0.8 to about 0.9, about 0.8 to about 0.85, about 0.8 to about 0.845, about 0.803 to about 1.0, about 0.803 to about 0.99, about 0.803 to about 0.95, about 0.803 to about 0.9, about 0.803 to about 0.85, about 0.803 to about 0.845, about 0.81 to about 1.0, about 0.81 to about 0.99, about 0.81 to about 0.95, about 0.81 to about 0.9, about 0.81 to about 0.85, about 0.81 to about 0.845, about 0.83 to about 1.0, about 0.83 to about 0.99, about 0.83 to about 0.95, about 0.83 to about 0.9, about 0.83 to about 0.85, about 0.83 to about 0.845, about 0.84 to about 1.0, about 0.84 to about 0.99, about 0.84 to about 0.95, about 0.84 to about 0.9, about 0.84 to about 0.85, about 0.84 to about 0.845, about 0.845 to about 1.0, about 0.845 to about 0.99, about 0.845 to about 0.95, about 0.845 to about 0.9, or about 0.845 to about 0.85.

Singlet (S₁) energy of the emitter may be in a range of about 2.700 eV to about 3.050 eV, about 2.800 eV to about 3.050 eV, about 2.900 eV to about 3.050 eV, about 3.000 eV to about 3.050 eV, about 2.700 eV to about 3.035 eV, about 2.800 eV to about 3.035 eV, about 2.900 eV to about 3.035 eV, about 3.000 eV to about 3.035 eV, or about 3.016 eV to about 3.035 eV. In addition, an absolute value of a difference between singlet (S₁) energy and triplet (T₁) energy of the emitter may be in a range of 0 eV to about 1 eV, 0 eV to about 0.8 eV, 0 eV to about 0.6 eV, 0 eV to about 0.415 eV, 0 eV to about 0.410 eV, 0 eV to about 0.404 eV, about 0.1 eV to about 1 eV, about 0.1 eV to about 0.8 eV, about 0.1 eV to about 0.6 eV, about 0.1 eV to about 0.415 eV, about 0.1 eV to about 0.410 eV, about 0.1 eV to about 0.404 eV, about 0.2 eV to about 1 eV, about 0.2 eV to about 0.8 eV, about 0.2 eV to about 0.6 eV, about 0.2 eV to about 0.415 eV, about 0.2 eV to about 0.410 eV, about 0.2 eV to about 0.404 eV, about 0.3 eV to about 1 eV, about 0.3 eV to about 0.8 eV, about 0.3 eV to about 0.6 eV, about 0.3 eV to about 0.415 eV, about 0.3 eV to about 0.410 eV, or about 0.3 eV to about 0.404 eV. As a result, reverse intersystem crossing in the emitter may be more easily achieved, and thus, the light-emitting device may have improved internal quantum efficiency.

In an embodiment, the emitter may satisfy at least one of Conditions A or B:
Condition A
the singlet (S₁) energy of the emitter is in a range of about 2.700 eV to about 3.050 eV
Condition B
the absolute value of the difference between the singlet (S₁) energy and the triplet (T₁) energy of the emitter is in a range of 0 eV to about 0.415 eV.

A FWHM of an emission spectrum of the emitter may be in a range of about 5 nm to about 30 nm, for example, about 10 nm to about 30 nm, or about 20 nm to about 30 nm.

An emission peak wavelength (maximum emission peak wavelength) of the emission spectrum of the emitter may be in a range of about 400 nm to about 500 nm, about 440 nm to about 470 nm, about 445 nm to about 470 nm, about 450 nm to about 470 nm, about 455 nm to about 470 nm, about 460 nm to about 470 nm, about 440 nm to about 465 nm, about 445 nm to about 465 nm, about 450 nm to about 465 nm, about 455 nm to about 465 nm, or about 460 nm to about 465 nm.

The FWHM and emission peak wavelength of the emission spectrum of the emitter may be evaluated for a film including the emitter. The “film including the emitter” may be manufactured using various methods, such as vacuum deposition, coating, and heating. The “film including the emitter” may further include, in addition to the emitter, other compounds, for example, the host described herein.

An absolute value of a highest occupied molecular orbital (HOMO) energy level of the emitter may be in a range of about 4.0 eV to about 6.5 eV.

In an embodiment, the emitter may include at least one (e.g., one or two) group represented by Formula 2:

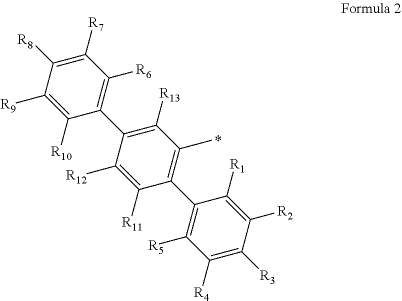

wherein, in Formula 2,
R₁ to R₁₀ may each independently be:
hydrogen, deuterium, —F, or a cyano group;
a C₁-C₆₀ alkyl group unsubstituted or substituted with deuterium, —F, a cyano group, or any combination thereof; or
a C₆-C₆₀ aryl group unsubstituted or substituted with deuterium, —F, a cyano group, a C₁-C₆₀ alkyl group, a C₆-C₆₀ aryl group, or any combination thereof,
R₁₁, R₁₂, and R₁₃ may each independently be:
hydrogen, deuterium, —F, or a cyano group; or
a C₁-C₆₀ alkyl group unsubstituted or substituted with deuterium, —F, a cyano group, or any combination thereof, and
* indicates a binding site to the condensed ring included in the emitter.

The group represented by Formula 2 may effectively protect the boron atom included in the emitter.

The C₁-C₆₀ alkyl group described herein may be C₁-C₂₀ alkyl group, C₁-C₁₀ alkyl group, or C₁-C₅ alkyl group. The C₁-C₆₀ alkyl group, C₁-C₂₀ alkyl group, C₁-C₁₀ alkyl group, or C₁-C₅ alkyl group may each be linear or branched, and in the case of a branched alkyl group, the lower limit of the carbon number in the above various alkyl groups becomes 3. The examples of the alkyl group may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, and the like. The C₆-C₆₀ aryl group described herein may be C₆-C₂₀ aryl group, C₆-C₁₂ aryl group, or C₆-C₁₀ aryl group, and examples thereof may include a phenyl group, a naphthyl group, a biphenyl group, a terphenyl group, a phenanthryl group, and the like.

In an embodiment, in Formula 2,
R₁ to R₁₀ may each independently be:
hydrogen, deuterium, —F, or a cyano group;
a C₁-C₂₀ alkyl group unsubstituted or substituted with deuterium, —F, a cyano group, or any combination thereof; or
a phenyl group unsubstituted or substituted with deuterium, —F, a cyano group, a C₁-C₂₀ alkyl group, a phenyl group, or any combination thereof.

In an embodiment, in Formula 2,
R₁₁, R₁₂, and R₁₃ may each independently be:
   hydrogen, deuterium, —F, or a cyano group; or
a C₁-C₂₀ alkyl group unsubstituted or substituted with deuterium, —F, a cyano group, or any combination thereof.

In an embodiment, the group represented by Formula 2 may include (or, may be) a tert-butyl group unsubstituted or substituted with deuterium. For example, the number of tert-butyl groups, each unsubstituted or substituted with deuterium, included in the group represented by Formula 2 may be in a range of about 1 to about 6, about 2 to about 6, about 3 to about 6, or about 4 to about 6.

In an embodiment, at least one of R₁ to R₁₃ in Formula 2 may include (or, may be) a tert-butyl group unsubstituted or substituted with deuterium.

In one or more embodiments, two or more of R₁ to R₁₃ in Formula 2 may include (or, may be) a tert-butyl group unsubstituted or substituted with deuterium.

In one or more embodiments, three, four, five, or six of R₁ to R₁₃ in Formula 2 may include (or, may be) a tert-butyl group unsubstituted or substituted with deuterium.

In one or more embodiments, at least one of R₁ to R₅ and/or at least one of R₆ to R₁₀ in Formula 2 may be a tert-butyl group unsubstituted or substituted with deuterium.

In one or more embodiments, two or more of R₁ to R₅ and/or two or more of R₆ to R₁₀ in Formula 2 may be a tert-butyl group unsubstituted or substituted with deuterium.

In one or more embodiments, R₁₁, R₁₂, and R₁₃ in Formula 2 may each independently be hydrogen or deuterium.

In one or more embodiments, the group represented by Formula 2 may be one of groups represented by Formulae 2-1 to 2-30:

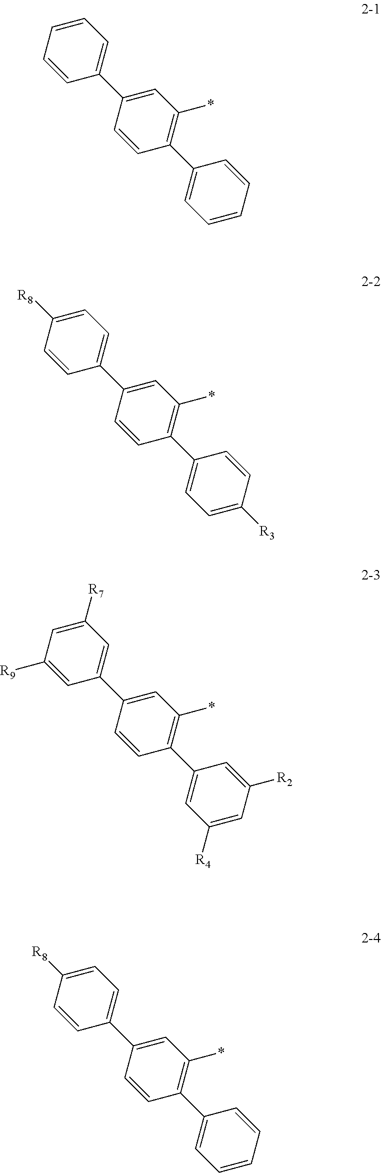

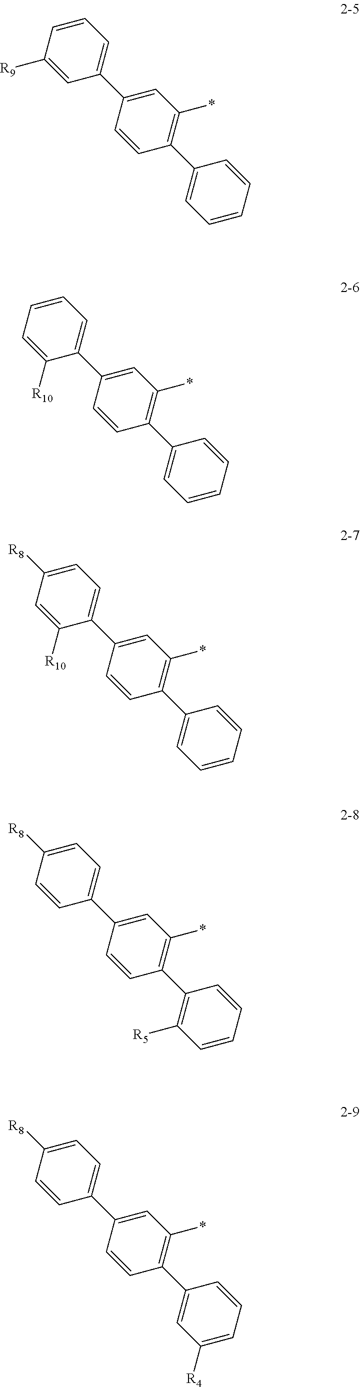

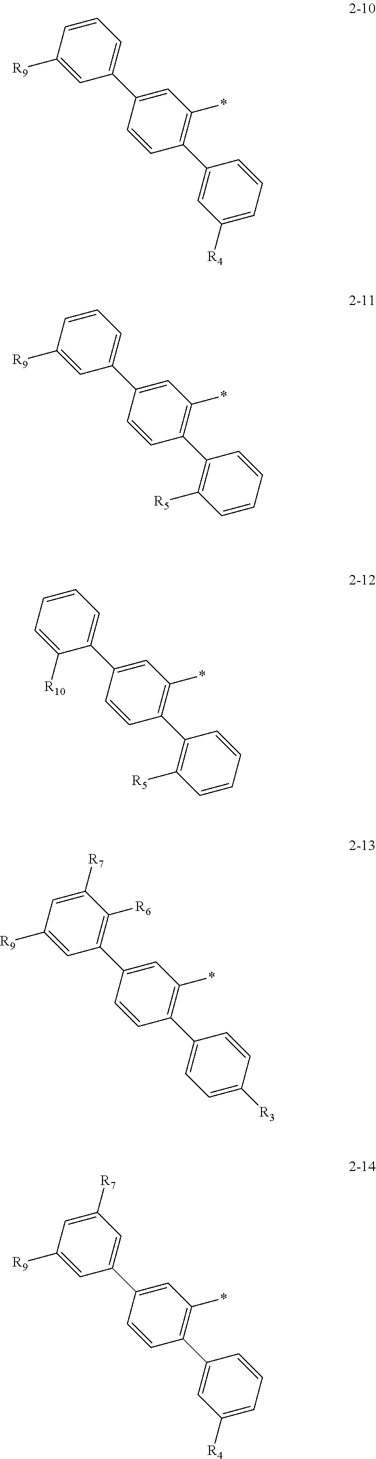

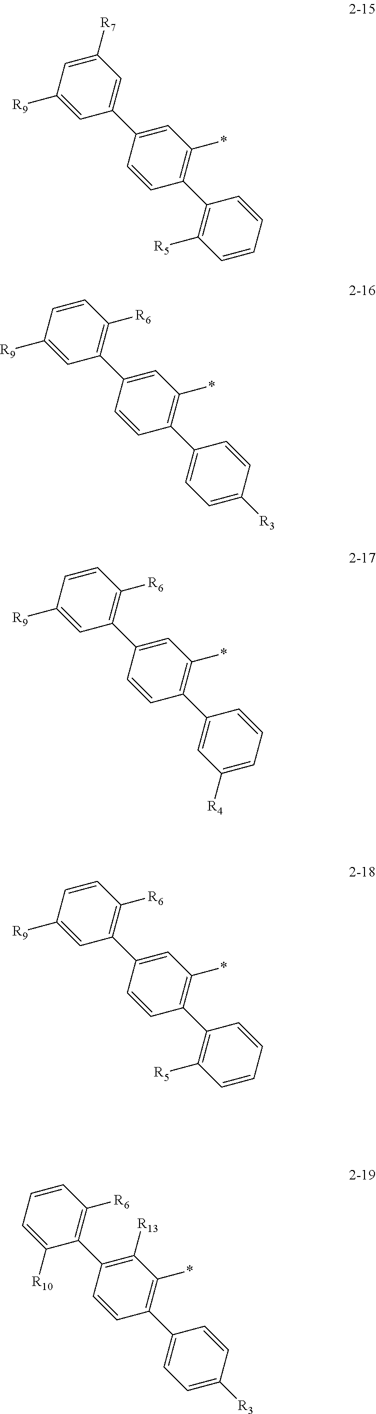

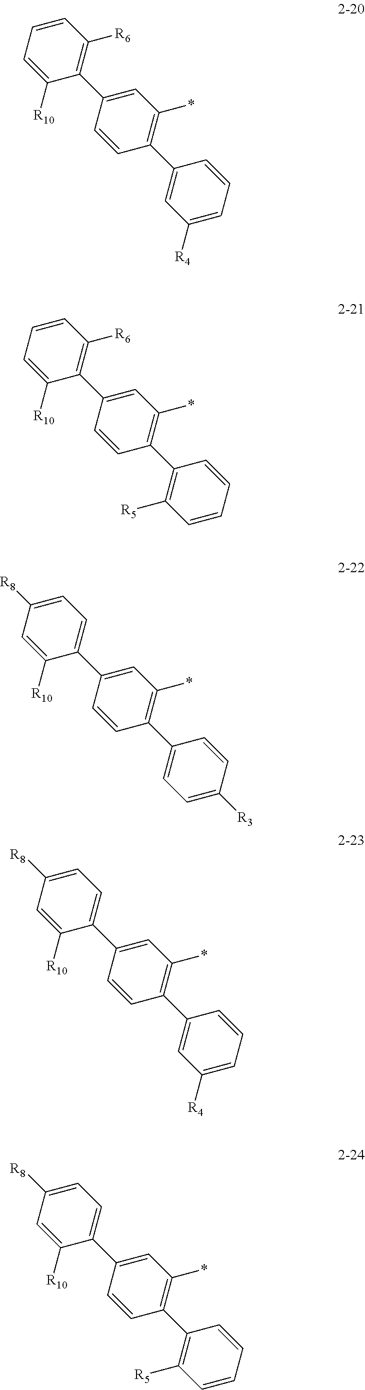

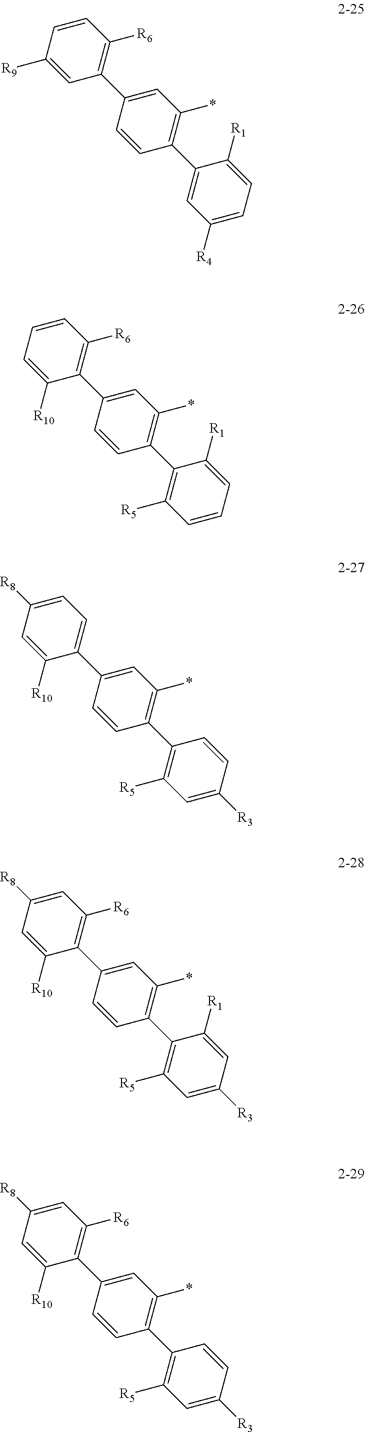

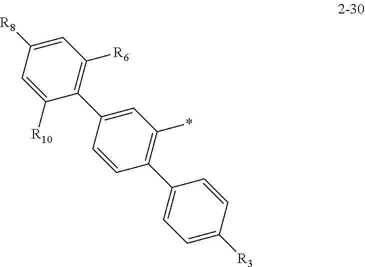

wherein, in Formulae 2-1 to 2-30, R₁ to R₁₀ may each be a tert-butyl group unsubstituted or substituted with deuterium, and * indicates a binding site to the condensed ring included in the emitter.

In an embodiment, the emitter may be a condensed cyclic compound represented by Formula 1:

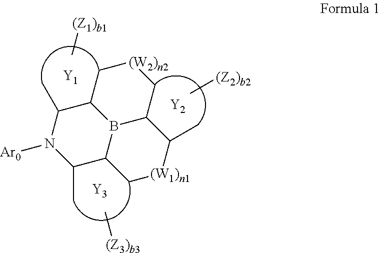

wherein, in Formula 1, Ar₀ may be a group represented by Formula 2,
   and details on Formula 2 may be the same as described herein,

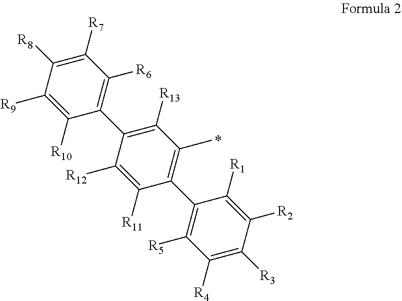

wherein, in Formula 1,
ring Y₁, ring Y₂, and ring Y₃ may each independently be a C₅-C₆₀ carbocyclic group or a C₃-C₆₀ heterocyclic group,
W₁ may be a single bond, O, S, N(Ar₁), N(T₁₁), C(T₁₂)(T₁₃), or Si(T₁₂)(T₁₃),
W₂ may be a single bond, O, S, N(Ar₂), N(T₂₁), C(T₂₂)(T₂₃), or Si(T₂₂)(T₂₃),
n1 and n2 may each independently be 0 or 1,
when n1 is 0, *—(W₁)ₙ₁—*′ may not be present,
when n2 is 0, *—(W₂)ₙ₂—*′ may not be present,
the sum of n1 and n2 may be 1 or more,
Ar₁ and Ar₂ may each be a group represented by Formula 2,
Z₁, Z₂, Z₃, T₁₁, T₁₂, T₁₃, T₂₁, T₂₂, and T₂₃ may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), —P(Q₈)(Q₉), or a group represented by Formula 2,
b1, b2, and b3 may each independently be an integer from 0 to 10,
two or more of Z₁, Z₂, Z₃, T₁₁, T₁₂, T₁₃, T₂₁, T₂₂, and T₂₃ may optionally be linked to each other to form a substituted or unsubstituted C₅-C₃₀ carbocyclic group or a substituted or unsubstituted C₁-C₃₀ heterocyclic group,
at least one substituent of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group may each independently be:
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or any combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or any combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
any combination thereof, and
Q₁ to Q₉, Q₁₁ to Q₁₉, Q₂₁ to Q₂₉, and Q₃₁ to Q₃₉ may each independently be: hydrogen; deuterium; —F; or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, a cyano group, a C₁-C₆₀ alkyl group, a C₆-C₆₀ aryl group, or any combination thereof.

In an embodiment, ring Y₁, ring Y₂, and ring Y₃ in Formula 1 may each independently be a benzene group, a naphthalene group, a phenanthrene group, a pyridine group, a pyrimidine group, a pyridazine group, a pyrazine group, a quinoline group, an isoquinoline group, a dibenzofuran group, a dibenzothiophene group, a carbazole group, a fluorene group, a dibenzosilole group, an azadibenzofuran group, an azadibenzothiophene group, an azacarbazole group, an azafluorene group, or an azadibenzosilole group.

In an embodiment, ring Y₁, ring Y₂, and ring Y₃ may each independently be a benzene group, a naphthalene group, a dibenzofuran group, a dibenzothiophene group, a carbazole group, a fluorene group, or a dibenzosilole group.

In an embodiment, in Formula 1,
i) n1 may be 1, and n2 may be 0,
ii) n1 may be 0, and n2 may be 1, or
iii) n1 and n2 may each be 1.

In an embodiment, in Formula 1, n1 may be 1, and W₁ may be N(Ar₁) or N(T₁₁).

In one or more embodiments, in Formula 1, n2 may be 1, and W₂ may be N(Ar₂) or N(T₂₁).

In one or more embodiments, in Formula 1, n1 may be 1, W₁ may be N(Ar₁), and Ar₀ and Ar₁ may be identical to each other.

In one or more embodiments, in Formula 1, n1 may be 1, W₁ may be N(Ar₁), and Ar₀ and Ar₁ may be different from each other.

In one or more embodiments, in Formula 1, n2 may be 1, W₂ may be N(Ar₂), and Ar₀ and Ar₂ may be identical to each other.

In one or more embodiments, in Formula 1, n2 may be 1, W₂ may be N(Ar₂), and Ar₀ and Ar₂ may be different from each other.

In an embodiment, Z₁, Z₂, Z₃, T₁₁, T₁₂, T₁₃, T₂₁, T₂₂, and T₂₃ in Formula 1 may each independently be:
hydrogen, deuterium, —F, or a cyano group;
a C₁-C₂₀ alkyl group (e.g., C₁-C₂₀ linear alkyl group or C₃-C₂₀ branched alkyl group, C₁-C₁₀ linear alkyl group or C₃-C₁₀ branched alkyl group, or C₁-C₅ linear alkyl group or C₃-C₅ branched alkyl group), a phenyl group, a biphenyl group, a dibenzofuranyl group, a dibenzothiophenyl group, a carbazolyl group, a fluorenyl group, or a dibenzosilolyl group, each unsubstituted or substituted with deuterium, —F, a cyano group, a C₁-C₂₀ alkyl group, a phenyl group, a dibenzofuranyl group, a dibenzothiophenyl group, a carbazolyl group, a fluorenyl group, a dibenzosilolyl group, or any combination thereof; or
—N(Q₁)(Q₂), and
Q₁, Q₂, and Q₂ may each independently be a C₁-C₂₀ alkyl group, a phenyl group, a biphenyl group, a dibenzofuranyl group, a dibenzothiophenyl group, a carbazolyl group, a fluorenyl group, or a dibenzosilolyl group, each unsubstituted or substituted with deuterium, —F, a cyano group, a C₁-C₂₀ alkyl group, a phenyl group, a dibenzofuranyl group, a dibenzothiophenyl group, a carbazolyl group, a fluorenyl group, a dibenzosilolyl group, or any combination thereof.

In Formula 1, b1, b2, and b3 indicate the numbers of Z₁, Z₂, and Z₃, respectively, and b1, b2, and b3 may each independently be an integer from 0 to 10. When b1 is 2 or more, two or more of Z₁ may be identical to or different from each other, when b2 is 2 or more, two or more of Z₂ may be identical to or different from each other, and when b3 is 2 or more, two or more of Z₃ may be identical to or different from each other. For example, b1, b₂, and b3 may each independently be 0, 1, or 2.

In an embodiment, Formula 1 may satisfy at least one of Conditions 1 or 2:
Condition 1
b1 is 1 or more, and at least one of Z₁ in the number of b1 includes a carbazole group
Condition 2
b2 is 1 or more, and at least one of Z₂ in the number of b2 includes a carbazole group.

In an embodiment, Formula 1 may satisfy both Conditions 1 and 2.

In one or more embodiments, in Formula 1, b1 and b2 may each be 1 or more, and at least one of Z₁ or Z₂ may be a group represented by Formula 3(1):

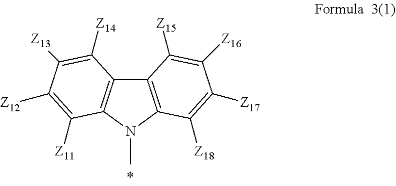

wherein, in Formula 3(1),
Z₁₁ to Z₁₈ may each independently be:
hydrogen, deuterium, —F, or a cyano group;
a C₁-C₂₀ alkyl group unsubstituted or substituted with deuterium, —F, a cyano group, or any combination thereof; or
a phenyl group unsubstituted or substituted with deuterium, —F, a cyano group, a C₁-C₂₀ alkyl group, a phenyl group, or any combination thereof, and
* indicates a binding site to Formula 1.

In an embodiment, Z₁₁ to Z₁₈ in Formula 3(1) may each be hydrogen or deuterium.

In one or more embodiments, at least one of Z₁₃ or Z₁₆ (e.g., Z₁₃ and Z₁₆) in Formula 3(1) may be:
a C₁-C₂₀ alkyl group unsubstituted or substituted with deuterium, —F, a cyano group, or any combination thereof (e.g., a tert-butyl group unsubstituted or substituted with deuterium); or
a phenyl group unsubstituted or substituted with deuterium, —F, a cyano group, a C₁-C₂₀ alkyl group, a phenyl group, or any combination thereof.

In one or more embodiments, at least one of Z₁₁ to Z₁₈ in Formula 3(1) may each independently be: deuterium; or a first group substituted with at least one deuterium, and the first group may be:
a C₁-C₂₀ alkyl group unsubstituted or substituted with —F, a cyano group, or any combination thereof; or
a phenyl group unsubstituted or substituted with —F, a cyano group, a C₁-C₂₀ alkyl group, a phenyl group, or any combination thereof.

The term “first group substituted with at least one deuterium” as used herein refers to a substituent of the first group, in which at least one hydrogen is substituted with deuterium. For example, the “first group substituted with at least one deuterium” may be —CD₃, —CD₂H, —CDH₂, —CD₂F, —C(CD₃)₃, —C₆D₅, —C₆D₂H₃, —C₆D₄(CH₃), —C₆H₄(CD₃), —C₆D₄(CD₃), —C₆F₄(CD₃), —C₆D₄(C₆H₅), or the like.

In an embodiment, in Formula 1, b1 and b2 may each be 1, and Z₁ and Z₂ may each be an N-carbazolyl group unsubstituted or substituted with deuterium, —F, a cyano group, a C₁-C₂₀ alkyl group, a phenyl group, or any combination thereof.

The term “N-carbazolyl group” as used herein refers to a monovalent group in which hydrogen may be separated from N in the carbazole group and bonded to another group via said N, and is indicated as

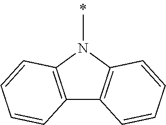

(wherein * indicates a binding site to a neighboring atom).

In one or more embodiments, in Formula 1, b3 may be 1 or more, and at least one of Z₃ in the number of b3 may be a C₁-C₆₀ alkyl group (e.g., a C₁-C₂₀ alkyl group) unsubstituted or substituted with deuterium, —F, a cyano group, or any combination thereof.

In one or more embodiments, in Formula 1, b3 may be 1 or more (e.g., 1), and at least one of Z₃ in the number of b3 may be a tert-butyl group unsubstituted or substituted with deuterium.

In Formula 1, two or more of Z₁, Z₂, Z₃, T₁₁, T₁₂, T₁₃, T₂₁, T₂₂, and T₂₃ may optionally be linked to each other to form a substituted or unsubstituted C₅-C₃₀ carbocyclic group or a substituted or unsubstituted C₁-C₃₀ heterocyclic group.

In an embodiment, in Formula 1, two or more of Z₁, Z₂, Z₃, T₁₁, T₁₂, T₁₃, T₂₁, T₂₂, and T₂₃ may be linked to each other to form a substituted or unsubstituted C₅-C₃₀ carbocyclic group or a substituted or unsubstituted C₁-C₃₀ heterocyclic group. As a result, the condensed cyclic compound may be represented, for example, by Formula 1-1, 1-2, or 1-3:

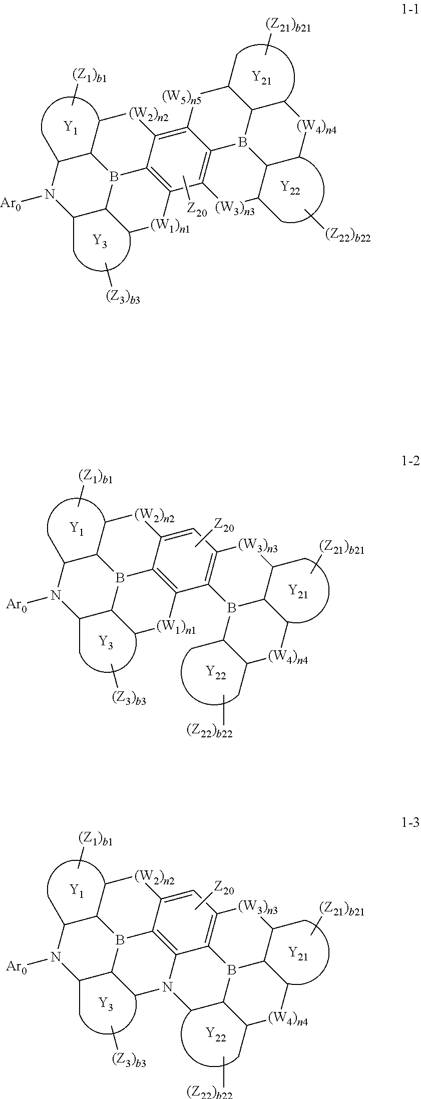

wherein, in Formulae 1-1, 1-2, and 1-3,
Ar₀, ring Y₁, ring Y₃, W₁, W₂, n1, n2, Z₁, Z₃, b1, and b3 may each be the same as described herein,
ring Y₂₁ and ring Y₂₂ may each independently be a C₅-C₆₀ carbocyclic group or a C₃-C₆₀ heterocyclic group,
W₃ may be a single bond, O, S, N(Ar₃), N(T₃₁), C(T₃₂)(T₃₃), or Si(T₃₂)(T₃₃),
W₄ may be a single bond, O, S, N(Ar₄), N(T₄₁), C(T₄₂)(T₄₃), or Si(T₄₂)(T₄₃),
W₅ may be a single bond, O, S, N(Ar₅), N(T₅₁), C(T₅₂)(T₅₃), or Si(T₅₂)(T₅₃),
n3, n4, and n5 may each independently be 0 or 1,
when n3 is 0, *—(W₃)ₙ₃—*′ may not be present,
when n4 is 0, *—(W₄)ₙ₄—*′ may not be present,
when n5 is 0, *—(W₅)ₙ₅—*′ may not be present,
the sum of n1 and n2 in Formulae 1-1 and 1-2 may be 1 or more,
the sum of n3, n4, and n5 in Formula 1-1 may be 1 or more,
the sum of n3 and n4 in Formulae 1-2 and 1-3 may be 1 or more,
Ar₃, Ar₄, and Ar₅ may each be a group represented by Formula 2,
Z₂₀, Z₂₁, and Z₂₂ may each be the same as described herein in connection with Z₂, and b21 and b22 may each independently be an integer from 0 to 5.
Ring Y₂₁ and ring Y₂₂ may each be the same as described herein in connection with ring Y₁.

In an embodiment, the emitter may include at least one deuterium, at least one tert-butyl group, or any combination thereof.

In one or more embodiments, the condensed cyclic compound represented by Formula 1 may have a symmetric structure.

In one or more embodiments, the condensed cyclic compound represented by Formula 1 may have an asymmetric structure.

In one or more embodiments, the emitter may be a compound represented by Formula 1A:

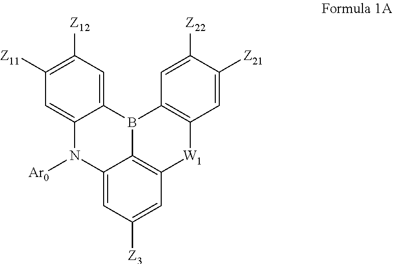

wherein, in Formula 1A,
W₁ may be O, S, N(Ar₁), N(T₁₁), C(T₁₂)(T₁₃), or Si(T₁₂)(T₁₃),
Ar₀, Ar₁, Z₃, and T₁₁ to T₁₃ may each be the same as described herein,
Z₁₁ and Z₁₂ may each be the same as described herein in connection with Z₁, and
Z₂₁ and Z₂₂ may each be the same as described herein in connection with Z₂.

In an embodiment, Formula 1A may satisfy at least one of Conditions 3 to 5:
Condition 3
at least one of Z₁₁ and Z₁₂ is an N-carbazolyl group unsubstituted or substituted with deuterium, —F, a cyano group, a C₁-C₂₀ alkyl group, a phenyl group, or any combination thereof
Condition 4
at least one of Z₂₁ and Z₂₂ is an N-carbazolyl group unsubstituted or substituted with deuterium, —F, a cyano group, a C₁-C₂₀ alkyl group, a phenyl group, or any combination thereof
Condition 5
Z₃ is a C₁-C₂₀ alkyl group unsubstituted or substituted with deuterium, —F, a cyano group, or any combination thereof (e.g., a tert-butyl group unsubstituted or substituted with deuterium).

In an embodiment, in Formula 1A, Z₁₁ and Z₂₁ may each be an N-carbazolyl group unsubstituted or substituted with deuterium, —F, a cyano group, a C₁-C₂₀ alkyl group, a phenyl group, or any combination thereof, and Z₁₂ and Z₂₂ may each be hydrogen or deuterium.

In one or more embodiments, in Formula 1A, Z₁₂ and Z₂₂ may each be an N-carbazolyl group unsubstituted or substituted with deuterium, —F, a cyano group, a C₁-C₂₀ alkyl group, a phenyl group, or any combination thereof, and Z₁₁ and Z₂₁ may each be hydrogen or deuterium. In one or more embodiments, in Formula 1A, Z₃ may be a C₁-C₂₀ alkyl group (e.g., C₃-C₂₀ branched alkyl group or C₃-C₁₀ branched alkyl group) unsubstituted or substituted with deuterium, —F, a cyano group, or any combination thereof (e.g., a tert-butyl group unsubstituted or substituted with deuterium).

In one or more embodiments, the emitter (or the condensed cyclic compound represented by Formula 1) may include a C₃-C₂₀ branched alkyl group (e.g., C₃-C₁₀ branched alkyl group such as a tert-butyl group) unsubstituted or substituted with deuterium. For example, the number of C₃-C₂₀ branched alkyl groups (e.g., C₃-C₁₀ branched alkyl groups such as tert-butyl groups), each unsubstituted or substituted with deuterium, included in the emitter (or the condensed cyclic compound represented by Formula 1) may be in a range of about 1 to about 15, for example, about 2 to about 15, about 2 to about 10, about 2 to about 9, or about 2 to about 5.

In one or more embodiments, the emitter (or the condensed cyclic compound represented by Formula 1) may be a multiple resonance thermally activated delayed fluorescence material.

In one or more embodiments, the emitter (or the condensed cyclic compound represented by Formula 1) may be one of Compounds 1 to 90 and compounds in which at least one hydrogen of Compounds 1 to 90 is substituted with deuterium (e.g., Compounds 91, 92, 93, etc.):

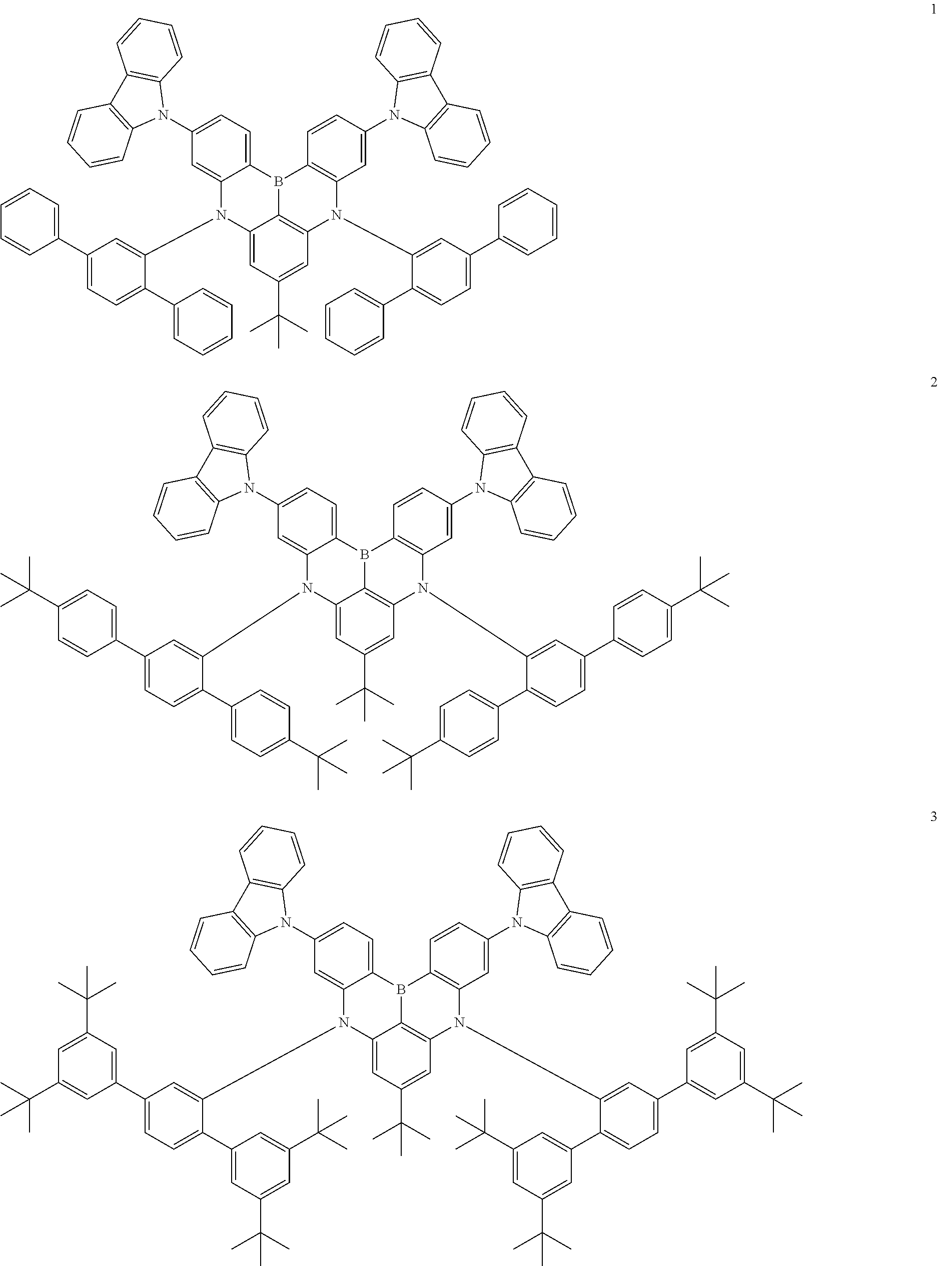

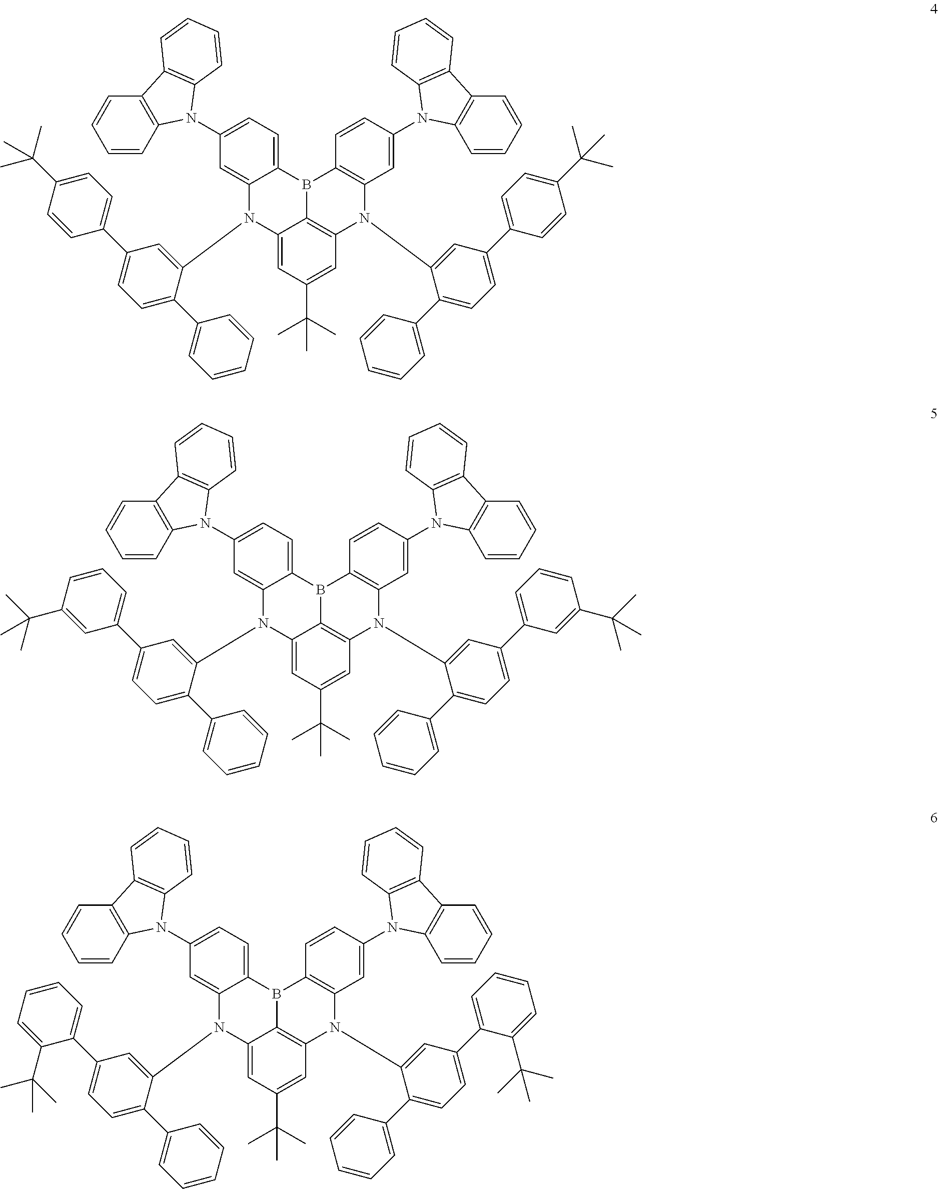

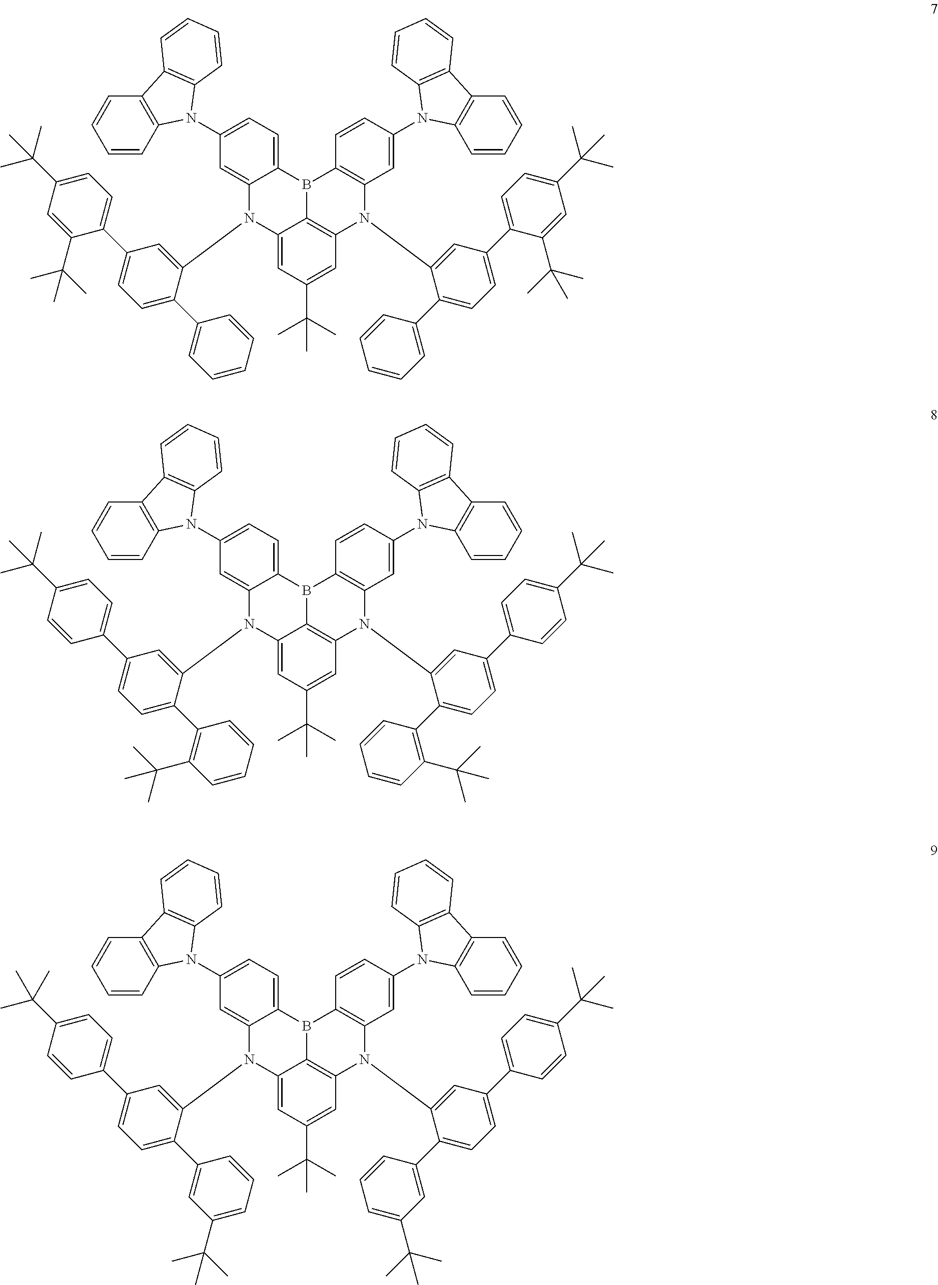

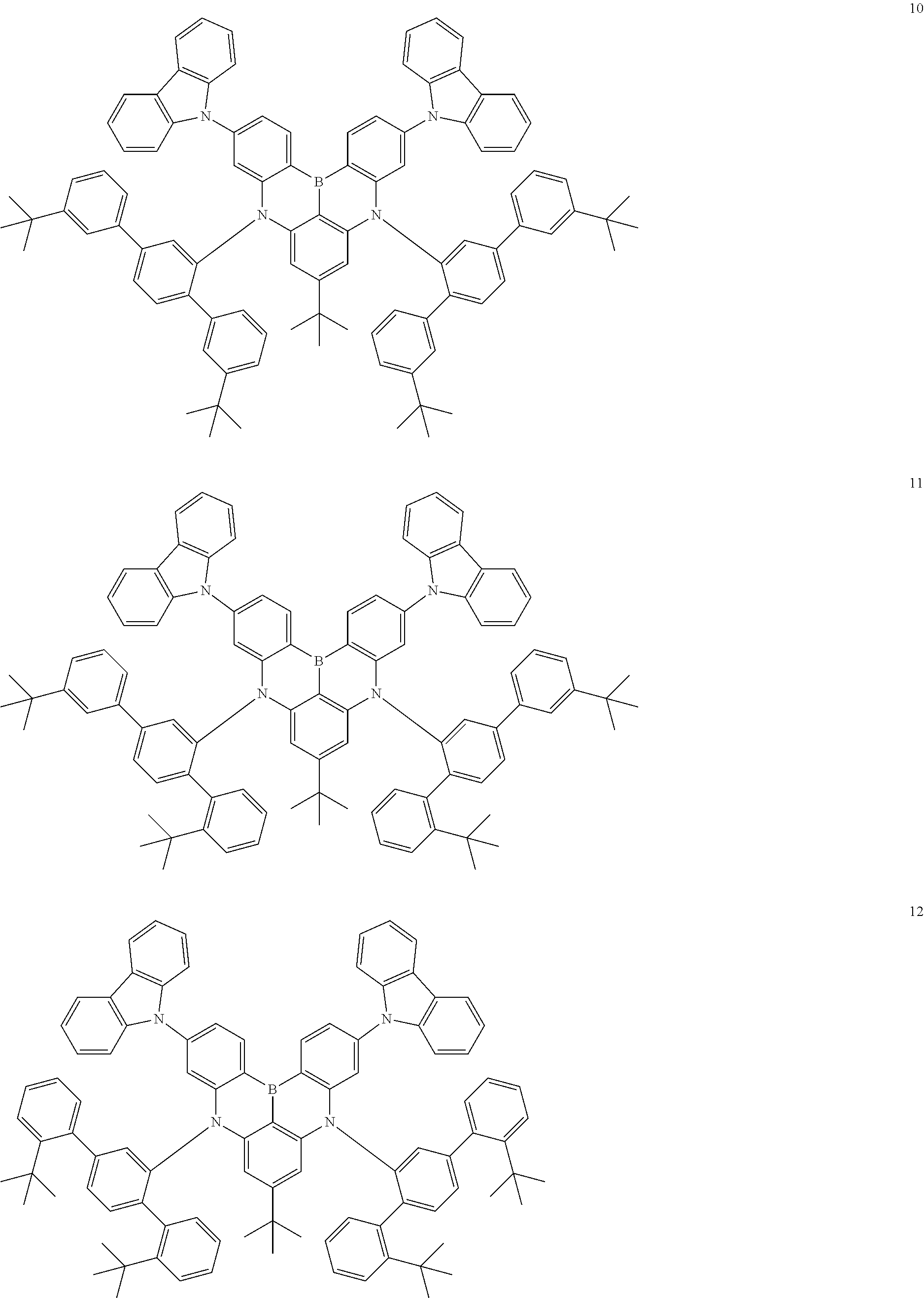

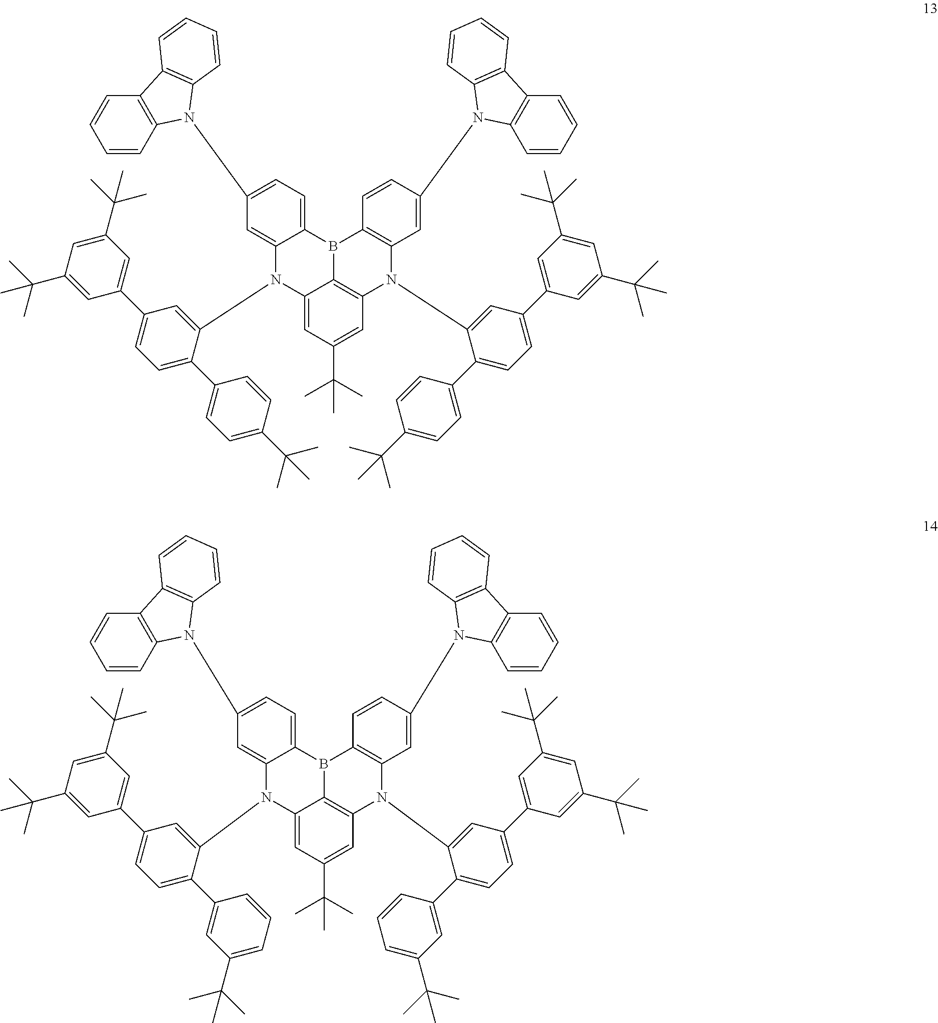

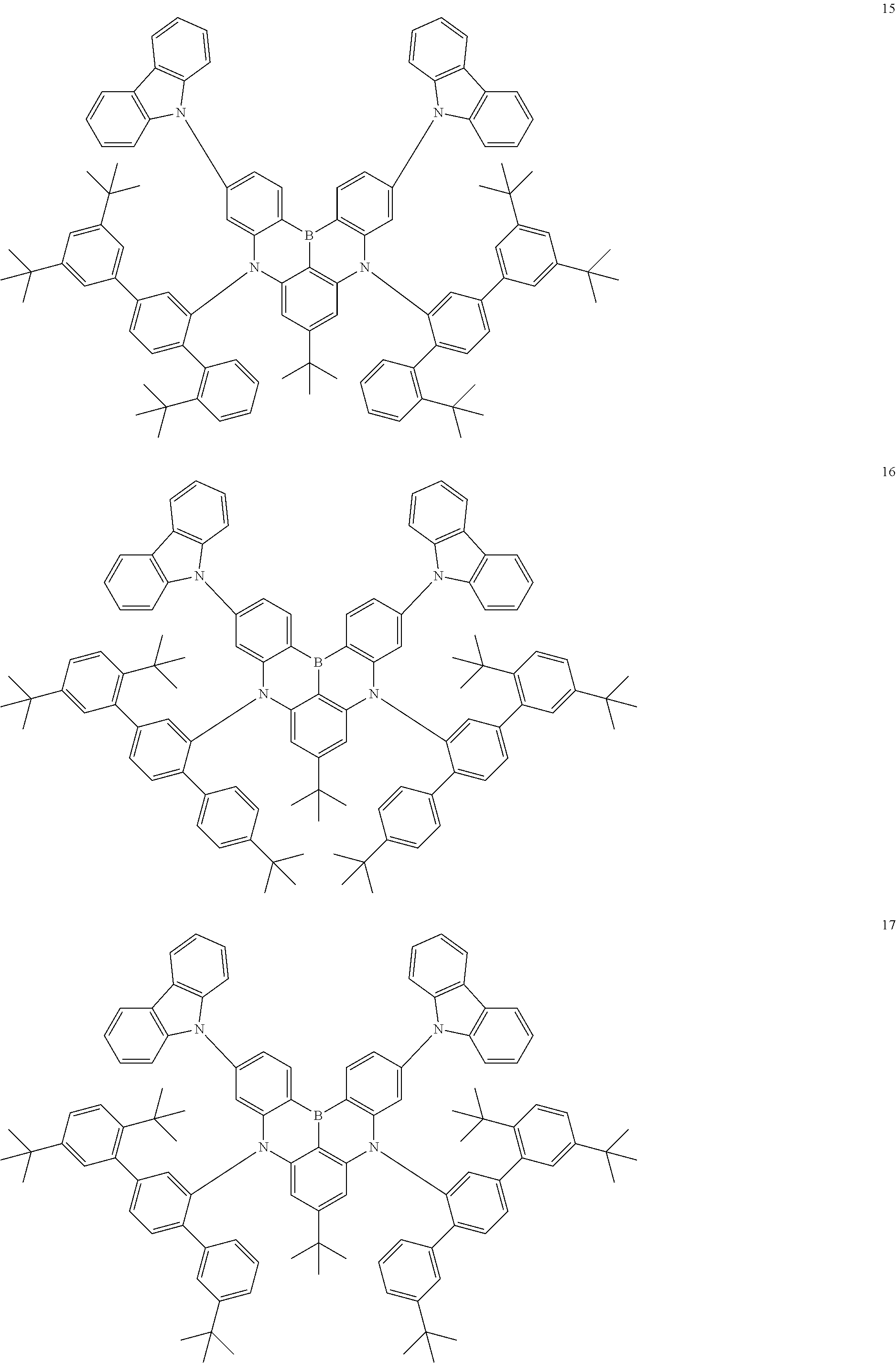

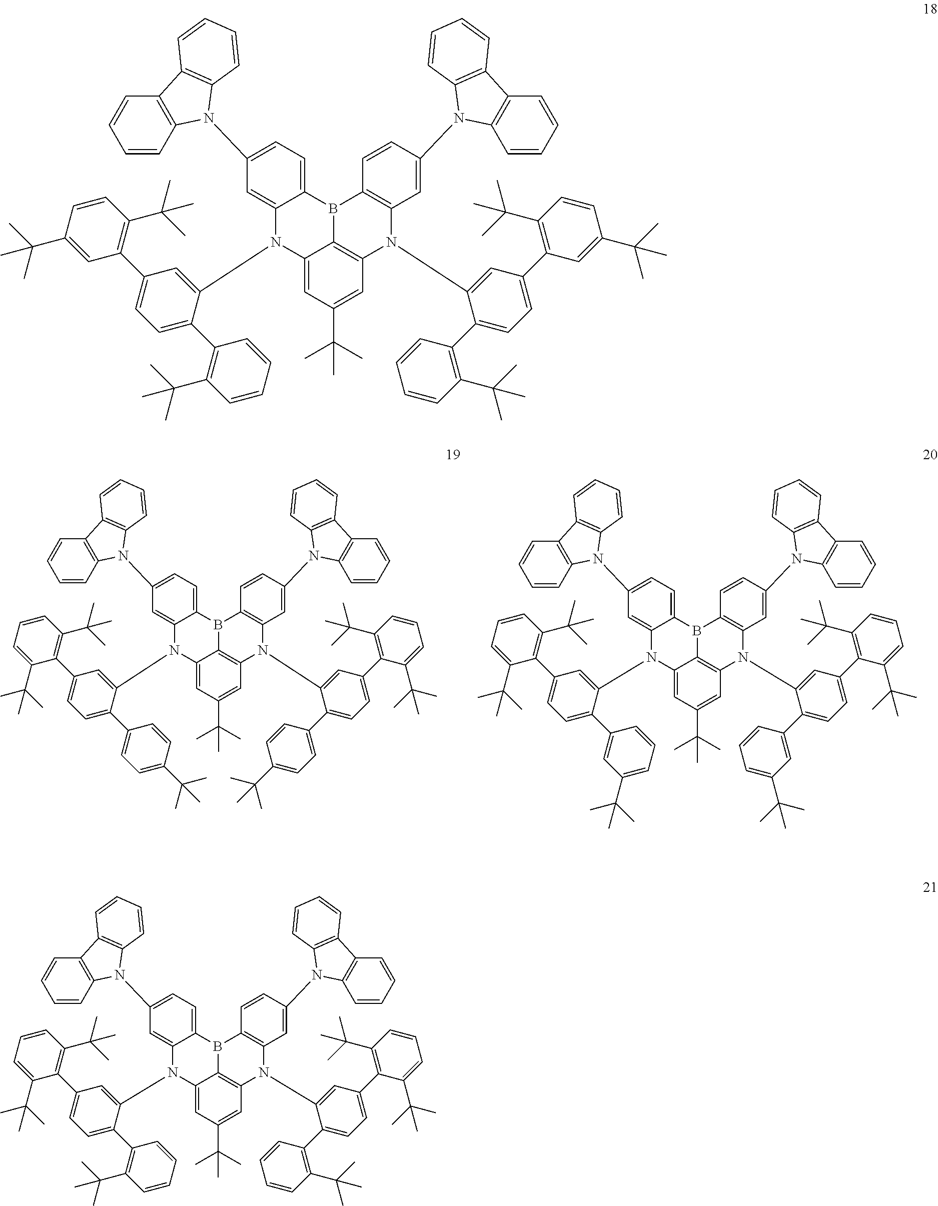

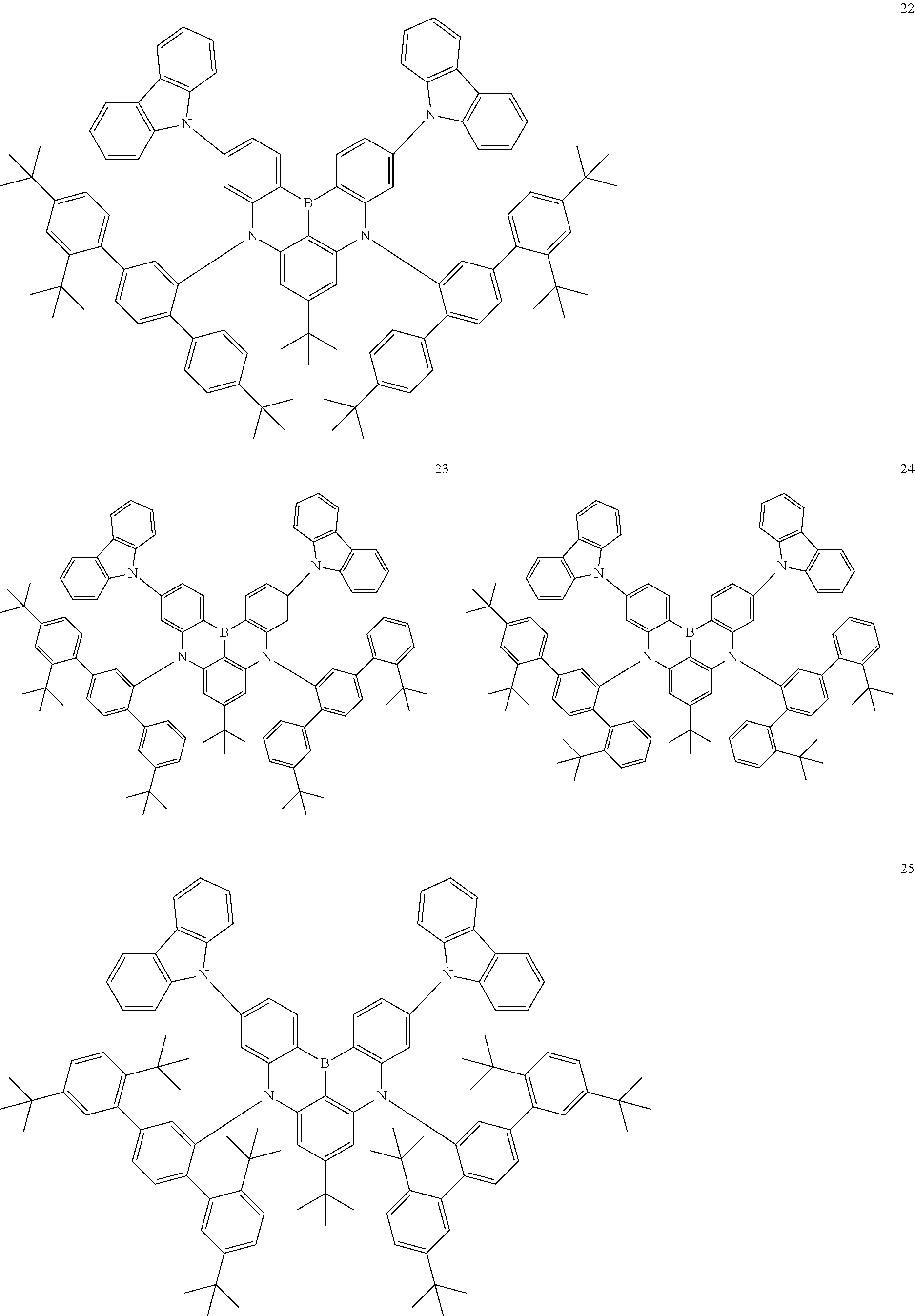

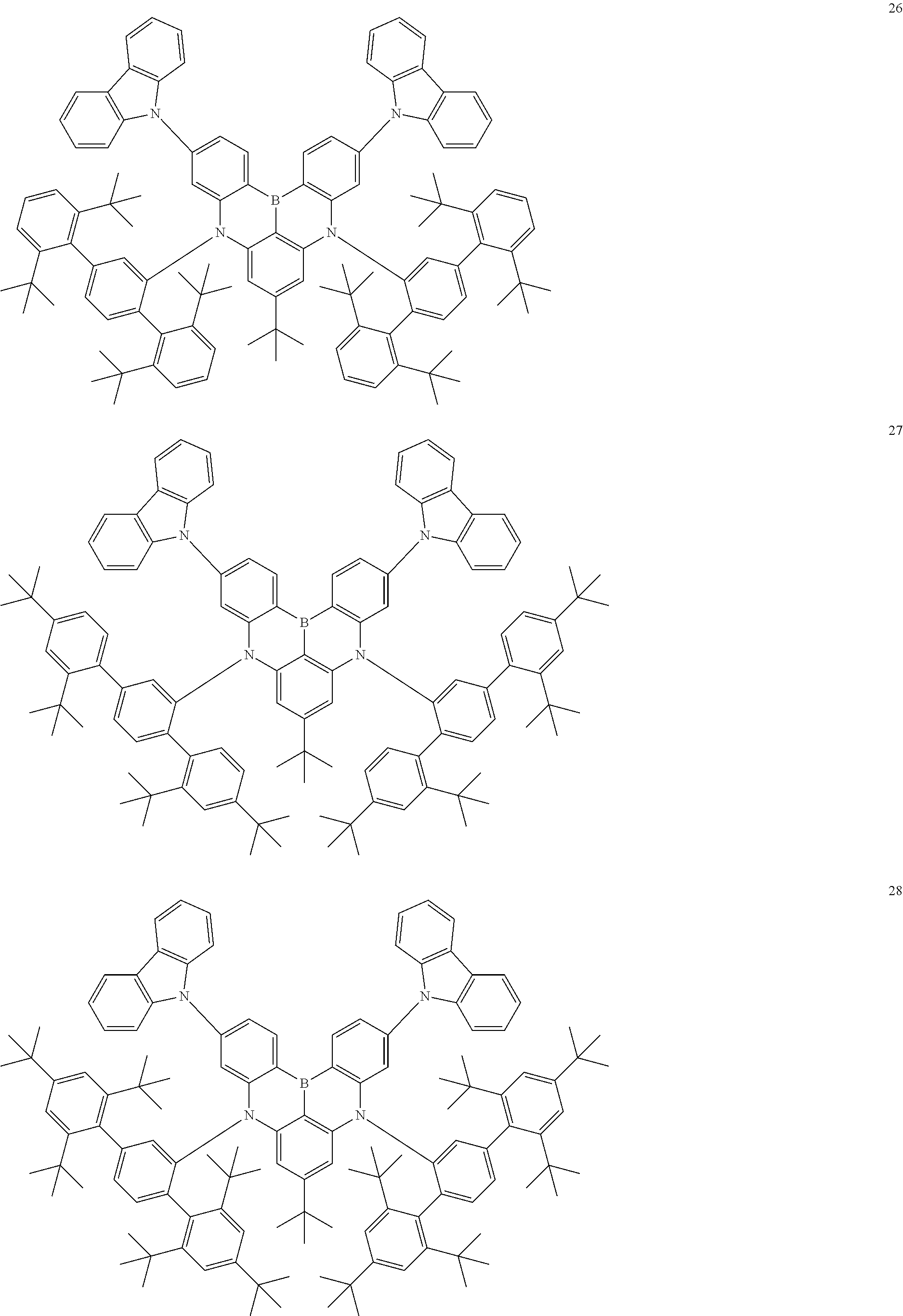

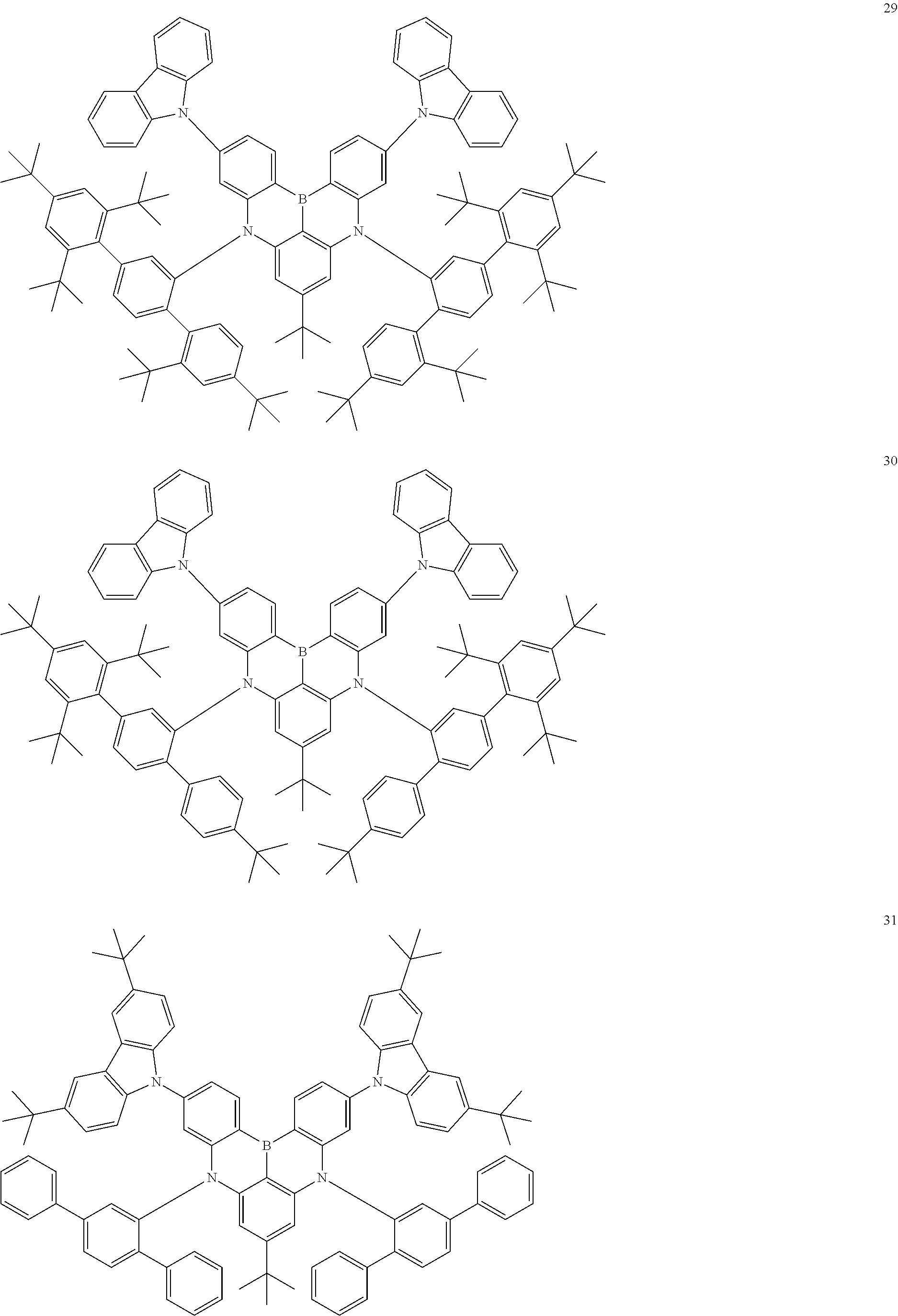

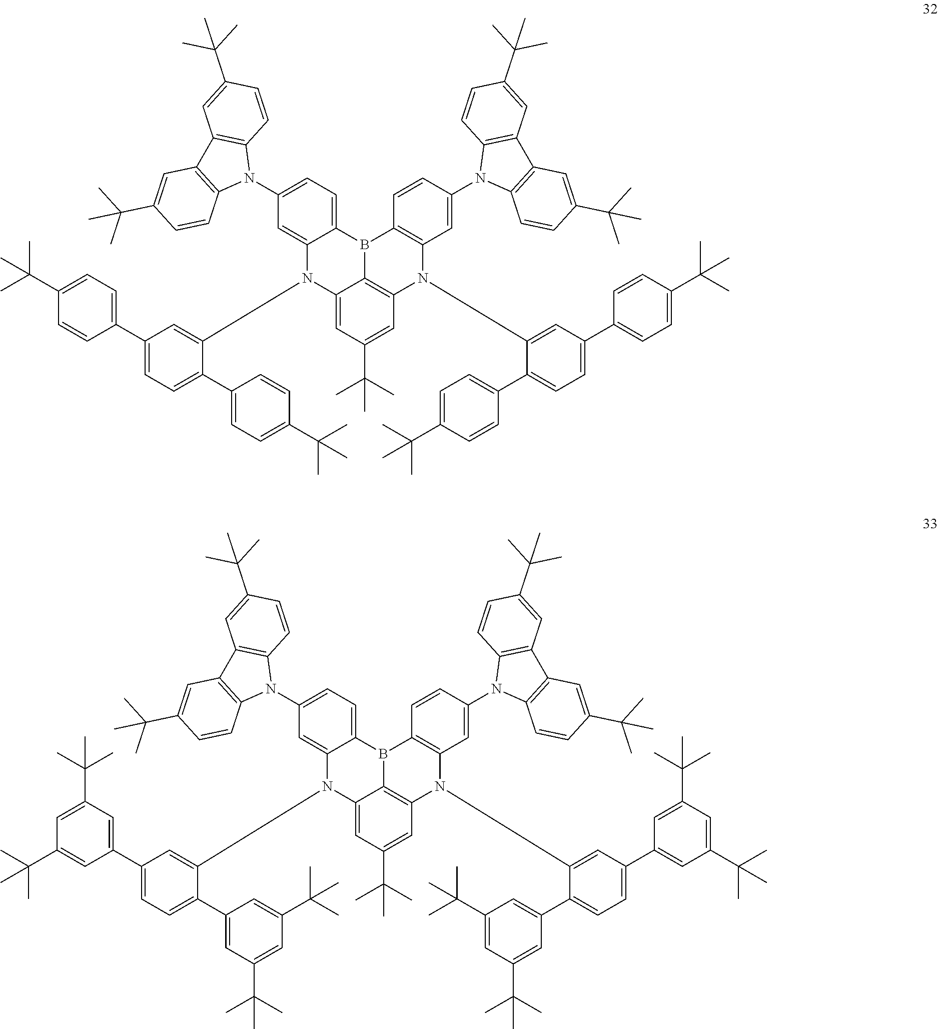

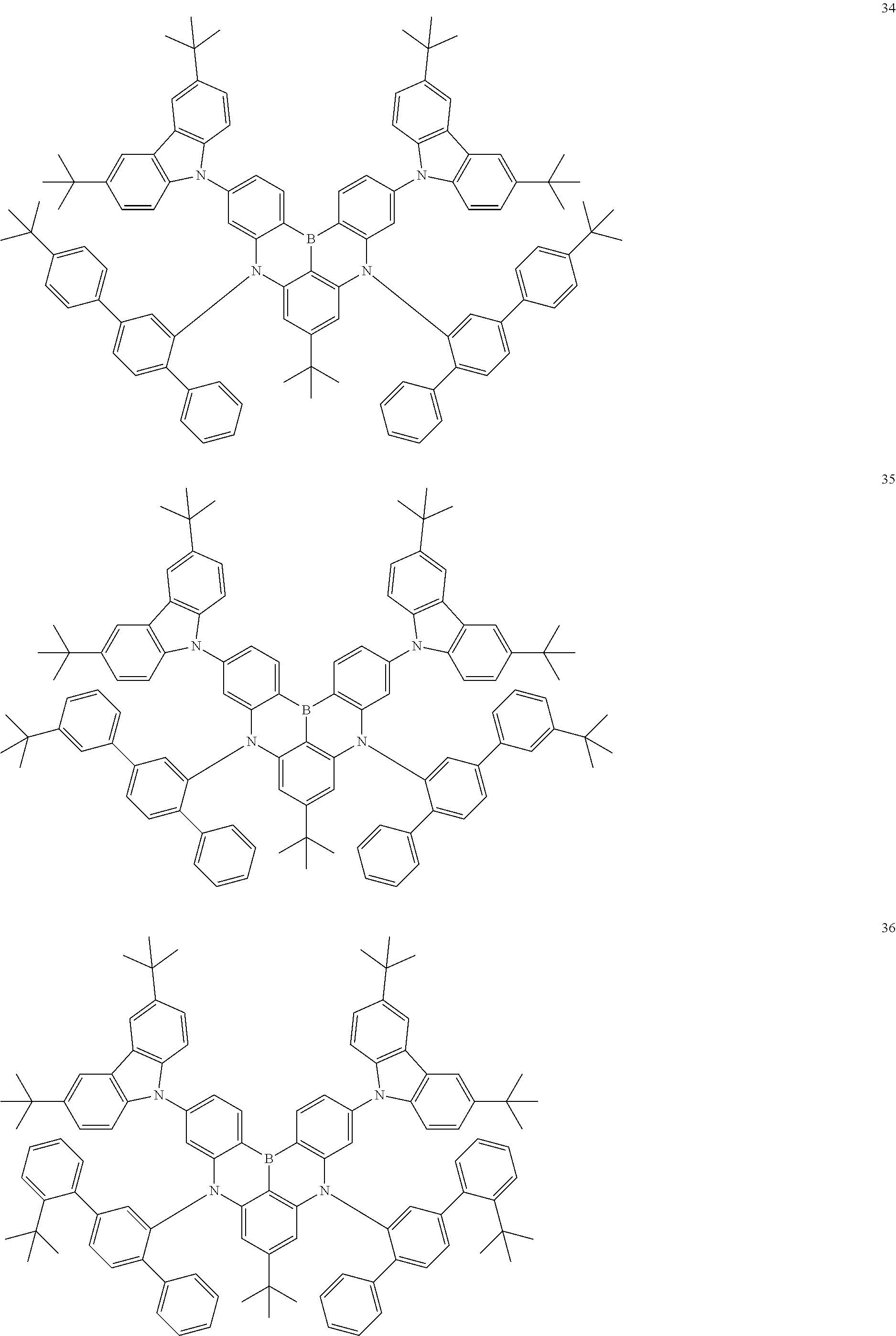

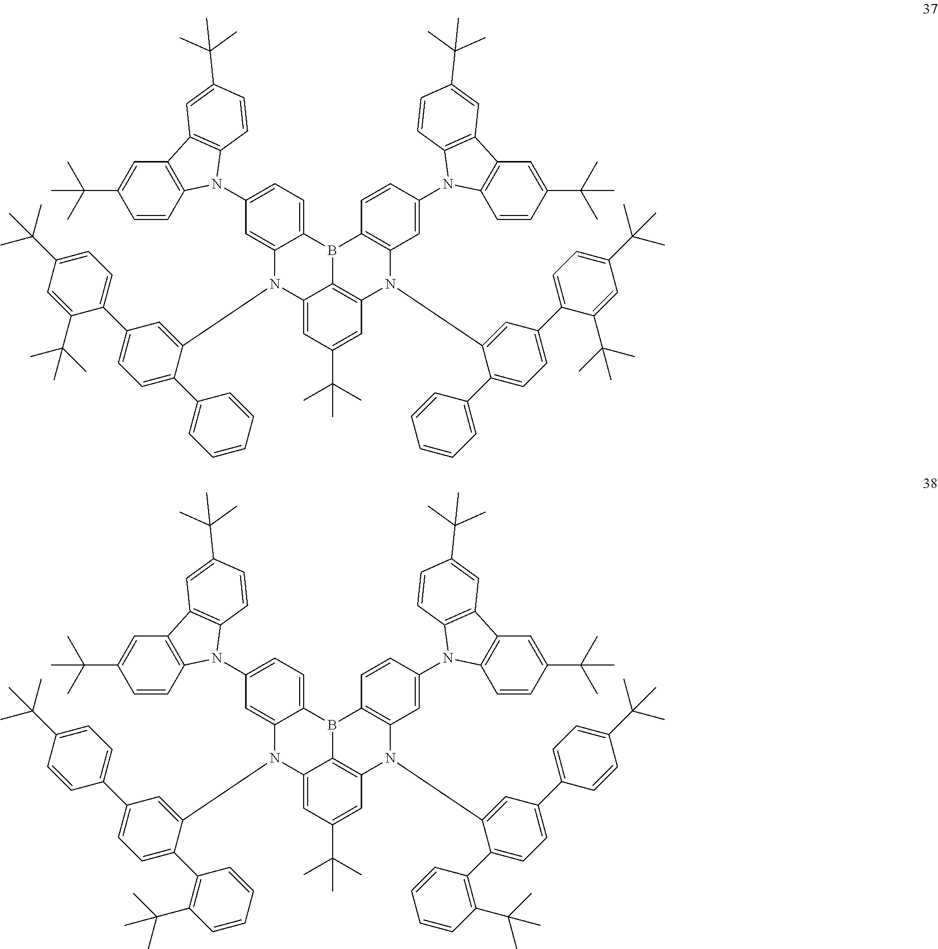

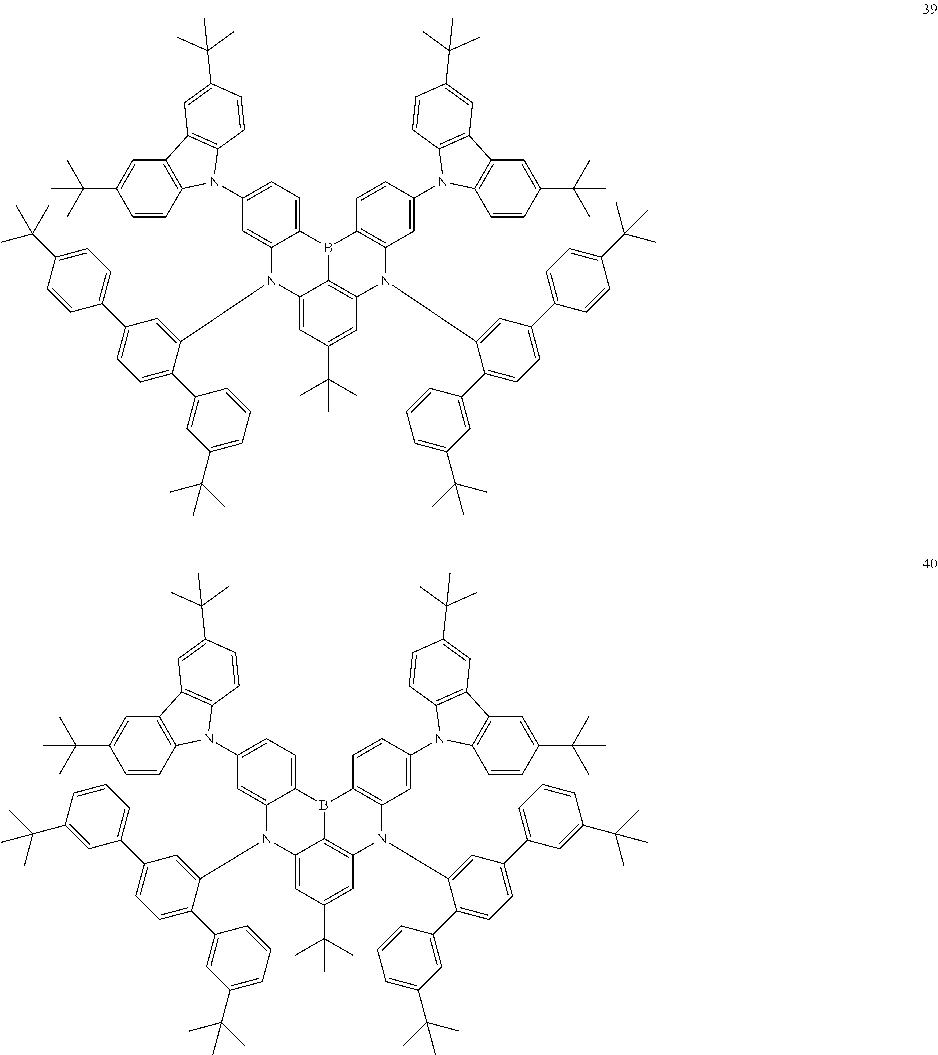

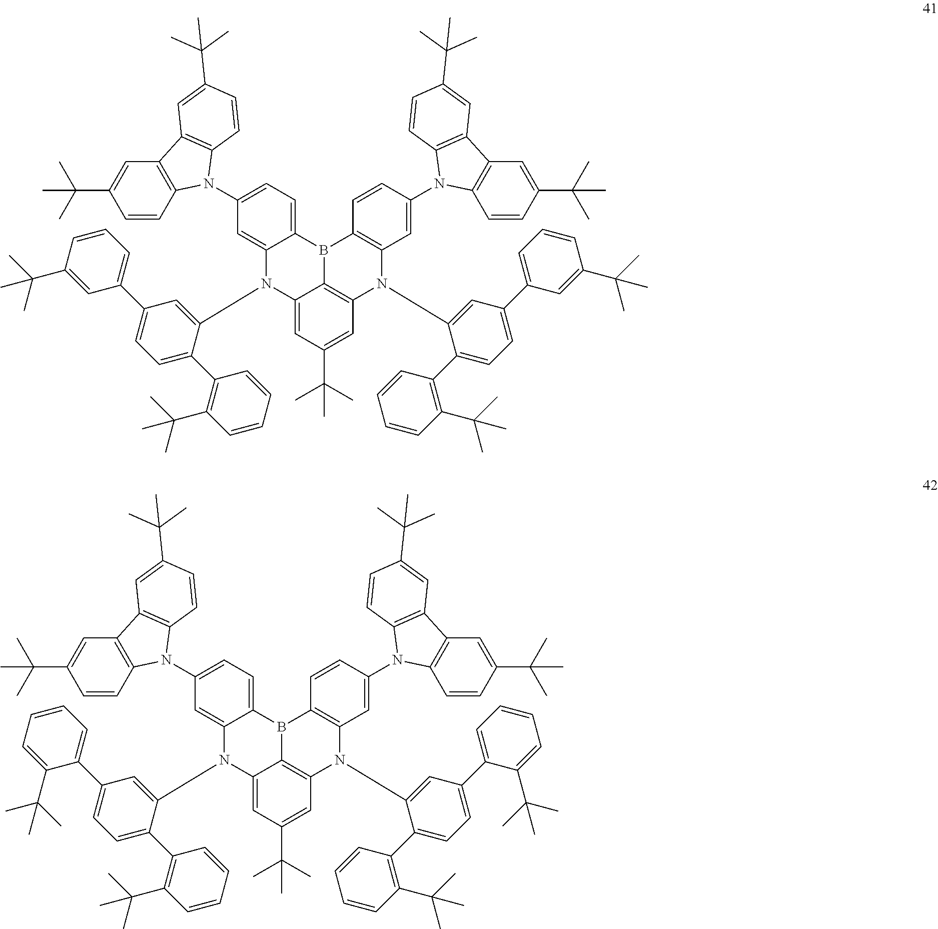

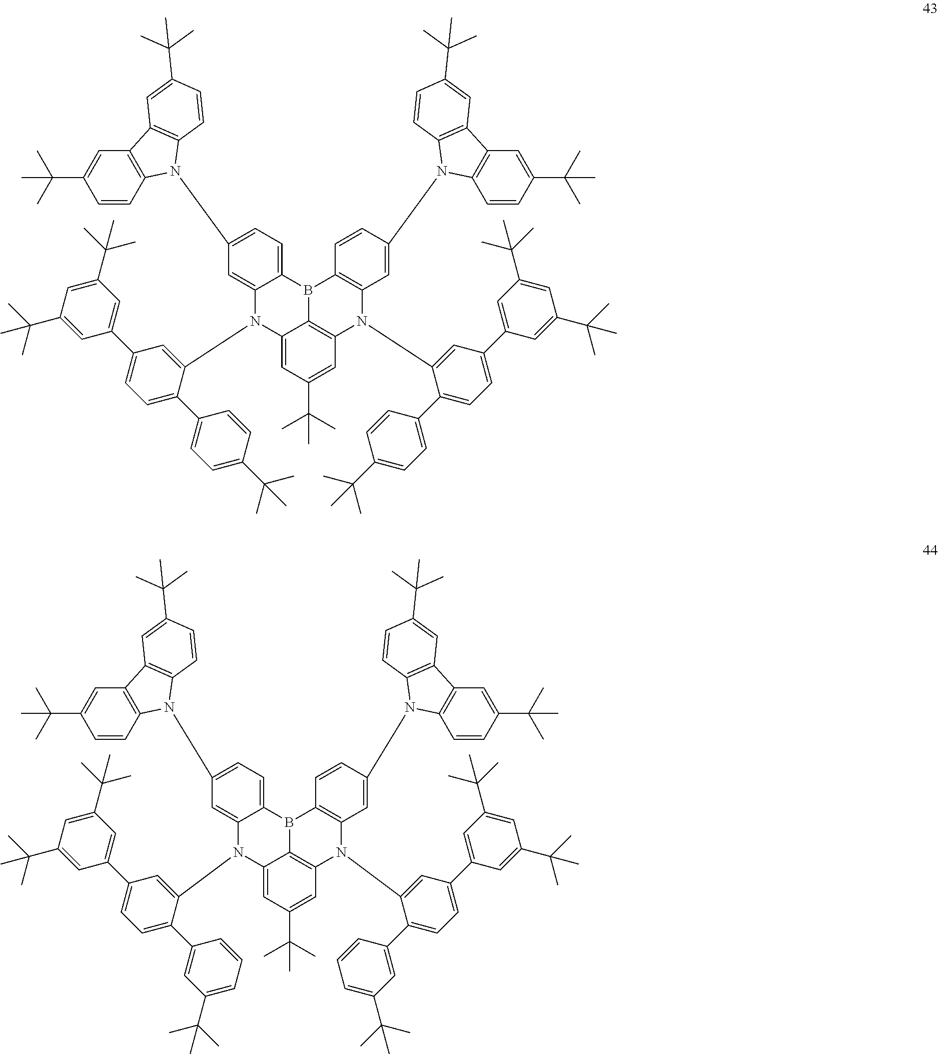

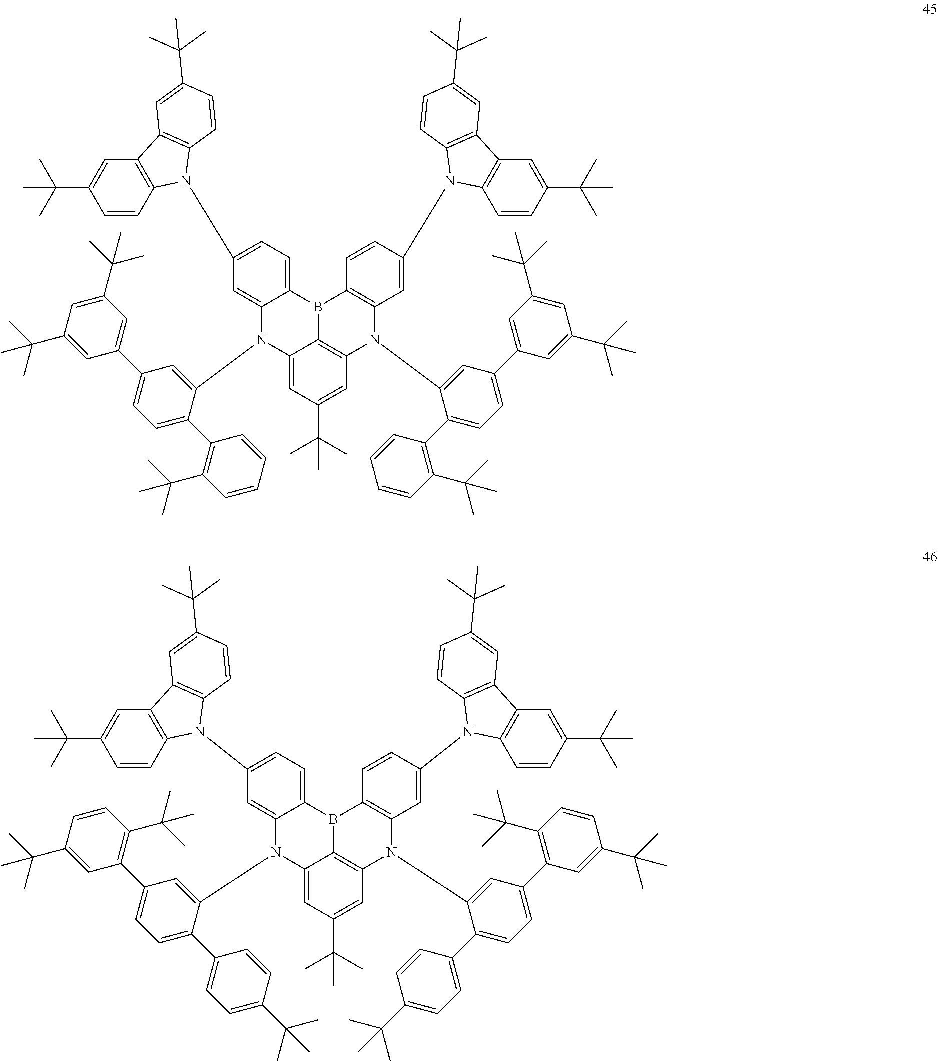

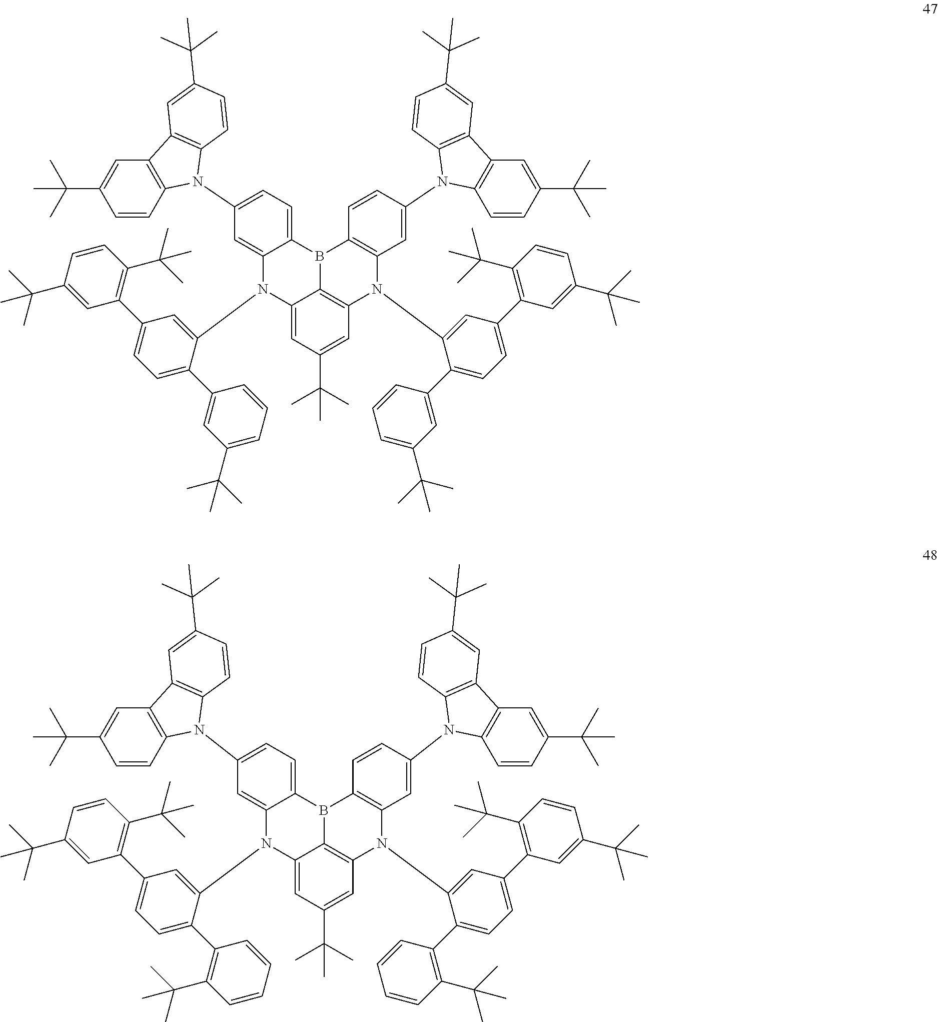

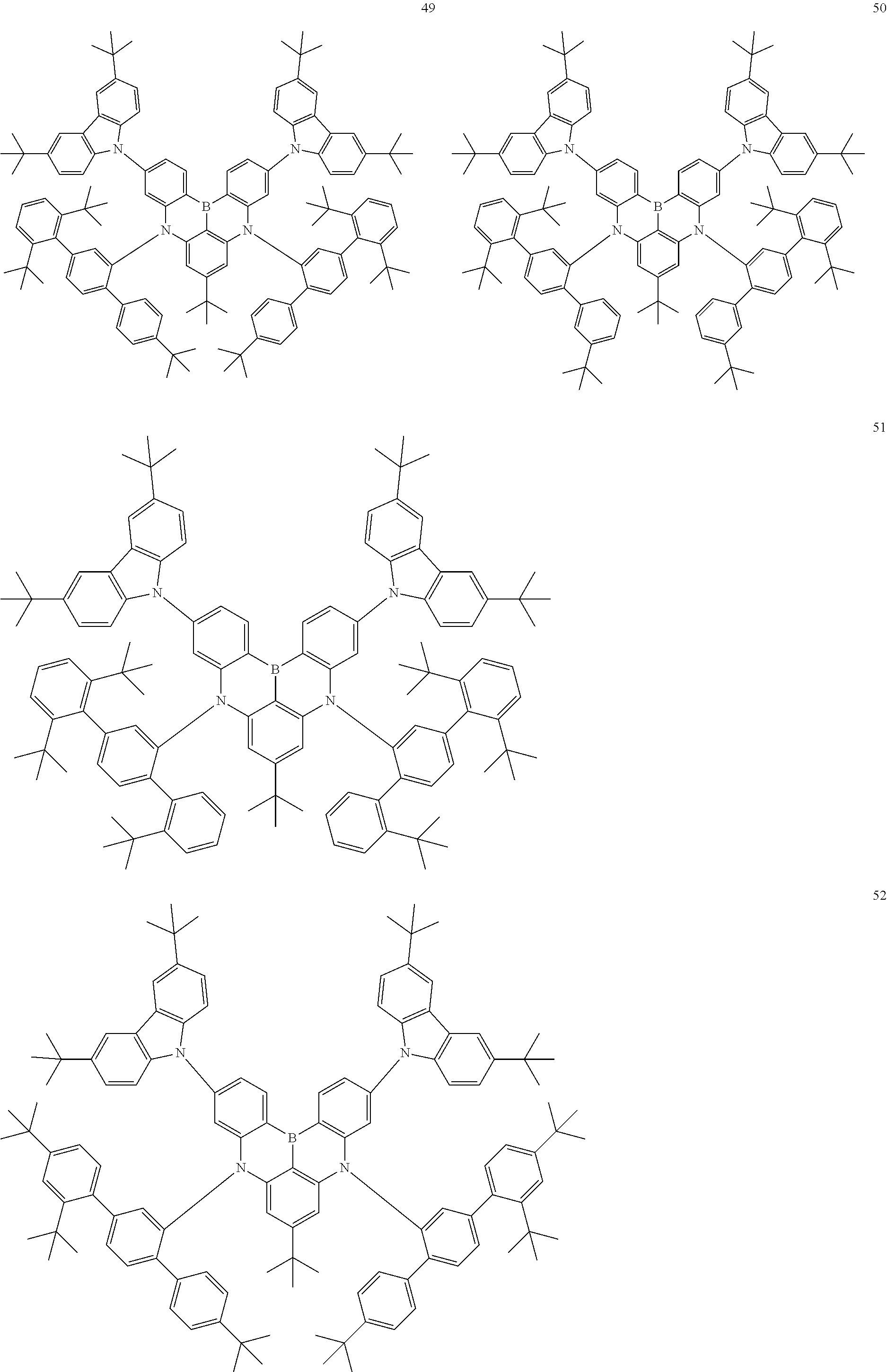

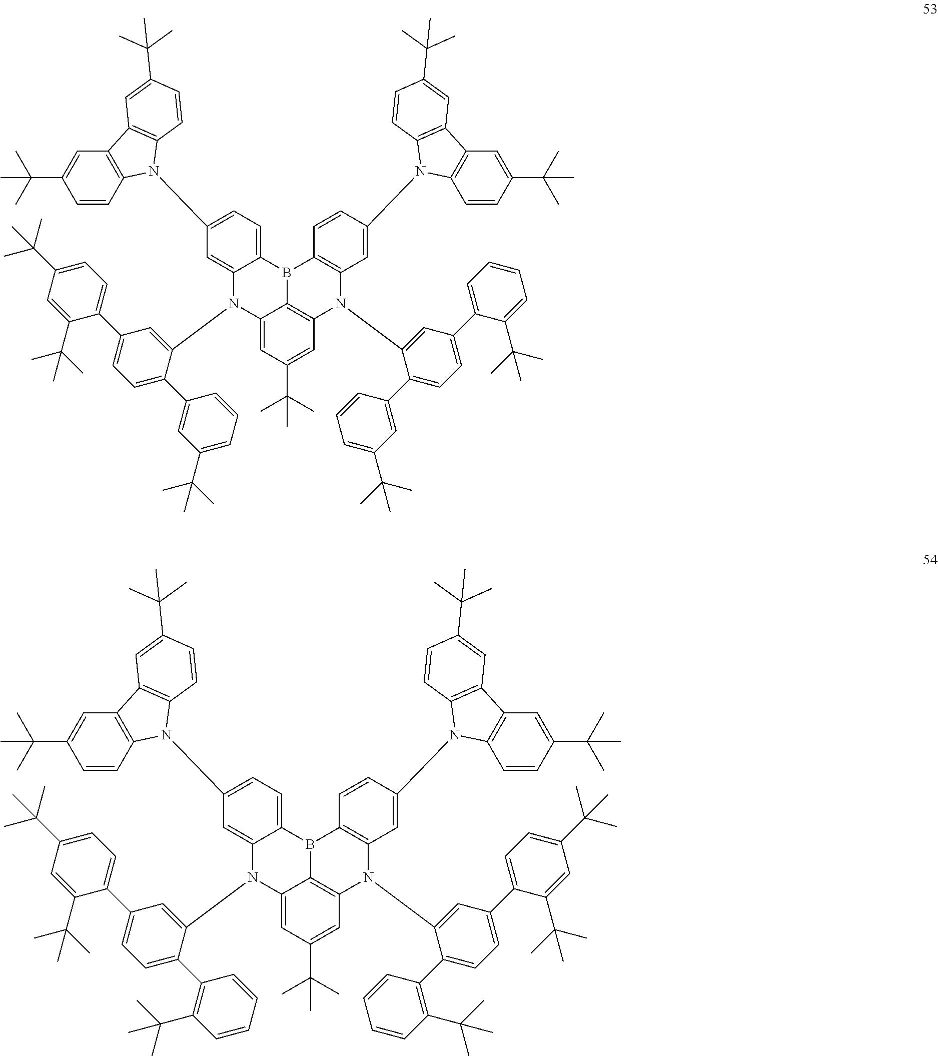

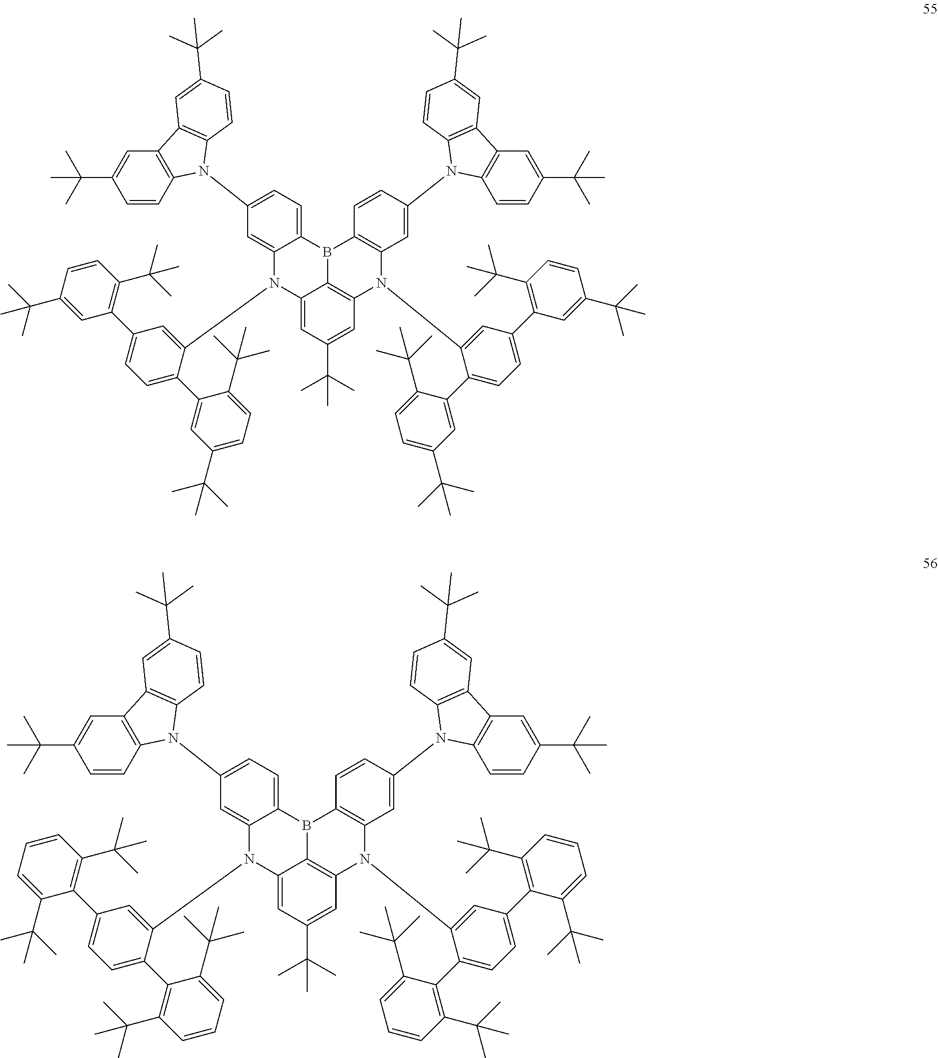

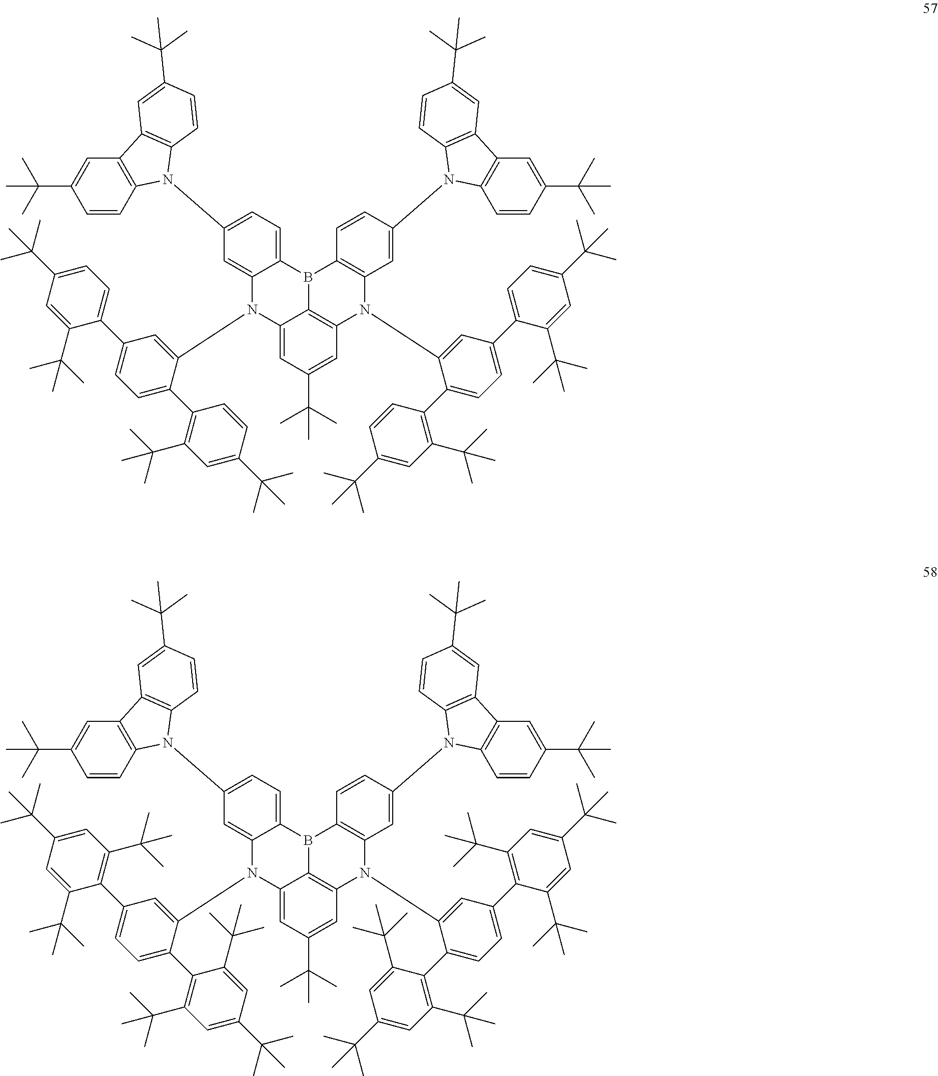

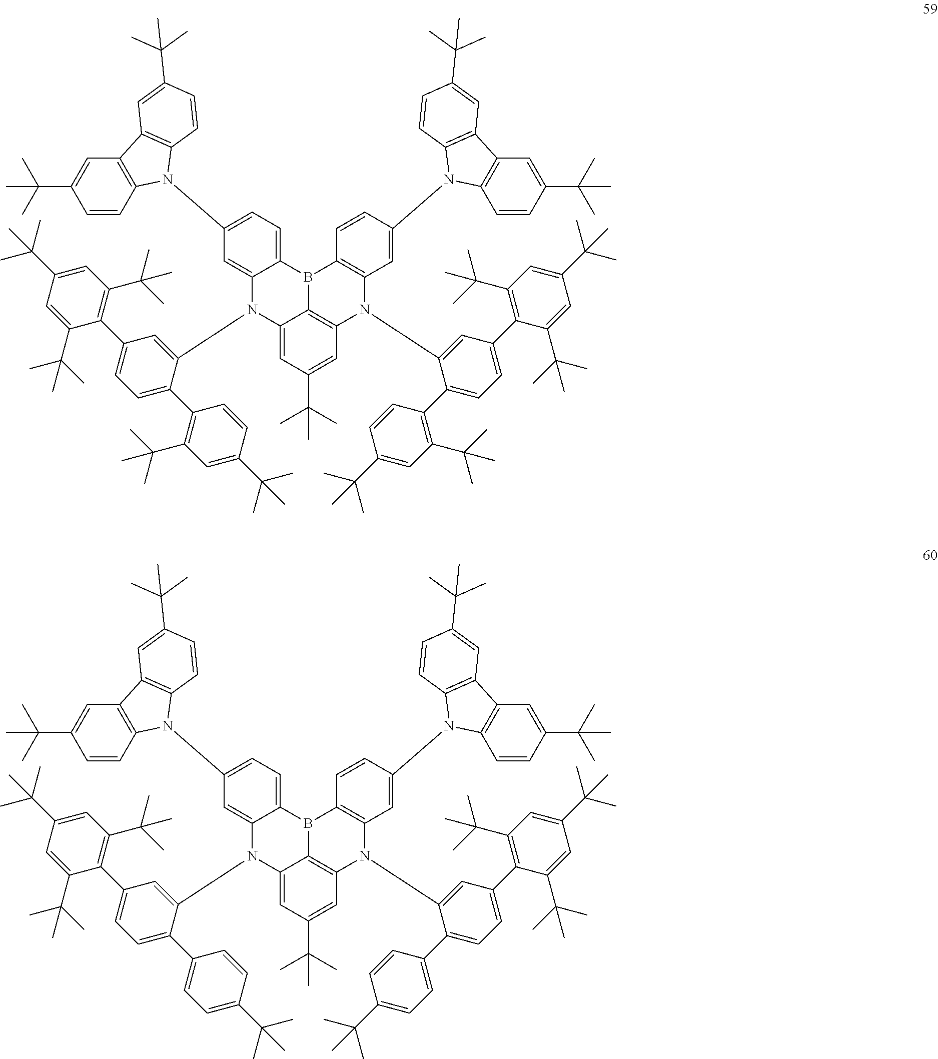

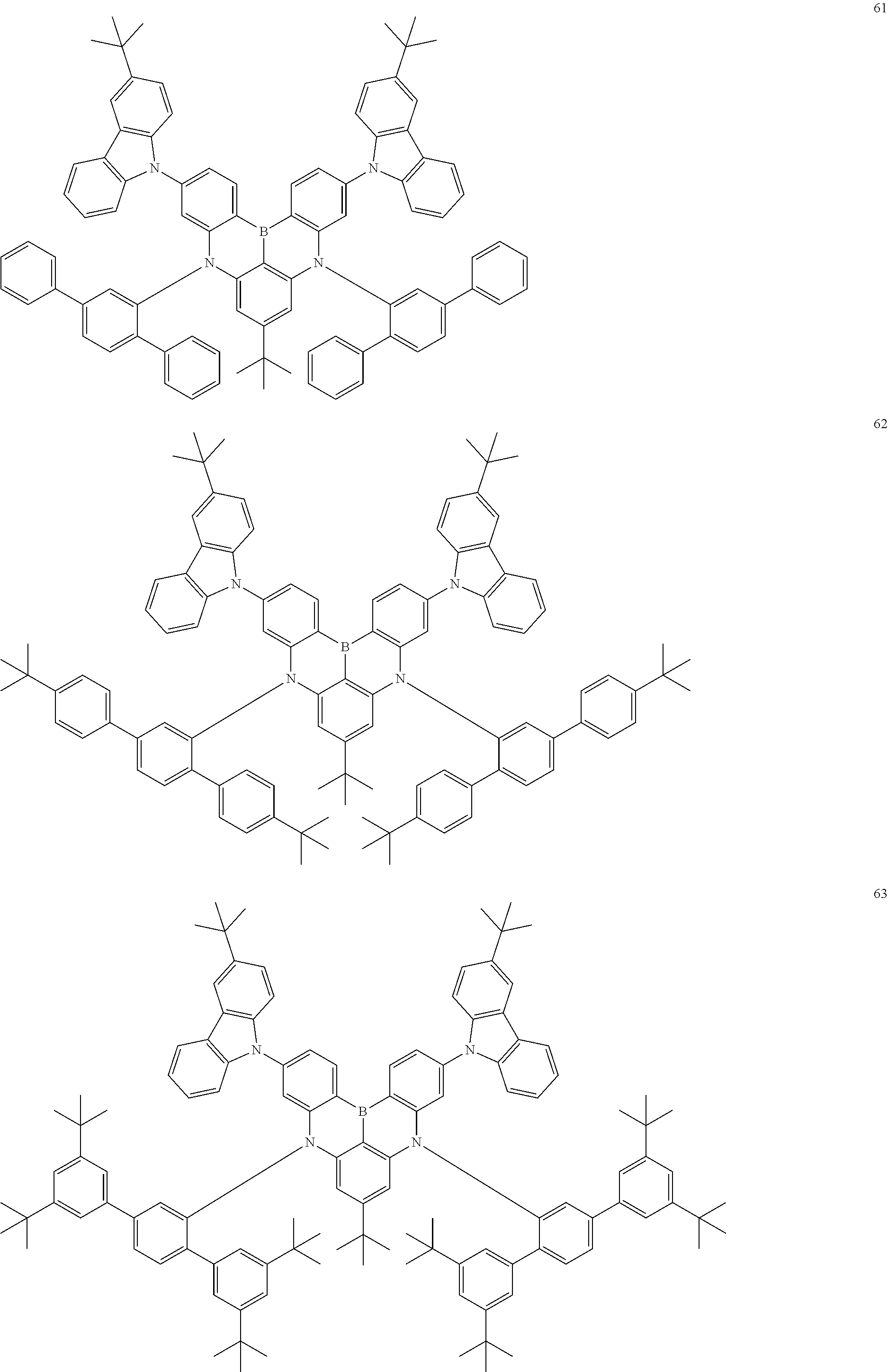

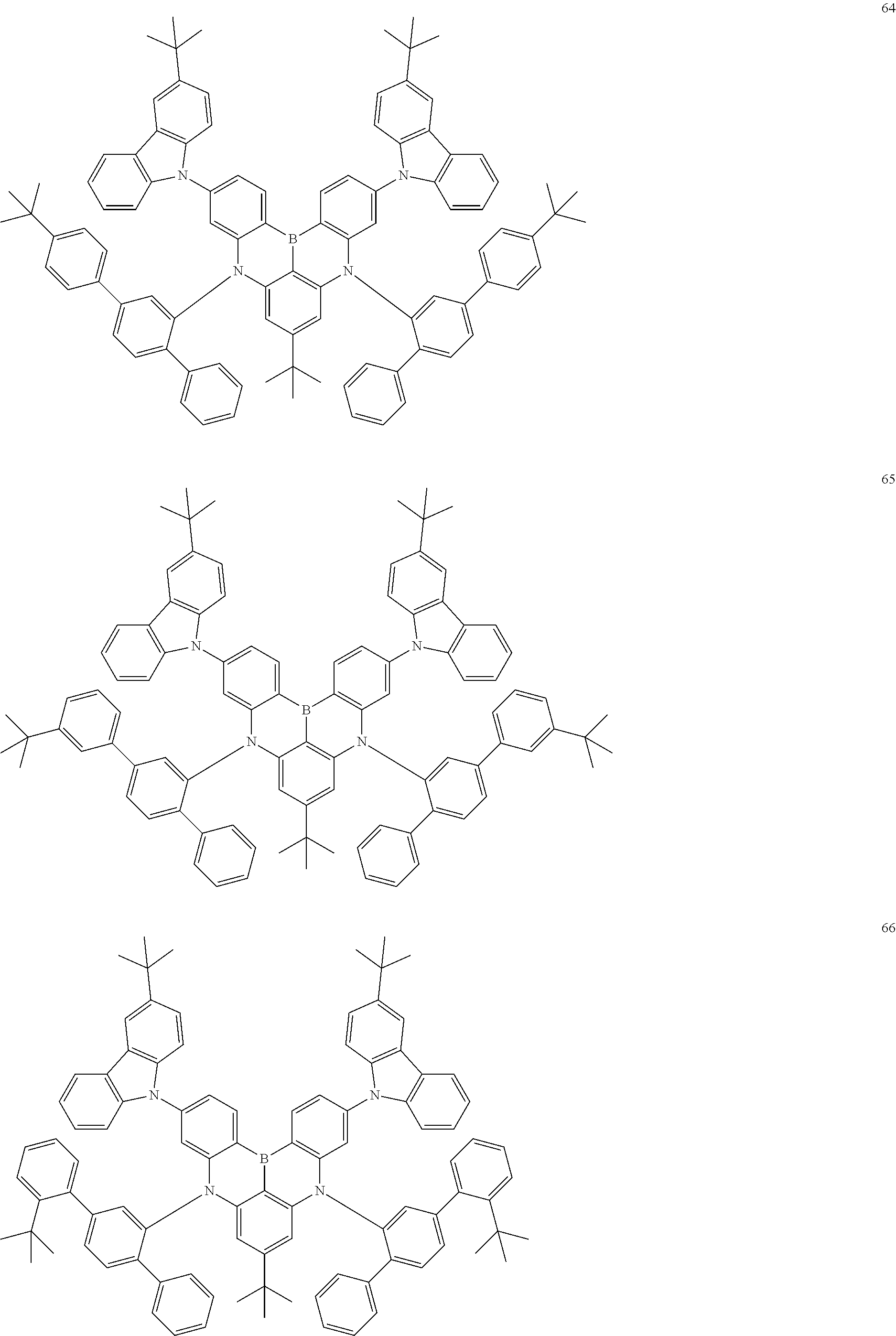

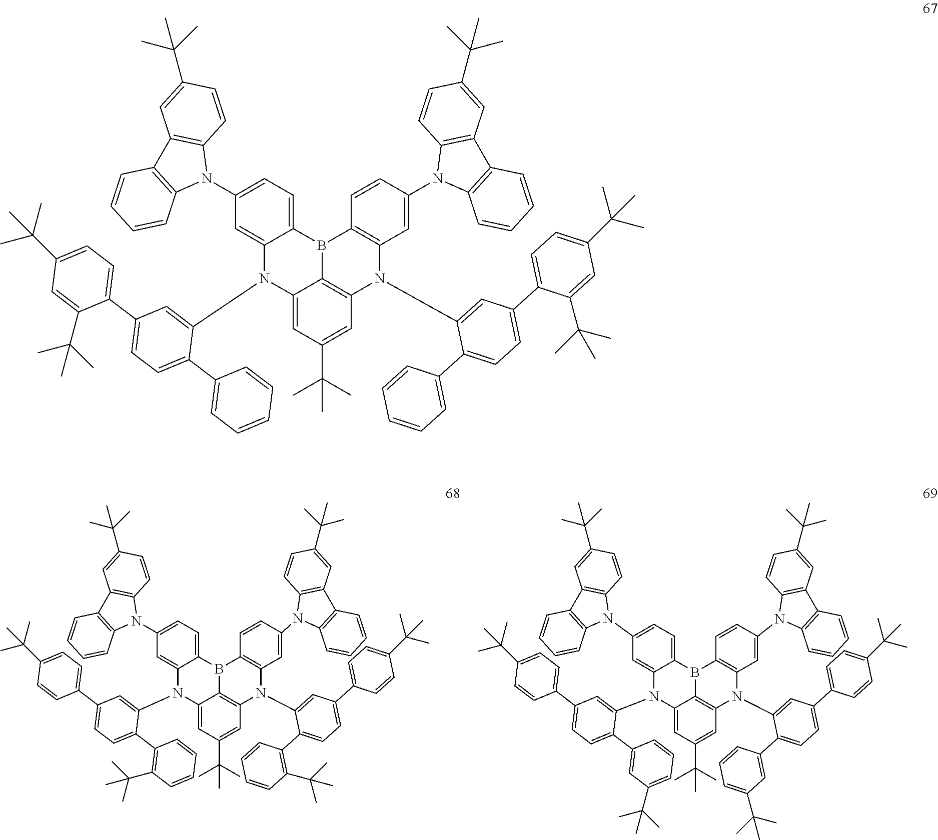

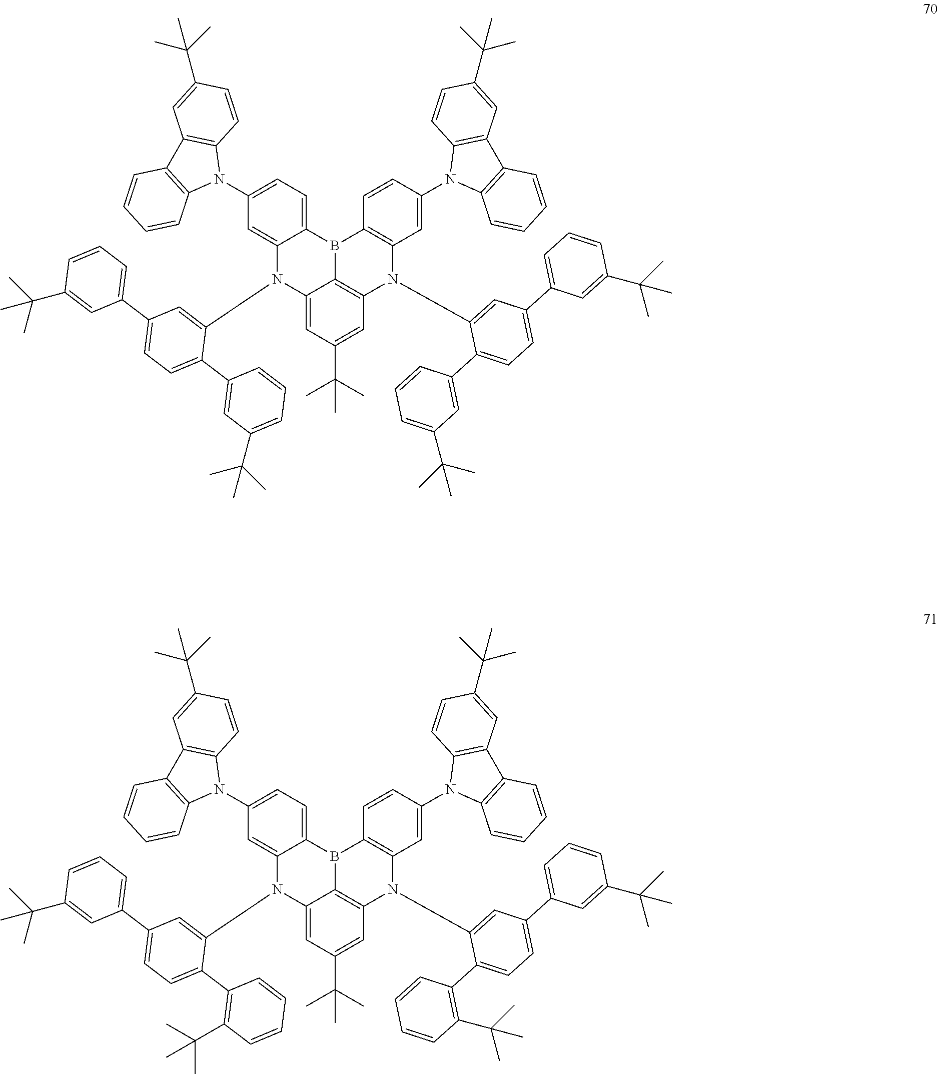

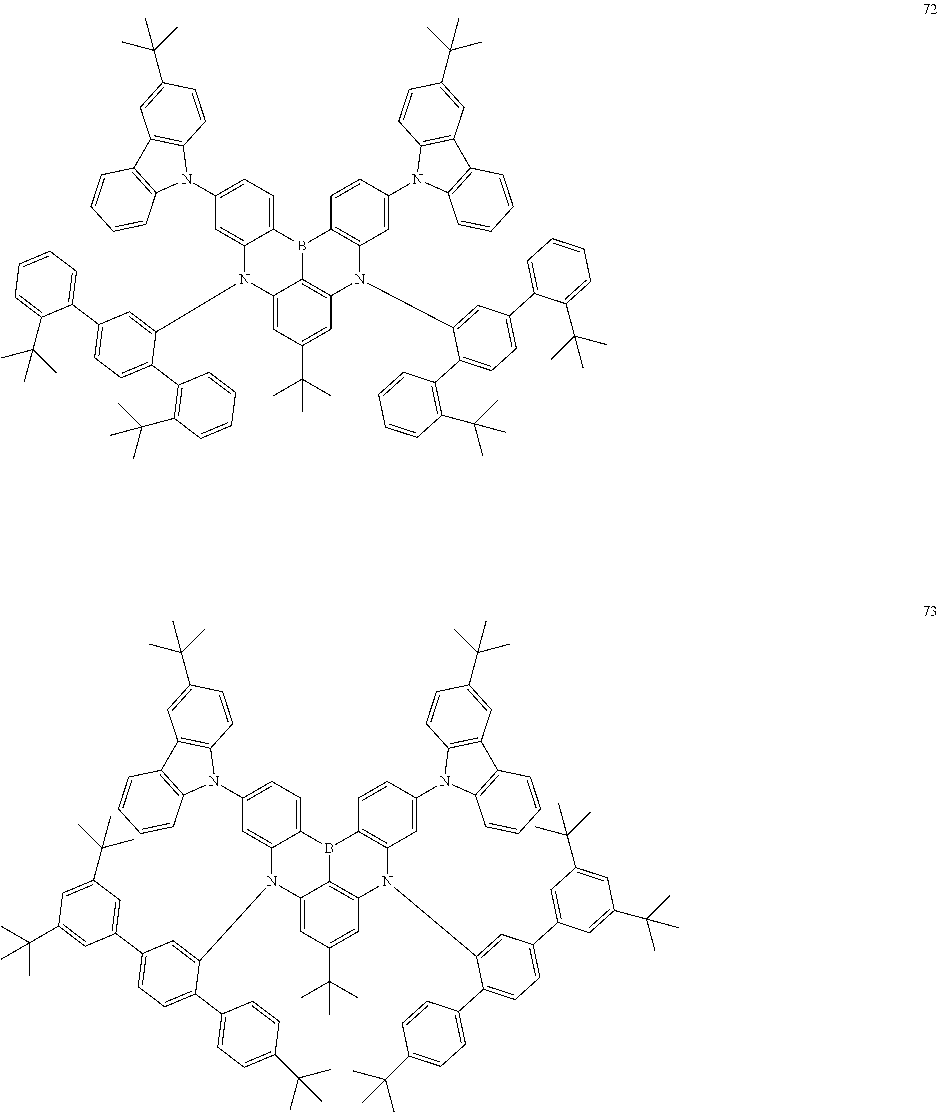

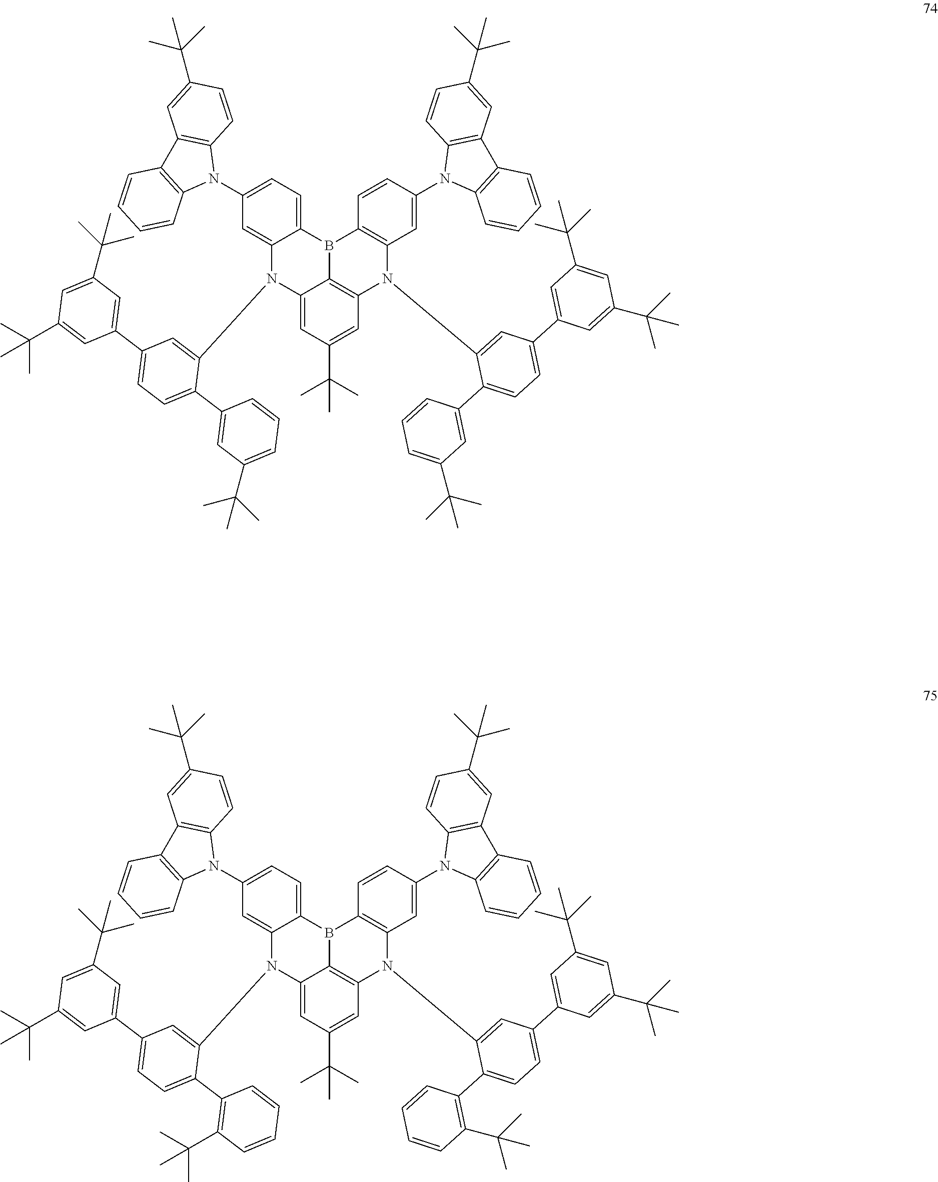

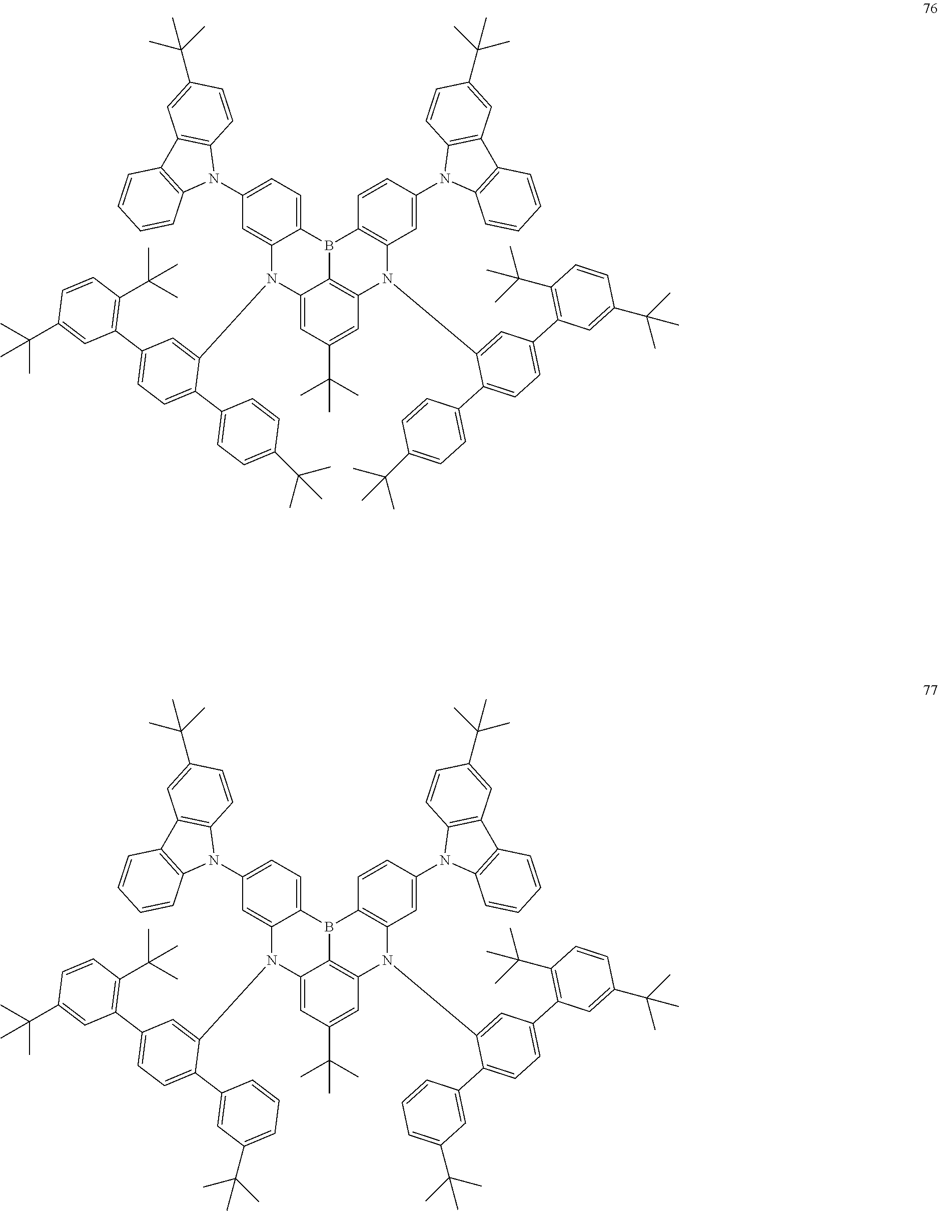

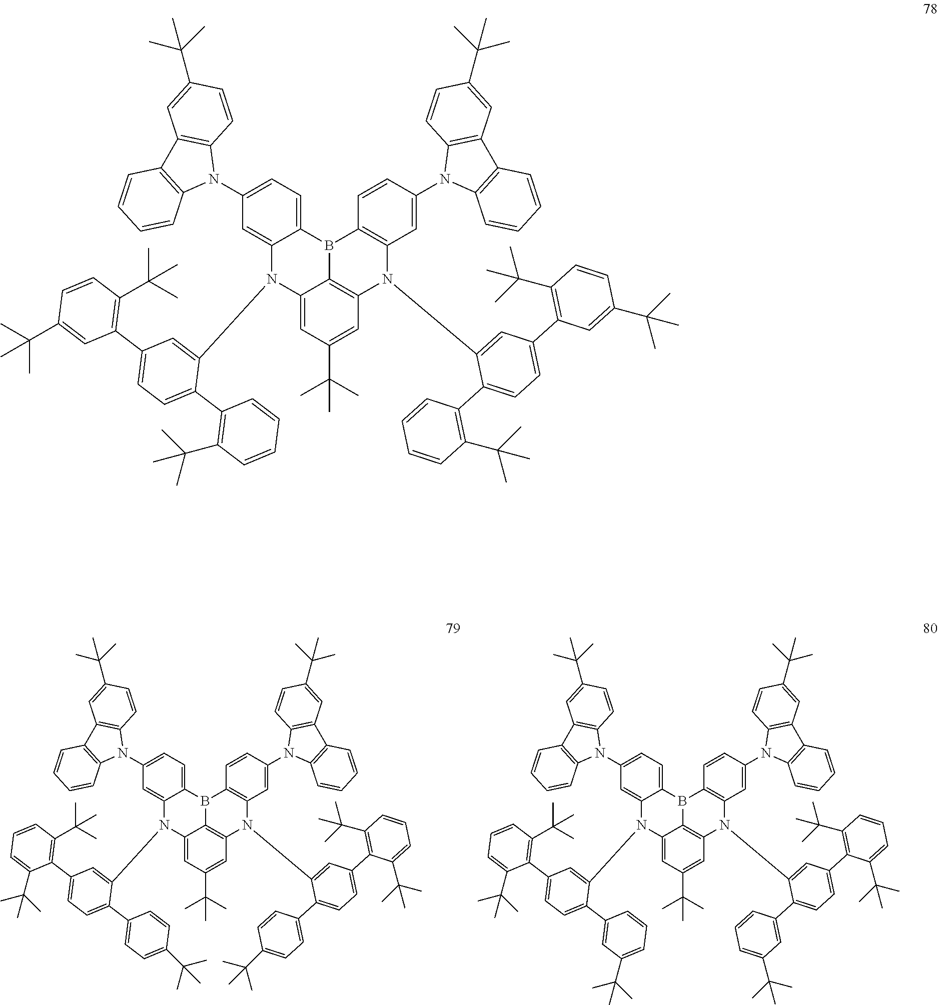

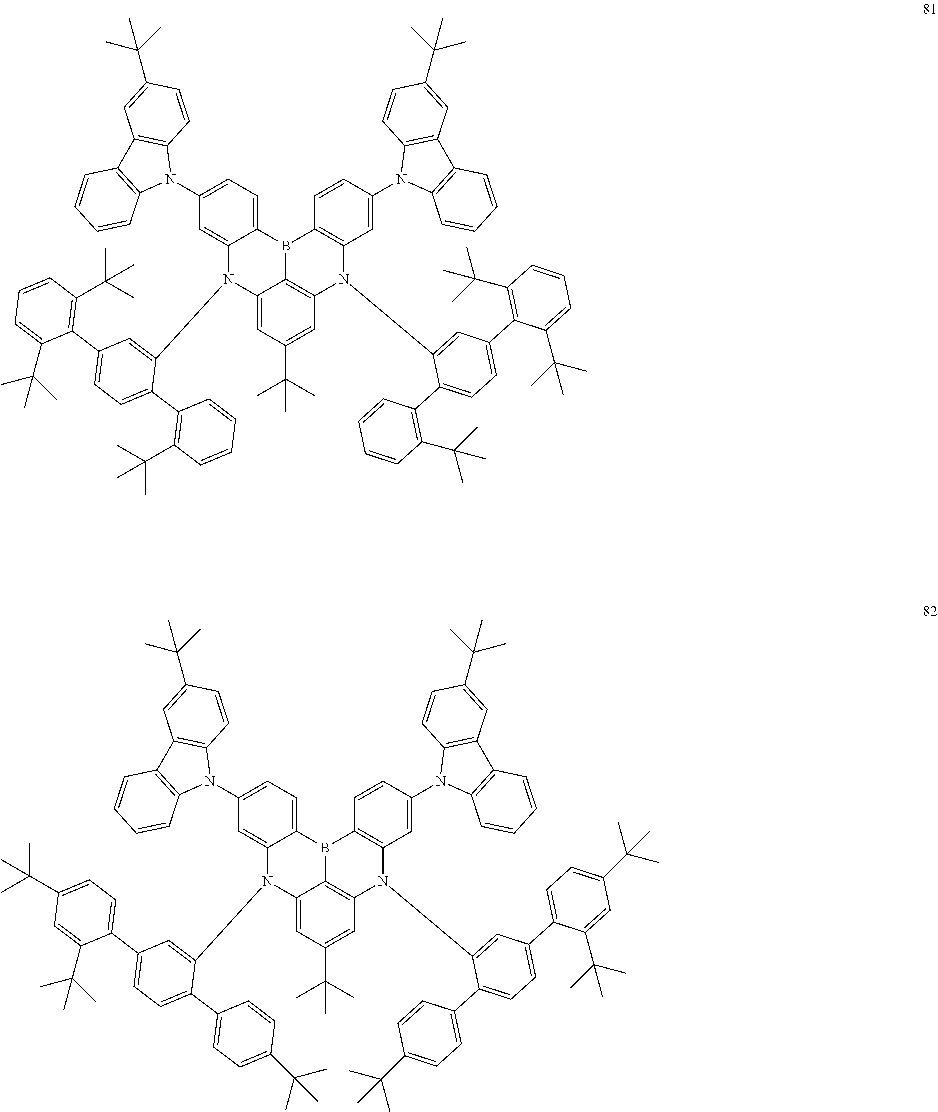

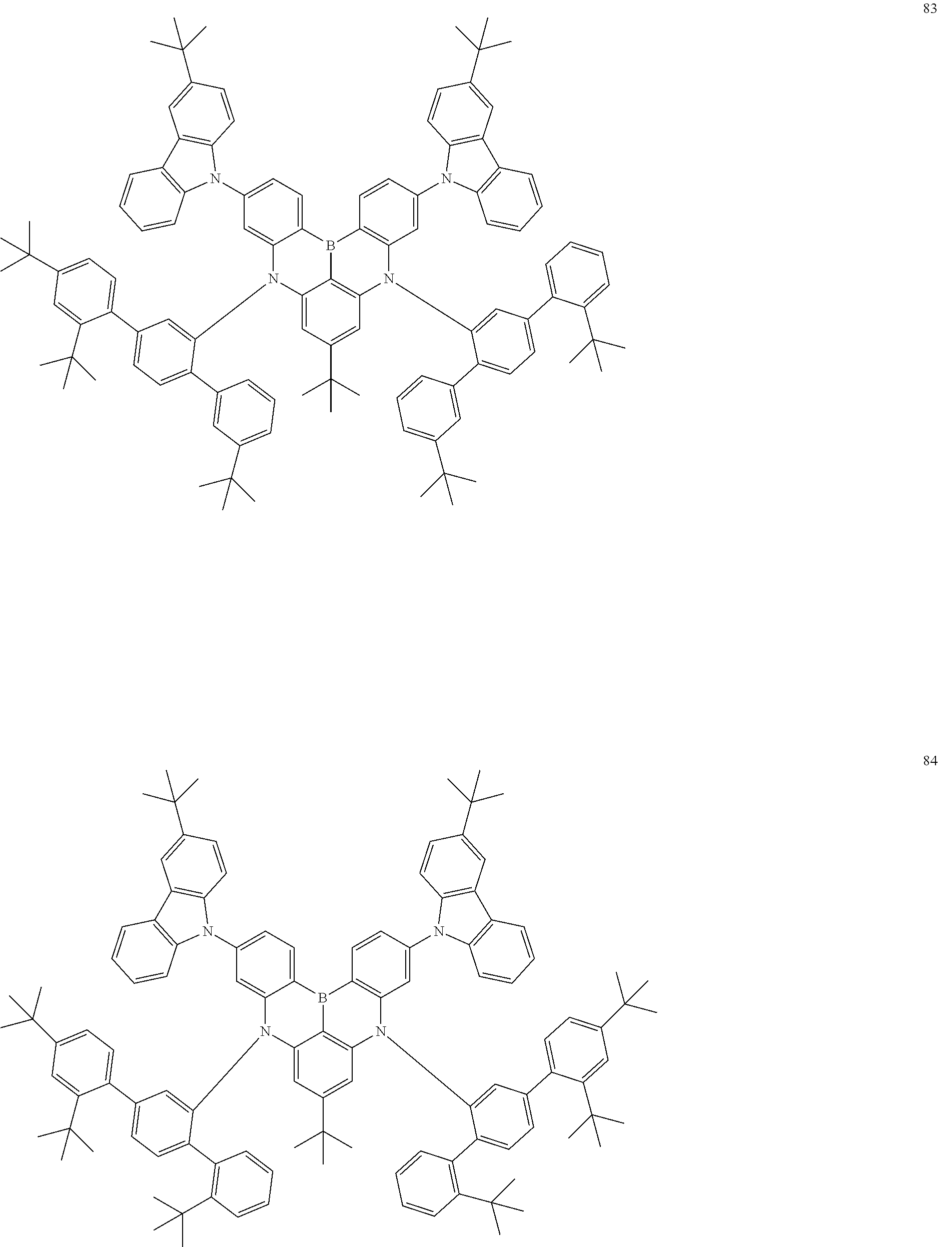

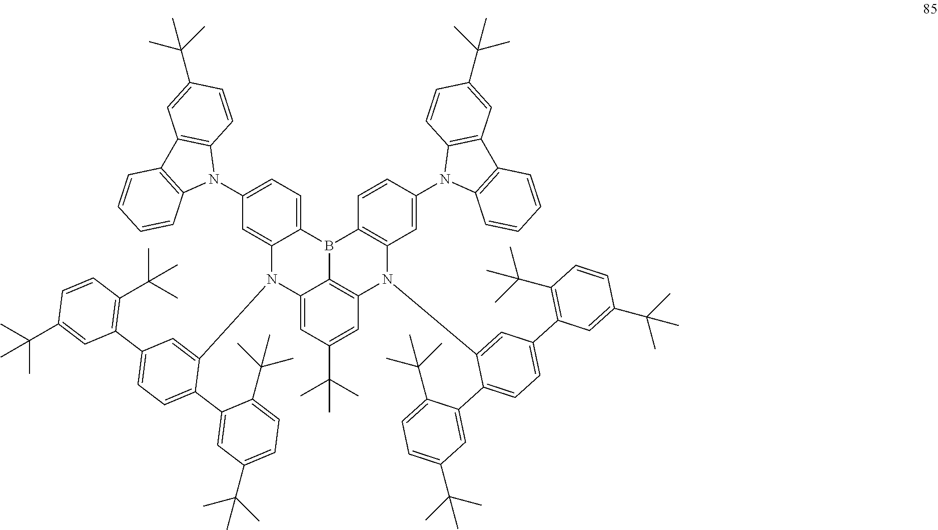 [SMILES: CC(C)(C)c1ccc(C(C)(C)C)c(-c2ccc(-c3cc(C(C)(C)C)ccc3C(C)(C)C)c(N3c4cc(-n5c6ccccc6c6cc(C(C)(C)C)ccc65)ccc4B4c5ccc(-n6c7ccccc7c7cc(C(C)(C)C)ccc76)cc5N(c5cc(-c6cc(C(C)(C)C)ccc6C(C)(C)C)ccc5-c5cc(C(C)(C)C)ccc5C(C)(C)C)c5cc(C(C)(C)C)cc3c54)c2)c1]

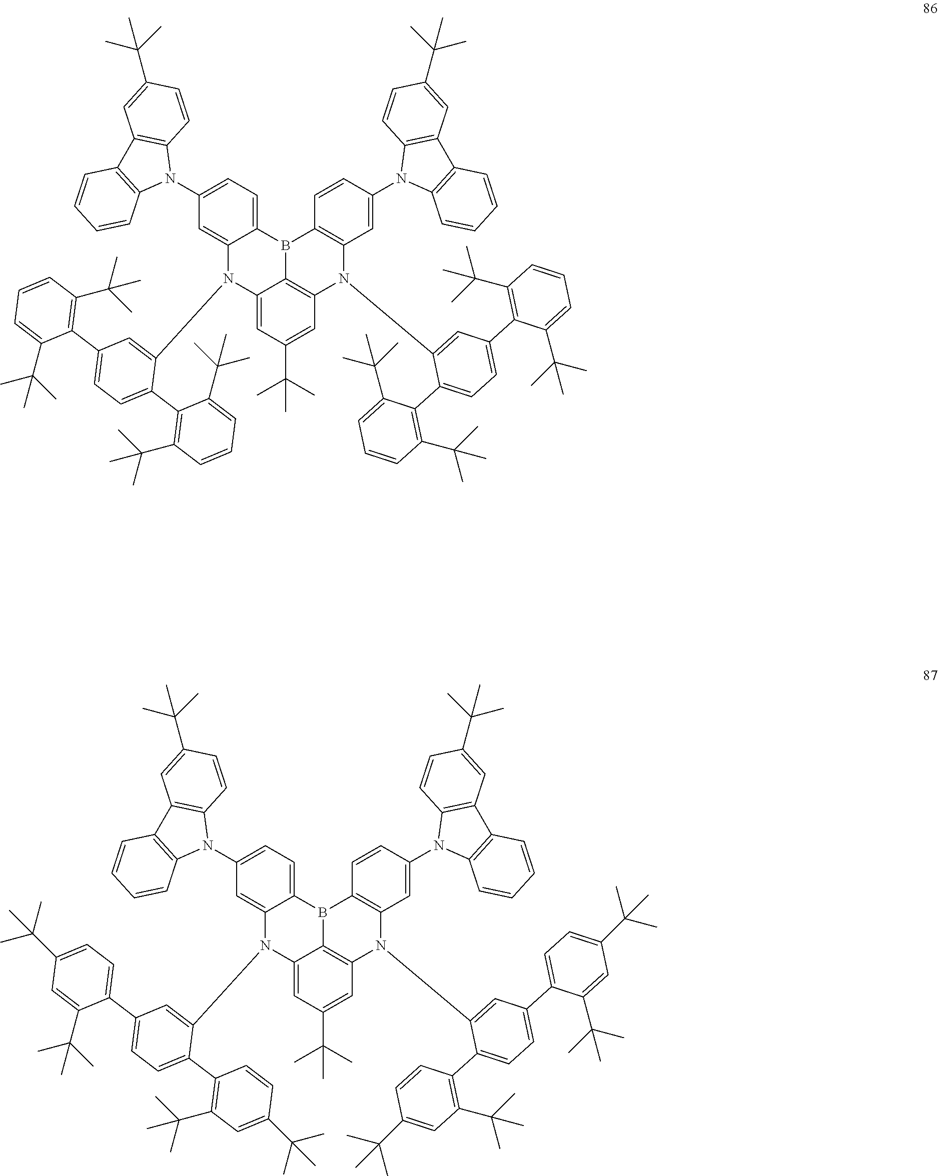

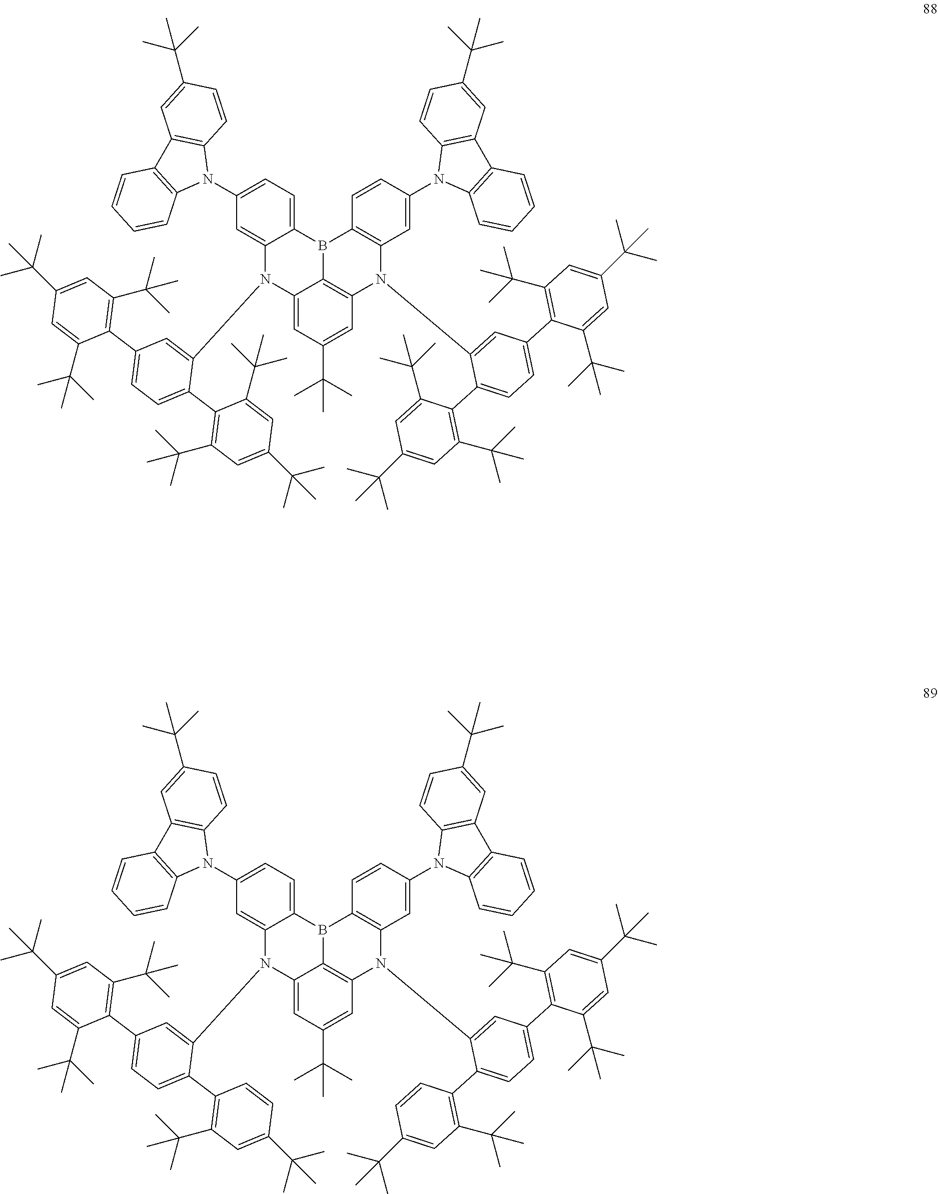

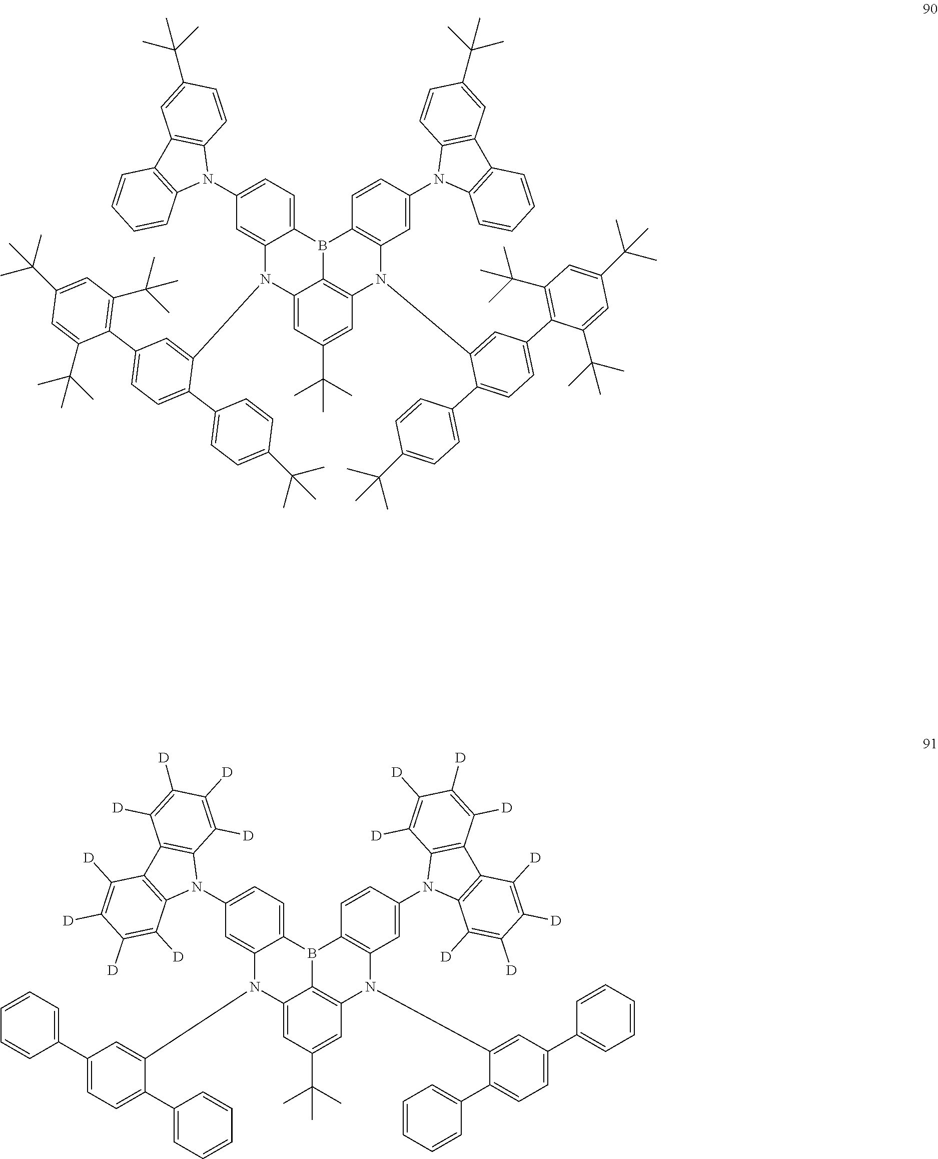 [SMILES: CC(C)(C)c1ccc(-c2ccc(-c3c(C(C)(C)C)cc(C(C)(C)C)cc3C(C)(C)C)cc2N2c3cc(-n4c5ccccc5c5cc(C(C)(C)C)ccc54)ccc3B3c4ccc(-n5c6ccccc6c6cc(C(C)(C)C)ccc65)cc4N(c4cc(-c5c(C(C)(C)C)cc(C(C)(C)C)cc5C(C)(C)C)ccc4-c4ccc(C(C)(C)C)cc4)c4cc(C(C)(C)C)cc2c43)cc1 ; [2H]c1c([2H])c([2H])c2c(c1[2H])c1c([2H])c([2H])c([2H])c([2H])c1n2-c1ccc2c(c1)N(c1cc(-c3ccccc3)ccc1-c1ccccc1)c1cc(C(C)(C)C)cc3c1B2c1ccc(-n2c4c([2H])c([2H])c([2H])c([2H])c4c4c([2H])c([2H])c([2H])c([2H])c42)cc1N3c1cc(-c2ccccc2)ccc1-c1ccccc1]

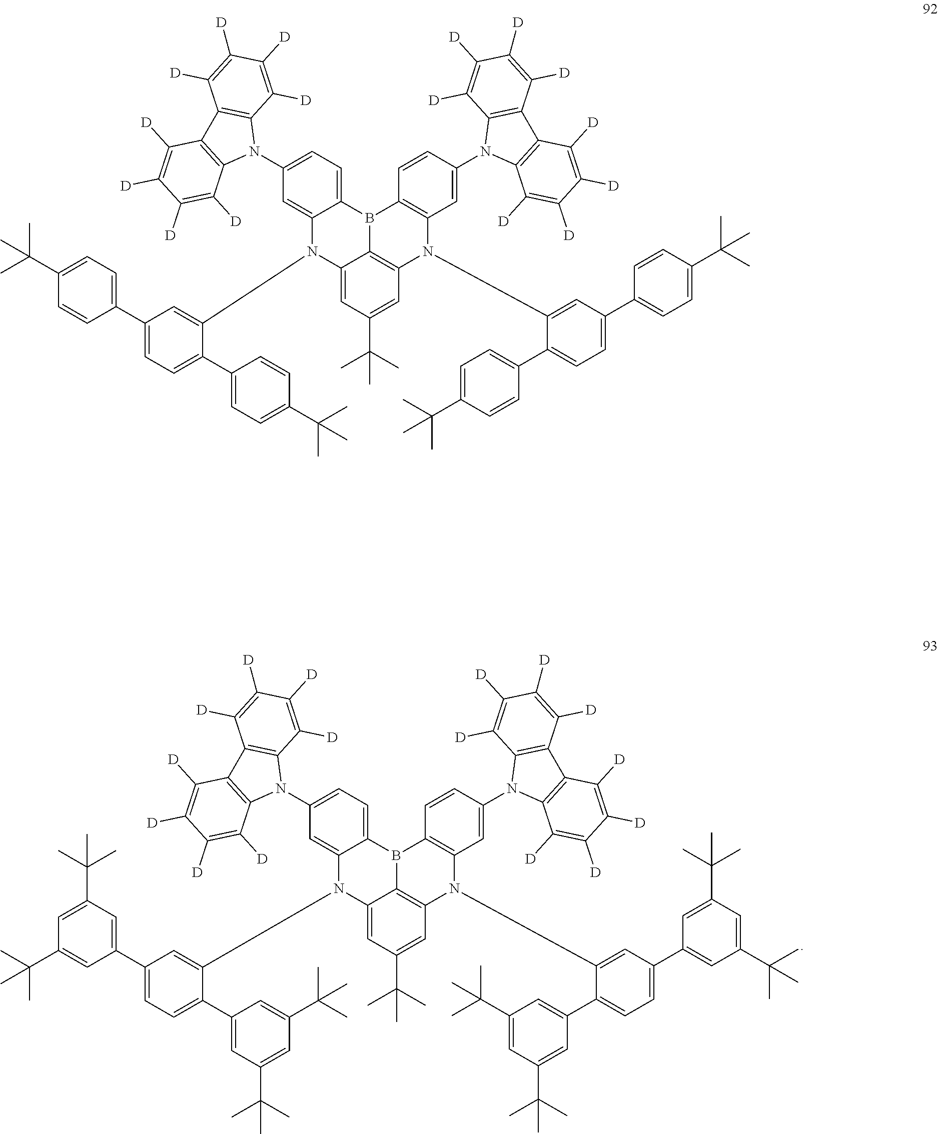

Synthesis methods of the emitter may be recognizable by one of ordinary skill in the art by referring to Synthesis Examples provided below.

An amount of the emitter in the emission layer may be in a range of about 0.01 parts by weight to about 40 parts by weight, about 0.1 parts by weight to about 20 parts by weight, about 0.1 parts by weight to about 10 parts by weight, about 0.1 parts by weight to about 5 parts by weight, about 0.5 parts by weight to about 5 parts by weight, or about 0.6 parts by weight to about 2 parts by weight, based on 100 parts by weight of the emission layer.

The term “emitter” as used herein refers to a material that may receive excitons as a host, sensitizer, and/or auxiliary dopant and emit light through transition of the excitons to a ground state.

The sensitizer may transfer excitation energy (or excitons) from the host to the emitter, and may relatively reduce “Dexter energy transfer from the host to the emitter,” which inhibits hyper fluorescence, thereby improving the luminescence efficiency and/or lifespan characteristics of the light-emitting device.

The sensitizer may be an organometallic compound, a delayed fluorescence material, a prompt fluorescence material, or any combination thereof.

The organometallic compound may include a transition metal and ligand(s) in the number of n, which are bonded to the transition metal, and n may be an integer from 1 to 4.

In an embodiment, in the organometallic compound, the transition metal may be platinum (Pt) or palladium (Pd), n may be 1, and the ligand may be a tetradentate ligand. The tetradentate ligand may include, for example, a carbene moiety bonded to the transition metal.

In one or more embodiments, the organometallic compound may include a transition metal and a tetradentate ligand bonded to the transition metal, the transition metal may be platinum or palladium, and the tetradentate ligand may include a carbene moiety bonded to the transition metal.

In one or more embodiments, in the organometallic compound, the transition metal may be iridium (Ir) or osmium (Os), n may be 3, and at least one of the ligand(s) in the number of n may be a bidentate ligand including —F, a cyano group, or a combination thereof, or a bidentate ligand including a carbene moiety bonded to the transition metal. For example, the bidentate ligand may further include an imidazole group or a triazole group.

In one or more embodiments, the organometallic compound may be an organometallic compound represented by Formula 3 and/or an organometallic compound represented by Formula 5 as described herein. Details on Formulae 3 and 5 may be the same as described below.

The delayed fluorescence material may be, for example, a thermally activated delayed fluorescence material. In one or more embodiments, the delayed fluorescence material may be a multiple resonance thermally activated delayed fluorescence material that is different from the delayed fluorescence emitter described herein.

The multiple resonance thermally activated delayed fluorescence material may be a polycyclic compound that i) does not include a transition metal and ii) includes a core in which two or more C₃-C₆₀ cyclic groups are condensed with each other. In this regard, two C₃-C₆₀ cyclic groups in the core may be condensed with each other while sharing boron (B) or nitrogen (N).

The prompt fluorescence material may be an amino group-containing compound, a styryl group-containing compound, or the like. For example, the prompt fluorescence material may include a naphthalene group, a fluorene group, a spiro-bifluorene group, a benzofluorene group, a dibenzofluorene group, a phenanthrene group, an anthracene group, a fluoranthene group, a triphenylene group, a pyrene group, a chrysene group, a naphthacene group(tetracene group), a picene group, a perylene group, a pentaphene group, an indenoanthracene group, a group represented by one of Formulae 501-1 to 501-21, or any combination thereof:

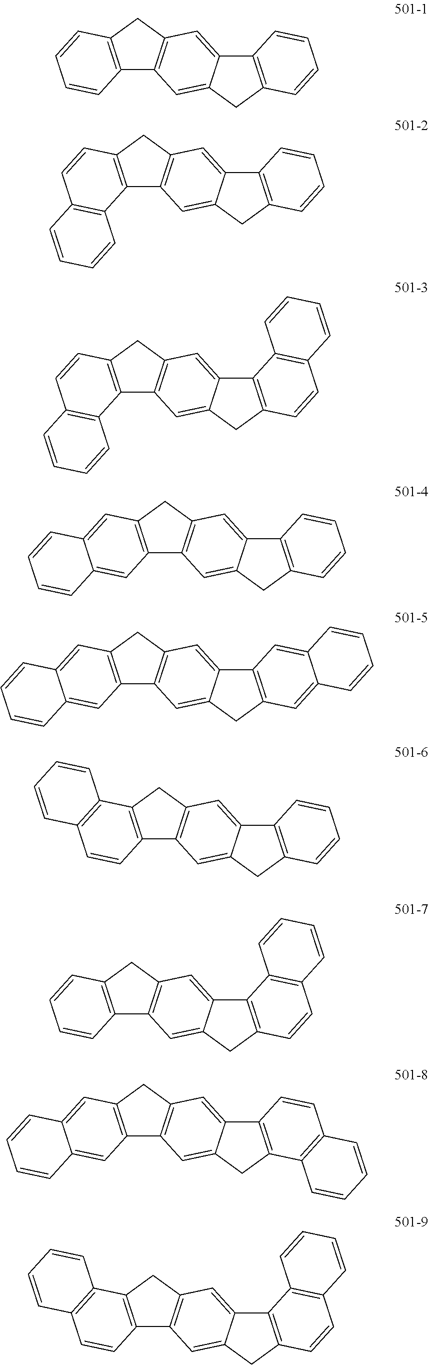

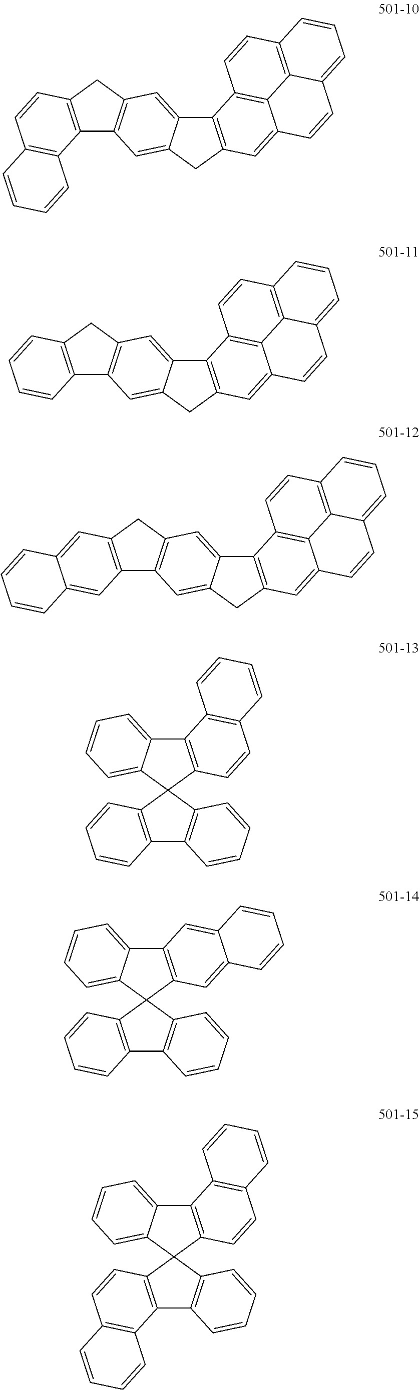

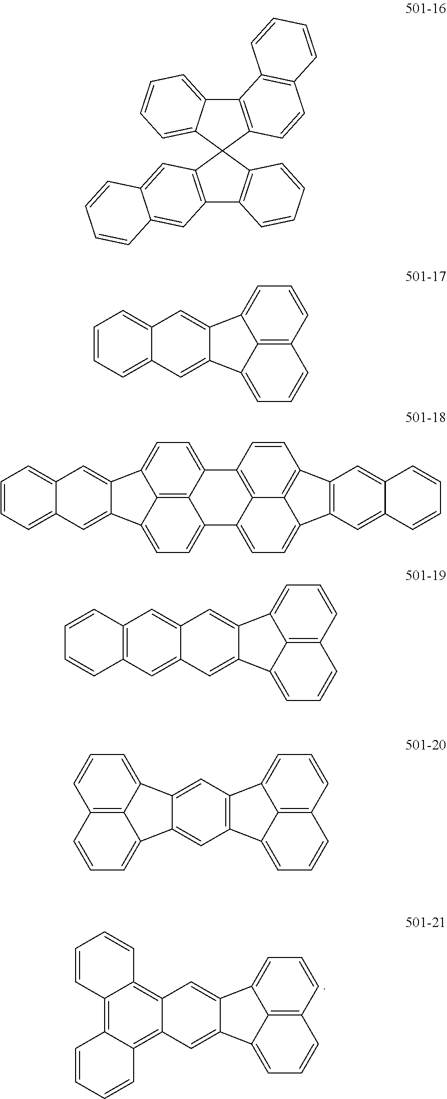

In an embodiment, the sensitizer may be an organometallic compound.

An amount (weight) of the sensitizer may be in a range of about 0.01 parts by weight to about 30 parts by weight, or about 0.01 parts by weight to about 20 parts by weight, about 1 parts by weight to about 18 parts by weight, or about 5 parts by weight to about 15 parts by weight, based on 100 parts by weight of the emission layer.

The host(s) in the number of m1 in the emission layer may include a hole-transporting compound, an electron-transporting compound, a bipolar compound, or any combination thereof. The first host and the second host may each not include a transition metal.

In an embodiment, m1 may be 2, two hosts in the emission layer may each include a hole-transporting compound and an electron-transporting compound, and the hole-transporting compound and the electron-transporting compound may be different from each other.

In an embodiment, the hole-transporting compound may include at least one π electron-rich C₃-C₆₀ cyclic group and may not include an electron-transporting group. Examples of the electron-transporting group include a cyano group, a fluoro group, a π electron-deficient nitrogen-containing cyclic group, a phosphine oxide group, a sulfoxide group, and the like.

The “π electron-deficient nitrogen-containing cyclic group” described herein may be a C₁-C₆₀ heterocyclic group that has at least one *—N═*′ moiety as a ring-forming moiety. Examples of the π electron-deficient nitrogen-containing cyclic group include a triazine group, an imidazole group, and the like.

The “π electron-rich C₃-C₆₀ cyclic group” described herein may be a C₃-C₆₀ cyclic group that does not include a *—N═*′ moiety as a ring-forming moiety. Examples of the π electron-rich C₃-C₆₀ cyclic group include a benzene group, a naphthalene group, a triphenylene group, a dibenzofuran group, a dibenzothiophene group, a carbazole group, an indolodibenzofuran group, an indolodibenzothiophene group, an indolocarbazole group, a naphthobenzofuran group, a naphthobenzothiophene group, a benzocarbazole group, a phenanthrenobenzofuran group, a phenanthrenobenzothiophene group, a naphthocarbazole group, a dinaphthofuran group, a dinaphthothiophene group, a dibenzocarbazole group, and the like.

In an embodiment, the hole-transporting compound may include two or more carbazole groups.

In one or more embodiments, the hole-transporting compound may include at least one silicon (e.g., a triphenylsilyl group). For example, the hole-transporting compound may include at least one carbazole group and at least one silicon (e.g., a triphenylsilyl group). For example, the silicon may be connected to nitrogen of the carbazole group through an o-phenylene group or an m-phenylene group.

In one or more embodiments, the electron-transporting compound may be a compound including at least one electron-transporting group. The electron-transporting group may be a cyano group, a fluoro group, a π electron-deficient nitrogen-containing C₁-C₆₀ cyclic group, a phosphine oxide group, a sulfoxide group, or any combination thereof. In an embodiment, the electron-transporting compound may include a triazine group.

In an embodiment, the electron-transporting compound may include at least one electron-transporting group (e.g., a triazine group) and at least one π electron-rich C₃-C₆₀ cyclic group (e.g., a benzene group, a naphthalene group, a triphenylene group, a dibenzofuran group, a dibenzothiophene group, a carbazole group, an indolodibenzofuran group, an indolodibenzothiophene group, an indolocarbazole group, a naphthobenzofuran group, a naphthobenzothiophene group, a benzocarbazole group, a phenanthrenobenzofuran group, a phenanthrenobenzothiophene group, a naphthocarbazole group, a dinaphthofuran group, a dinaphthothiophene group, a dibenzocarbazole group, or any combination thereof).

In an embodiment, the electron-transporting compound may include at least one silicon (e.g., a triphenylsilyl group). For example, the electron-transporting compound may include a triazine group, at least one carbazole group, and at least one silicon (e.g., a triphenylsilyl group). For example, the silicon may be connected to carbon of the triazine group through an o-phenylene group or an m-phenylene group. In an embodiment, nitrogen of the carbazole group may be directly bonded to the carbon of the triazine group, or may be linked to the carbon of the triazine group through an o-phenylene group or an m-phenylene group.

In an embodiment, the hole-transporting compound may be a compound represented by Formula 6:

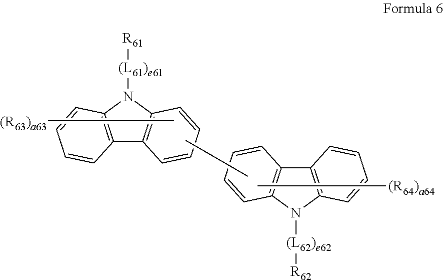

wherein, in Formula 6,
L₆₁ and L₆₂ may each independently be a π electron-rich C₃-C₆₀ cyclic group (e.g., C₆-C₁₂ arylene group or C₆-C₁₀ arylene group) unsubstituted or substituted with deuterium, a C₁-C₂₀ alkyl group, a deuterated C₁-C₂₀ alkyl group, a phenyl group, a deuterated phenyl group, a (C₁-C₂₀ alkyl)phenyl group, a biphenyl group, a deuterated biphenyl group, a (C₁-C₂₀ alkyl)biphenyl group, —Si(Q₃₃)(Q₃₄)(Q₃₅), or any combination thereof,
e61 and e62 may each independently be an integer from 1 to 6,
R₆₁ to R₆₄ may each independently be:
hydrogen, deuterium, a C₁-C₂₀ alkyl group, or a deuterated C₁-C₂₀ alkyl group;
   a π electron-rich C₃-C₆₀ cyclic group (e.g., C₆-C₁₂ aryl group or C₆-C₁₀ aryl group) unsubstituted or substituted with deuterium, a C₁-C₂₀ alkyl group, a deuterated C₁-C₂₀ alkyl group, a phenyl group, a deuterated phenyl group, a (C₁-C₂₀ alkyl)phenyl group, a biphenyl group, a deuterated biphenyl group, a (C₁-C₂₀ alkyl)biphenyl group, —Si(Q₃₃)(Q₃₄)(Q₃₅), or any combination thereof; or
—Si(Q₃)(Q₄)(Q₅),
a63 and a64 may each independently be an integer from 0 to 7, and
Q₃ to Q₅ and Q₃₃ to Q₃₅ may each be the same as described herein. For example, Q₃ to Q₅ and Q₃₃ to Q₃₅ may each be a phenyl group.

In one or more embodiments, the hole-transporting compound may be a compound represented by Formula 6-1, 6-2, or 6-3:

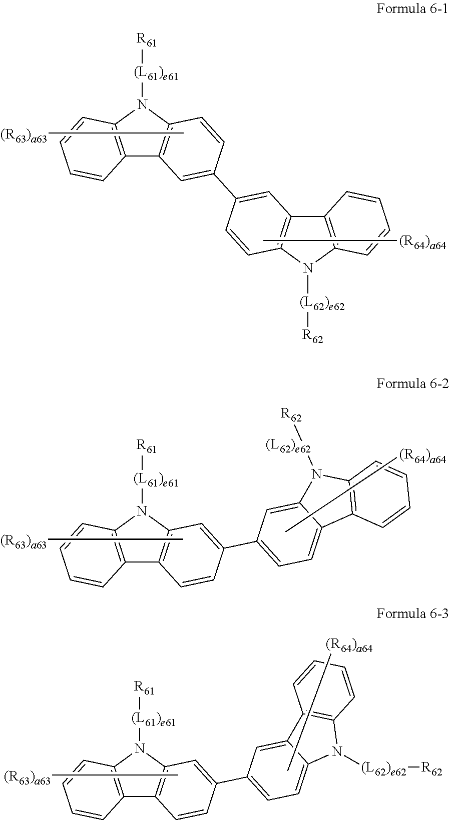

wherein, in Formulae 6-1, 6-2, and 6-3, L₆₁, L₆₂, R₆₁ to R₆₄, e61, e62, a63, and a64 may each be the same as described herein.

In one or more embodiments, the hole-transporting compound may be one of Compounds HTH1 to HTH7:

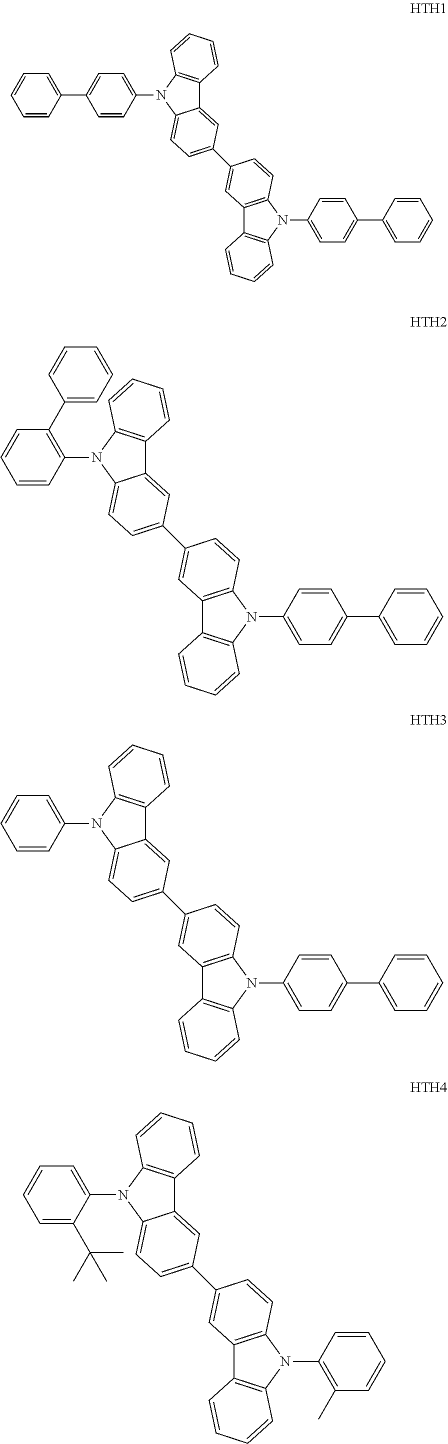 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5ccccc5-c5ccccc5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; Cc1ccccc1-n1c2ccccc2c2cc(-c3ccc4c(c3)c3ccccc3n4-c3ccccc3C(C)(C)C)ccc21]

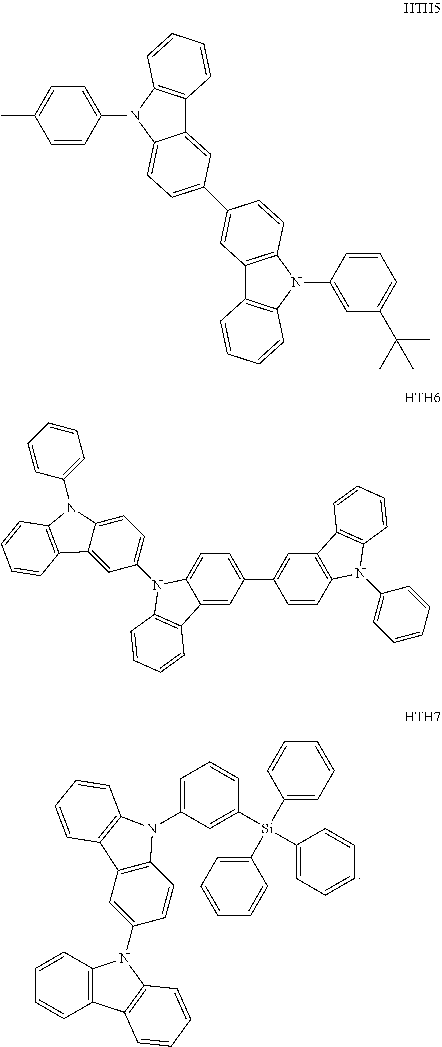 [SMILES: Cc1ccc(-n2c3ccccc3c3cc(-c4ccc5c(c4)c4ccccc4n5-c4cccc(C(C)(C)C)c4)ccc32)cc1 ; c1ccc(-n2c3ccccc3c3cc(-c4ccc5c(c4)c4ccccc4n5-c4ccc5c(c4)c4ccccc4n5-c4ccccc4)ccc32)cc1 ; c1ccc([Si](c2ccccc2)(c2ccccc2)c2cccc(-n3c4ccccc4c4cc(-n5c6ccccc6c6ccccc65)ccc43)c2)cc1 ; "."]

In one or more embodiments, the electron-transporting compound may be a compound represented by Formula 7:

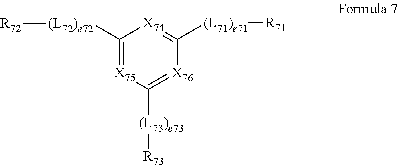

wherein, in Formula 7,
X₇₄ may be C(R₇₄) or N, X₇₅ may be C(R₇₅) or N, X₇₆ may be C(R₇₆) or N, and at least one of X₇₄ to X₇₆ (e.g., all) may be N,
L₇₁, L₇₂, and L₇₃ may each independently be a C₅-C₃₀ carbocyclic group or a C₁-C₃₀ heterocyclic group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, —Si(Q₃₃)(Q₃₄)(Q₃₅), or any combination thereof,
e71, e72, and e73 may each independently be an integer from 1 to 10, and
R₇₁ to R₇₆ may each independently be:
hydrogen, deuterium, —F, or a cyano group;
a C₁-C₂₀ alkyl group unsubstituted or substituted with deuterium, —F, a cyano group, or any combination thereof;
a C₅-C₃₀ carbocyclic group or a C₁-C₃₀ heterocyclic group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, —Si(Q₃₃)(Q₃₄)(Q₃₅), or any combination thereof; or
—Si(Q₃)(Q₄)(Q₅),
wherein Q₃ to Q₅ and Q₃₃ to Q₃₅ may each be the same as described herein. For example, Q₃ to Q₅ and Q₃₃ to Q₃₅ may each be a phenyl group.

In one or more embodiments, X₇₄, X₇₅, and X₇₆ in Formula 7 may each be N.

In one or more embodiments, L₇₁, L₇₂, and L₇₃ in Formula 7 may each independently be a benzene group, a naphthalene group, a triphenylene group, a dibenzofuran group, a dibenzothiophene group, a carbazole group, an indolodibenzofuran group, an indolodibenzothiophene group, an indolocarbazole group, a naphthobenzofuran group, a naphthobenzothiophene group, a benzocarbazole group, a phenanthrenobenzofuran group, a phenanthrenobenzothiophene group, a naphthocarbazole group, a dinaphthofuran group, a dinaphthothiophene group, or a dibenzocarbazole group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, —Si(Q₃₃)(Q₃₄)(Q₃₅), or any combination thereof.

In one or more embodiments, at least one of L₇₁ in the number of e71, at least one of L₇₂ in the number of e72, at least one of L₇₃ in the number of e73, or any combination thereof in Formula 7 may each independently be a dibenzofuran group, a dibenzothiophene group, a carbazole group, an indolodibenzofuran group, an indolodibenzothiophene group, an indolocarbazole group, a naphthobenzofuran group, a naphthobenzothiophene group, a benzocarbazole group, a phenanthrenobenzofuran group, a phenanthrenobenzothiophene group, a naphthocarbazole group, a dinaphthofuran group, a dinaphthothiophene group, or a dibenzocarbazole group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, —Si(Q₃₃)(Q₃₄)(Q₃₅), or any combination thereof.

In one or more embodiments, at least one of L₇₁ in the number of e71, at least one of L₇₂ in the number of e72, at least one of L₇₃ in the number of e73, or any combination thereof in Formula 7 may include a carbazole group, an indolocarbazole group, a benzocarbazole group, a naphthocarbazole group, or a dibenzocarbazole group, wherein a nitrogen atom of a pyrrole group in the carbazole group, the indolocarbazole group, the benzocarbazole group, the naphthocarbazole group, or the dibenzocarbazole group may be linked to a carbon atom of a 6-membered ring including X₇₄, X₇₅, and X₇₆ in Formula 7, with a single bond or neighboring L₇₁, L₇₂, and/or L₇₃ therebetween.

In one or more embodiments, e71, e72, and e73 in Formula 7 indicate the numbers of L₇₁, L₇₂, and to L₇₃, respectively, and may each independently be 1, 2, 3, 4, or 5.

In one or more embodiments, R₇₁ to R₇₆ in Formula 7 may each independently be:
hydrogen, deuterium, —F, or a cyano group;
a C₁-C₂₀ alkyl group unsubstituted or substituted with deuterium, —F, a cyano group, or any combination thereof;
a benzene group, a naphthalene group, a triphenylene group, a dibenzofuran group, a dibenzothiophene group, a carbazole group, an indolodibenzofuran group, an indolodibenzothiophene group, an indolocarbazole group, a naphthobenzofuran group, a naphthobenzothiophene group, a benzocarbazole group, a phenanthrenobenzofuran group, a phenanthrenobenzothiophene group, a naphthocarbazole group, a dinaphthofuran group, a dinaphthothiophene group, or a dibenzocarbazole group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀alkyl)phenyl group, a biphenyl group, a deuterated biphenyl group, a fluorinated biphenyl group, a (C₁-C₂₀ alkyl)biphenyl group, —Si(Q₃₃)(Q₃₄)(Q₃₅), or any combination thereof; or
—Si(Q₃)(Q₄)(Q₅).

In one or more embodiments, the electron-transporting compound may be one of Compounds ETH1 to ETH8:

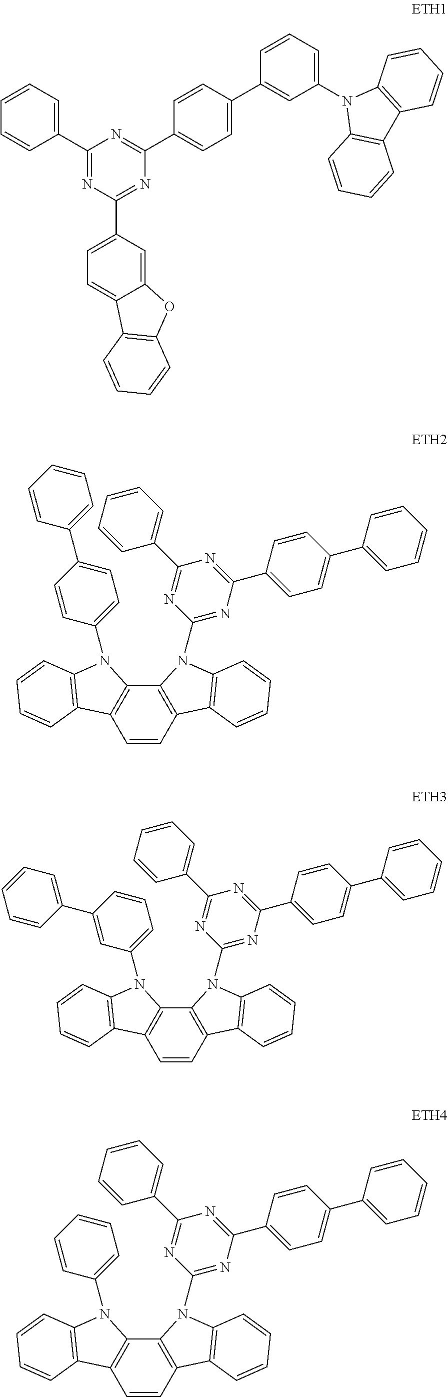 [SMILES: c1ccc(-c2nc(-c3ccc(-c4cccc(-n5c6ccccc6c6ccccc65)c4)cc3)nc(-c3ccc4c(c3)oc3ccccc34)n2)cc1 ; c1ccc(-c2ccc(-c3nc(-c4ccccc4)nc(-n4c5ccccc5c5ccc6c7ccccc7n(-c7ccc(-c8ccccc8)cc7)c6c54)n3)cc2)cc1 ; c1ccc(-c2ccc(-c3nc(-c4ccccc4)nc(-n4c5ccccc5c5ccc6c7ccccc7n(-c7cccc(-c8ccccc8)c7)c6c54)n3)cc2)cc1 ; c1ccc(-c2ccc(-c3nc(-c4ccccc4)nc(-n4c5ccccc5c5ccc6c7ccccc7n(-c7ccccc7)c6c54)n3)cc2)cc1]

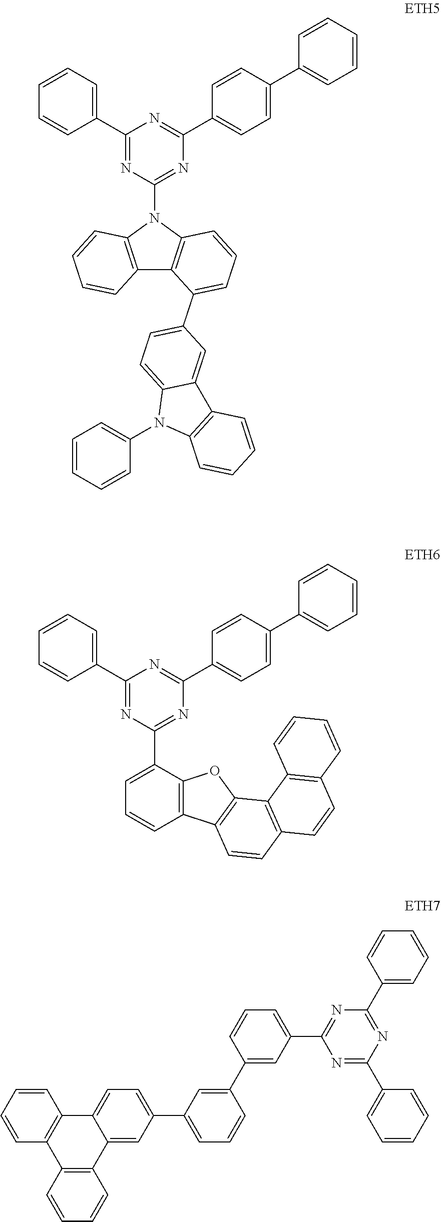 [SMILES: c1ccc(-c2ccc(-c3nc(-c4ccccc4)nc(-n4c5ccccc5c5c(-c6ccc7c(c6)c6ccccc6n7-c6ccccc6)cccc54)n3)cc2)cc1 ; c1ccc(-c2ccc(-c3nc(-c4ccccc4)nc(-c4cccc5c4oc4c5ccc5ccc6ccccc6c54)n3)cc2)cc1 ; c1ccc(-c2nc(-c3ccccc3)nc(-c3cccc(-c4cccc(-c5ccc6c7ccccc7c7ccccc7c6c5)c4)c3)n2)cc1]

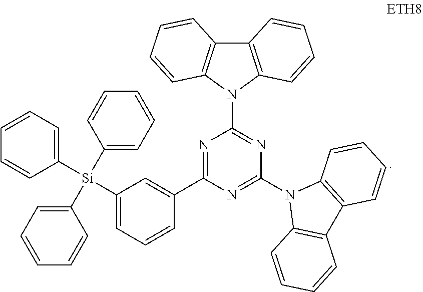 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1 ; "."]

The organometallic compound may be an organometallic compound represented by Formula 3:

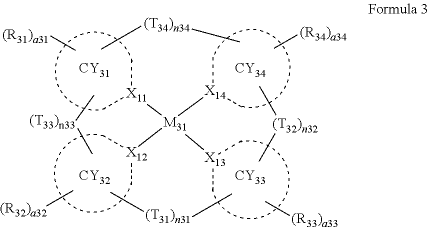

wherein, in Formula 3,
M₃₁ may be a transition metal,
X₁₁, X₁₂, X₁₃, and X₁₄ may each independently be C or N,
two of a bond between X₁₁ and M₃₁, a bond between X₁₂ and M₃₁, a bond between X₁₃ and M₃₁, and a bond between X₁₄ and M₃₁ may be coordinate bonds, and the other two may be covalent bonds.
ring CY₃₁, ring CY₃₂, ring CY3₃, and ring CY₃₄ may each independently be a C₅-C₃₀ carbocyclic group or a C₁-C₃₀ heterocyclic group,
T₃₁ may be a single bond, a double bond, *—N(R₃₅ₐ)—*′, *—B(R₃₅ₐ)—*′, *—P(R₃₅ₐ)—*′, *—C(R₃₅ₐ)(R_{35b})—*′, *—Si(R₃₅ₐ)(R_{35b})—*′, *—Ge(R₃₅ₐ)(R_{35b})—*′, *—S—*′, *—Se—*′, *—O—*′, *—C(═O)—*′, *—S(═O)—*′, *—S(═O)₂—*′, *—C(R₃₅ₐ)═*′, *═C(R₃₅ₐ)—*′, *—C(R₃₅ₐ)═C(R_{35b})—*′, *—C(═S)—*′, *—C≡C—*′, a C₅-C₃₀ carbocyclic group unsubstituted or substituted with at least one R₁₀ₐ, or a C₁-C₃₀ heterocyclic group unsubstituted or substituted with at least one R₁₀ₐ,
T₃₂ may be a single bond, a double bond, *—N(R₃₆ₐ)—*′, *—B(R₃₆ₐ)—*′, *—P(R₃₆ₐ)—*′, *—C(R₃₆ₐ)(R_{36b})—*′, *—Si(R₃₆ₐ)(R_{36b})—*′, *—Ge(R₃₆ₐ)(R_{36b})—*′, *—S—*′, *—Se—*′, *—O—*′, *—C(═O)—*′, *—S(═O)—*′, *—S(═O)₂—*′, *—C(R₃₆ₐ)═*′, *═C(R₃₆ₐ)—*′, *—C(R₃₆ₐ)═C(R_{36b})—*′, *—C(═S)—*′, *—C≡C—*′, a C₅-C₃₀ carbocyclic group unsubstituted or substituted with at least one R₁₀ₐ, or a C₁-C₃₀ heterocyclic group unsubstituted or substituted with at least one R₁₀ₐ,
T₃₃ may be a single bond, a double bond, *—N(R₃₇ₐ)—*′, *—B(R₃₇ₐ)—*′, *—P(R₃₇ₐ)—*′, *—C(R₃₇ₐ)(R_{37b})—*′, *—Si(R₃₇ₐ)(R_{37b})—*′, *—Ge(R₃₇ₐ)(R_{37b})—*′, *—S—*′, *—Se—*′, *—O—*′, *—C(═O)—*′, *—S(═O)—*′, *—S(═O)₂—*′, *—C(R₃₇ₐ)═*′, *═C(R₃₇ₐ)—*′, *—C(R₃₇ₐ)═C(R_{37b})—*′, *—C(═S)—*′, *—C≡C—*′, a C₅-C₃₀ carbocyclic group unsubstituted or substituted with at least one R₁₀ₐ, or a C₁-C₃₀ heterocyclic group unsubstituted or substituted with at least one R₁₀ₐ,
T₃₄ may be a single bond, a double bond, *—N(R₃₈ₐ)—*′, *—B(R₃₈ₐ)—*′, *—P(R₃₈ₐ)—*′, *—C(R₃₈ₐ)(R_{38b})—*′, *—Si(R₃₈ₐ)(R_{38b})—*′, *—Ge(R₃₈ₐ)(R_{38b})—*′, *—S—*′, *—Se—*′, *—O—*′ *—C(═O)—*′, *—S(═O)—*, *—S(═O)₂—*′, *—C(R₃₈ₐ)═*′, *═C(R₃₈ₐ)—*′, *—C(R₃₈ₐ)═C(R_{38b})—*′, *—C(═S)—*′, *—C≡C—*′, a C₅-C₃₀ carbocyclic group unsubstituted or substituted with at least one R₁₀ₐ, or a C₁-C₃₀ heterocyclic group unsubstituted or substituted with at least one R₁₀ₐ,
n31 to n34 may each independently be an integer from 0 to 5, and three or more of n31 to n34 may each independently be an integer from 1 to 5,
when n31 is 0, T₃₁ may not be present, when n32 is 0, T₃₂ may not be present, when n33 is 0, T₃₃ may not be present, and when n34 is 0, T₃₄ may not be present,
when n31 is 2 or more, two or more of T₃₁ may be identical to or different from each other, when n32 is 2 or more, two or more of T₃₂ may be identical to or different from each other, when n33 is 2 or more, two or more of T₃₃ may be identical to or different from each other, and when n34 is 2 or more, two or more of T₃₄ may be identical to or different from each other,
R₃₁ to R₃₄, R₃₅ₐ, R_{35b}, R₃₆ₐ, R_{36b}, R₃₇ₐ, R_{37b}, R₃₈ₐ, and R_{38b} may each independently be hydrogen, deuterium, —F, —Cl, —Br, —I, —CD₃, —CD₂H, —CDH₂, —CF₃, —CF₂H, —CFH₂, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ arylalkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉),
a31 to a34 may each independently be an integer from 0 to 20,
two or more of R₃₁ in the number of a31 may optionally be bonded to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
two or more of R₃₂ in the number of a32 may optionally be bonded to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
two or more of R₃₃ in the number of a33 may optionally be bonded to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
two or more of R₃₄ in the number of a34 may optionally be bonded to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
two or more of R₃₁, R₃₂, R₃₃, R₃₄, R₃₅ₐ, R_{35b}, R₃₆ₐ, R_{36b}, R₃₇ₐ, R_{37b}, R₃₈ₐ, and R_{38b} may optionally be bonded to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
R₁₀ₐ may be the same as described herein in connection with R₃₁,
* and *′ each indicate a binding site to a neighboring atom,
at least one substituent of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ arylalkyl group, the substituted C₆-C₆₀ aryloxy group, the substituted C₆-C₆₀ arylthio group, the substituted C₁-C₆₀ heteroaryl group, the substituted C₂-C₆₀ heteroarylalkyl group, the substituted monovalent non-aromatic condensed polycyclic group, and the substituted monovalent non-aromatic condensed heteropolycyclic group may each independently be:
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, or a C₁-C₆₀ alkoxy group;
a C₁-C₆₀ alkyl group, a C₂-C₆₀ alkenyl group, a C₂-C₆₀ alkynyl group, or a C₁-C₆₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or any combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), or —P(Q₂₈)(Q₂₉);
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), —P(Q₃₈)(Q₃₉), or any combination thereof; or
any combination thereof, and
Q₁ to Q₉, Q₁₁ to Q₁₉, Q₂₁ to Q₂₉, and Q₃₁ to Q₃₉ may each independently be: hydrogen; deuterium; —F; —Cl; —Br; —I; a hydroxyl group; a cyano group; a nitro group; an amidino group; a hydrazine group; a hydrazone group; a carboxylic acid group or a salt thereof; a sulfonic acid group or a salt thereof; a phosphoric acid group or a salt thereof; a C₁-C₆₀ alkyl group unsubstituted or substituted with deuterium, a C₁-C₆₀ alkyl group, a C₆-C₆₀ aryl group, or any combination thereof; a C₂-C₆₀ alkenyl group; a C₂-C₆₀ alkynyl group; a C₁-C₆₀ alkoxy group; a C₃-C₁₀ cycloalkyl group; a C₁-C₁₀ heterocycloalkyl group; a C₃-C₁₀ cycloalkenyl group; a C₁-C₁₀ heterocycloalkenyl group; a C₆-C₆₀ aryl group unsubstituted or substituted with deuterium, a C₁-C₆₀ alkyl group, a C₆-C₆₀ aryl group, or any combination thereof; a C₆-C₆₀ aryloxy group; a C₆-C₆₀ arylthio group; a C₁-C₆₀ heteroaryl group; a monovalent non-aromatic condensed polycyclic group; or a monovalent non-aromatic condensed heteropolycyclic group.

In an embodiment, M₃₁ in Formula 3 may be Pt, Pd, or Au.

In one or more embodiments, M₃₁ in Formula 3 may be Pt or Pd.

In one or more embodiments, in Formula 3, a bond between X₁₁ and M₃₁ may be a coordinate bond.

In one or more embodiments, in Formula 3, X₁₁ may be C, and a bond between X₁₁ and M₃₁ may be a coordinate bond. That is, X₁₁ in Formula 3 may be C in a carbene moiety.

In one or more embodiments, ring CY₃₁ to ring CY₃₄ in Formula 3 may each independently be i) a first ring, ii) a second ring, iii) a condensed ring in which two or more first rings are condensed with each other, iv) a condensed ring in which two or more second rings are condensed with each other, or v) a condensed ring in which at least one first ring is condensed with at least one second ring,

In one or more embodiments, the first ring may be a cyclopentane group, a cyclopentadiene group, a furan group, a thiophene group, a pyrrole group, a silole group, an oxazole group, an isoxazole group, an oxadiazole group, an isoxadiazole group, an oxatriazole group, an isoxatriazole group, a thiazole group, an isothiazole group, a thiadiazole group, an isothiadiazole group, a thiatriazole group, an isothiatriazole group, a pyrazole group, an imidazole group, a triazole group, a tetrazole group, an azasilole group, a diazasilole group, or a triazasilole group, and

In one or more embodiments, the second ring may be an adamantane group, a norbornane group, a norbornene group, a cyclohexane group, a cyclohexene group, a benzene group, a pyridine group, a pyrimidine group, a pyrazine group, a pyridazine group, a triazine group, an oxazine group, a thiazine group, a dihydropyrazine group, a dihydropyridine group, or a dihydroazasiline group.

In an embodiment, R₃₁ to R₃₄, R₃₅ₐ, R_{35b}, R₃₆ₐ, R_{36b}, R₃₇ₐ, R_{37b}, R₃₈ₐ, and R_{38b} may each independently be:
hydrogen, deuterium, —F, —Cl, —Br, —I, —CD₃, —CD₂H, —CDH₂, —CF₃, —CF₂H, —CFH₂, a cyano group (CN), a nitro group, an amino group, a C₁-C₂₀ alkyl group, or a C₁-C₂₀ alkoxy group;

a C₁-C₂₀ alkyl group or a C₁-C₂₀ alkoxy group, each substituted with at least one of deuterium, —F, —Cl, —Br, —I, —CD₃, —CD₂H, —CDH₂, —CF₃, —CF₂H, —CFH₂, a cyano group (CN), a nitro group, an amino group, and a phenyl group; or

a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, or an anthracenyl group, each unsubstituted or substituted with at least one of deuterium, —F, —Cl, —Br, —I, —CD₃, —CD₂H, —CDH₂, —CF₃, —CF₂H, —CFH₂, a cyano group (CN), a nitro group, an amino group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a cycloheptenyl group, a phenyl group, a biphenyl group, a naphthyl group, a fluorenyl group, a phenanthrenyl group, and an anthracenyl group.

In an embodiment, the organometallic compound represented by Formula 3 may be an organometallic compound represented by Formula 3-1 or an organometallic compound represented by Formula 3-2:

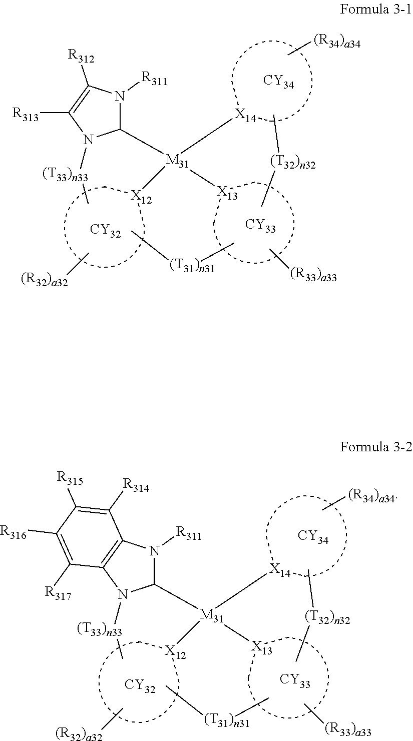

In Formula 3-1, a bond between carbon of an imidazole group and M₃₁ may be a coordinate bond. That is, the imidazole group in Formula 3-1 may include a carbene moiety bonded to M₃₁.

In Formula 3-2, a bond between carbon of a benzimidazole group and M₃₁ may be a coordinate bond. That is, the benzimidazole group in Formula 3-2 may include a carbene moiety bonded to M₃₁.

Therefore, Formula 3-1′ in which the carbon bonded to M₃₁ in the imidazole group is carbene, is the same as Formula 3-1, and Formula 3-2′ in which the carbon bonded to M₃₁ in the benzimidazole group is carbene, is the same as Formula 3-2:

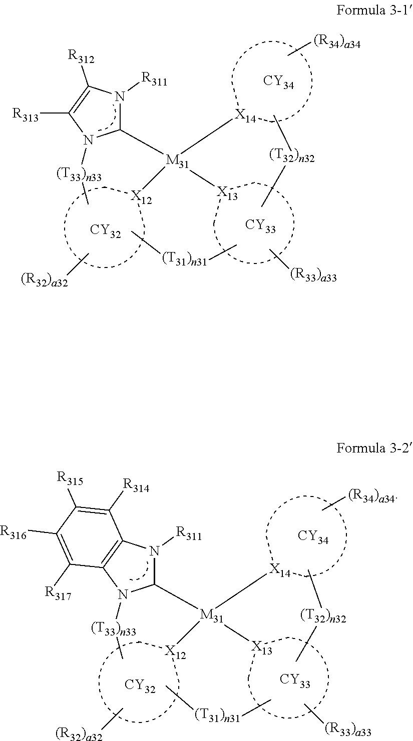

wherein, In Formulae 3-1 and 3-2,
M₃₁, CY₃₂, CY₃₃, CY₃₄, X₁₂, X₁₃, X₁₄, T₃₁, T₃₂, T₃₃, n31, n32, n33, R₃₂, R₃₃, R₃₄, a32, a33, and a34 may each be the same as described herein, and
R₃₁₁ to R₃₁₇ may each be the same as described herein in connection with R₃₁.

In an embodiment, in Formulae 3-1 and 3-2,
R₃₁₁ to R₃₁₇ may each independently be:
hydrogen, deuterium, —F, —Cl, —Br, —I, —CD₃, —CD₂H, —CDH₂, —CF₃, —CF₂H, —CFH₂, —SF₅, a hydroxyl group, a cyano group, a nitro group, an amidino group, a hydrazine group, a hydrazone group, a carboxylic acid group or a salt thereof, a sulfonic acid group or a salt thereof, or a phosphoric acid group or a salt thereof;
a C₁-C₂₀ alkyl group or a C₁-C₂₀ alkoxy group, each unsubstituted or substituted with deuterium, —F, —Cl, —Br, —I, —CD₃, —CD₂H, —CDH₂, —CF₃, —CF₂H, —CFH₂, —SF₅, a hydroxyl group, a cyano group, a nitro group, an amidino group, a hydrazine group, a hydrazone group, or any combination thereof;
a C₃-C₁₀ cycloalkyl group, a C₁-C₁₀ heterocycloalkyl group, a C₆-C₆₀ aryl group, a C₇-C₆₀ arylalkyl group, a C₆-C₆₀ aryloxy group, a C₆-C₆₀ arylthio group, a C₁-C₆₀ heteroaryl group, a C₂-C₆₀ heteroarylalkyl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, —SF₅, a hydroxyl group, a cyano group, a nitro group, an amidino group, a hydrazine group, a hydrazone group, a C₁-C₂₀ alkyl group, a C₁-C₂₀ alkoxy group, or any combination thereof; or
—N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉).

In an embodiment, at least one of R₃₁₁ to R₃₁₇ in Formulae 3-1 and 3-2 may include a C₁-C₂₀ alkyl group, a C₆-C₆₀ aryl group, or a C₇-C₆₀ arylalkyl group, each unsubstituted or substituted with deuterium, a methyl group, an ethyl group, an n-propyl group, an isopropyl group, an n-butyl group, an isobutyl group, a sec-butyl group, a tert-butyl group, a phenyl group, a cumyl group, or any combination thereof.

According to an embodiment, the organometallic compound represented by Formula 3 may be an organometallic compound represented by Formula 3-1(1) or an organometallic compound represented by Formula 3-2(1):

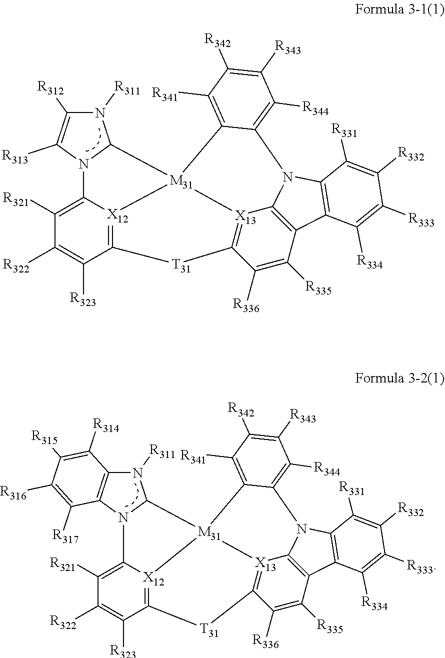

wherein, In Formulae 3-1(1) and 3-2(1),
M₃₁, X₁₂, X₁₃, X₁₄, and T₃₁ are each the same as described herein,
R₃₁₁ to R₃₁₇ may each be the same as described in connection with R₃₁,
R₃₂₁, R₃₂₂, and R₃₂₃ may each be the same as described in connection with R₃₂, and two or more of R₃₂₁, R₃₂₂, and R₃₂₃ may optionally be bonded together to form a C₅-C₃₀ carbocyclic group unsubstituted or substituted with at least one R₁₀ₐ or a C₁-C₃₀ heterocyclic group unsubstituted or substituted with at least one R₁₀ₐ,
R₃₃₁ to R₃₃₆ may each be the same as described in connection with R₃₃, and two or more of R₃₃₁ to R₃₃₆ may optionally be bonded together to form a C₅-C₃₀ carbocyclic group unsubstituted or substituted with at least one R₁₀ₐ or a C₁-C₃₀ heterocyclic group unsubstituted or substituted with at least one R₁₀ₐ, and
R₃₄₁ to R₃₄₄ may each be the same as described in connection with R₃₄, and two or more of R₃₄₁ to R₃₄₄ may optionally be bonded together to form a C₅-C₃₀ carbocyclic group unsubstituted or substituted with at least one R₁₀ₐ or a C₁-C₃₀ heterocyclic group unsubstituted or substituted with at least one R₁₀ₐ. R₁₀ₐ is as described herein.

The organometallic compound may be an organometallic compound represented by Formula 5:

M₅₁(L₅₁)ₙ₅₁(L₅₂)ₙ₅₂ Formula 5
wherein, in Formula 5, M₅₁ may be a transition metal.

In an embodiment, M₅₁ may be a first-row transition metal, a second-row transition metal, or a third-row transition metal of the Periodic Table of Elements.

In one or more embodiments, M₅₁ may be iridium (Ir), platinum (Pt), osmium (Os), titanium (Ti), zirconium (Zr), hafnium (Hf), europium (Eu), terbium (Tb), thulium (Tm), or rhodium (Rh).

In one or more embodiments, M₅₁ may be Ir, Pt, Os, or Rh.

In one or more embodiments, M₅₁ may be Ir or Os.

In Formula 5, L₅₁ may be a ligand represented by Formula 5A, and L₅₂ may be a ligand represented by Formula 5B:

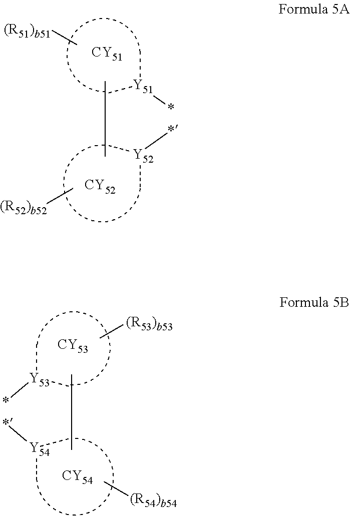

wherein details on Formulae 5A and 5B may be the same as described herein.

In Formula 5, n51 may be 1, 2, or 3, and when n51 is 2 or more, two or more of L₅₁ may be identical to or different from each other.

In Formula 5, n52 may be 0, 1, or 2, and when n52 is 2, two of L₅₂ may be identical to or different from each other.

The sum of n51 and n52 in Formula 5 may be 2 or 3. For example, the sum of n51 and n52 may be 3.

In an embodiment, in Formula 5, i) M may be Ir, and the sum of n51 and n52 may be 3; or ii) M may be Pt, and the sum of n51 and n52 may be 2.

In one or more embodiments, in Formula 5, M may be Ir, and i) n51 may be 1, and n52 may be 2; or ii) n51 may be 2, and n52 may be 1.

L₅₁ and L₅₂ in Formula 5 may be different from each other.

Y₅₁ to Y₅₄ in Formulae 5A to 5B may each independently be C or N. For example, Y₅₁ and Y₅₃ may each be N, and Y₅₂ and Y₅₄ may each be C.

Ring CY₅₁ and ring CY₅₂ in Formula 5A, and ring CY₅₃ and ring CY₅₄ in Formula 5B may each independently be a C₅-C₃₀ carbocyclic group or a C₁-C₃₀ heterocyclic group.

For example, ring CY₅₁ to ring CY₅₄ in Formulae 5A and 5B may each independently include i) a third ring, ii) a fourth ring, iii) a condensed ring in which two or more third rings are condensed with each other, iv) a condensed ring in which two or more fourth rings are condensed with each other, or v) a condensed ring in which at least one third ring is condensed with at least one fourth ring.

In one or more embodiments, the third ring may be a cyclopentane group, a cyclopentene group, a furan group, a thiophene group, a pyrrole group, a silole group, a borole group, a phosphole group, a germole group, a selenophene group, an oxazole group, an oxadiazole group, an oxatriazole group, a thiazole group, a thiadiazole group, a thiatriazole group, a pyrazole group, an imidazole group, a triazole group, a tetrazole group, or an azasilole group, and

In one or more embodiments, the fourth ring may be an adamantane group, a norbornane group, a norbornene group, a cyclohexane group, a cyclohexene group, a benzene group, a pyridine group, a pyrimidine group, a pyrazine group, a pyridazine group, or a triazine group.

In one or more embodiments, ring CY₅₁ to ring CY₅₄ in Formulae 5A and 5B may each independently be a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, a cyclopentadiene group, a pyrrole group, a furan group, a thiophene group, a silole group, a borole group, a phosphole group, a germole group, a selenophene group, an indene group, an indole group, a benzofuran group, a benzothiophene group, a benzosilole group, a benzoborole group, a benzophosphole group, a benzogermole group, a benzoselenophene group, a fluorene group, a carbazole group, a dibenzofuran group, a dibenzothiophene group, a dibenzosilole group, a dibenzoborole group, a dibenzophosphole group, a dibenzogermole group, a dibenzoselenophene group, a benzofluorene group, a benzocarbazole group, a naphthobenzofuran group, a naphthobenzothiophene group, a naphthobenzosilole group, a naphthobenzoborole group, a naphthobenzophosphole group, a naphthobenzogermole group, a naphthobenzoselenophene group, a dibenzofluorene group, a dibenzocarbazole group, a dinaphthofuran group, a dinaphthothiophene group, a dinaphthosilole group, a dinaphthoborole group, a dinaphthophosphole group, a dinaphthogermole group, a dinaphthoselenophene group, an indenophenanthrene group, an indolophenanthrene group, a phenanthrobenzofuran group, a phenanthrobenzothiophene group, a phenanthrobenzosilole group, a phenanthrobenzoborole group, a phenanthrobenzophosphole group, a phenanthrobenzogermole group, a phenanthrobenzoselenophene group, a dibenzothiophene 5-oxide group, a 9H-fluorene-9-one group, a dibenzothiophene 5,5-dioxide group, an azaindene group, an azaindole group, an azabenzofuran group, an azabenzothiophene group, an azabenzosilole group, an azabenzoborole group, an azabenzophosphole group, an azabenzogermole group, an azabenzoselenophene group, an azafluorene group, an azacarbazole group, an azadibenzofuran group, an azadibenzothiophene group, an azadibenzosilole group, an azadibenzoborole group, an azadibenzophosphole group, an azadibenzogermole group, an azadibenzoselenophene group, an azabenzofluorene group, an azabenzocarbazole group, an azanaphthobenzofuran group, an azanaphthobenzothiophene group, an azanaphthobenzosilole group, an azanaphthobenzoborole group, an azanaphthobenzophosphole group, an azanaphthobenzogermole group, an azanaphthobenzoselenophene group, an azadibenzofluorene group, an azadibenzocarbazole group, an azadinaphthofuran group, an azadinaphthothiophene group, an azadinaphthosilole group, an azadinaphthoborole group, an azadinaphthophosphole group, an azadinaphthogermole group, an azadinaphthoselenophene group, an azaindenophenanthrene group, an azaindolophenanthrene group, an azaphenanthrobenzofuran group, an azaphenanthrobenzothiophene group, an azaphenanthrobenzosilole group, an azaphenanthrobenzoborole group, an azaphenanthrobenzophosphole group, an azaphenanthrobenzogermole group, an azaphenanthrobenzoselenophene group, an azadibenzothiophene 5-oxide group, an aza9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a benzoquinoline group, a benzoisoquinoline group, a benzoquinoxaline group, a benzoquinazoline group, a phenanthroline group, a phenanthridine group, a pyrazole group, an imidazole group, a triazole group, an oxazole group, an isoxazole group, a thiazole group, an isothiazole group, an oxadiazole group, a thiadiazole group, an azasilole group, an azaborole group, an azaphosphole group, an azagermole group, an azaselenophene group, a benzopyrrole group, a benzopyrazole group, a benzimidazole group, a benzoxazole group, a benzisoxazole group, a benzothiazole group, a benzisothiazole group, a benzoxadiazole group, a benzothiadiazole group, a pyridinopyrrole group, a pyridinopyrazole group, a pyridinoimidazole group, a pyridinoxazole group, a pyridinoisoxazole group, a pyridinothiazole group, a pyridinoisothiazole group, a pyridinoxadiazole group, a pyridinothiadiazole group, a pyrimidinopyrrole group, a pyrimidinopyrazole group, a pyrimidinoimidazole group, a pyrimidinoxazole group, a pyrimidinoisoxazole group, a pyrimidinothiazole group, a pyrimidinoisothiazole group, a pyrimidinoxadiazole group, a pyrimidinothiadiazole group, a 5,6,7,8-tetrahydroisoquinoline group, a 5,6,7,8-tetrahydroquinoline group, an adamantane group, a norbornane group, a norbornene group, a benzene group condensed with a cyclohexane group, a benzene group condensed with a norbornane group, a pyridine group condensed with a cyclohexane group, or a pyridine group condensed with a norbornane group.

In an embodiment, ring CY₅₁ and ring CY₅₃ in Formulae 5A and 5B may be different from each other.

In one or more embodiments, ring CY₅₂ and ring CY₅₄ in Formulae 5A and 5B may be different from each other.

In one or more embodiments, ring CY₅₁ to ring CY₅₄ in Formulae 5A and 5B may be different from each other.

R₅₁ to R₅₄ in Formulae 5A and 5B may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —N(Q₅₁)(Q₅₂), —Si(Q₅₃)(Q₅₄)(Q₅₅), —Ge(Q₅₃)(Q₅₄)(Q₅₅), —B(Q₅₆)(Q₅₇), —P(═O)(Q₅₈)(Q₅₉), or —P(Q₅₈)(Q₅₉). Q₅₁ to Q₅₉ may each be the same as described herein.

In an embodiment, R₅₁ to R₅₄ in Formulae 5A and 5B may each independently be:
hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a C₁-C₂₀ alkyl group, a C₁-C₂₀ alkoxy group, or a C₁-C₂₀ alkylthio group;
a C₁-C₂₀ alkyl group, a C₁-C₂₀ alkoxy group, or a C₁-C₂₀ alkylthio group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a pyridinyl group, a pyrimidinyl group, or any combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a phenyl group, a (C₁-C₂₀ alkyl)phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, or an azadibenzothiophenyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a (phenyl)C₁-C₁₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, or any combination thereof; or
—N(Q₅₁)(Q₅₂), —Si(Q₅₃)(Q₅₄)(Q₅₅), —Ge(Q₅₃)(Q₅₄)(Q₅₅), —B(Q₅₆)(Q₅₇), —P(═O)(Q₅₈)(Q₅₉), or —P(Q₅₈)(Q₅₉), and
Q₅₁ to Q₅₉ may each independently be:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with deuterium, a C₁-C₁₀ alkyl group, a phenyl group, or any combination thereof.

In one or more embodiments, R₅₁ to R₅₄ may each independently be:
hydrogen, deuterium, —F, or a cyano group;
a C₁-C₂₀ alkyl group unsubstituted or substituted with deuterium, a cyano group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a fluorinated C₁-C₁₀ heterocycloalkyl group, a (C₁-C₂₀ alkyl)C₁-C₁₀ heterocycloalkyl group, a phenyl group, a deuterated a phenyl group, a fluorinated phenyl group, a (C₁-C₂₀ alkyl)phenyl group, a biphenyl group, a deuterated a biphenyl group, a fluorinated biphenyl group, a (C₁-C₂₀ alkyl)biphenyl group, a dibenzofuranyl group, a deuterated a dibenzofuranyl group, a fluorinated dibenzofuranyl group, a (C₁-C₂₀ alkyl)dibenzofuranyl group, a dibenzothiophenyl group, a deuterated a dibenzothiophenyl group, a fluorinated dibenzothiophenyl group, a (C₁-C₂₀ alkyl)dibenzothiophenyl group, or any combination thereof;
a C₃-C₁₀ cycloalkyl group, a C₁-C₁₀ heterocycloalkyl group, a phenyl group, or a biphenyl group, each unsubstituted or substituted with deuterium, a cyano group, a C₁-C₂₀ alkyl group, a deuterated C₁-C₂₀ alkyl group, a fluorinated C₁-C₂₀ alkyl group, a C₁-C₂₀ alkoxy group, a deuterated C₁-C₂₀ alkoxy group, a fluorinated C₁-C₂₀ alkoxy group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a fluorinated C₁-C₁₀ heterocycloalkyl group, a (C₁-C₂₀ alkyl)C₁-C₁₀ heterocycloalkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, a dibenzofuranyl group, a deuterated dibenzofuranyl group, a fluorinated dibenzofuranyl group, a (C₁-C₂₀ alkyl)dibenzofuranyl group, a dibenzothiophenyl group, a deuterated dibenzothiophenyl group, a fluorinated dibenzothiophenyl group, a (C₁-C₂₀ alkyl)dibenzothiophenyl group, or any combination thereof; or
—Si(Q₅₃)(Q₅₄)(Q₅₅) or —Ge(Q₅₃)(Q₅₄)(Q₅₅).

b51 to b54 in Formulae 5A and 5B indicate the numbers of R₅₁ to R₅₄, respectively, and may each independently be an integer from 0 to 20. When b51 is 2 or more, two or more of R₅₁ may be identical to or different from each other, when b52 is 2 or more, two or more of R₅₂ may be identical to or different from each other, when b53 is 2 or more, two or more of R₅₃ may be identical to or different from each other, and when b54 is 2 or more, two or more of R₅₄ may be identical to or different from each other. For example, b51 to b54 may each independently be an integer from 0 to 8.

In an embodiment, in Formula 5A, Y₅₂ may be C, a bond between Y₅₂ and M₅₁ may be a covalent bond, and at least one of R₅₂ in the number of b52 may be a cyano group or —F.

In one or more embodiments, in Formula 5A, Y₅₁ may be N, a bond between Y₅₁ and M₅₁ may be a coordinate bond, CY₅₁ may be an imidazole group, a triazole group, a benzimidazole group, or a triazolopyridine group, and at least one of R₅₂ in the number of b52 may be a cyano group or —F.

In one or more embodiments, in Formula 5A, Y₅₁ may be C, and a bond between Y₅₁ and M₅₁ may be a coordinate bond.

In one or more embodiments, in Formula 5A, Y₅₁ may be C, a bond between Y₅₁ and M₅₁ may be a coordinate bond, and CY₅₁ may be a benzimidazole group or an imidazopyrazine group.

In an embodiment, the organometallic compound represented by Formula 3 or 5 may be one of Compounds P1 to P52:

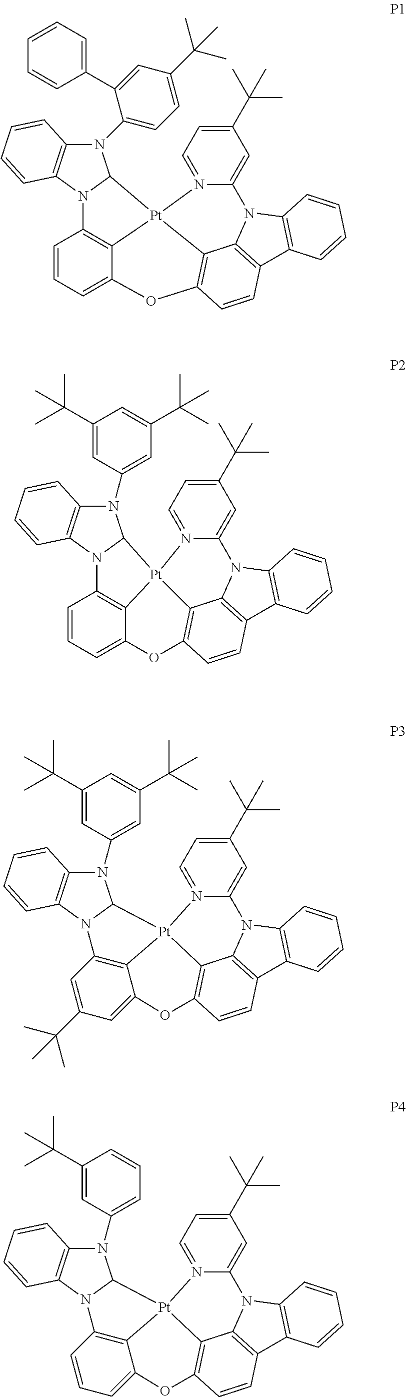

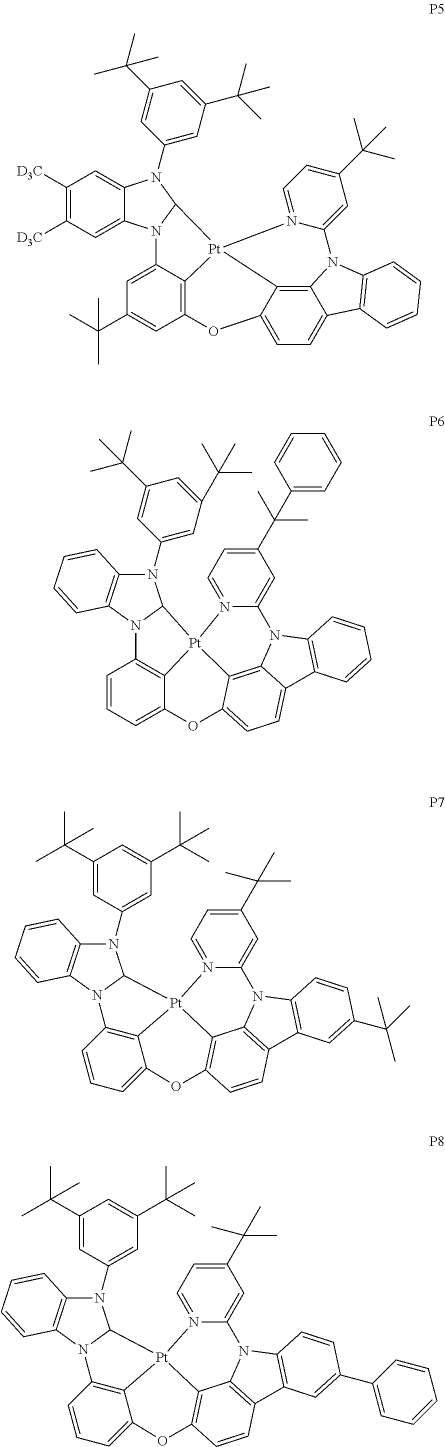

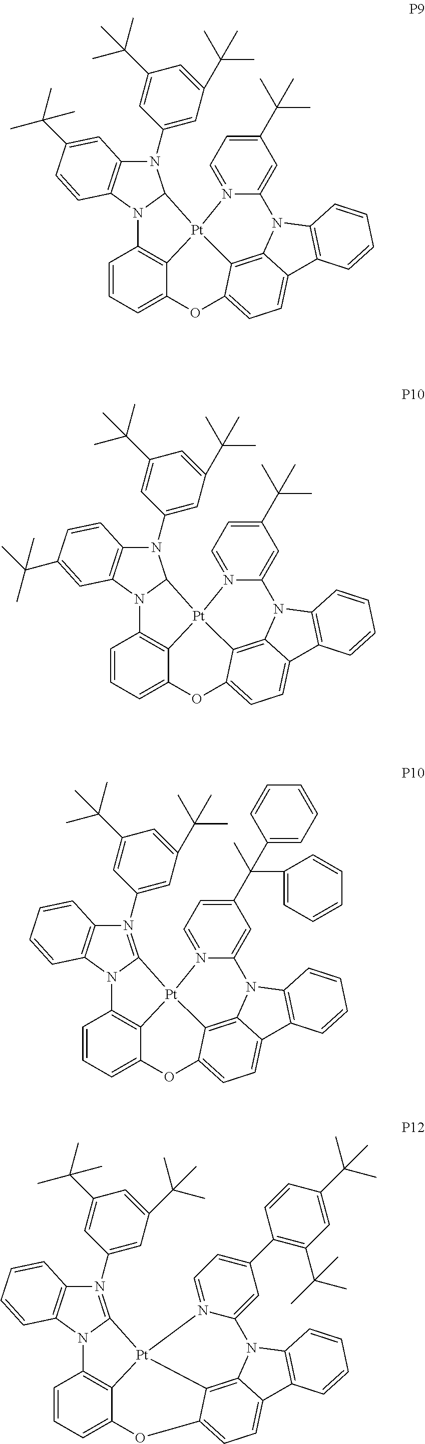

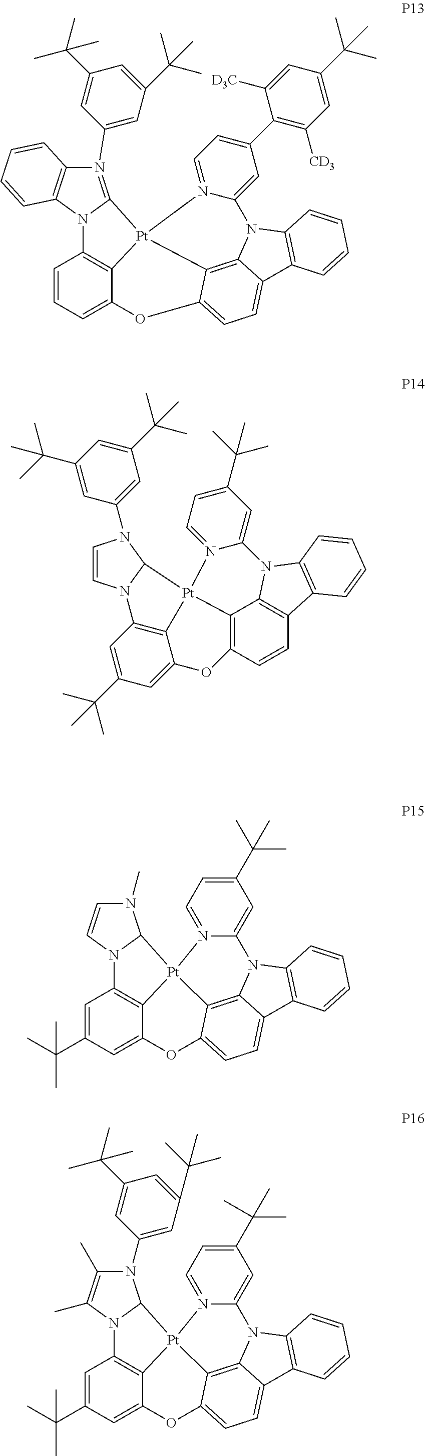

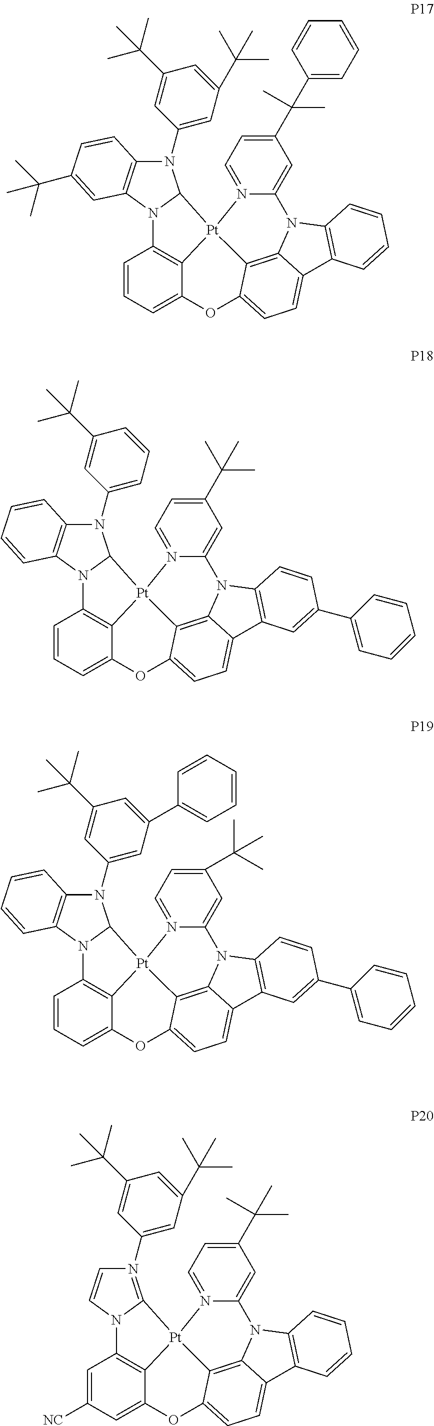

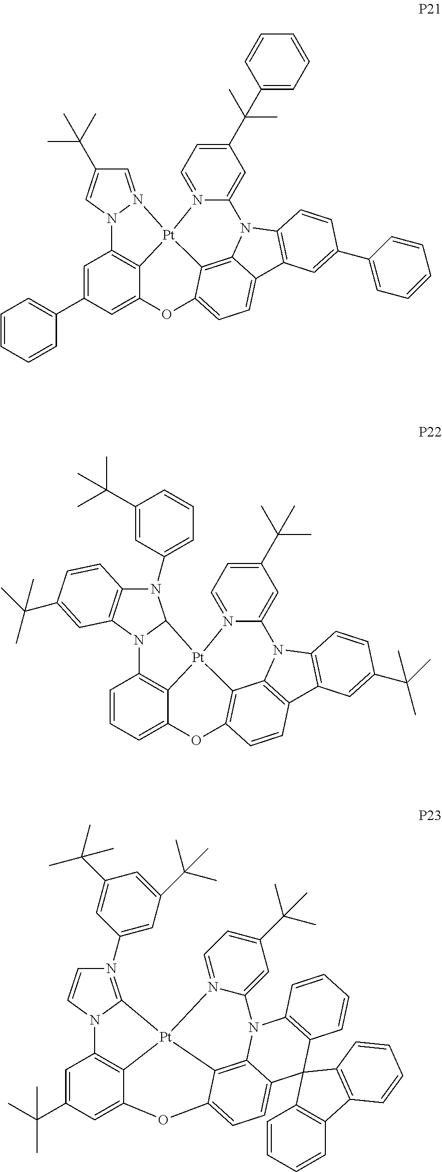

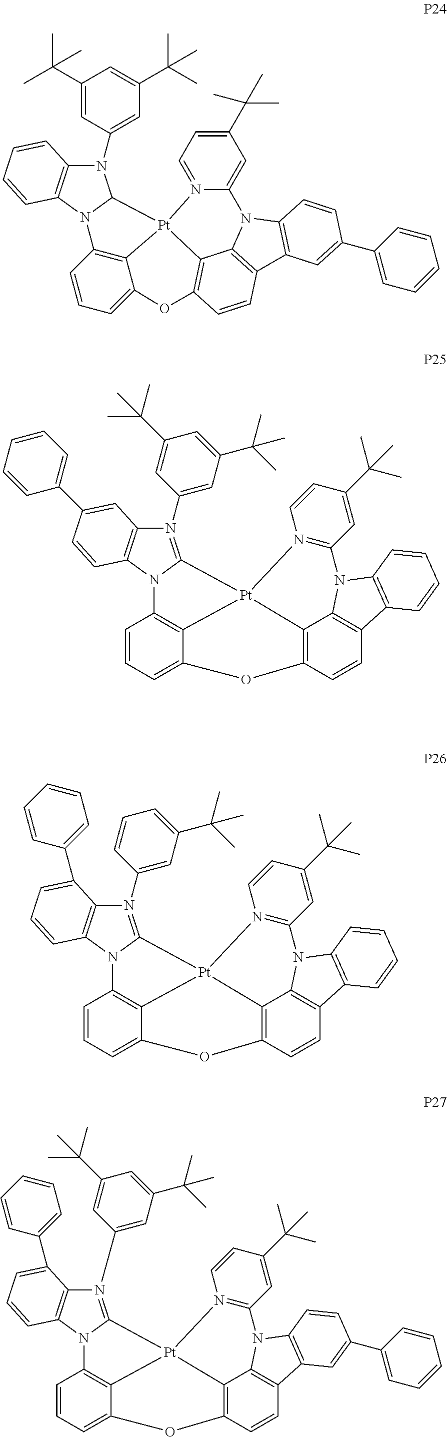

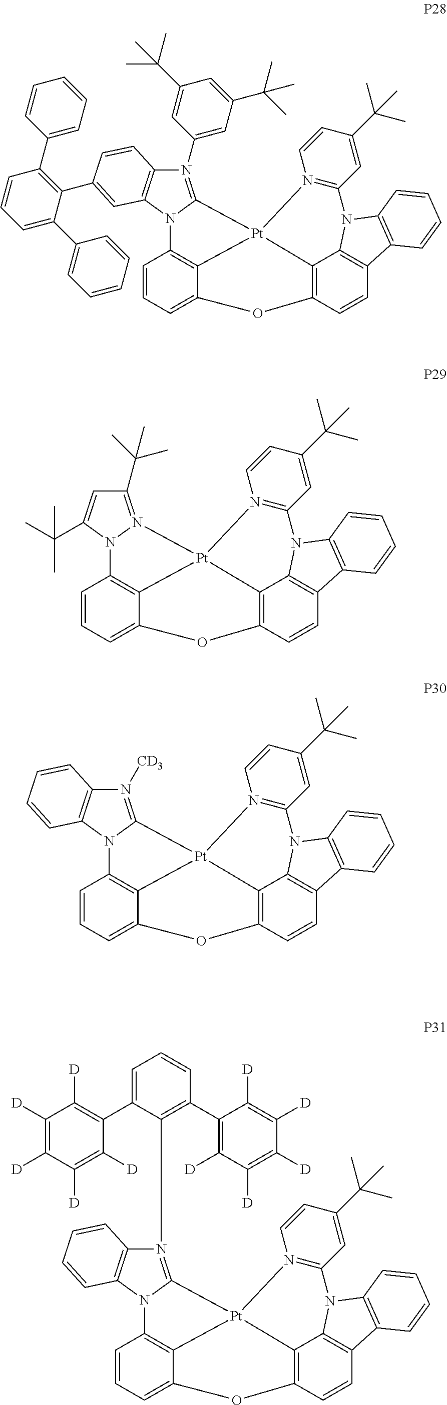

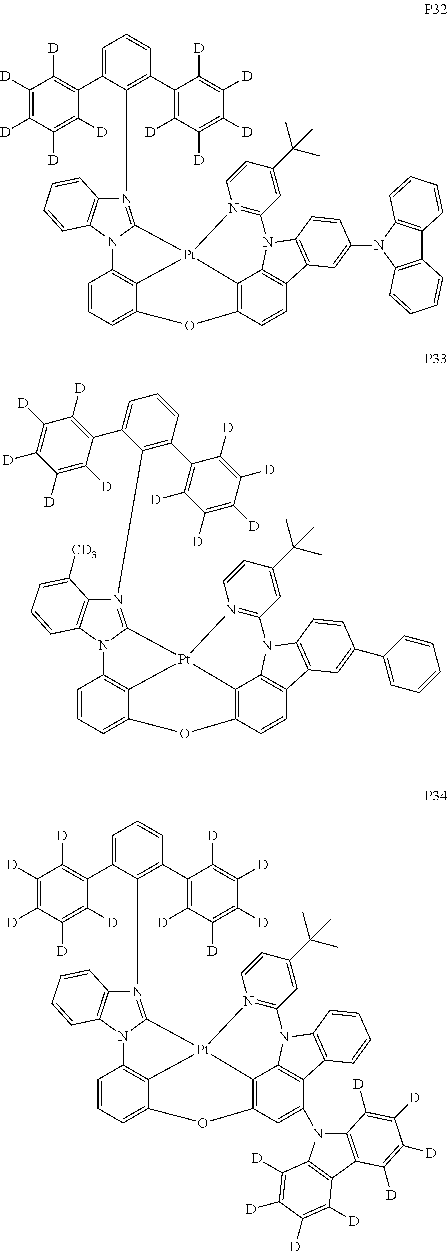

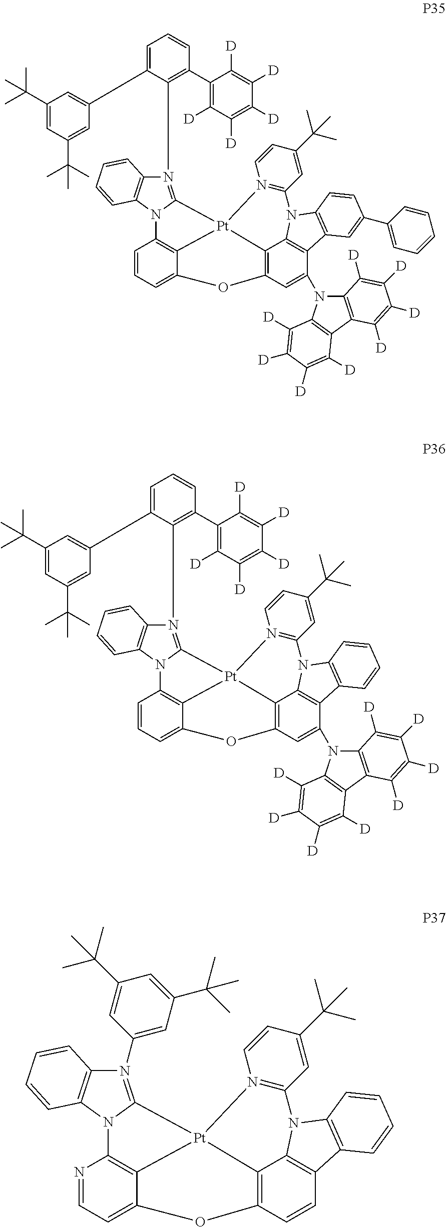

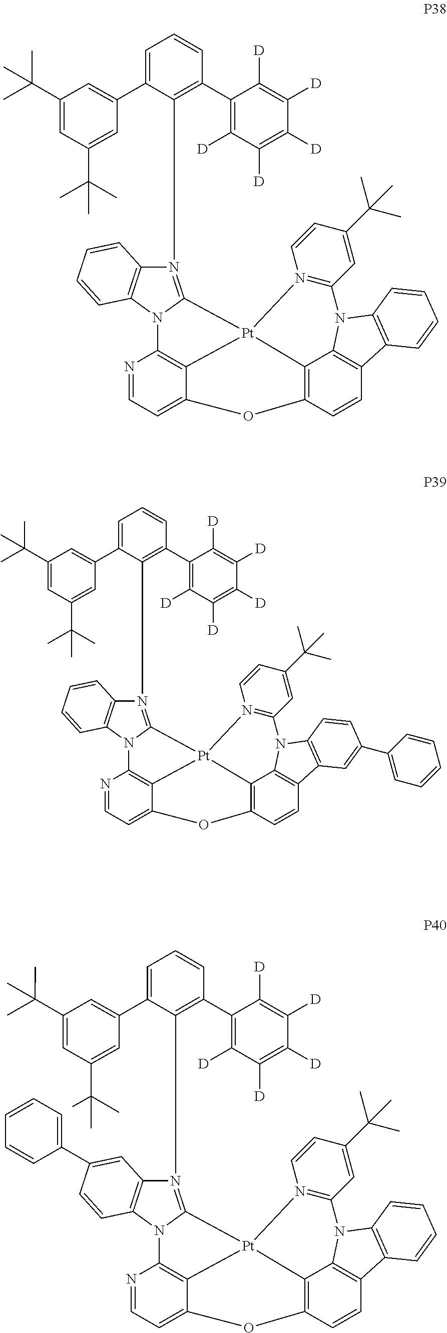

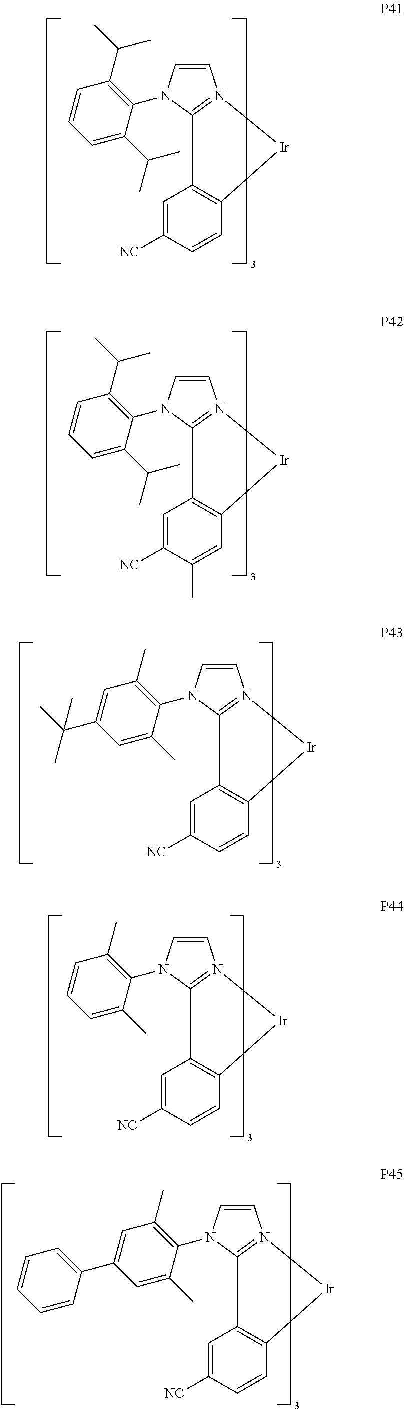

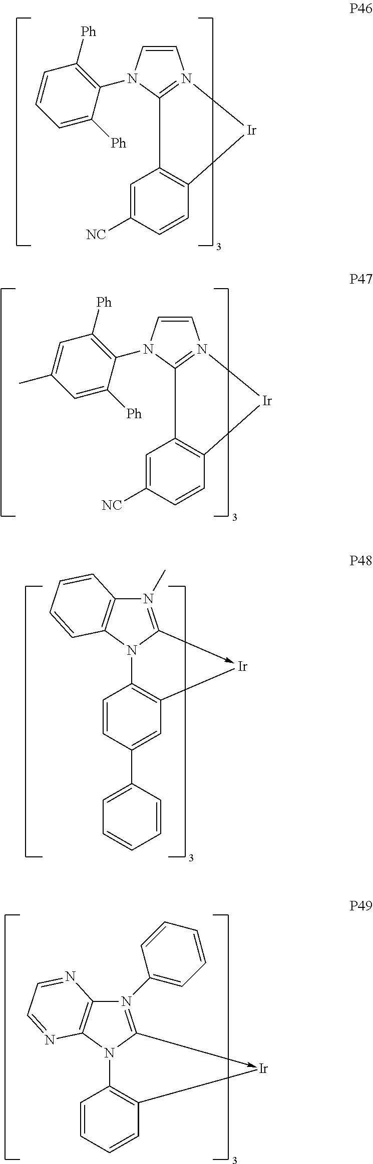

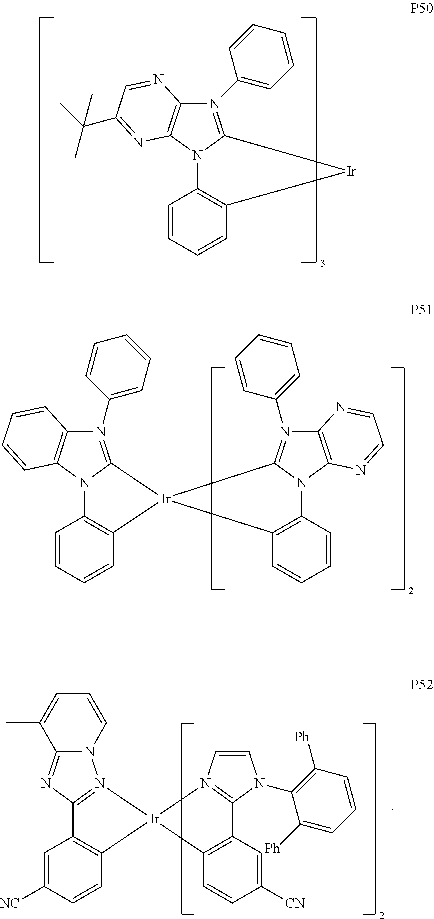

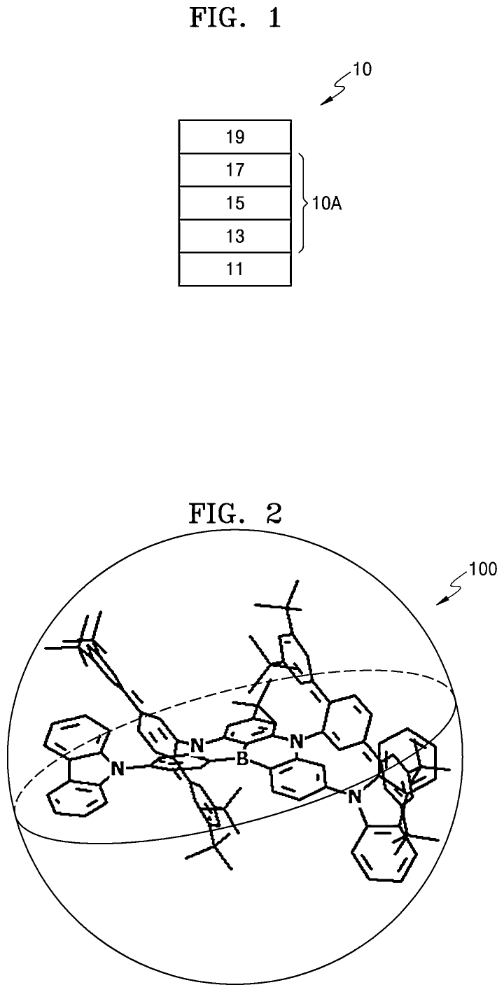

FIG. 1 is a schematic cross-sectional view of an organic light-emitting device 10 according to an embodiment. Hereinafter, the structure and manufacturing method of the organic light-emitting device 10 according to an embodiment will be described with reference to FIG. 1.

In FIG. 1, the organic light-emitting device 10 includes a first electrode 11, a second electrode 19 facing the first electrode 11, and an interlayer 10A arranged between the first electrode 11 and the second electrode 19.

In FIG. 1, the interlayer 10A includes an emission layer 15, a hole transport region 13 is arranged between the first electrode 11 and the emission layer 15, and an electron transport region 17 is arranged between the emission layer 15 and the second electrode 19.

A substrate may be additionally arranged under the first electrode 11 or on the second electrode 19. For use as the substrate, any substrate that is used in organic light-emitting devices available in the art may be used, and for example, a glass substrate or a transparent plastic substrate, each having excellent mechanical strength, thermal stability, transparency, surface smoothness, ease of handling, and water resistance, may be used.

The first electrode 11 may be formed by, for example, depositing or sputtering, onto a substrate, a material for forming the first electrode 11. The first electrode 11 may be an anode. The material for forming the first electrode 11 may include materials with a high work function to facilitate hole injection.

The first electrode 11 may be a reflective electrode, a semi-transmissive electrode, or a transmissive electrode. In an embodiment, when the first electrode 11 is a transmissive electrode, the material for forming the first electrode 11 may include indium tin oxide (ITO), indium zinc oxide (IZO), tin oxide (SnO₂), zinc oxide (ZnO), or any combination thereof. In one or more embodiments, when the first electrode 11 is a semi-transmissive electrode or a reflective electrode, the material for forming the first electrode 11 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 11 may have a single-layer structure or a multi-layer structure including two or more layers.

A thickness of the emission layer 15 may be in a range of about 100 Å to about 1,000 Å, for example, about 200 Å to about 600 Å. When the thickness of the emission layer 15 is within the ranges described above, excellent luminescence characteristics may be obtained without a substantial increase in driving voltage.

In an embodiment, the emission layer 15 may include the emitter and the host(s) in the number of m1 (and, optionally, the sensitizer), as described herein.

The hole transport region 13 may have a single-layer structure or a multi-layer structure.

In an embodiment, the hole transport region 13 may have a hole injection layer, a hole transport layer, a hole injection layer/hole transport layer structure, a hole injection layer/first hole transport layer/second hole transport layer structure, a hole injection layer/first hole transport layer/second hole transport layer/electron-blocking layer structure, a hole transport layer/buffer layer structure, a hole injection layer/hole transport layer/buffer layer structure, a hole transport layer/electron-blocking layer structure, or a hole injection layer/hole transport layer/electron-blocking layer structure.

The hole transport region 13 may include any compound having hole-transporting characteristics.

In an embodiment, the hole transport region 13 may include an amine-based compound.

In an embodiment, the hole transport region 13 may include m-MTDATA, TDATA, 2-TNATA, NPB, β-NPB, TPD, spiro-TPD, spiro-NPB, methylated-NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor-sulfonic acid (PANI/CSA), polyaniline/poly(4-styrene sulfonate) (PANI/PSS), a compound represented by one of Formulae 201 to 205, or any combination thereof:

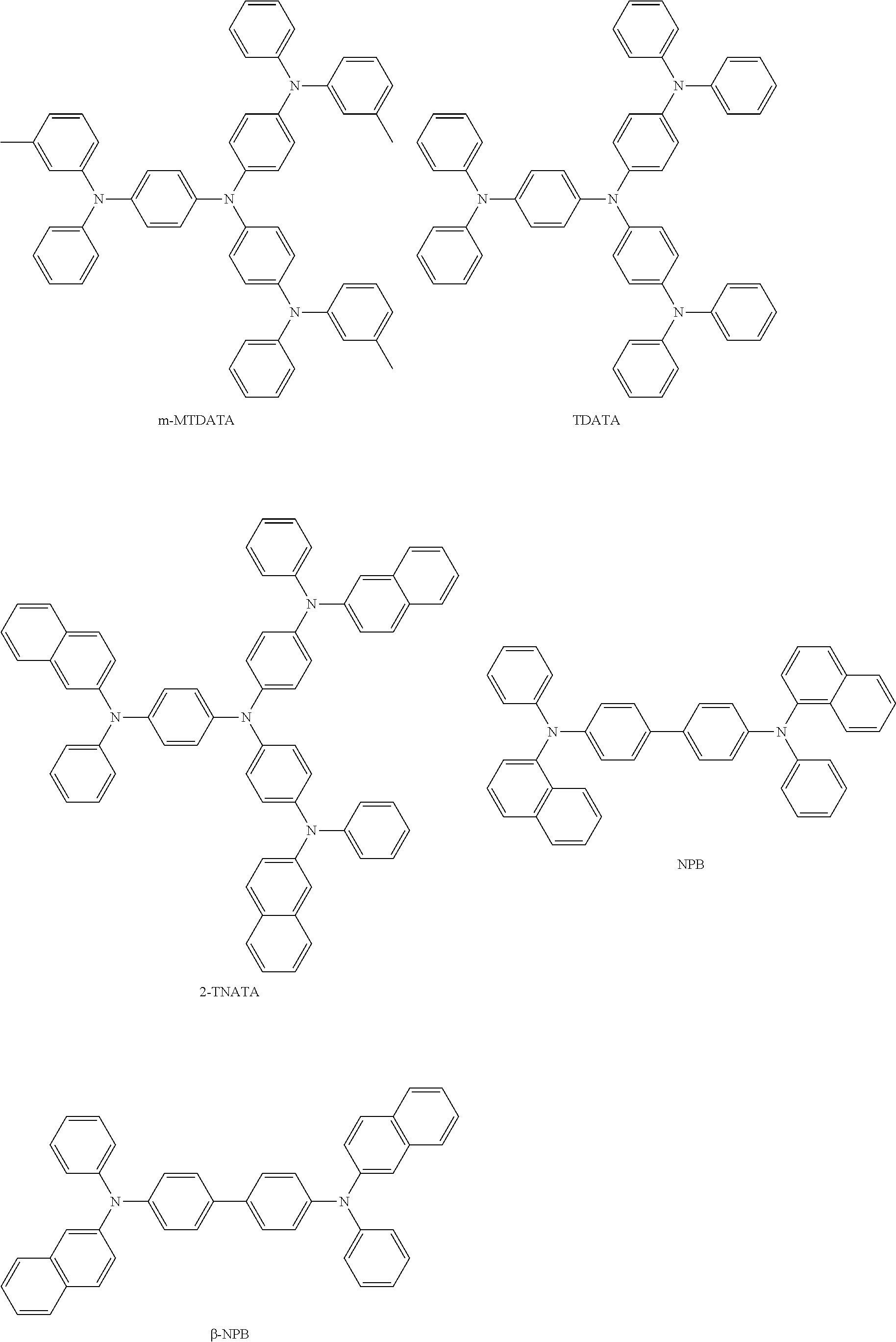

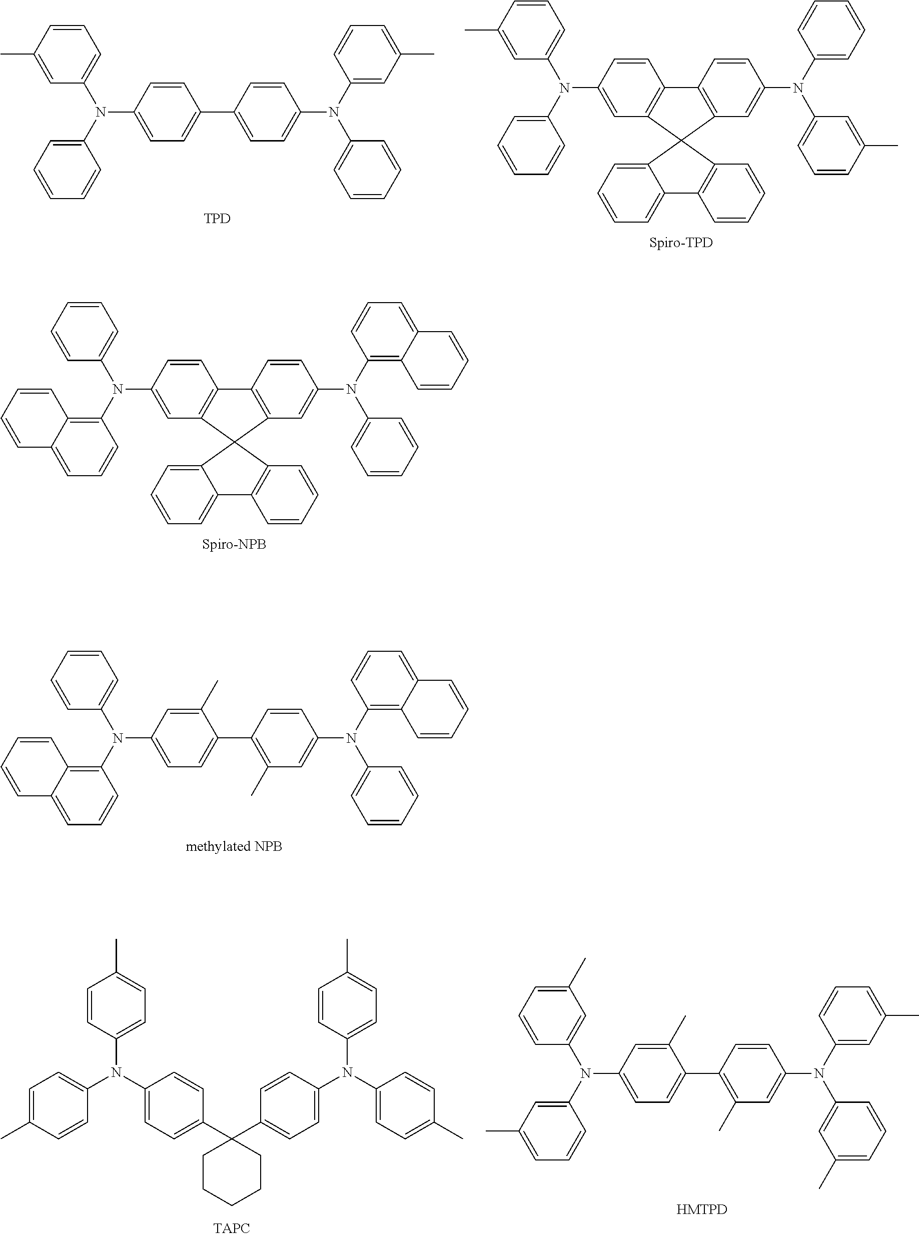

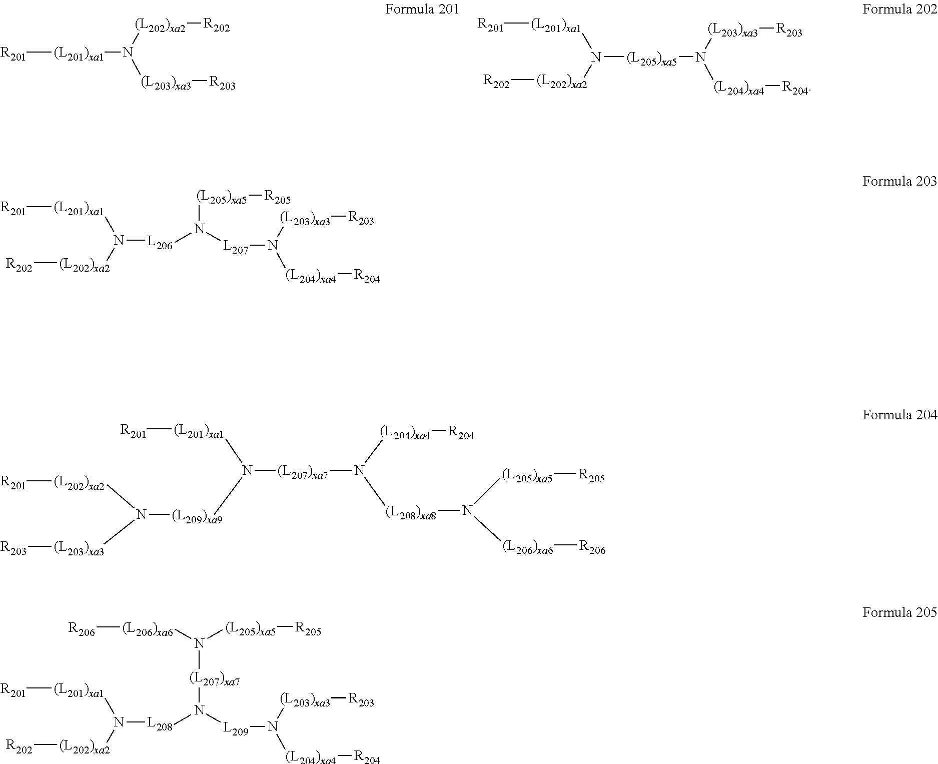

wherein, in Formulae 201 to 205,
L₂₀₁ to L₂₀₉ may each independently be *—O—*′, *—S—*′, a substituted or unsubstituted C₅-C₆₀ carbocyclic group, or a substituted or unsubstituted C₁-C₆₀ heterocyclic group,
xa1 to xa9 may each independently be an integer from 0 to 5, and
R₂₀₁ to R₂₀₆ may each independently be a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group, wherein neighboring two groups of R₂₀₁ to R₂₀₆ may optionally be linked to each other via a single bond, a dimethyl-methylene group, or a diphenyl-methylene group.

In an embodiment,
L₂₀₁ to L₂₀₉ may be a benzene group, a heptalene group, an indene group, a naphthalene group, an azulene group, a heptalene group, an indacene group, an acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, a hexacene group, a pentacene group, a rubicene group, a coronene group, an ovalene group, a pyrrole group, an isoindole group, an indole group, a furan group, a thiophene group, a benzofuran group, a benzothiophene group, a benzocarbazole group, a dibenzocarbazole group, a dibenzofuran group, a dibenzothiophene group, a dibenzothiophene sulfone group, a carbazole group, a dibenzosilole group, an indenocarbazole group, an indolocarbazole group, a benzofurocarbazole group, a benzothienocarbazole group, or a triindolobenzene group, each unsubstituted or substituted with deuterium, a C₁-C₁₀ alkyl group, a C₁-C₁₀ alkoxy group, a phenyl group, a naphthyl group, a fluorenyl group, a carbazolyl group, a dibenzofuranyl group, a dibenzothiophenyl group, a triphenylenyl group, a biphenyl group, a terphenyl group, a quarterphenyl (or, tetraphenyl group), —Si(Q₁₁)(Q₁₂)(Q₁₃), or any combination thereof,
xa1 to xa9 may each independently be 0, 1, or 2, and
R₂₀₁ to R₂₀₆ may each independently be a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an indeno carbazolyl group, an indolocarbazolyl group, a benzofurocarbazolyl group, or a benzothienocarbazolyl group, each unsubstituted or substituted with deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a phenyl group substituted with a C₁-C₁₀ alkyl group, a phenyl group substituted with —F, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, —Si(Q₃₁)(Q₃₂)(Q₃₃), —N(Q₃₁)(Q₃₂) or any combination thereof, and
Q₁₁, Q₁₂, and Q₁₃, and Q₃₁, Q₃₂, and Q₃₃, may each independently be a C₁-C₁₀ alkyl group, a C₁-C₁₀ alkoxy group, a phenyl group, a biphenyl group, a terphenyl group, or a naphthyl group.

In an embodiment, the hole transport region 13 may include a carbazole-containing amine-based compound.

In one or more embodiments, the hole transport region 13 may include a carbazole-containing amine-based compound and a carbazole-free amine-based compound.

The carbazole-containing amine-based compound may include, for example, compounds represented by Formula 201 including a carbazole group and further including at least one of a dibenzofuran group, a dibenzothiophene group, a fluorene group, a spiro-bifluorene group, an indenocarbazole group, an indolocarbazole group, a benzofurocarbazole group, and a benzothienocarbazole group.

The carbazole-free amine-based compound may include, for example, compounds represented by Formula 201 not including a carbazole group and including at least one of a dibenzofuran group, a dibenzothiophene group, a fluorene group, a spiro-bifluorene group, an indenocarbazole group, an indolocarbazole group, a benzofurocarbazole group, and a benzothienocarbazole group.

In one or more embodiments, the hole transport region 13 may include a compound represented by Formula 201, a compound represented by Formula 202, or any combination thereof.

In one or more embodiments, the hole transport region 12 may include a compound represented by Formula 201-1, 202-1, or 201-2, or any combination thereof:

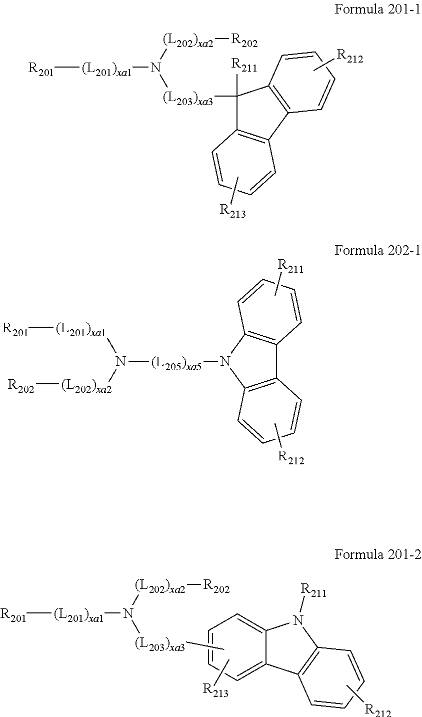

wherein, in Formulae 201-1, 202-1, and 201-2, L₂₀₁, L₂₀₂, L₂₀₃, L₂₀₅, xa1, xa2, xa3, xa5, R₂₀₁, and R₂₀₂ may each be the same as described herein, and R₂₁₁, R₂₁₂, and R₂₁₃ may each independently be hydrogen, deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a phenyl group substituted with a C₁-C₁₀ alkyl group, a phenyl group substituted with —F, a naphthyl group, a fluorenyl group, a spiro-bifluorenyl group, a dimethylfluorenyl group, a diphenylfluorenyl group, a triphenylenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, or a pyridinyl group.

In an embodiment, the hole transport region 13 may include one of Compounds HT1 to HT39 or any combination thereof:

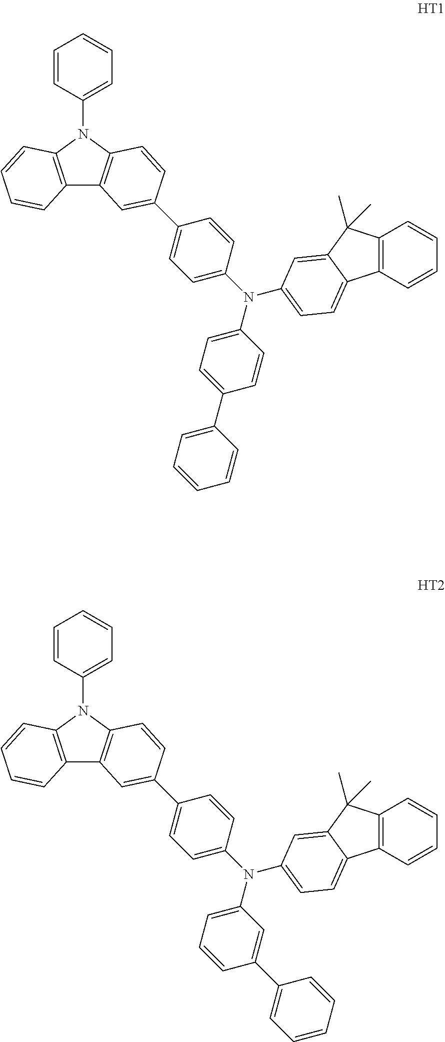 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21]

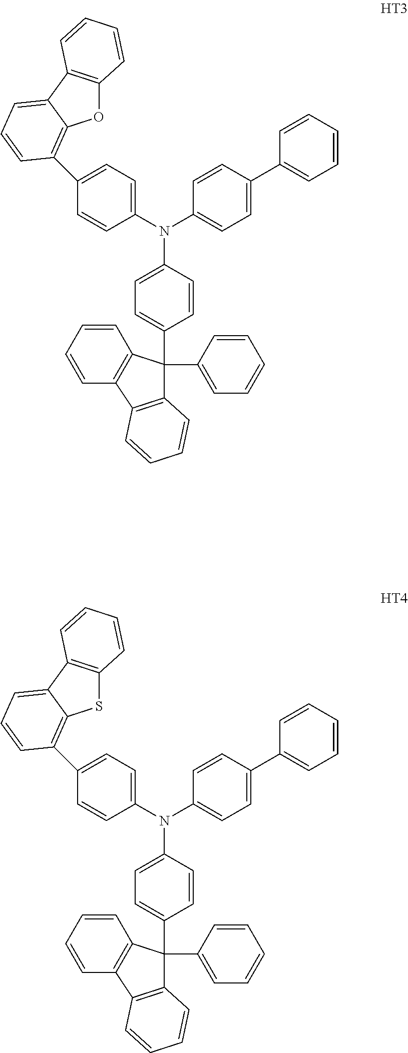 [SMILES: c1ccc(-c2ccc(N(c3ccc(-c4cccc5c4oc4ccccc45)cc3)c3ccc(C4(c5ccccc5)c5ccccc5-c5ccccc54)cc3)cc2)cc1 ; c1ccc(-c2ccc(N(c3ccc(-c4cccc5c4sc4ccccc45)cc3)c3ccc(C4(c5ccccc5)c5ccccc5-c5ccccc54)cc3)cc2)cc1]

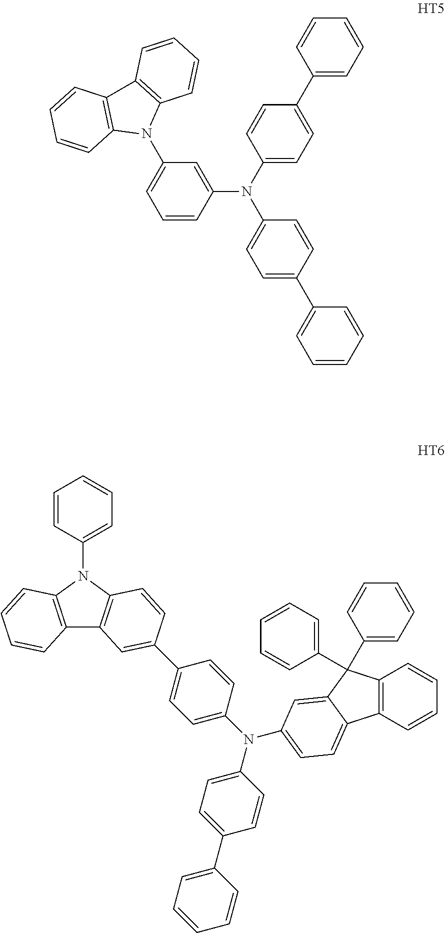 [SMILES: c1ccc(-c2ccc(N(c3ccc(-c4ccccc4)cc3)c3cccc(-n4c5ccccc5c5ccccc54)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

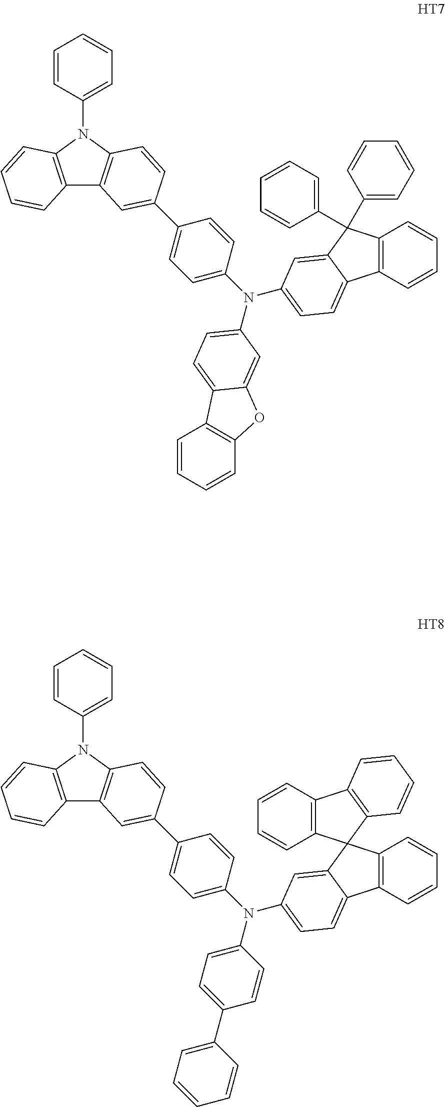 [SMILES: c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

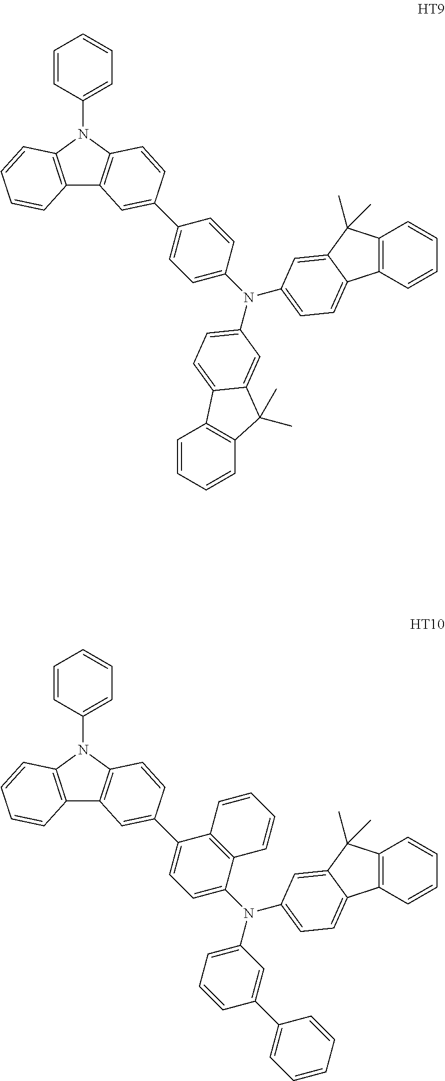 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21]

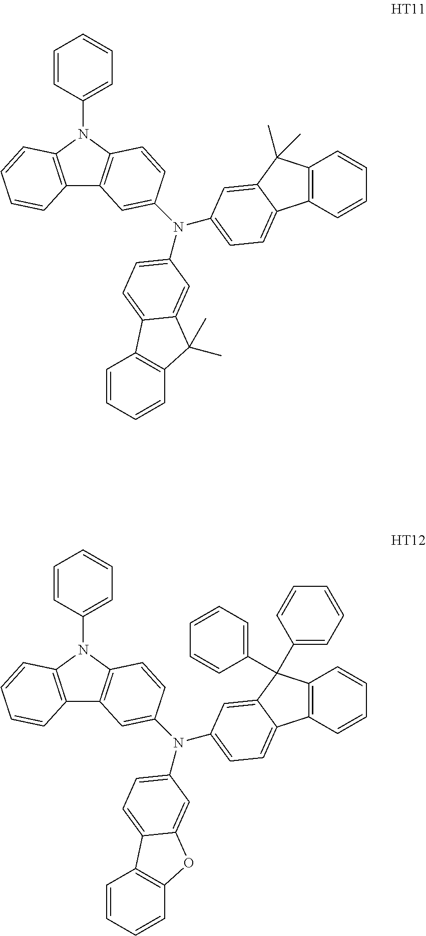 [SMILES: CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

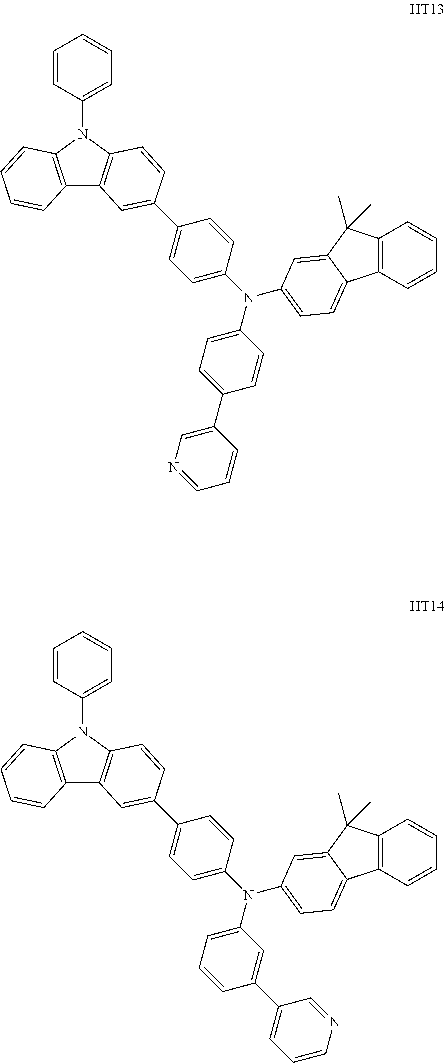 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21]

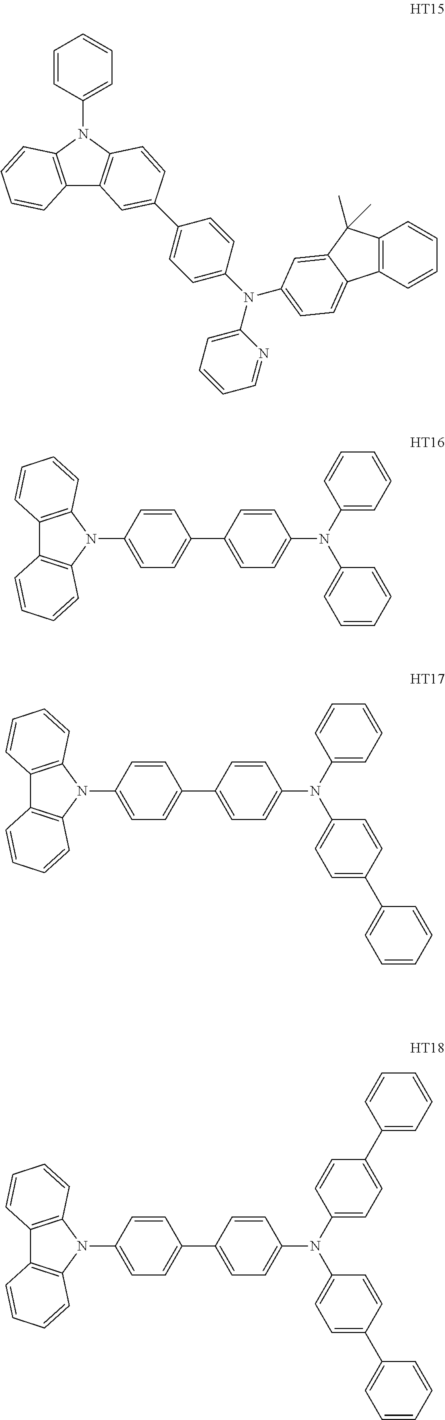 [SMILES: CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

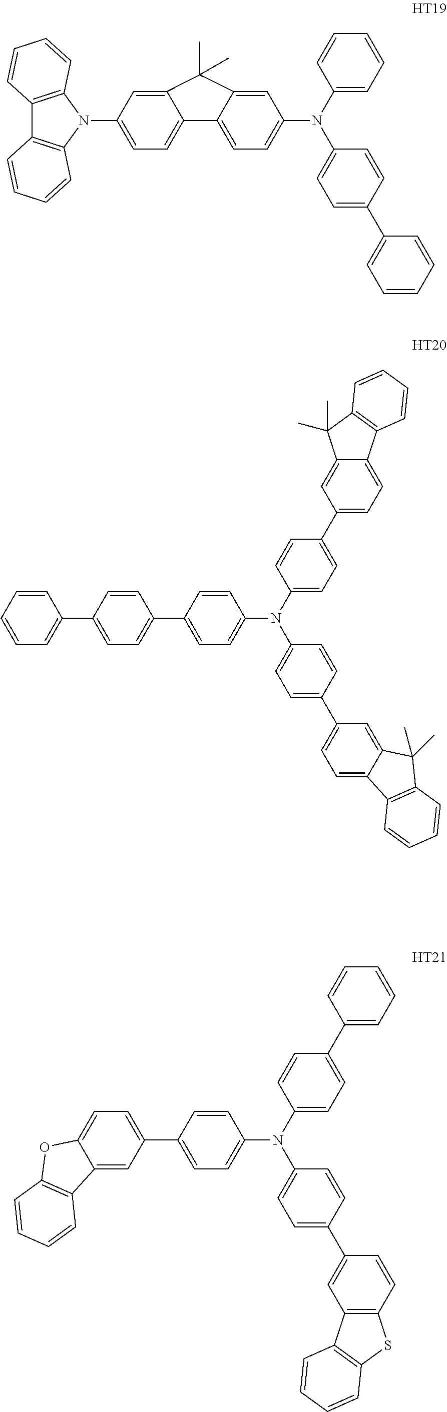 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1]

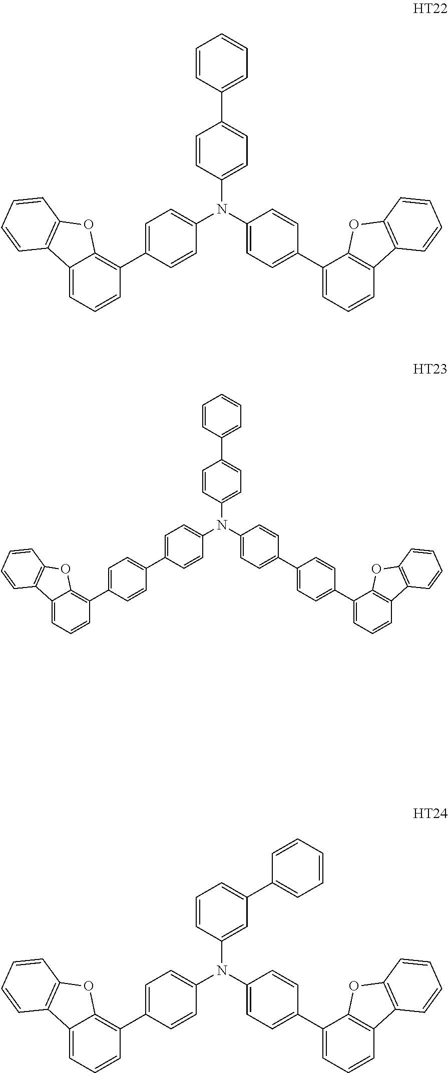 [SMILES: c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1 ; c1ccc(-c2cccc(N(c3ccc(-c4cccc5c4oc4ccccc45)cc3)c3ccc(-c4cccc5c4oc4ccccc45)cc3)c2)cc1]

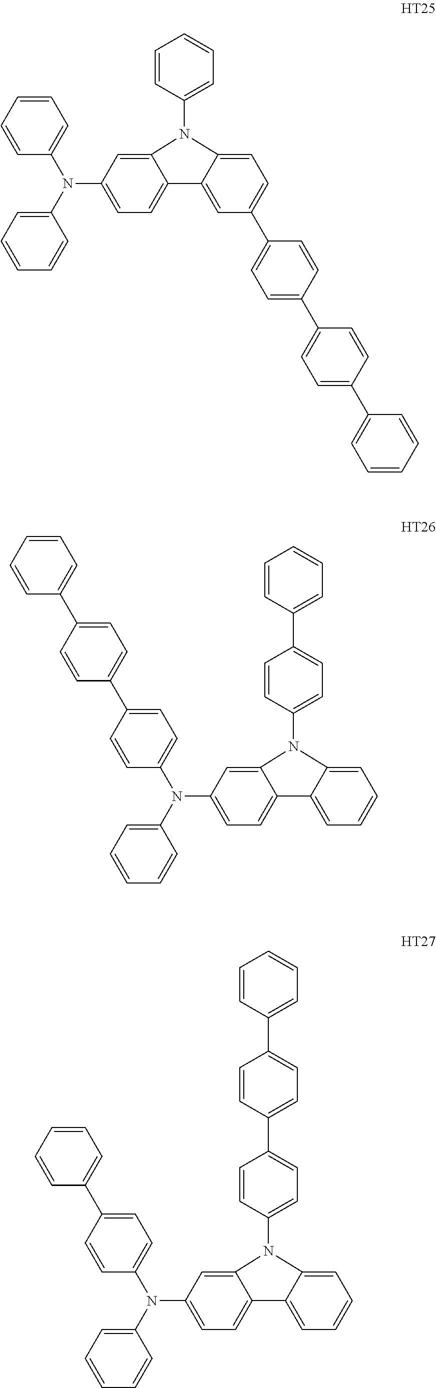 [SMILES: c1ccc(-c2ccc(-c3ccc(-c4ccc5c(c4)c4ccc(N(c6ccccc6)c6ccccc6)cc4n5-c4ccccc4)cc3)cc2)cc1 ; c1ccc(-c2ccc(-c3ccc(N(c4ccccc4)c4ccc5c6ccccc6n(-c6ccc(-c7ccccc7)cc6)c5c4)cc3)cc2)cc1 ; c1ccc(-c2ccc(-c3ccc(-n4c5ccccc5c5ccc(N(c6ccccc6)c6ccc(-c7ccccc7)cc6)cc54)cc3)cc2)cc1]

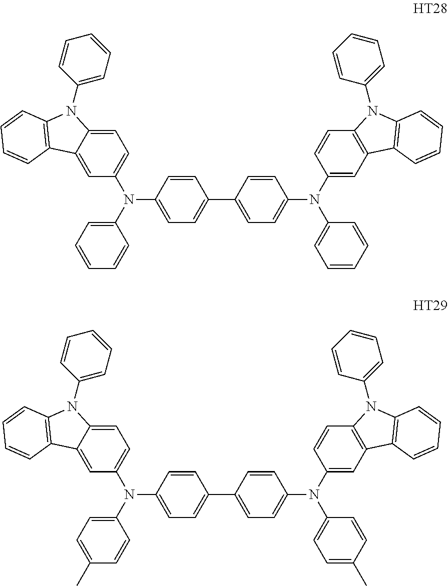 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1]

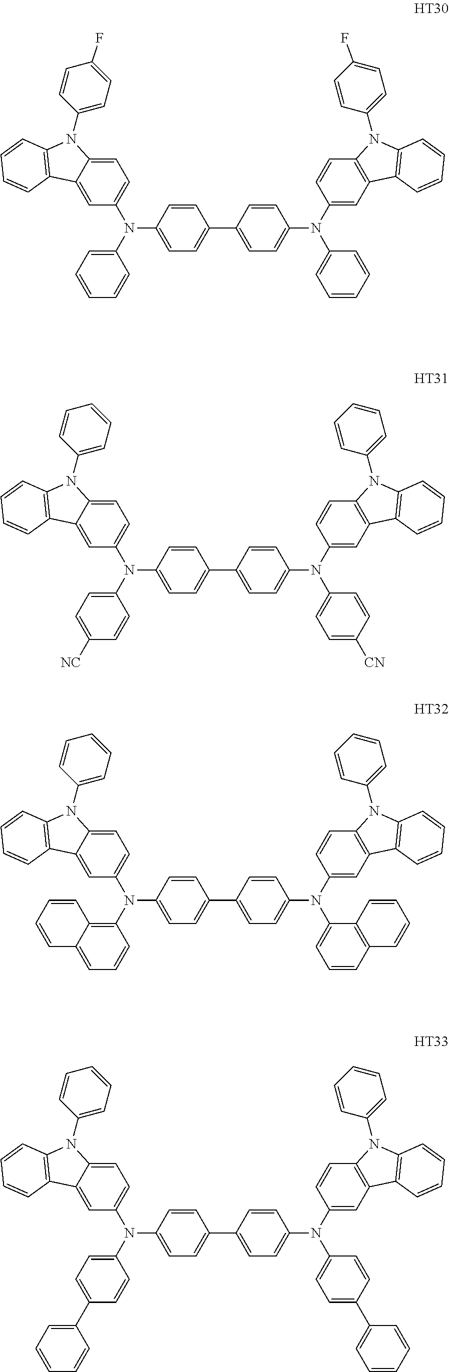 [SMILES: Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1 ; c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1]

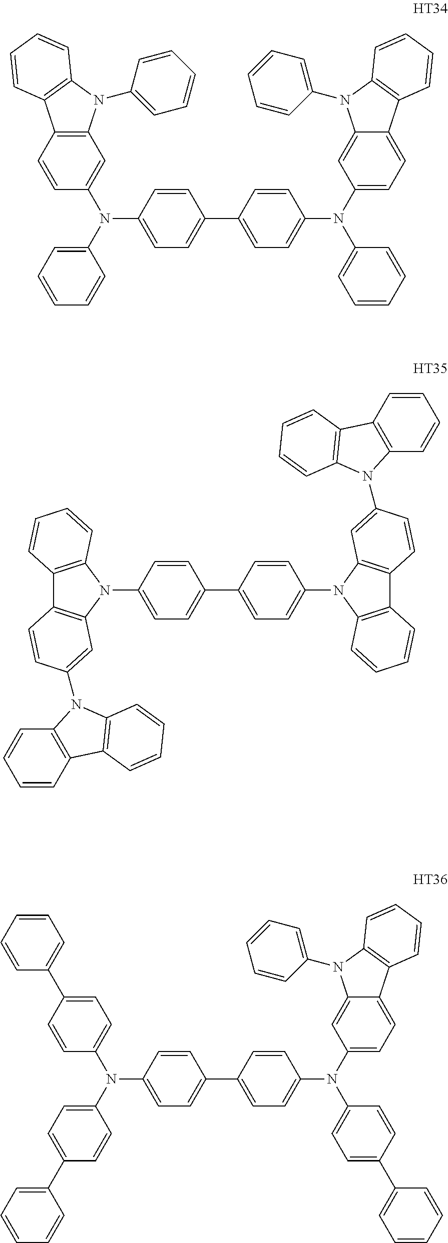 [SMILES: c1ccc(N(c2ccc(-c3ccc(N(c4ccccc4)c4ccc5c6ccccc6n(-c6ccccc6)c5c4)cc3)cc2)c2ccc3c4ccccc4n(-c4ccccc4)c3c2)cc1 ; c1ccc2c(c1)c1ccccc1n2-c1ccc2c3ccccc3n(-c3ccc(-c4ccc(-n5c6ccccc6c6ccc(-n7c8ccccc8c8ccccc87)cc65)cc4)cc3)c2c1 ; c1ccc(-c2ccc(N(c3ccc(-c4ccccc4)cc3)c3ccc(-c4ccc(N(c5ccc(-c6ccccc6)cc5)c5ccc6c7ccccc7n(-c7ccccc7)c6c5)cc4)cc3)cc2)cc1]

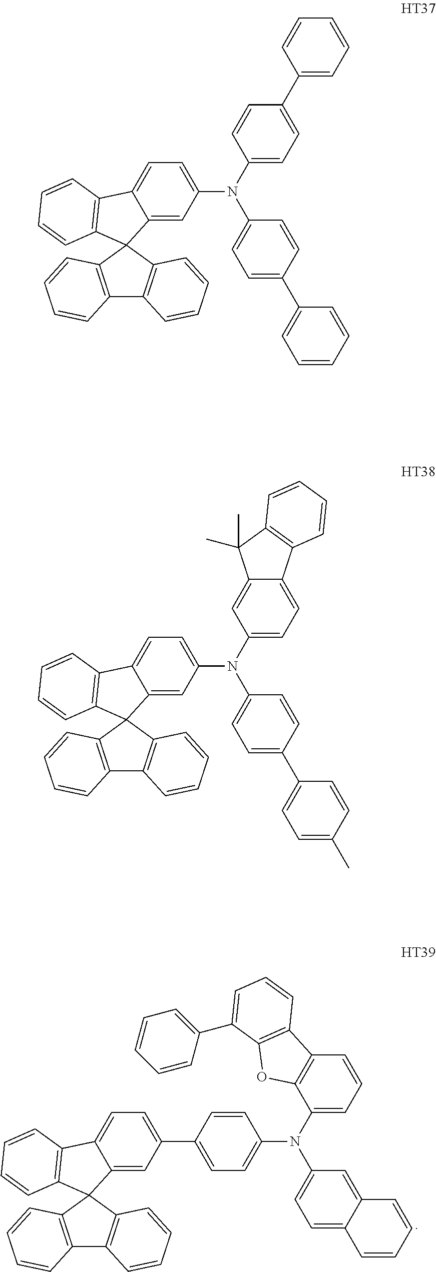 [SMILES: c1ccc(-c2ccc(N(c3ccc(-c4ccccc4)cc3)c3ccc4c(c3)C3(c5ccccc5-c5ccccc53)c3ccccc3-4)cc2)cc1 ; Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; c1ccc(-c2cccc3c2oc2c(N(c4ccc(-c5ccc6c(c5)C5(c7ccccc7-c7ccccc75)c5ccccc5-6)cc4)c4ccc5ccccc5c4)cccc23)cc1]

In one or more embodiments, the hole transport region 13 of the organic light-emitting device 10 may further include a p-dopant. When the hole transport region 13 further includes a p-dopant, the hole transport region 13 may have a matrix (e.g., at least one of compounds represented by Formulae 201 to 205) and a p-dopant included in the matrix. The p-dopant may be uniformly or non-uniformly doped in the hole transport region 13.

In an embodiment, a lowest unoccupied molecular orbital (LUMO) energy level of the p-dopant may be −3.5 eV or less.

The p-dopant may include a quinone derivative, a metal oxide, a cyano group-containing compound, or any combination thereof.

For example, the p-dopant may include:
a quinone derivative, such as tetracyanoquinodimethane (TCNQ), 2,3,5,6-tetrafluoro-7,7,8,8-tetracyanoquinodimethane (F4-TCNQ), or F6-TCNNQ;
a metal oxide, such as tungsten oxide or molybdenum oxide;
1,4,5,8,9,12-hexaazatriphenylene-hexacarbonitrile (HAT-CN);
a compound represented by Formula 221; or
any combination thereof:

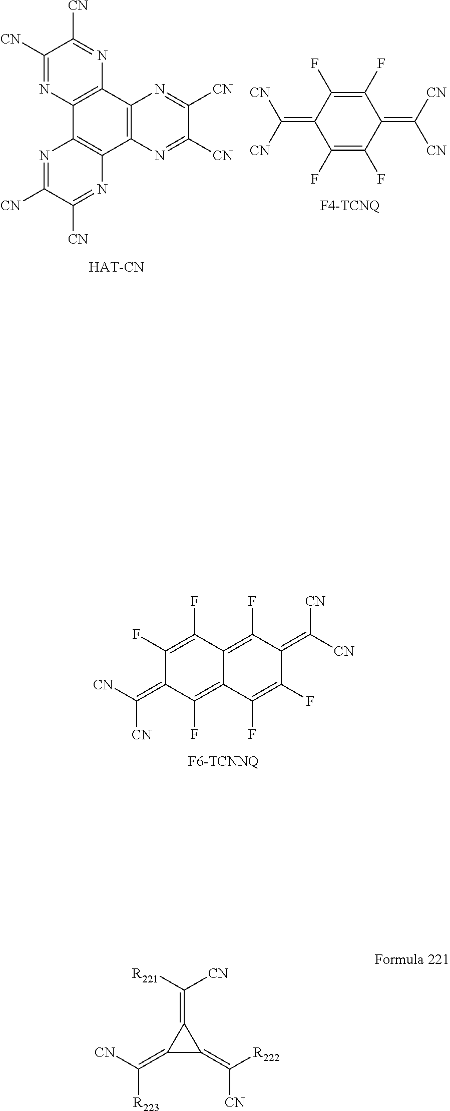

wherein, in Formula 221,
R₂₂₁, R₂₂₂, and R₂₂₃ may each independently be a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group, wherein at least one substituent of R₂₂₁ to R₂₂₃ may be: a cyano group; —F; —Cl; —Br; —I; a C₁-C₂₀ alkyl group substituted with —F; a C₁-C₂₀ alkyl group substituted with —Cl; a C₁-C₂₀ alkyl group substituted with —Br; a C₁-C₂₀ alkyl group substituted with —I; or any combination thereof.

The compound represented by Formula 221 may include, for example, Compound HT-D2:

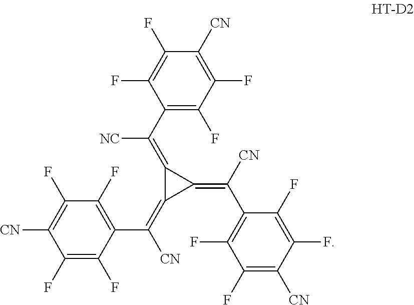

A thickness of the hole transport region 13 may be in a range of about 100 Å to about 10,000 Å, for example, about 400 Å to about 2,000 Å, and a thickness of the emission layer 15 may be in a range of about 100 Å to about 3,000 Å, for example, about 300 Å to about 1,000 Å. When the thicknesses of the hole transport region 13 and the emission layer 15 are within the ranges described above, satisfactory hole-transporting characteristics and/or luminescence characteristics may be obtained without a substantial increase in driving voltage. In the hole transport region 13, a thickness of the hole injection layer may be about 50 Å to about 1,000 Å, for example, about 100 Å to about 800 Å, and a thickness of the hole transport layer may be about 50 Å to about 2,000 Å, for example, about 100 Å to about 1,500 Å.

The hole transport region 13 may further include a buffer layer.

The buffer layer may compensate for an optical resonance distance according to a wavelength of light emitted from the emission layer 15, and thus, the efficiency of a formed organic light-emitting device may be improved.

The hole transport region 13 may further include an electron-blocking layer. The electron-blocking layer may include a known material, for example, mCP or DBFPO:

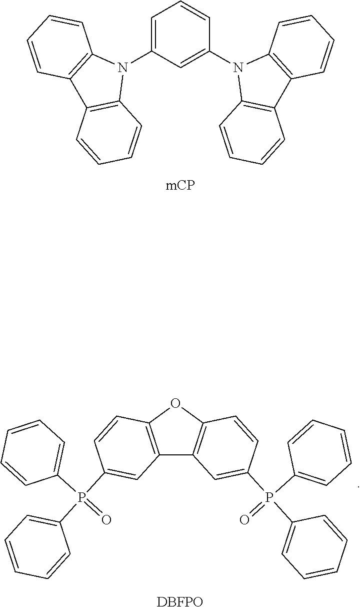 [SMILES: c1cc(-n2c3ccccc3c3ccccc32)cc(-n2c3ccccc3c3ccccc32)c1 ; O=P(c1ccccc1)(c1ccccc1)c1ccc2oc3ccc(P(=O)(c4ccccc4)c4ccccc4)cc3c2c1 ; "DBFPO"]

A thickness of the electron-blocking layer may be about 50 Å to about 1,000 Å, for example, about 100 Å to about 800 Å.

The electron transport region 17 may have a single-layer structure or a multi-layer structure.

In an embodiment, the electron transport region 17 may have an electron transport layer, an electron transport layer/electron injection layer structure, a buffer layer/electron transport layer structure, a hole-blocking layer/electron transport layer structure, a buffer layer/electron transport layer/electron injection layer structure, or a hole-blocking layer/electron transport layer/electron injection layer structure. The electron transport region 17 may further include an electron control layer.

The electron transport region 17 may include a known electron-transporting material.

The electron transport region 17 (e.g., a buffer layer, a hole-blocking layer, an electron control layer, or an electron transport layer in the electron transport region) may include a metal-free compound containing at least one π electron-deficient nitrogen-containing C₁-C₆₀ cyclic group. The π electron-deficient nitrogen-containing C₁-C₆₀ cyclic group may be the same as described herein.

In an embodiment, the electron transport region 17 may include a compound represented by Formula 601:

[Ar₆₀₁]ₓₑ₁₁-[(L₆₀₁)ₓₑ₁-R₆₀₁]ₓₑ₂₁ Formula 601
wherein, in Formula 601,
Ar₆₀₁ and L₆₀₁ may each independently be a C₅-C₆₀ carbocyclic group unsubstituted or substituted with at least one R₆₀₁ₐ or a C₁-C₆₀ heterocyclic group unsubstituted or substituted with at least one R₆₀₁ₐ,
xe11 may be 1, 2, or 3,
xe1 may be an integer from 0 to 5,
R₆₀₁ₐ and R₆₀₁ may each independently be a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₆₀₁)(Q₆₀₂)(Q₆₀₃), —C(═O)(Q₆₀₁), —S(═O)₂(Q₆₀₁), —P(═O)(Q₆₀₁)(Q₆₀₂), or any combination thereof,
Q₆₀₁ to Q₆₀₃ may each independently be a C₁-C₁₀ alkyl group, a C₁-C₁₀ alkoxy group, a phenyl group, a biphenyl group, a terphenyl group, or a naphthyl group, and
xe21 may be an integer from 1 to 5.

In an embodiment, at least one of Ar₆₀₁ in the number of xe11 and R₆₀₁ in the number of xe21 may include the π electron-deficient nitrogen-containing C₁-C₆₀ cyclic group.

In an embodiment, Ar₆₀₁ and L₆₀₁ in Formula 601 may each independently be a benzene group, a naphthalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, an indenoanthracene group, a dibenzofuran group, a dibenzothiophene group, a carbazole group, an imidazole group, a pyrazole group, a thiazole group, an isothiazole group, an oxazole group, an isoxazole group, a pyridine group, a pyrazine group, a pyrimidine group, a pyridazine group, an indazole group, a purine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzimidazole group, a benzoisothiazole group, a benzoxazole group, a benzoisoxazole group, a triazole group, a tetrazole group, an oxadiazole group, a triazine group, a thiadiazole group, an imidazopyridine group, an imidazopyrimidine group, or an azacarbazole group, each unsubstituted or substituted with deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, —Si(Q₃₁)(Q₃₂)(Q₃₃), —S(═O)₂(Q₃₁), or —P(═O)(Q₃₁)(Q₃₂), and

Q₃₁, Q₃₂, and Q₃₃ may each independently be a C₁-C₁₀ alkyl group, a C₁-C₁₀ alkoxy group, a phenyl group, a biphenyl group, a terphenyl group, or a naphthyl group.

When xe11 in Formula 601 is 2 or more, two or more of Ar₆₀₁ may be linked to each other via a single bond.

In one or more embodiments, Ar₆₀₁ in Formula 601 may be an anthracene group.

In one or more embodiments, the compound represented by Formula 601 may be represented by Formula 601-1:

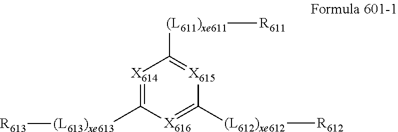

wherein, in Formula 601-1,
X₆₁₄ may be N or C(R₆₁₄), X₆₁₅ may be N or C(R₆₁₅), X₆₁₆ may be N or C(R₆₁₆), and at least one of X₆₁₄ to X₆₁₆ may be N,
L₆₁₁, L₆₁₂, and L₆₁₃ may each independently be the same as described herein in connection with L₆₀₁,
xe611, xe612, and xe613 may each independently be the same as described herein in connection with xe1,
R₆₁₁, R₆₁₂, and R₆₁₃ may each independently be the same as described herein in connection with R₆₀₁, and
R₆₁₄, R₆₁₅, and R₆₁₆ may each independently be hydrogen, deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, or a naphthyl group.

In one or more embodiments, xe1 and xe611 to xe613 in Formulae 601 and 601-1 may each independently be 0, 1, or 2.

In one or more embodiments, R₆₀₁ and R₆₁₁, R₆₁₂, and R₆₁₃ in Formulae 601 and 601-1 may each independently be a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, a benzoisothiazolyl group, a benzoxazolyl group, a benzoisoxazolyl group, a triazolyl group, a tetrazolyl group, an imidazopyridinyl group, an imidazopyrimidinyl group, or an azacarbazolyl group, each unsubstituted or substituted with deuterium, —F, —Cl, —Br, —I, a hydroxyl group, a cyano group, a nitro group, an amidino group, a hydrazino group, a hydrazono group, a C₁-C₂₀ alkyl group, a C₁-C₂₀ alkoxy group, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, a benzoisothiazolyl group, a benzoxazolyl group, a benzoisoxazolyl group, a triazolyl group, a tetrazolyl group, an imidazopyridinyl group, an imidazopyrimidinyl group, an azacarbazolyl group, or any combination thereof; or
—S(═O)₂(Q₆₀₁) or —P(═O)(Q₆₀₁)(Q₆₀₂), and
Q₆₀₁ and Q₆₀₂ may each be the same as described herein.

The electron transport region 17 may include one of Compounds ET1 to ET36 or any combination thereof:

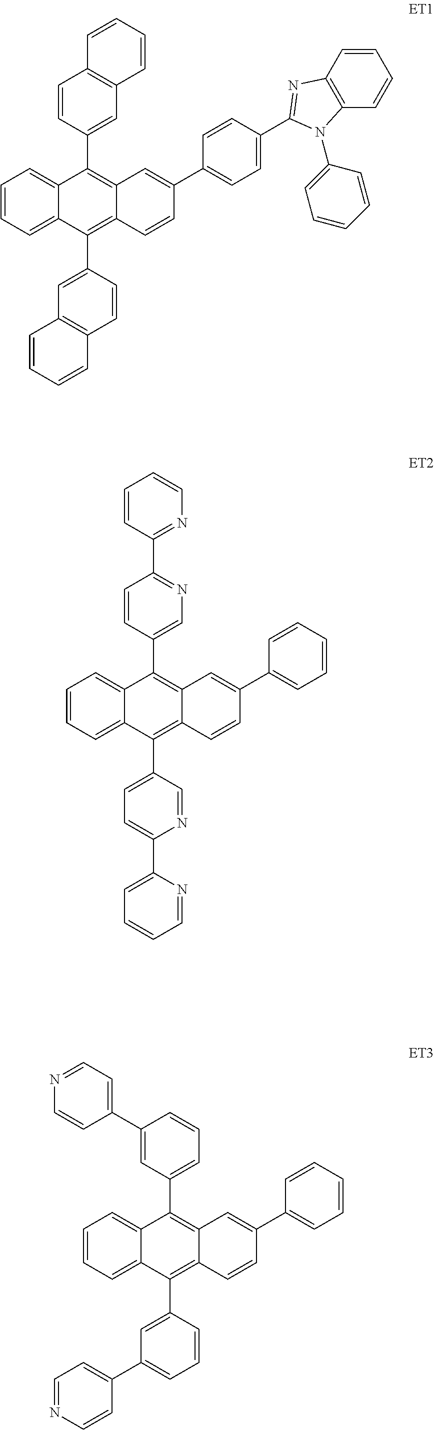 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

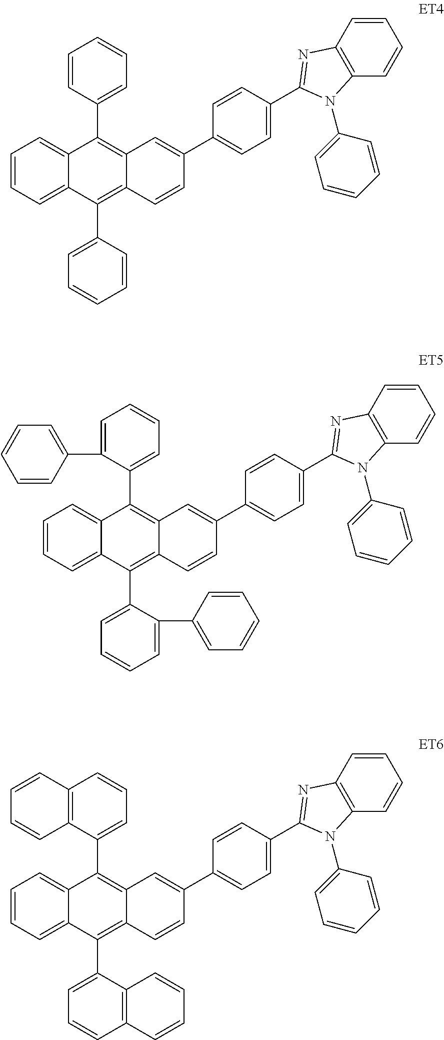 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

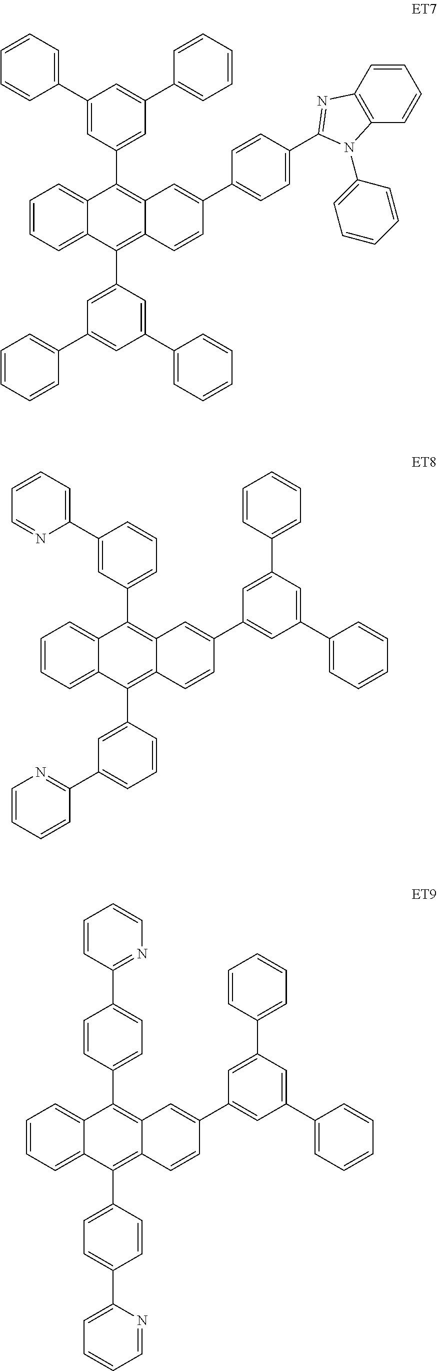 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

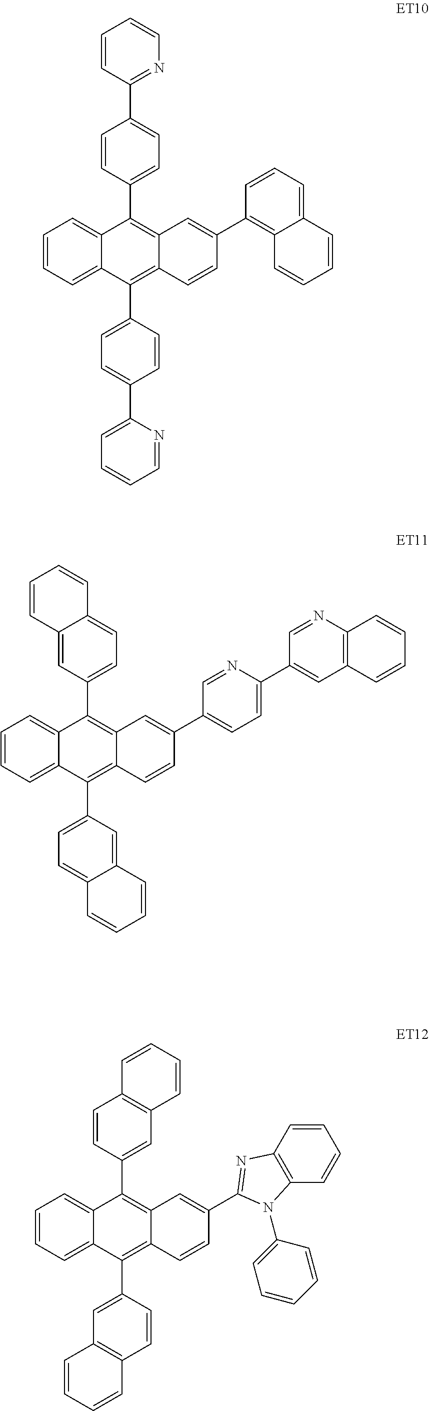 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

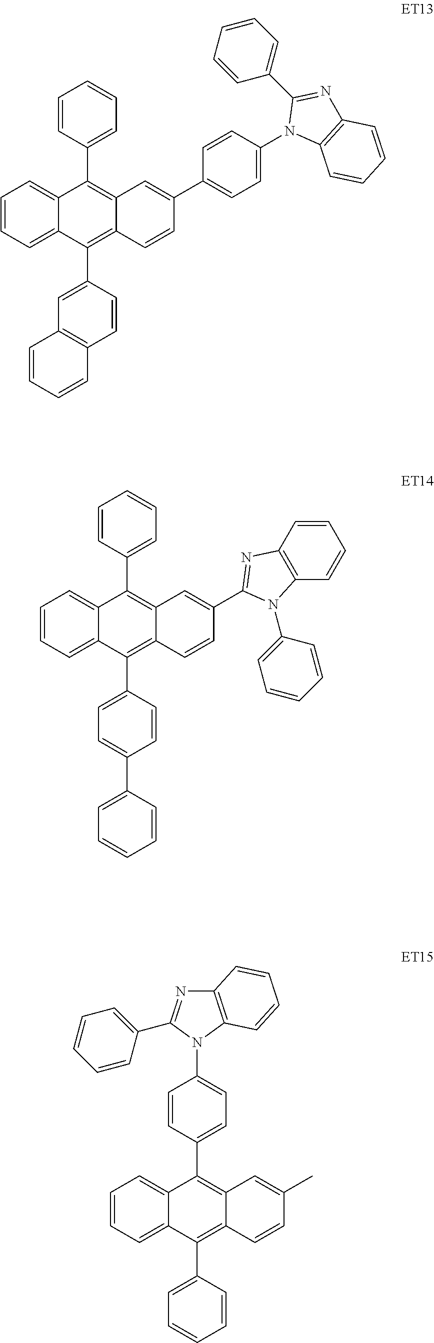 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

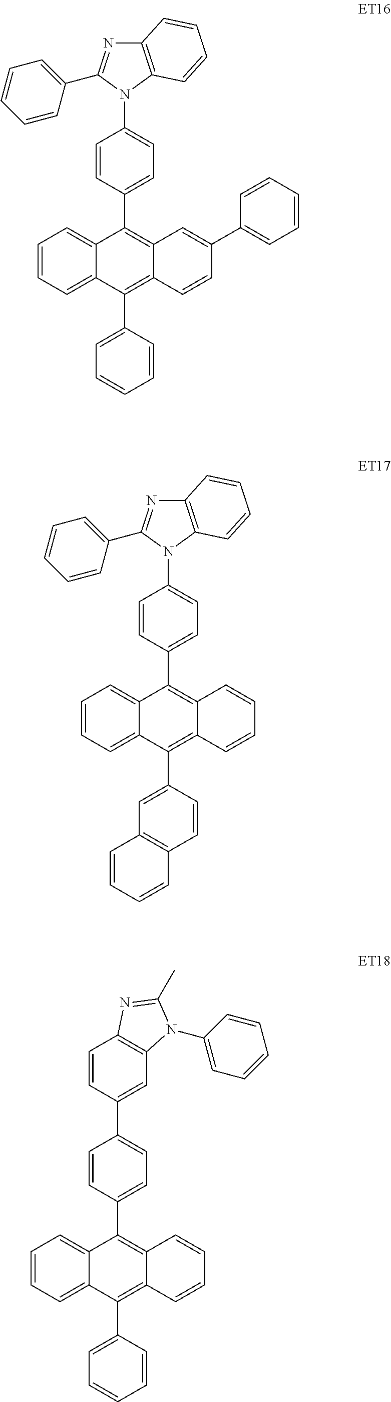 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

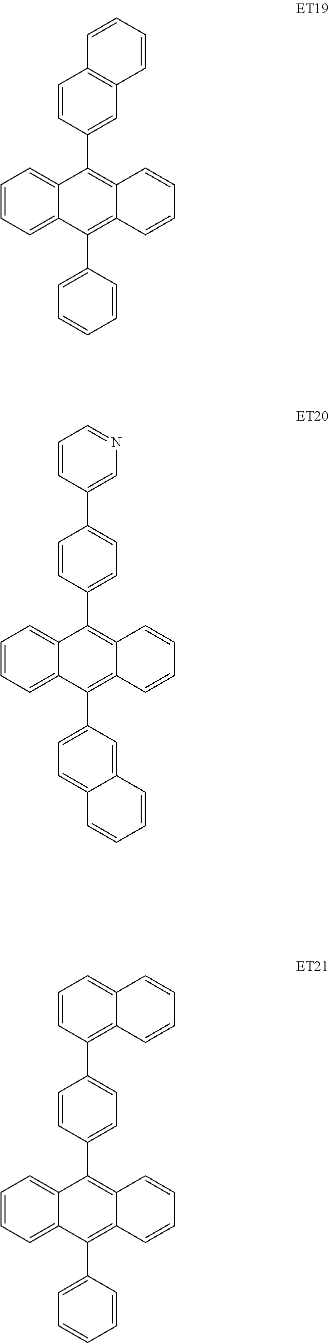

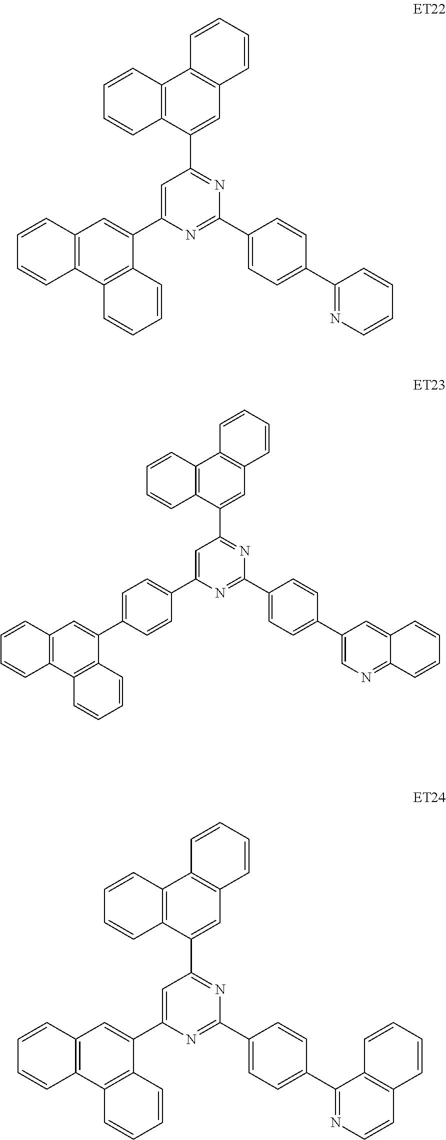 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

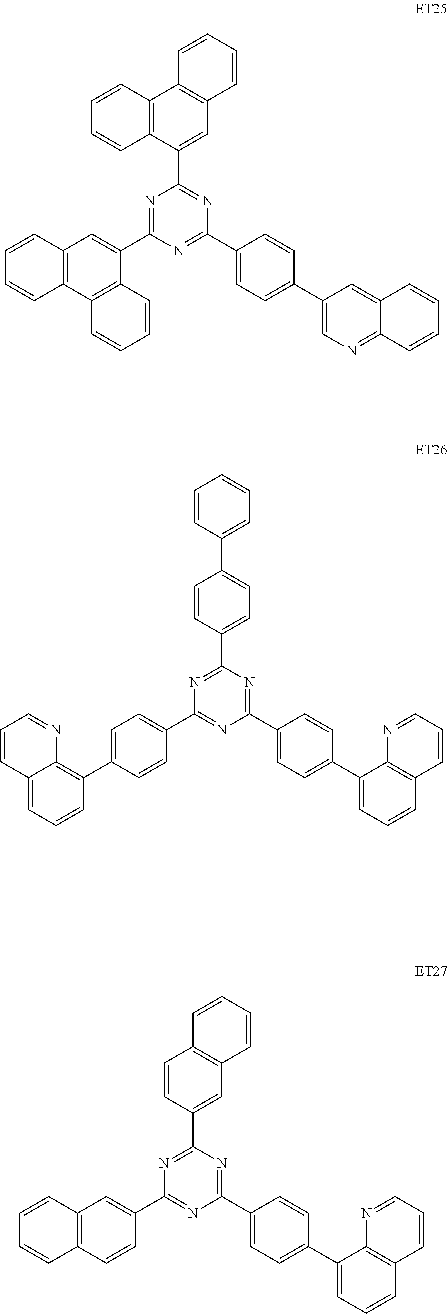 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

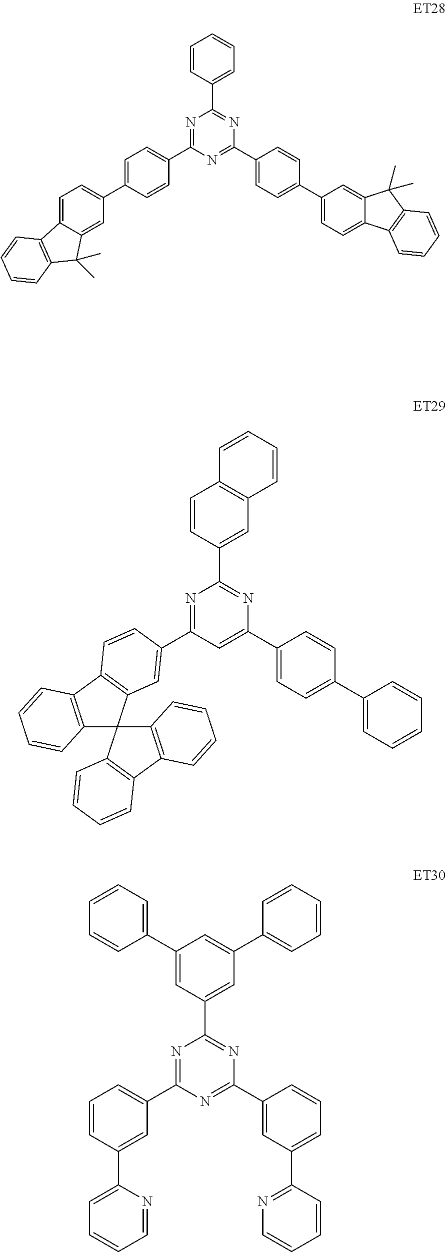 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

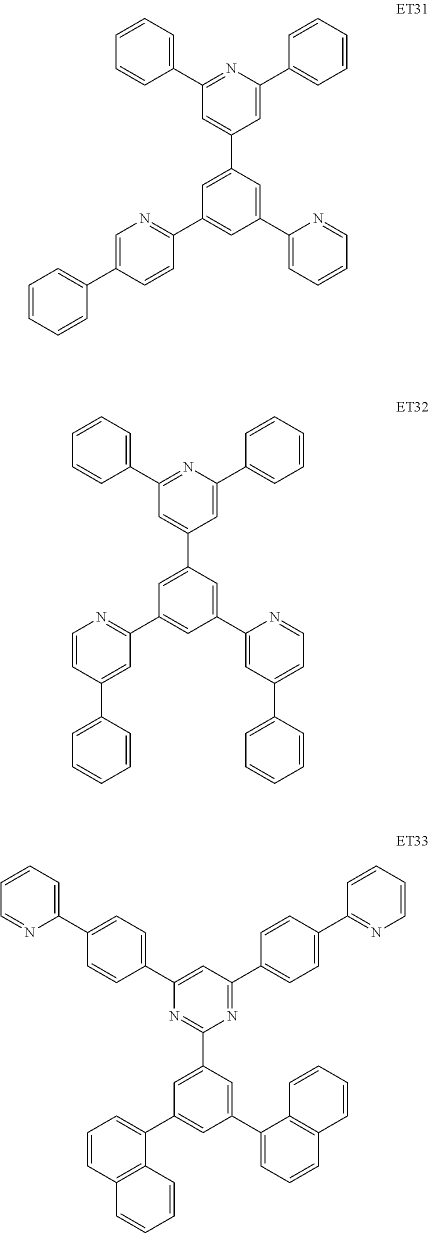 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

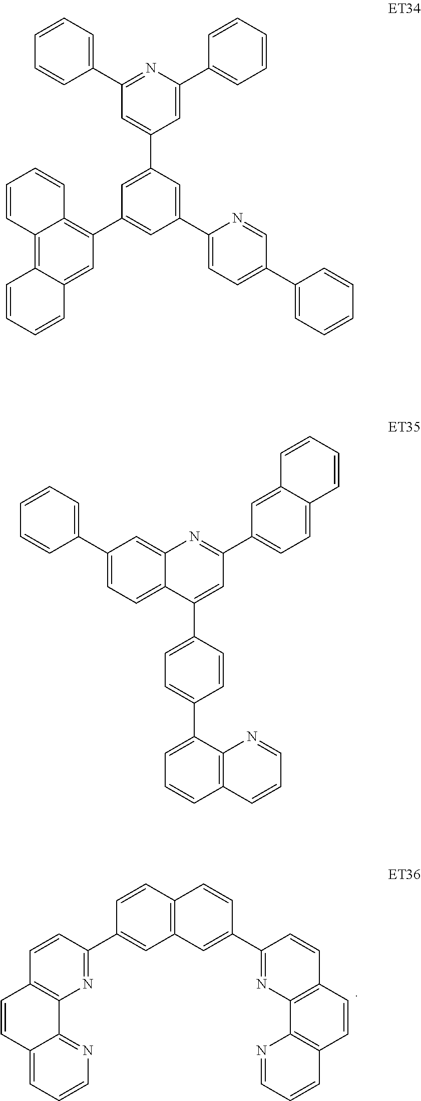 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In one or more embodiments, the electron transport region 17 may include 2,9-dimethyl-4,7-diphenyl-1,10-phenanthroline (BCP), 4,7-dphenyl-1,10-phenanthroline (Bphen), Alq₃, BAlq, 3-(biphenyl-4-yl)-5-(4-tert-butylphenyl)-4-phenyl-4H-1,2,4-triazole (TAZ), NTAZ, DBFPO, or any combination thereof. For example, when the electron transport region 17 includes a hole-blocking layer, the hole-blocking layer may include BCP or Bphen:

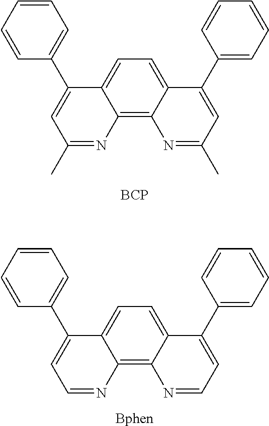

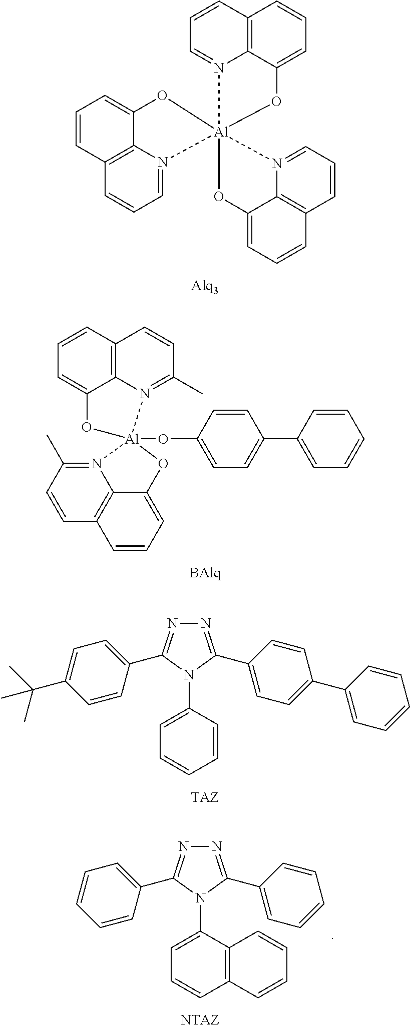

Thicknesses of the buffer layer, the hole-blocking layer, and the electron control layer may each independently be in a range of about 20 Å to about 1,000 Å, for example, about 30 Å to about 300 Å. When the thicknesses of the buffer layer, the hole-blocking layer, and the electron control layer are within the ranges described above, excellent hole-blocking characteristics or excellent electron control characteristics may be obtained without a substantial increase in driving voltage.

A thickness of the electron transport layer may be in a range of about 100 Å to about 1,000 Å, for example, about 150 Å to about 500 Å. When the thickness of the electron transport layer is within the ranges described above, satisfactory electron-transporting characteristics may be obtained without a substantial increase in driving voltage.

The electron transport region 17 (e.g., the electron transport layer in the electron transport region 17) may further include, in addition to the materials described above, a metal-containing material.

The metal-containing material may include an alkali metal complex, an alkaline earth metal complex, or any combination thereof. A metal ion of the alkali metal complex may include a Li ion, a Na ion, a K ion, a Rb ion, a Cs ion, or any combination thereof, and a metal ion of the alkaline earth metal complex may include a Be ion, a Mg ion, a Ca ion, a Sr ion, a Ba ion, or any combination thereof. A ligand coordinated with the metal ion of the alkali metal complex or the alkaline earth-metal complex may include hydroxyquinoline, hydroxyisoquinoline, hydroxybenzoquinoline, hydroxyacridine, hydroxyphenanthridine, hydroxyphenyloxazole, hydroxyphenylthiazole, hydroxydiphenyloxadiazole, hydroxydiphenylthiadiazole, hydroxyphenylpyridine, hydroxyphenylbenzimidazole, hydroxyphenylbenzothiazole, bipyridine, phenanthroline, cyclopentadiene, or any combination thereof.

In an embodiment, the metal-containing material may include a Li complex. The Li complex may include, for example, Compound ET-D1 (LiQ) or ET-D2:

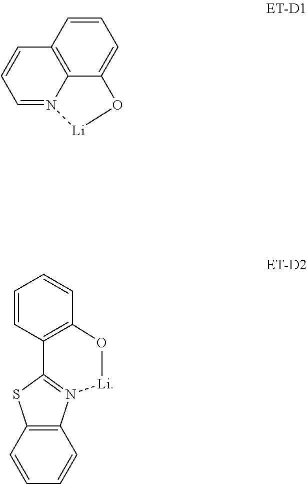

The electron transport region 17 may include an electron injection layer that facilitates injection of electrons from the second electrode 19. The electron injection layer may directly contact the second electrode 19. The thickness of the electron injection layer may be about 1 Å to about 100 Å, for example, about 3 Å to about 90 Å.

The electron injection layer may have i) a single-layer structure consisting of a single layer including a single material, ii) a single-layer structure consisting of a single layer including multiple materials that are different from each other, or iii) a multi-layer structure consisting of multiple layers including multiple materials that are different from each other.

The electron injection layer may include an alkali metal, an alkaline earth metal, a rare earth metal, an alkali metal compound, an alkaline earth-metal compound, a rare earth metal compound, an alkali metal complex, an alkaline earth-metal complex, a rare earth metal complex, or any combinations thereof.

The alkali metal may include Li, Na, K, Rb, Cs, or any combination thereof. In an embodiment, the alkali metal may be Li, Na, or Cs. In one or more embodiments, the alkali metal may be Li or Cs.

The alkaline earth metal may include Mg, Ca, Sr, Ba, or any combination thereof.

The rare earth metal may include Sc, Y, Ce, Tb, Yb, Gd, or any combination thereof.

The alkali metal compound, the alkaline earth metal compound, and the rare earth metal compound may include oxides and halides (e.g., fluorides, chlorides, bromides, iodides, etc.) of the alkali metal, the alkaline earth metal, and the rare earth metal, or any combination thereof.

The alkali metal compound may include: one of alkali metal oxides such as Li₂O, Cs₂O, and K₂O; one of alkali metal halides such as LiF, NaF, CsF, KF, LiI, NaI, CsI, and KI; or any combination thereof. In an embodiment, the alkali metal compound may include LiF, Li₂O, NaF, LiI, NaI, CsI, KI, or any combination thereof.

The alkaline earth-metal compound may include one of alkaline earth-metal compounds, such as BaO, SrO, CaO, BaₓSr₁₋ₓO (wherein 0<x<1), and BaₓCa₁₋ₓO (wherein 0<x<1), or any combination thereof. In an embodiment, the alkaline earth metal compound may include BaO, SrO, CaO, or any combination thereof.

The rare earth metal compound may include YbF₃, ScF₃, ScO₃, Y₂O₃, Ce₂O₃, GdF₃, TbF₃, or any combination thereof. In an embodiment, the rare earth metal compound may include YbF₃, ScF₃, TbF₃, YbI₃, ScI₃, TbI₃, or any combination thereof.

The alkali metal complex, the alkaline earth metal complex, and the rare earth metal complex may include an ion of alkali metal, alkaline earth metal, and rare earth metal as described above, and a ligand coordinated with a metal ion of the alkali metal complex, the alkaline earth metal complex, or the rare earth metal complex may include hydroxy quinoline, hydroxy isoquinoline, hydroxy benzoquinoline, hydroxy acridine, hydroxy phenanthridine, hydroxy phenyloxazole, hydroxy phenylthiazole, hydroxy diphenyloxadiazole, hydroxy diphenylthiadiazole, hydroxy phenylpyridine, hydroxy phenylbenzimidazole, hydroxy phenylbenzothiazole, bipyridine, phenanthroline, cyclopentadiene, or any combination thereof.

The electron injection layer may consist of an alkali metal, an alkaline earth metal, a rare earth metal, an alkali metal compound, an alkaline earth-metal compound, a rare earth metal compound, an alkali metal complex, an alkaline earth-metal complex, a rare earth metal complex, or any combinations thereof, as described above. In one or more embodiments, the electron injection layer may further include an organic material. When the electron injection layer further includes an organic material, an alkali metal, an alkaline earth metal, a rare earth metal, an alkali metal compound, an alkaline earth-metal compound, a rare earth metal compound, an alkali metal complex, an alkaline earth-metal complex, a rare earth metal complex, or any combination thereof may be homogeneously or non-homogeneously dispersed in a matrix including the organic material.

A thickness of the electron injection layer may be in a range of about 1 Å to about 100 Å, for example, about 3 Å to about 90 Å. When the thickness of the electron injection layer is within the ranges described above, satisfactory electron injection characteristics may be obtained without a substantial increase in driving voltage.

The second electrode 19 may be arranged on the interlayer 10A. The second electrode 19 may be a cathode which is an electron injection electrode, and in this regard, a material for forming the second electrode 19 may be selected from a metal, an alloy, an electrically conductive compound, and a combination thereof, which have a relatively low work function.

The second electrode 19 may include lithium (Li), silver (Ag), magnesium (Mg), aluminum (Al), aluminum-lithium (Al—Li), calcium (Ca), magnesium-indium (Mg—In), magnesium-silver (Mg—Ag), ITO, IZO, or any combination thereof. The second electrode 19 may be a transmissive electrode, a semi-transmissive electrode, or a reflective electrode.

The second electrode 19 may have a single-layer structure having a single layer or a multi-layer structure including multiple layers.

A method of evaluating a protection coefficient of an atom X, e.g., a boron atom, in a compound Y, e.g., in an emitter compound Y.

According to another aspect of the disclosure, the method of evaluating the protection coefficient of the atom X in the compound Y described herein is provided.

The protection coefficient obtained by using the method is a quantification value of a protected level of the atom X in the compound Y provided by the other atoms of the compound Y and may be used to evaluate a stability, robustness, etc. of the compound Y.

For example, the method may be used to screen a compound having a highly-protected atom described hereinafter.

### A Method of Screening a Compound Containing a Highly-Protected Atom

According to another aspect of the disclosure, provided is a method of screening a compound containing a highly-protected atom, comprising:
(1) evaluating a protection coefficient of an atom X comprised in compounds which are necessary to be screened, by using the method of evaluating the protection coefficient, and
(2) selecting a compound having a protection coefficient above a reference value from the compounds which are necessary to be screened, based on results obtained from the step (1), to screen the compound containing a highly-protected atom.

The atom X in the step (1) and the reference value in the step (2) may be selected according to a purpose of use for the compound containing a highly-protected atom.

For example, when it is necessary to screen an emitter described herein as the compound containing a highly-protected atom, “a boron atom” may be selected as the atom X in the step (1) and “0.7” may be selected as the reference value in the step (2).

### A Method of Generating an Artificial Intelligence Model for Predicting a Property of a Compound

According to another aspect of the disclosure, provided is a method of generating an artificial intelligence for predicting a property of a compound (for example, a protection coefficient of an atom in a compound), comprising:
collecting a dataset including the protection coefficient of evaluated by using the method of evaluating the protection coefficient, the atom X having the protection coefficient and a molecular structure of the compound Y including the atom X, and
performing a machine learning by using the dataset.

### A Method of Predicting a Property of a Compound

According to another aspect of the disclosure, provided is a method of predicting a property of a compound, comprising:
inputting a molecular structure of a compound Z in an artificial intelligence model generated by using the method of generating an artificial intelligence model, and
extracting a property of the compound Z (for example, a protection coefficient of an atom in the compound Z) from the artificial intelligence model.

The compound Z is any compound of which a property (for example, a protection coefficient) is necessary to be confirmed and may be identical to or different from the compound Y.

The method of predicting a property of a compound may further comprise collecting a correction dataset including a property of the compound Z (for example, a protection coefficient of an atom in the compound Z) and informations of the compound Z (for example, an atom having the protection coefficient and a molecular structure of the compound Z) and inputting the correction dataset in the artificial intelligence model.

By using the artificial intelligence model generated by using the method of generating an artificial intelligence model, a property of a compound having a complicated molecular structure may be easily predicted and by using the predicted property, an effective compound which is necessary to be actually synthesized and a real property thereof is necessary to be confirmed may be easily screened from a group of compounds which are necessary to be screened.

### Explanation of Terms

The term “C₁-C₆₀ alkyl group” as used herein refers to a linear or branched saturated aliphatic hydrocarbons monovalent group having 1 to 60 carbon atoms, and the term “C₁-C₆₀ alkylene group” as used here refers to a divalent group having the same structure as the C₁-C₆₀ alkyl group.

Examples of the C₁-C₆₀ alkyl group, the C₁-C₂₀ alkyl group, and/or the C₁-C₁₀ alkyl group include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, or a tert-decyl group, each unsubstituted or substituted with a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, or any combination thereof.

The term “C₁-C₆₀ alkoxy group” as used herein refers to a monovalent group represented by —OA₁₀₁ (wherein A₁₀₁ is the C₁-C₆₀ alkyl group), and examples thereof may include a methoxy group, an ethoxy group, a propoxy group, a butoxy group, a pentoxy group, and the like.

The term “C₂-C₆₀ alkenyl group” as used herein refers to a hydrocarbon group formed by substituting at least one carbon-carbon double bond in the middle or at the terminus of the C₂-C₆₀ alkyl group, and examples thereof may include an ethenyl group, a propenyl group, a butenyl group, and the like. The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group formed by substituting at least one carbon-carbon triple bond in the middle or at the terminus of the C₂-C₆₀ alkyl group, and examples thereof may include an ethynyl group, a propynyl group, and the like. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon cyclic group having 3 to 10 carbon atoms, and the term “C₃-C₁₀ cycloalkylene group” as used herein refers to a divalent group having the same structure as the C₃-C₁₀ cycloalkyl group.

Examples of the C₃-C₁₀ cycloalkyl group include a cyclopropyl group, a cyclobutyl group, a cyclopentyl group, a cyclohexyl group, a cycloheptyl group, a cyclooctyl group, an adamantanyl group, a norbornanyl group (a bicyclo[2.2.1]heptyl group), a bicyclo[1.1.1]pentyl group, a bicyclo[2.1.1]hexyl group, a bicyclo[2.2.2]octyl group, and the like.

The term “C₁-C₁₀ heterocycloalkyl group” as used herein refers to a monovalent monocyclic group that includes at least one heteroatom selected from N, O, P, Si, S, Se, Ge, and B as a ring-forming atom and 1 to 10 carbon atoms, and the term “the C₁-C₁₀ heterocycloalkylene group” as used herein refers to a divalent group having the same structure as the C₁-C₁₀ heterocycloalkyl group.

Examples of the C₁-C₁₀ heterocycloalkyl group include a silolanyl group, a silinanyl group, tetrahydrofuranyl group, a tetrahydro-2H-pyranyl group, a tetrahydrothiophenyl group, and the like.

The term “C₃-C₁₀ cycloalkenyl group” as used herein refers to a monovalent cyclic group that includes 3 to 10 carbon atoms and at least one carbon-carbon double bond in the ring thereof and has no aromaticity, and examples thereof may include a cyclopentenyl group, a cyclohexenyl group, a cycloheptenyl group, and the like. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent monocyclic group that has at least one heteroatom selected from N, O, P, Si, S, Se, Ge, and B as a ring-forming atom, 1 to 10 carbon atoms, and at least one carbon-carbon double bond in the ring thereof. Examples of the C₁-C₁₀ heterocycloalkenyl group include a 2,3-dihydrofuranyl group, a 2,3-dihydrothiophenyl group, and the like. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system having 6 to 60 carbon atoms, and the term “C₆-C₆₀ arylene group” as used herein refers to a divalent group having a carbocyclic aromatic system having 6 to 60 carbon atoms. Examples of the C₆-C₆₀ aryl group include a phenyl group, a naphthyl group, an anthracenyl group, a phenanthrenyl group, a pyrenyl group, a chrysenyl group, and the like. When the C₆-C₆₀ aryl group and the C₆-C₆₀ arylene group each include two or more rings, the rings may be fused to each other.

The term “C₁-C₆₀ heteroaryl group” as used herein refers to a monovalent group that includes at least one heteroatom selected from N, O, P, Si, S, Se, Ge, and B as a ring-forming atom and a heterocyclic aromatic system having 1 to 60 carbon atoms, and the term “C₁-C₆₀ heteroarylene group” as used herein refers to a divalent group that includes at least one heteroatom selected from N, O, P, Si, S, Se, Ge, and B as a ring-forming atom and a heterocyclic aromatic system having 1 to 60 carbon atoms. Examples of the C₁-C₆₀ heteroaryl group include a pyridinyl group, a pyrimidinyl group, a pyrazinyl group, a pyridazinyl group, a triazinyl group, a quinolinyl group, an isoquinolinyl group, and the like. When the C₁-C₆₀ heteroaryl group and the C₁-C₆₀ heteroarylene group each include two or more rings, the rings may be fused to each other.

The term “C₆-C₆₀ aryloxy group” as used herein refers to —OA₁₀₂ (wherein A₁₀₂ is the C₆-C₆₀ aryl group), and the term “C₆-C₆₀ arylthio group” as used herein refers to —SA₁₀₃ (wherein A₁₀₃ is the C₆-C₆₀ aryl group).

The term “monovalent non-aromatic condensed polycyclic group” as used herein refers to a monovalent group having two or more rings condensed with each other, only carbon atoms (e.g., having 8 to 60 carbon atoms) as ring-forming atoms, and no aromaticity in the entire molecular structure thereof. Examples of the monovalent non-aromatic condensed polycyclic group include a fluorenyl group and the like. The term “divalent non-aromatic condensed polycyclic group” as used herein refers to a divalent group having the same structure as the monovalent non-aromatic condensed polycyclic group.

The term “monovalent non-aromatic condensed heteropolycyclic group” as used herein refers to a monovalent group having two or more rings condensed with each other, a heteroatom selected from N, O, P, Si, S, Se, Ge, and B, other than carbon atoms (e.g., having 1 to 60 carbon atoms), as a ring-forming atom, and no aromaticity in the entire molecular structure thereof. Examples of the monovalent non-aromatic condensed heteropolycyclic group include a carbazolyl group and the like. The term “divalent non-aromatic condensed heteropolycyclic group” as used herein refers to a divalent group having the same structure as the monovalent non-aromatic condensed heteropolycyclic group.

The term “π electron-deficient nitrogen-containing C₁-C₆₀ cyclic group” as used herein refers to a cyclic group having 1 to 60 carbon atoms and including at least one *—N═*′ (wherein * and *′ each indicate a binding site to a neighboring atom) as a ring-forming moiety. For example, the π electron-deficient nitrogen-containing C₁-C₆₀ cyclic group may be a) a first ring, b) a condensed ring in which two or more first rings are condensed with each other, or c) a condensed ring in which at least one first ring is condensed with at least one second ring.

The term “π electron-rich C₃-C₆₀ cyclic group” as used herein refers to a cyclic group having 3 to 60 carbon atoms and not including at least one *—N═*′ (wherein * and *′ each indicate a binding site to a neighboring atom) as a ring-forming moiety. For example, the π electron-rich C₃-C₆₀ cyclic group may be a) a second ring or b) a condensed ring in which two or more second rings are condensed with each other.

The term “C₅-C₆₀ cyclic group” as used herein refers to a monocyclic or polycyclic group having 5 to 60 carbon atoms, and may be, for example, a) a third ring or b) a condensed ring in which two or more third rings are condensed with each other.

The term “C₁-C₆₀ heterocyclic group” as used herein refers to a monocyclic or polycyclic group that has 1 to 60 carbon atoms and includes at least one heteroatom, and may be, for example, a) a fourth ring, b) a condensed ring in which two or more fourth rings are condensed with each other, or c) a condensed ring in which at least one third ring is condensed with at least one fourth ring.

The “first ring” as used herein may be an imidazole group, a pyrazole group, a thiazole group, an isothiazole group, an oxazole group, an isoxazole group, a pyridine group, a pyrazine group, a pyridazine group, a pyrimidine group, a triazole group, a tetrazole group, an oxadiazole group, a triazine group, or a thiadiazole group.

The “second ring” as used herein may be a benzene group, a cyclopentadiene group, a pyrrole group, a furan group, a thiophene group, or a silole group.

The “third ring” as used herein may be a cyclopentane group, a cyclopentadiene group, an indene group, an adamantane group, a norbornene group, a bicyclo[1.1.1]pentane group, a bicyclo[2.1.1]hexane group, a bicyclo[2.2.1]heptane group (a norbornane group), a bicyclo[2.2.2]octane group, a cyclohexane group, a cyclohexene group, or a benzene group.

The “fourth ring” as used herein may be a furan group, a thiophene group, a pyrrole group, a silole group, an oxazole group, an isoxazole group, an oxadiazole group, an isoxadiazole group, an oxatriazole group, an isoxatriazole group, a thiazole group, an isothiazole group, a thiadiazole group, an isothiadiazole group, a thiatriazole group, an isothiatriazole group, a pyrazole group, an imidazole group, a triazole group, a tetrazole group, an azasilole group, a diazasilole group, a triazasilole group, a pyridine group, a pyrimidine group, a pyrazine group, a pyridazine group, or a triazine group.

For example, the π electron-deficient nitrogen-containing C₁-C₆₀ cyclic group may be an imidazole group, a pyrazole group, a thiazole group, an isothiazole group, an oxazole group, an isoxazole group, a pyridine group, a pyrazine group, a pyridazine group, a pyrimidine group, an indazole group, a purine group, a quinoline group, an isoquinoline group, a benzoquinoline group, a benzoisoquinoline group, a phthalazine group, a naphthyridine group, a quinoxaline group, a benzoquinoxaline group, a quinazoline group, a cinnoline group, a phenanthridine group, an acridine group, a phenanthroline group, a phenazine group, a benzimidazole group, an isobenzothiazole group, a benzoxazole group, an isobenzoxazole group, a triazole group, a tetrazole group, an oxadiazole group, a triazine group, a thiadiazole group, an imidazopyridine group, an imidazopyrimidine group, an azacarbazole group, an azadibenzofuran group, an azadibenzothiophene group, an azadibenzosilole group, an acridine group, or a pyridopyrazine group.

For example, the π electron-rich C₃-C₆₀ cyclic group may be a benzene group, a heptalene group, an indene group, a naphthalene group, an azulene group, an indacene group, an acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a pentaphene group, a rubicene group, a coronene group, an ovalene group, a pyrrole group, a furan group, a thiophene group, an isoindole group, an indole group, an indene group, a benzofuran group, a benzothiophene group, a benzosilole group, a naphthopyrrole group, a naphthofuran group, a naphthothiophene group, a naphthosilole group, a benzocarbazole group, a dibenzocarbazole group, a dibenzofuran group, a dibenzothiophene group, a carbazole group, a dibenzosilole group, an indenocarbazole group, an indolocarbazole group, a benzofurocarbazole group, a benzothienocarbazole group, a benzosilolocarbazole group, a triindolobenzene group, a pyrrolophenanthrene group, a furanophenanthrene group, a thienophenanthrene group, a benzonaphthofuran group, a benzonapthothiophene group, an (indolo)phenanthrene group, a (benzofurano)phenanthrene group, or a (benzothieno)phenanthrene group.

For example, the C₅-C₆₀ carbocyclic group may be a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, a cyclopentadiene group, an indene group, a fluorene group, a 5,6,7,8-tetrahydroisoquinoline group, a 5,6,7,8-tetrahydroquinoline group, an adamantane group, a norbornane group, or a norbornene group.

For example, the C₁-C₆₀ heterocyclic group may be a thiophene group, a furan group, a pyrrole group, a cyclopentadiene group, a silole group, a borole group, a phosphole group, a selenophene group, a germole group, a benzothiophene group, a benzofuran group, an indole group, an indene group, a benzosilole group, a benzoborole group, a benzophosphole group, a benzoselenophene group, a benzogermole group, a dibenzothiophene group, a dibenzofuran group, a carbazole group, a dibenzosilole group, a dibenzoborole group, a dibenzophosphole group, a dibenzoselenophene group, a dibenzogermole group, a dibenzothiophene 5-oxide group, a 9H-fluorene-9-one group, a dibenzothiophene 5,5-dioxide group, an azabenzothiophene group, an azabenzofuran group, an azaindole group, an azaindene group, an azabenzosilole group, an azabenzoborole group, an azabenzophosphole group, an azabenzoselenophene group, an azabenzogermole group, an azadibenzothiophene group, an azadibenzofuran group, an azacarbazole group, an azafluorene group, an azadibenzosilole group, an azadibenzoborole group, an azadibenzophosphole group, an azadibenzoselenophene group, an azadibenzogermole group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, or a benzothiadiazole group.

The terms “a π electron-deficient nitrogen-containing C₁-C₆₀ cyclic group, a π electron-rich C₃-C₆₀ cyclic group, a C₅-C₆₀ cyclic group, and a C₁-C₆₀ heterocyclic group” as used herein each refer to a part of a condensed ring or a monovalent, a divalent, a trivalent, a tetravalent, a pentavalent, or a hexavalent group, depending on the formula structure.

Substituents of the substituted π electron-deficient nitrogen-containing C₁-C₆₀ cyclic group, the substituted π electron-rich C₃-C₆₀ cyclic group, the substituted C₅-C₆₀ cyclic group, the substituted C₁-C₆₀ heterocyclic group, the substituted C₁-C₆₀ alkylene group, the substituted C₂-C₆₀ alkenylene group, the substituted C₂-C₆₀ alkynylene group, the substituted C₃-C₁₀ cycloalkylene group, the substituted C₁-C₁₀ heterocycloalkylene group, the substituted C₃-C₁₀ cycloalkenylene group, the substituted C₁-C₁₀ heterocycloalkenylene group, the substituted C₆-C₆₀ arylene group, the substituted C₁-C₆₀ heteroarylene group, the substituted divalent non-aromatic condensed polycyclic group, the substituted divalent non-aromatic condensed heteropolycyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group may each independently be:
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or any combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or any combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
any combination thereof.

Q₁ to Q₉, Q₁₁ to Q₁₉, Q₂₁ to Q₂₉, and Q₃₁ to Q₃₉ may each independently be: hydrogen; deuterium; —F; or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, a cyano group, a C₁-C₆₀ alkyl group, a C₆-C₆₀ aryl group, or any combination thereof.

Unless otherwise defined, for example, Q₁ to Q₉, Q₁₁ to Q₁₉, Q₂₁ to Q₂₉, and Q₃₁ to Q₃₉ described herein may each independently be:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with deuterium, a C₁-C₁₀ alkyl group, a phenyl group, or any combination thereof.

The term “room temperature” as used herein refers to a temperature of about 25° C.

The terms “a biphenyl group, a terphenyl group, and a tetraphenyl group” as used herein each refer to a monovalent group having two, three, and four phenyl groups linked via a single bond, respectively.

Hereinafter, a compound and an organic light-emitting device according to embodiments will be described in detail with reference to Synthesis Examples and Examples. However, the disclosure is not limited thereto. The wording “‘B’ was used instead of ‘A’” used in describing Synthesis Examples means that an amount of ‘A’ used was identical to an amount of ‘B’ used, in terms of a molar equivalent.

### EXAMPLES

### Synthesis Example 1: Synthesis of Compound 1

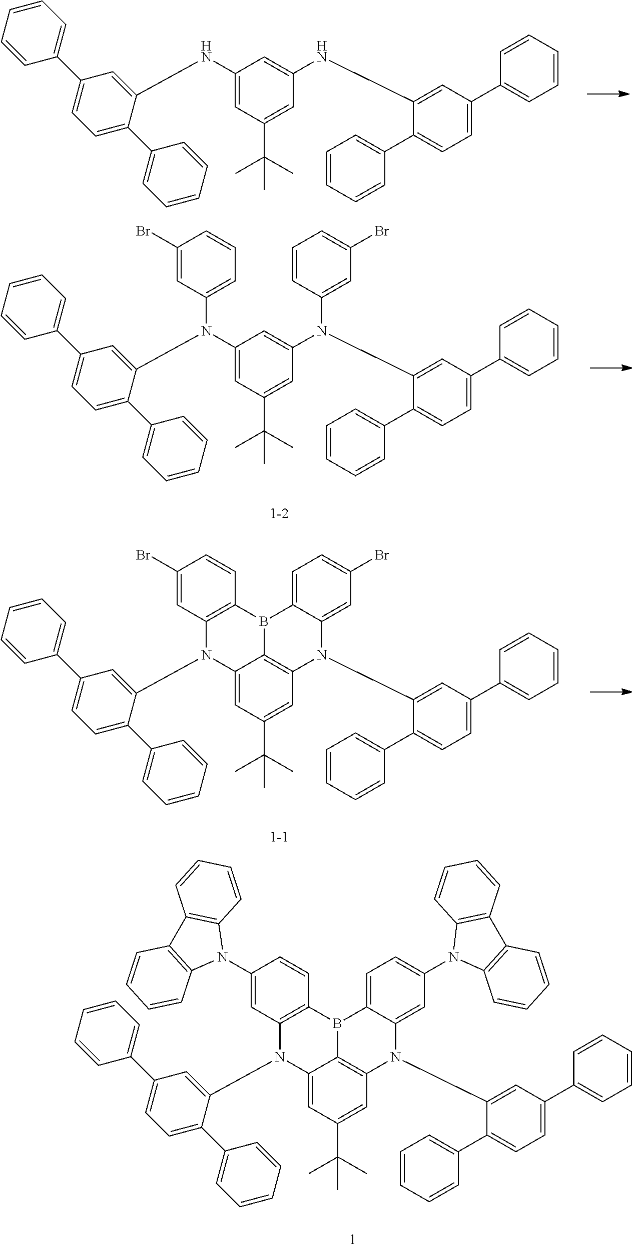

### Synthesis of Compound 1-2

In a nitrogen atmosphere, N1,N3-di([1,1′:4′,1″-terphenyl]-2′-yl)-5-(tert-butyl)benzene-1,3-diamine (15 g, 24.16 mmol), 1-bromo-3-iodobenzene (136.7 g, 483.3 mmol), CuI (0.46 g, 2.42 mmol), and K₂CO₃ (11.69 g, 84.56 mmol) were mixed and heated at 200° C. for 24 hours, and then, the reaction was terminated using an ammonium chloride solution. Subsequently, following an organic layer extraction with dichloromethane the collective extractions were dried using MgSO₄, and the solvent was removed in vacuo. A purification process was performed by column chromatography (a volume ratio of methylene chloride (MC):hexane was 1:3) to obtain Compound 1-2 (12 g), a white solid.

LCMS (m/z) calculated: 930.83 g/mol, found: [M+] 930.204 g/mol

### Synthesis of Compound 1-1

In a nitrogen atmosphere, Compound 1-2 (10.4 g, 11.17 mmol), 100 ml of 1,2-dichlorobenzene, and BI₃ (6.56 g, 16.76 mmol) were mixed and heated at 150° C. for 24 hour. The temperature of the reaction mixture was lowered to room temperature, and the reaction terminated using a Na₂CO₃ solution. Following an organic layer extraction with dichloromethane the collective extractions were dried using MgSO₄, the solvent was removed in vacuo. A purification process was performed by column chromatography (a volume ratio of MC:hexane was 1:3) to obtain Compound 1-1 (2.5 g).

LCMS (m/z) calculated: 938.61 g/mol, found: [M+] 938.19 g/mol

### Synthesis of Compound 1

In a nitrogen atmosphere, Compound 1-1 (1 g, 1.07 mmol), carbazole (0.35 g, 2.09 mmol), Pd₂(dba)₃ (0.01 g, 0.01 mmol), sphos (0.008 g, 0.02 mmol), and NaOBu-t (0.31 g, 3.21 mmol) were added to toluene and heated at 110° C. for 5 hours. The temperature of the reaction mixture was lowered to room temperature, and the reaction was terminated using an ammonium chloride solution. Following an organic layer extracted with dichloromethane the collective extractions were dried using MgSO₄, and the solvent was removed in vacuo. A purification process by column chromatography (a volume ratio of MC:hexane was 1:2) to obtain Compound 1 (0.5 g), as a yellow solid.

LCMS (m/z) calculated: 1111.21 g/mol, found: [M+] 1112.51 g/mol

### Synthesis Example 2: Synthesis of Compound 2

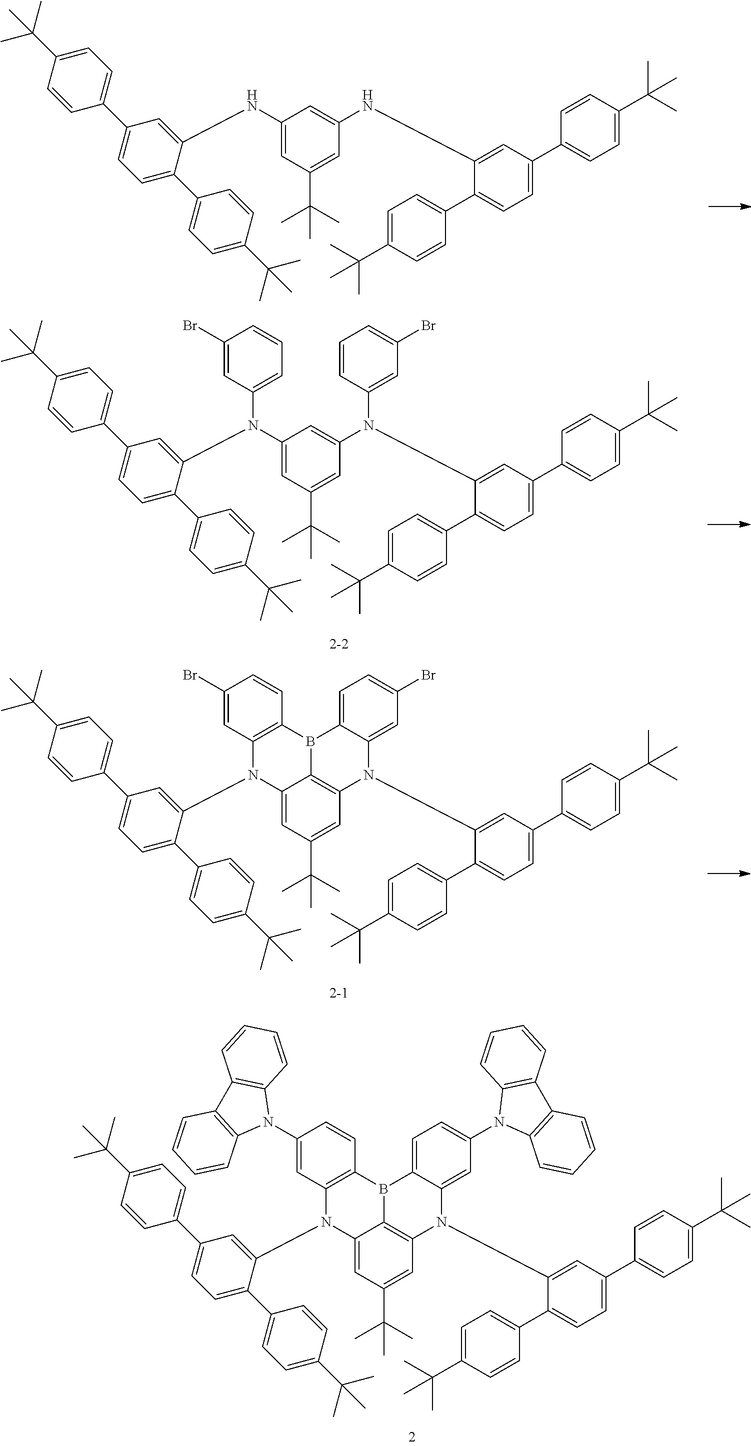

### Synthesis of Compound 2-2

In a nitrogen atmosphere, 5-(tert-butyl)-N1,N3-bis(4,4″-di-tert-butyl-[1,1′:4′,1″-terphenyl]-2′-yl)benzene-1,3-diamine (20 g, 23.66 mmol), 1-bromo-3-iodobenzene (133.88 g, 473.22 mmol), CuI (9 g, 47.32 mmol), and K₂CO₃ (26.16 g, 189.28 mmol) were mixed and heated at 200° C. for 24 hours. The reaction mixture was cooled to room temperature and an ammonium chloride solution is added. Subsequently, following an organic layer extraction with dichloromethane the collective extractions were dried using MgSO₄, and the solvent was removed in vacuo. A purification process by column chromatography (a volume ratio of MC:hexane was 1:3) to obtain Compound 2-2 (20 g), as a white solid.

LCMS (m/z) calculated: 1155.26 g/mol, found: [M+] 1155.46 g/mol

### Synthesis of Compound 2-1

In a nitrogen atmosphere, after Compound 2-2 (10 g, 8.59 mmol), 100 ml of 1,2-dichlorobenzene, and BI₃ (5.05 g, 12.9 mmol) were mixed and heated at 150° C. for 24 hours, the temperature was lowered to room temperature, and then, the reaction was terminated using a Na₂CO₃ solution. Following an organic layer extraction with dichloromethane the collective extractions were dried using MgSO₄, and the solvent was removed in vacuo. A purification process by column chromatography (a volume ratio of MC:hexane was 1:3) to obtain Compound 2-1 (3.0 g).

LCMS (m/z) calculated: 1163.05 g/mol, found: [M+] 1163.14 g/mol

### Synthesis of Compound 2

In a nitrogen atmosphere, after Compound 2-1 (1.5 g, 1.29 mmol), carbazole (0.33 g, 1.97 mmol), Pd₂(dba)₃ (0.11 g, 0.13 mmol), sphos (0.055 g, 0.13 mmol), and NaOBu-t (0.43 g, 4.47 mmol) were added to toluene and heated at 110° C. for 5 hours, the temperature was lowered to room temperature, and then, the reaction was terminated using an ammonium chloride solution. Following an organic layer extraction with dichloromethane the collective extractions were dried using MgSO₄, and the solvent was removed in vacuo. A purification process by column chromatography (a volume ratio of MC:hexane was 1:2) to obtain Compound 2 (1.2 g), as a yellow solid.

LCMS (m/z) calculated: 1335.64 g/mol, found: [M+] 1336.76 g/mol

### Synthesis Example 3: Synthesis of Compound 3

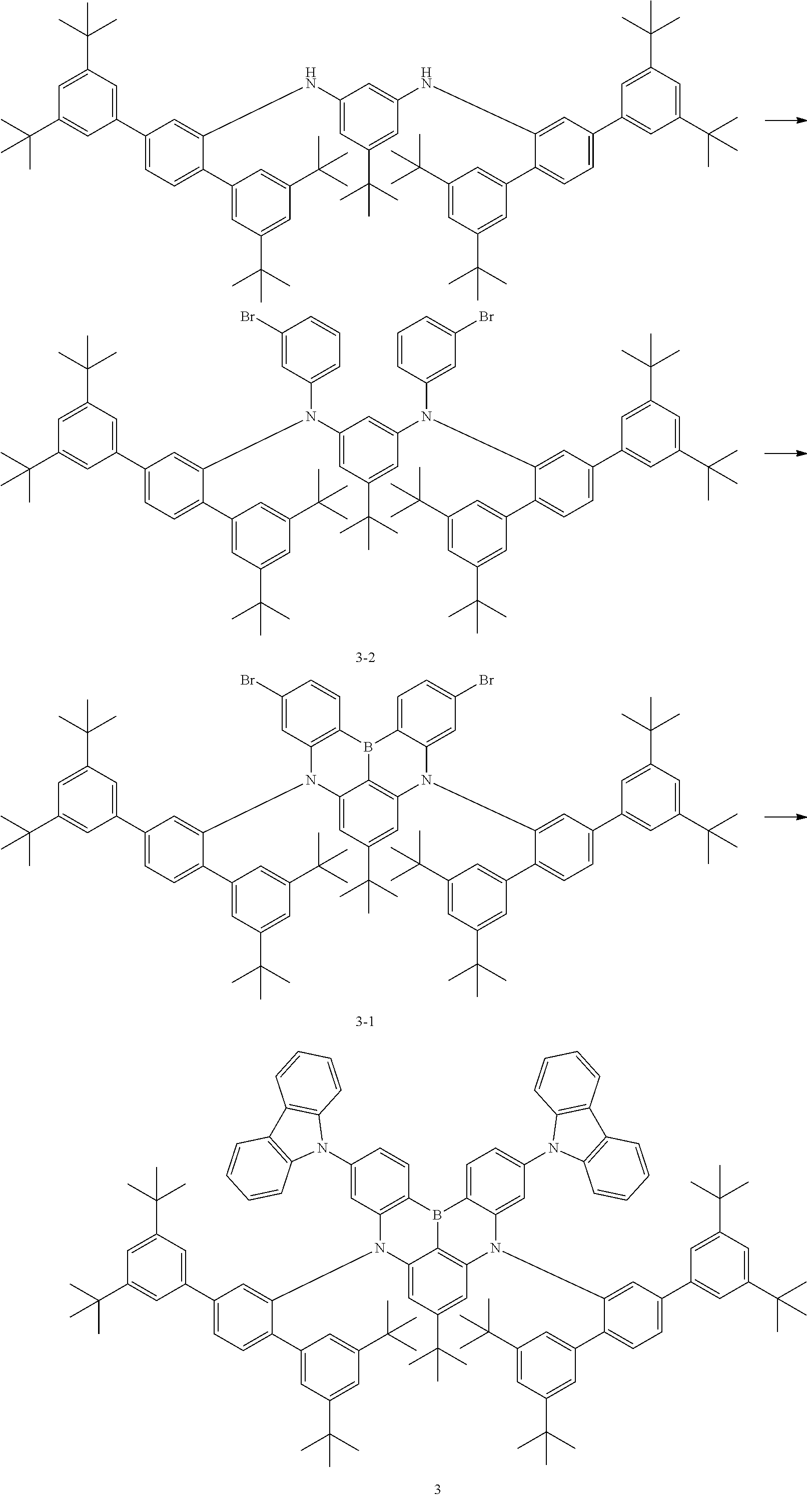

### Synthesis of Compound 3-2

Compound 3-2 was obtained in the same manner as used to obtain Compound 1-2 of Synthesis Example 1, except that 5-(tert-butyl)-N1,N3-bis(3,3″,5,5″-tetra-tert-butyl-[1,1′:4′,1″-terphenyl]-2′-yl)benzene-1,3-diamine was used instead of N1,N3-di([1,1′:4′,1″-terphenyl]-2′-yl)-5-(tert-butyl)benzene-1,3-diamine.

### Synthesis of Compound 3-1

Compound 3-1 was obtained in the same manner as used to obtain Compound 1-1 of Synthesis Example 1, except that Compound 3-2 was used instead of Compound 1-2.

### Synthesis of Compound 3

Compound 3 (1.5 g), which was a yellow solid, was obtained in the same manner as used to obtain Compound 1 of Synthesis Example 1, except that Compound 3-1 was used instead of Compound 1-1.

LCMS (m/z) calculated: 1560.08 g/mol, found: [M+] 1561.15 g/mol

### Evaluation Example 1

For each of Compounds 1, 2, and 3 and R1 to R5, a DFT calculation, which was based on a molecular structure optimized through the B3LYP/6-31 G(d,p) function, was performed using the Gaussian 16 program to evaluate a HOMO energy level, LUMO energy level, S₁ energy, T₁ energy, and ΔEst (an absolute value of a difference between S₁ energy and T₁ energy) of each of Compounds 1, 2, and 3 and R1 to R5, and results thereof are summarized in Table 1.

TABLE 1

| | HOMO | LUMO | | | |
|---|---|---|---|---|---|
| | energy | energy | S₁ | T₁ | |
| Compound | level | level | energy | energy | ΔEst |
| No. | (eV) | (eV) | (eV) | (eV) | (eV) |
| 1 | −4.939 | −1.417 | 3.016 | 2.632 | 0.384 |
| 2 | −4.938 | −1.421 | 3.019 | 2.637 | 0.383 |
| 3 | −4.886 | −1.383 | 3.035 | 2.631 | 0.404 |
| R1 | −5.212 | −1.637 | 3.100 | 2.656 | 0.444 |
| R2 | −5.013 | −1.463 | 3.059 | 2.632 | 0.426 |
| R3 | −4.936 | −1.395 | 3.077 | 2.655 | 0.422 |
| R4 | −4.902 | −1.347 | 3.076 | 2.650 | 0.426 |
| R5 | −4.923 | −1.382 | 3.055 | 2.637 | 0.418 |

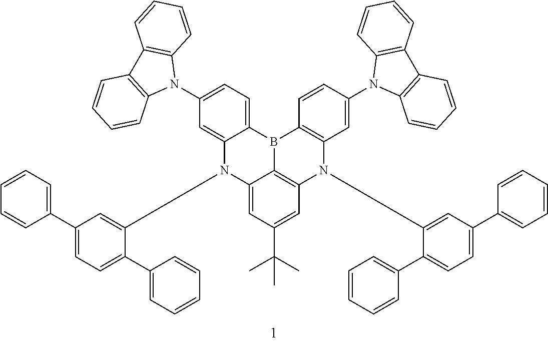 [SMILES: CC(C)(C)c1cc2c3c(c1)N(c1cc(-c4ccccc4)ccc1-c1ccccc1)c1cc(-n4c5ccccc5c5ccccc54)ccc1B3c1ccc(-n3c4ccccc4c4ccccc43)cc1N2c1cc(-c2ccccc2)ccc1-c1ccccc1]

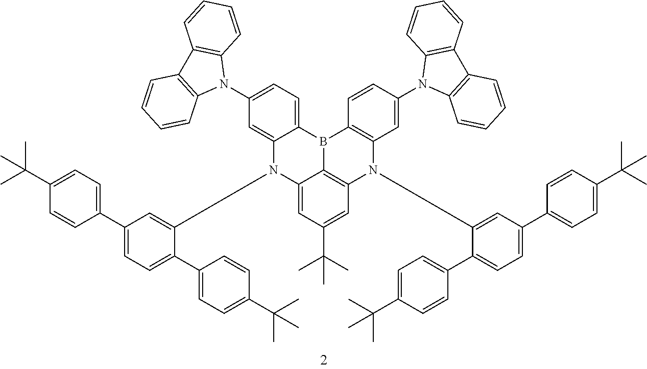 [SMILES: CC(C)(C)c1ccc(-c2ccc(-c3ccc(C(C)(C)C)cc3)c(N3c4cc(-n5c6ccccc6c6ccccc65)ccc4B4c5ccc(-n6c7ccccc7c7ccccc76)cc5N(c5cc(-c6ccc(C(C)(C)C)cc6)ccc5-c5ccc(C(C)(C)C)cc5)c5cc(C(C)(C)C)cc3c54)c2)cc1]

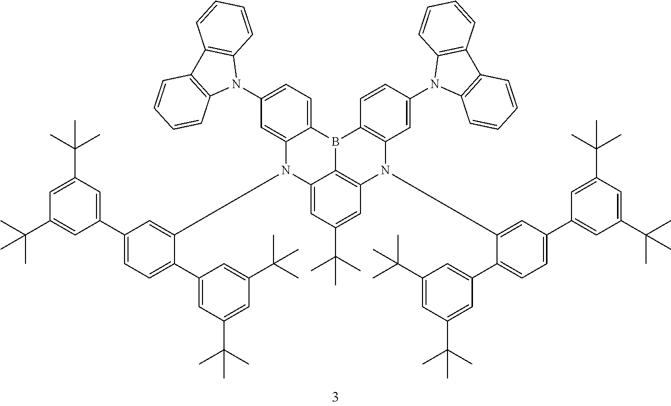 [SMILES: CC(C)(C)c1cc(-c2ccc(-c3cc(C(C)(C)C)cc(C(C)(C)C)c3)c(N3c4cc(-n5c6ccccc6c6ccccc65)ccc4B4c5ccc(-n6c7ccccc7c7ccccc76)cc5N(c5cc(-c6cc(C(C)(C)C)cc(C(C)(C)C)c6)ccc5-c5cc(C(C)(C)C)cc(C(C)(C)C)c5)c5cc(C(C)(C)C)cc3c54)c2)cc(C(C)(C)C)c1]

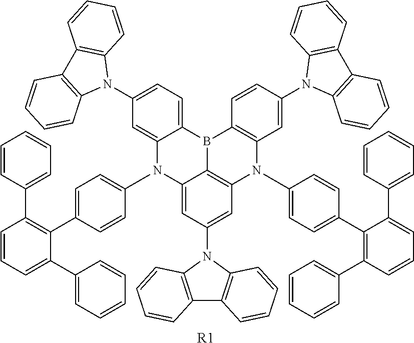

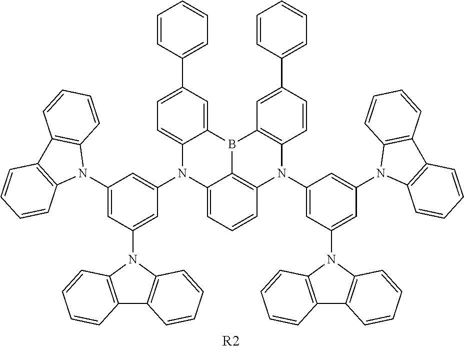

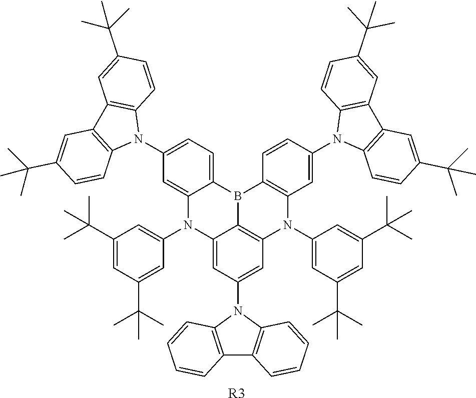

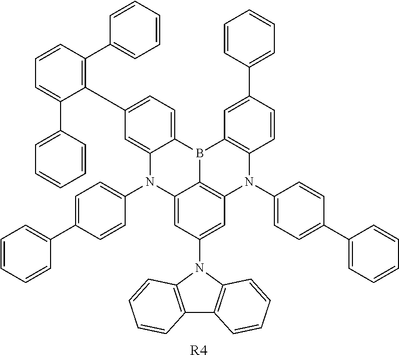

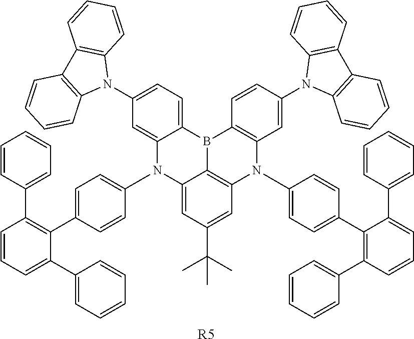

From Table 1, it was confirmed that Compounds 1, 2, and 3 had relatively small S₁ energy and ΔEst compared to Compounds R1 to R5.

### Evaluation Example 2

A surface of Sphere-1, that is, a virtual sphere with a radial distance from a boron atom of Compound 1 to an atom farthest from the boron atom among atoms included in Compound 1 was simulated, and a total area of the surface of Sphere-1, A₁, was calculated.

Next, the region M2, which is a region defined by a plurality of projection lines from the boron atom without contacting a surface surrounding a virtual Compound 1E having the same structure as Compound 1 except that the boron atom is not present as described herein, was simulated/projected to the surface of Sphere-1 and from a surface area of region M2, A₂ was calculated. As the surface surrounding the virtual Compound 1E, the solvent accessible surface of the virtual Compound 1E was obtained by using a solvent accessible surface area (SASA) method in which a probe radius is controlled to 0.5 Å.

In the virtual Compound 1E, no atom (for example, no hydrogen) is bonded to each of three carbon atoms, which were bonded to the boron atom removed from Compound 1, respectively. Accordingly, spatial arrangements of atoms included in the virtual Compound 1E are same as spatial arrangements of atoms other than the boron atom included in Compound 1.

Subsequently, “1−(A₂ of Compound 1/A₁ of Compound 1)” was obtained to evaluate a protection coefficient of the boron atom of Compound 1, and results are summarized in Table 2.

Each of A₁ and A₂ of Compound 1 was obtained using the Gaussian 16 program, and the B3LYP/6-31G(d,p) function was used to optimize the molecular structure of Compound 1.

The above calculation was repeated for each of Compounds 2, 3, and R1 to R5 to evaluate a protection coefficient of the boron atom of each of Compounds 2, 3, and R1 to R5, and results thereof are also summarized in Table 2.

TABLE 2

| | Protection coefficient of the boron atom |
|---|---|
| Compound No. | of corresponding compound |
| 1 | 0.739 |
| 2 | 0.803 |
| 3 | 0.845 |
| R1 | 0.650 |
| R2 | 0.680 |
| R3 | 0.662 |
| R4 | 0.661 |
| R5 | 0.651 |

From Table 2, it was confirmed that protection coefficients of the boron atom of Compounds 1 to 3 were 0.7 or more, whereas protection coefficients of the boron atom of Compounds R1 to R5 were less than 0.7.

### Manufacture of Organic Light-Emitting Devices (OLEDs) 1 to 3 and R1 to R5

A glass substrate on which a 1,500 Å-thick indium tin oxide (ITO) electrode (first electrode, anode) was formed was cleaned by ultrasonication using distilled water. After the completion of ultrasonication using distilled water, cleaning by ultrasonication using a solvent, such as isopropyl alcohol, acetone, and methanol, was performed, and the glass substrate was dried and transferred to a plasma cleaner. The glass substrate was cleaned by using oxygen plasma for 5 minutes, and then transferred to a vacuum laminator.

Compound HT1 and Compound HT-D2 were co-deposited on the ITO electrode on the glass substrate to form a hole injection layer having a thickness of 100 Å, Compound HT1 was deposited on the hole injection layer to form a hole transport layer having a thickness of 1,300 Å, and mCP was deposited on the hole transport layer to form an electron-blocking layer having a thickness of 100 Å, thereby forming a hole transport region.

HTH7 (first host), ETH8 (second host), P31 (sensitizer), and an emitter shown in Table 3 (a weight ratio of first host:second host:sensitizer:delayed fluorescence emitter was 56:30:13:1) were co-deposited on the hole transport region to form an emission layer having a thickness of 400 Å.

BCP was vacuum-deposited on the emission layer to form a hole-blocking layer having a thickness of 100 Å, Compound ET27 and LiQ were vacuum-co-deposited on the hole-blocking layer to form an electron transport layer having a thickness of 300 Å, LiQ was deposited on the electron transport layer to form an electron injection layer having a thickness of 10 Å, and an Al second electrode (cathode) having a thickness of 1,200 Å was formed on the electron injection layer, thereby completing the manufacture of an OLED.

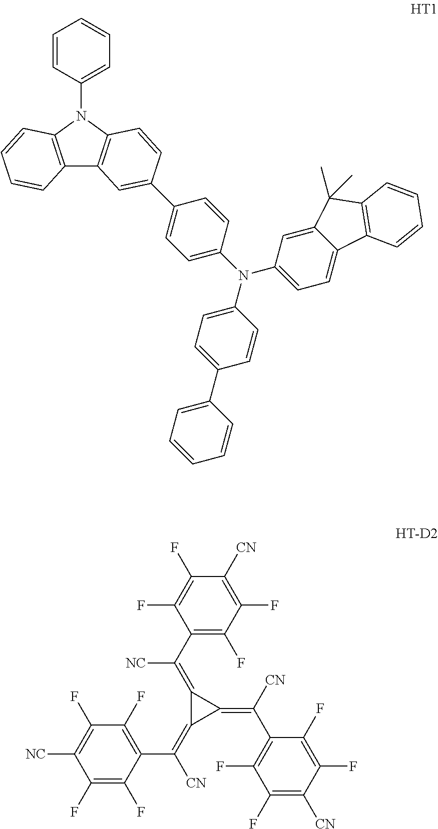 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

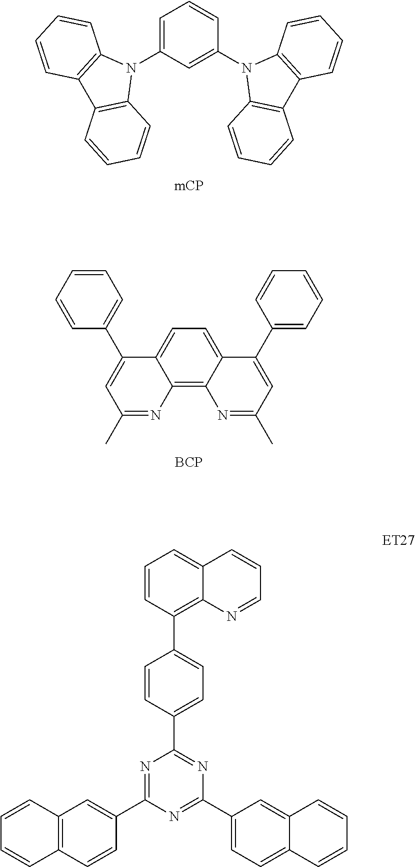

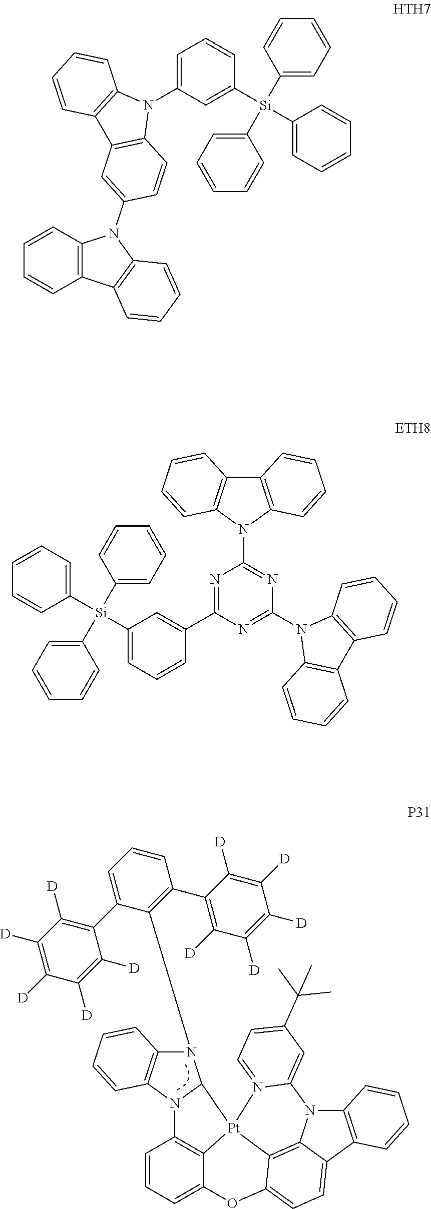

### Evaluation Example 3

For each of OLEDs 1 to 3 and R1 to R5, an emission peak wavelength (maximum emission peak wavelength) of electroluminescence (EL) spectrum, FWHM, driving voltage, and external quantum efficiency (EQE at 1,000 nit) and lifespan (LT₉₅ at 1,000 nit) at 1,000 nit were evaluated, and results thereof are shown in Table 3. The emission peak wavelength of EL spectrum and FWHM were evaluated from an EL spectrum (at 1,000 cd/m²) measured using a luminance meter (Minolta Cs-1000A). The driving voltage and external quantum efficiency were evaluated using a current-voltmeter (Keithley 2400) and a luminance meter (Minolta Cs-1000A). The lifespan (LT₉₅ at 1,000 nit) was obtained by measuring the amount of time (hr) that elapsed until luminance was reduced to 95% of the initial luminance of 100%, which was then converted into and expressed as a relative value (%). The external quantum efficiency was also converted into and expressed as a relative value (%).

TABLE 3

| | | | Emission | | | EQE at | LT₉₅ at |
|---|---|---|---|---|---|---|---|
| | | | peak | | Driving | 1,000 nit | 1,000 nit |
| | Emitter | Protection | wavelength | FWHM | voltage | (relative | (relative |
| | No. | coefficient | (nm) | (nm) | (V) | value, %) | value, %) |
| OLED 1 | 1 | 0.739 | 464 | 26 | 4.3 | 100 | 100.0 |
| OLED 2 | 2 | 0.803 | 464 | 28 | 4.3 | 100 | 106.3 |
| OLED 3 | 3 | 0.845 | 460 | 23 | 4.3 | 96 | 70.0 |
| OLED R1 | R1 | 0.650 | 461 | 24 | 4.4 | 83 | 19.6 |
| OLED R2 | R2 | 0.680 | 463 | 25 | 4.3 | 95 | 28.5 |
| OLED R3 | R3 | 0.662 | 461 | 23 | 4.3 | 95 | 33.6 |
| OLED R4 | R4 | 0.661 | 461 | 23 | 4.4 | 93 | 19.0 |
| OLED R5 | R5 | 0.651 | 463 | 23 | 4.4 | 95 | 29.9 |

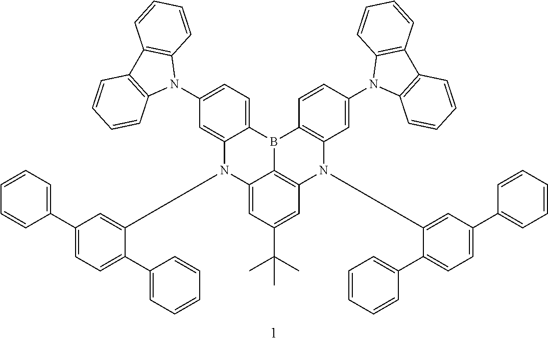 [SMILES: CC(C)(C)c1cc2c3c(c1)N(c1cc(-c4ccccc4)ccc1-c1ccccc1)c1cc(-n4c5ccccc5c5ccccc54)ccc1B3c1ccc(-n3c4ccccc4c4ccccc43)cc1N2c1cc(-c2ccccc2)ccc1-c1ccccc1]

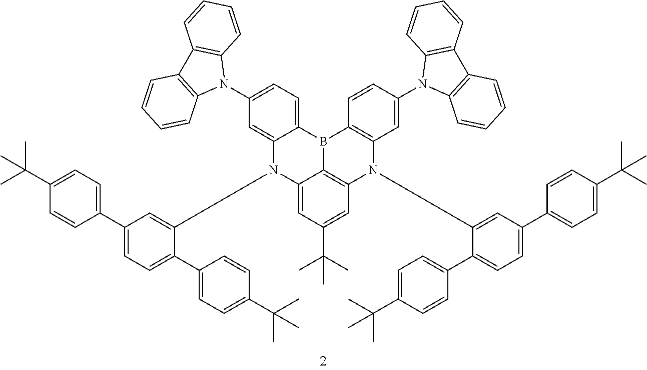 [SMILES: CC(C)(C)c1ccc(-c2ccc(-c3ccc(C(C)(C)C)cc3)c(N3c4cc(-n5c6ccccc6c6ccccc65)ccc4B4c5ccc(-n6c7ccccc7c7ccccc76)cc5N(c5cc(-c6ccc(C(C)(C)C)cc6)ccc5-c5ccc(C(C)(C)C)cc5)c5cc(C(C)(C)C)cc3c54)c2)cc1]

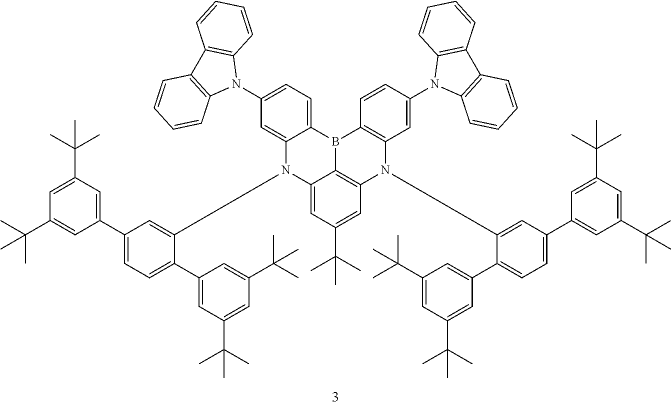 [SMILES: CC(C)(C)c1cc(-c2ccc(-c3cc(C(C)(C)C)cc(C(C)(C)C)c3)c(N3c4cc(-n5c6ccccc6c6ccccc65)ccc4B4c5ccc(-n6c7ccccc7c7ccccc76)cc5N(c5cc(-c6cc(C(C)(C)C)cc(C(C)(C)C)c6)ccc5-c5cc(C(C)(C)C)cc(C(C)(C)C)c5)c5cc(C(C)(C)C)cc3c54)c2)cc(C(C)(C)C)c1]

From Table 3, it was confirmed that OLEDs 1, 2, and 3 emitted blue light and had excellent external quantum efficiency and excellent lifespan characteristics, compared to OLEDs R1 to R5.

As described above, according to the one or more embodiments, a light-emitting device may emit blue light and simultaneously have improved external quantum efficiency and improved lifespan characteristics, and thus, a high-quality electronic apparatus may be manufactured using the light-emitting device. In addition, by using a condensed cyclic compound, a light-emitting device with improved external quantum efficiency and improved lifespan characteristics may be implemented.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A light-emitting device comprising:
a first electrode and a second electrode facing the first electrode; and
an interlayer arranged between the first electrode and the second electrode, the interlayer comprising an emission layer,
wherein the emission layer comprises an emitter and one or more hosts of number m1, m1 is an integer of 1 or more, and if m1 is 2 or more, two or more of the hosts are each different from the other,
the emitter and the one or more hosts are each different from the other,
the emitter comprises a condensed ring with two or more monocyclic groups condensed to the other, and at least one of the two or more monocyclic groups is a 6-membered ring comprising a boron atom and a carbon atom as ring-forming atoms,
wherein a protection coefficient of the boron atom in the emitter is represented by Expression 1 and at least one of the protection coefficient of the boron atom is 0.7 or more:
$$1 - ( {A}_{2} / {A}_{1} ) \qquad Expression 1$$
wherein, in Expression 1,
A₁ is a total surface area of a virtual sphere defined by a radial distance from the boron atom used in the determination of Expression 1 to an atom of the emitter furthest from the boron atom,
A₂ is an area of a region M2 at the surface of the virtual sphere, wherein the region M2 is a surface region defined by a plurality of projection lines from the boron atom without contacting a surface surrounding a virtual compound E having the same structure as the emitter except that the boron atom is not present, and
A₁ and A₂ are each evaluated by a density functional theory (DFT) calculation.

2. The light-emitting device of claim 1, wherein the emission layer further comprises a sensitizer, and
excitation energy in the emission layer is transferred from the sensitizer to the emitter and the emitter emits as fluorescence the excitation energy absorbed from the sensitizer.

3. The light-emitting device of claim 2, wherein the fluorescence emitted from the emission layer has an emission peak wavelength in a range of about 400 nm to about 500 nm.

4. The light-emitting device of claim 1, wherein at least one of the protection coefficient of the boron atom is in a range of about 0.72 to about 0.99.

5. The light-emitting device of claim 1, wherein at least one of the protection coefficient of the boron atom is in a range of about 0.8 to about 0.99.

6. The light-emitting device of claim 1, wherein the emitter satisfies at least one of Conditions A or B:
Condition A
singlet (S₁) energy of the emitter is in a range of about 2.700 eV to about 3.050 eV;
Condition B
an absolute value of a difference between singlet (S₁) energy and triplet (T₁) energy of the emitter is in a range of 0 eV to about 0.415 eV.

7. The light-emitting device of claim 1, wherein an emission peak wavelength of an emission spectrum of the emitter is in a range of about 400 nm to about 500 nm.

8. The light-emitting device of claim 1, wherein the emitter comprises at least one group represented by Formula 2: 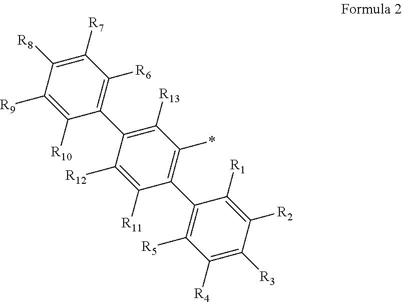
wherein, in Formula 2,
R₁ to R₁₀ are each independently:
hydrogen, deuterium, —F, or a cyano group;
a C₁-C₆₀ alkyl group unsubstituted or substituted with deuterium, —F, a cyano group, or any combination thereof; or
a C₆-C₆₀ aryl group unsubstituted or substituted with deuterium, —F, a cyano group, a C₁-C₆₀ alkyl group, a C₆-C₆₀ aryl group, or any combination thereof,
R₁₁ to R₁₃ are each independently:
hydrogen, deuterium, —F, or a cyano group; or
a C₁-C₆₀ alkyl group unsubstituted or substituted with deuterium, —F, a cyano group, or any combination thereof, and
* indicates a binding site to the condensed ring comprised in the emitter.

9. The light-emitting device of claim 8, wherein the group represented by Formula 2 comprises a tert-butyl group unsubstituted or substituted with deuterium.

10. The light-emitting device of claim 1, wherein the emitter is a condensed cyclic compound represented by Formula 1: 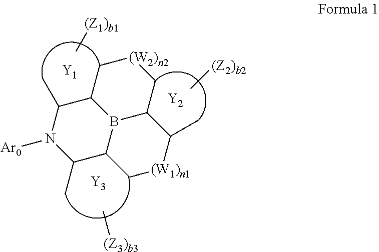
wherein, in Formula 1,
Ar₀ is a group represented by Formula 2, 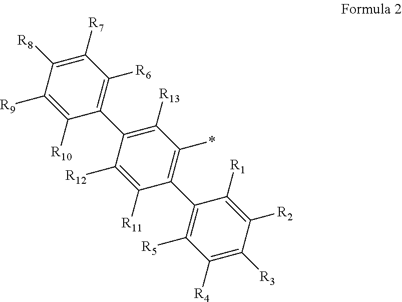
wherein, in Formulae 1 and 2,
ring Y₁, ring Y₂, and ring Y₃ are each independently a C₅-C₆₀ carbocyclic group or a C₃-C₆₀ heterocyclic group,
W₁ is a single bond, O, S, N(Ar₁), N(T₁₁), C(T₁₂)(T₁₃), or Si(T₁₂)(T₁₃),
W₂ is a single bond, O, S, N(Ar₂), N(T₂₁), C(T₂₂)(T₂₃), or Si(T₂₂)(T₂₃),
n1 and n2 are each independently 0 or 1,
when n1 is 0, *—(W₁)ₙ₁—*′ is not present,
when n2 is 0, *—(W₂)ₙ₂—*′ is not present,
the sum of n1 and n2 is 1 or more,
Ar₁ and Ar₂ are each a group represented by Formula 2, R₁ to R₁₀ are each independently:
hydrogen, deuterium, —F, or a cyano group;
a C₁-C₆₀ alkyl group unsubstituted or substituted with deuterium, —F, a cyano group, or any combination thereof; or
a C₆-C₆₀ aryl group unsubstituted or substituted with deuterium, —F, a cyano group, a C₁-C₆₀ alkyl group, a C₆-C₆₀ aryl group, or any combination thereof,
R₁₁ to R₁₃ are each independently:
hydrogen, deuterium, —F, or a cyano group; or
a C₁-C₆₀ alkyl group unsubstituted or substituted with deuterium, —F, a cyano group, or any combination thereof,
* in Formula 2 indicates a binding site to Formula 1,
Z₁, Z₂, Z₃, T₁₁, T₁₂, T₁₃, T₂₁, T₂₂, and T₂₃ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), —P(Q₈)(Q₉), or a group represented by Formula 2,
b1 to b3 are each independently an integer from 0 to 10,
two or more of Z₁, Z₂, Z₃, T₁₁, T₁₂, T₁₃, T₂₁, T₂₂, and T₂₃ are optionally linked to each other to form a substituted or unsubstituted C₅-C₃₀ carbocyclic group or a substituted or unsubstituted C₁-C₃₀ heterocyclic group,
at least one substituent of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group is each independently:
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or any combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or any combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
any combination thereof, and
Q₁ to Q₉, Q₁₁ to Q₁₉, Q₂₁ to Q₂₉, and Q₃₁ to Q₃₉ are each independently: hydrogen; deuterium; —F; or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, a cyano group, a C₁-C₆₀ alkyl group, a C₆-C₆₀ aryl group, or any combination thereof.

11. The light-emitting device of claim 10, wherein ring Y₁, ring Y₂, and ring Y₃ are each independently a benzene group, a naphthalene group, a phenanthrene group, a pyridine group, a pyrimidine group, a pyridazine group, a pyrazine group, a quinoline group, an isoquinoline group, a dibenzofuran group, a dibenzothiophene group, a carbazole group, a fluorene group, a dibenzosilole group, an azadibenzofuran group, an azadibenzothiophene group, an azacarbazole group, an azafluorene group, or an azadibenzosilole group.

12. The light-emitting device of claim 10, wherein Z₁, Z₂, Z₃, T₁₁, T₁₂, T₁₃, T₂₁, T₂₂, and T₂₃ are each independently:
hydrogen, deuterium, —F, or a cyano group;
a C₁-C₂₀ alkyl group, a phenyl group, a biphenyl group, a dibenzofuranyl group, a dibenzothiophenyl group, a carbazolyl group, a fluorenyl group, or a dibenzosilolyl group, each unsubstituted or substituted with deuterium, —F, a cyano group, a C₁-C₂₀ alkyl group, a phenyl group, a dibenzofuranyl group, a dibenzothiophenyl group, a carbazolyl group, a fluorenyl group, a dibenzosilolyl group, or any combination thereof; or
—N(Q₁)(Q₂), and
Q₁ and Q₂ are each independently a C₁-C₂₀ alkyl group, a phenyl group, a biphenyl group, a dibenzofuranyl group, a dibenzothiophenyl group, a carbazolyl group, a fluorenyl group, or a dibenzosilolyl group, each unsubstituted or substituted with deuterium, —F, a cyano group, a C₁-C₂₀ alkyl group, a phenyl group, a dibenzofuranyl group, a dibenzothiophenyl group, a carbazolyl group, a fluorenyl group, a dibenzosilolyl group, or any combination thereof.

13. The light-emitting device of claim 10, wherein Formula 1 satisfies at least one of Conditions 1 and 2:
Condition 1
b1 is 1 or more, and at least one of Z₁ in the number of b1 comprises a carbazole group
Condition 2
b2 is 1 or more, and at least one of Z₂ in the number of b2 comprises a carbazole group.

14. The light-emitting device of claim 10, wherein b3 is 1 or more, and at least one of Z₃ in the number of b3 is a C₁-C₆₀ alkyl group that is unsubstituted or substituted with deuterium, —F, a cyano group, or any combination thereof.

15. The light-emitting device of claim 10, wherein the emitter is a compound represented by Formula 1A: 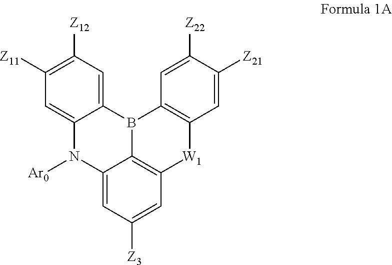
wherein, in Formula 1A,
W₁ is O, S, N(Ar₁), N(T₁₁), C(T₁₂)(T₁₃), or Si(T₁₂)(T₁₃),
Ar₀, Ar₁, and T₁₁, T₁₂, and T₁₃ are each as defined in claim 10,
Z₁₁ and Z₁₂ are each defined as in connection with Z₁ in claim 10, and
Z₂₁ and Z₂₂ are each defined as in connection with Z₂ in claim 10.

16. The light-emitting device of claim 15, wherein Formula 1A satisfies at least one of Conditions 3 to 5:
Condition 3
at least one of Z₁₁ and Z₁₂ is an N-carbazolyl group unsubstituted or substituted with deuterium, —F, a cyano group, a C₁-C₂₀ alkyl group, a phenyl group, or any combination thereof
Condition 4
at least one of Z₂₁ and Z₂₂ is an N-carbazolyl group unsubstituted or substituted with deuterium, —F, a cyano group, a C₁-C₂₀ alkyl group, a phenyl group, or any combination thereof
Condition 5
Z₃ is a C₁-C₂₀ alkyl group unsubstituted or substituted with deuterium, —F, a cyano group, or any combination thereof.

17. The light-emitting device of claim 2, wherein the sensitizer is an organometallic compound,
the organometallic compound comprises a transition metal and a tetradentate ligand bonded to the transition metal,
the transition metal is platinum or palladium, and
the tetradentate ligand comprises a carbene moiety bonded to the transition metal.

18. An electronic apparatus comprising the light-emitting device of claim 1.

19. A condensed cyclic compound represented by Formula 1: 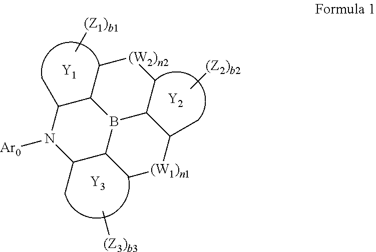
wherein, in Formula 1, Ar₀ is a group represented by Formula 2, 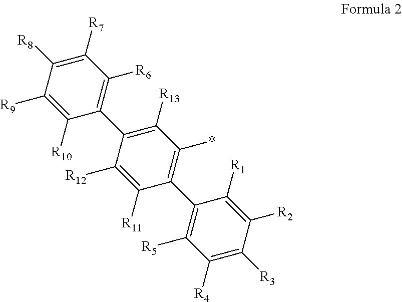
wherein, in Formulae 1 and 2,
ring Y₁, Y₂, and ring Y₃ are each independently a C₅-C₆₀ carbocyclic group or a C₃-C₆₀ heterocyclic group,
W₁ is a single bond, O, S, N(Ar₁), N(T₁₁), C(T₁₂)(T₁₃), or Si(T₁₂)(T₁₃),
W₂ is a single bond, O, S, N(Ar₂), N(T₂₁), C(T₂₂)(T₂₃), or Si(T₂₂)(T₂₃),
n1 and n2 are each independently 0 or 1,
when n1 is 0, *—(W₁)ₙ₁—*′ is not present,
when n2 is 0, *—(W₂)ₙ₂—*′ is not present,
the sum of n1 and n2 is 1 or more, and
Ar₁ and Ar₂ are each a group represented by Formula 2,
R₁ to R₁₀ are each independently:
hydrogen, deuterium, —F, or a cyano group;
a C₁-C₆₀ alkyl group unsubstituted or substituted with deuterium, —F, a cyano group, or any combination thereof; or
a C₆-C₆₀ aryl group unsubstituted or substituted with deuterium, —F, a cyano group, a C₁-C₆₀ alkyl group, a C₆-C₆₀ aryl group, or any combination thereof,
R₁₁ to R₁₃ are each independently:
hydrogen, deuterium, —F, or a cyano group; or
a C₁-C₆₀ alkyl group unsubstituted or substituted with deuterium, —F, a cyano group, or any combination thereof,
* in Formula 2 indicates a binding site to Formula 1,
Z₁, Z₂, Z₃, T₁₁, T₁₂, T₁₃, T₂₁, T₂₂, and T₂₃ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), —P(Q₈)(Q₉), or a group represented by Formula 2,
b1 to b3 are each independently an integer from 0 to 10,
two or more of Z₁, Z₂, Z₃, T₁₁, T₁₂, T₁₃, T₂₁, T₂₂, and T₂₃ are optionally linked to each other to form a substituted or unsubstituted C₅-C₃₀ carbocyclic group or a substituted or unsubstituted C₁-C₃₀ heterocyclic group,
at least one substituent of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group is each independently:
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or any combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or any combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
any combination thereof, and
Q₁ to Q₉, Q₁₁ to Q₁₉, Q₂₁ to Q₂₉, and Q₃₁ to Q₃₉ are each independently: hydrogen; deuterium; —F; or a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, a cyano group, a C₁-C₆₀ alkyl group, a C₆-C₆₀ aryl group, or any combination thereof.

20. A method of evaluating a protection coefficient of an atom X comprised in a compound Y, comprising:
(a) evaluating A₁ by using a density functional theory calculation, wherein A₁ is a total area of a surface of a virtual sphere having a radial distance between the atom X in the compound Y and an atom furthest from the atom X among the atoms of the compound Y,
(b) evaluating A₂ by using a density functional theory calculation, wherein A₂ is an area of a region M2 at the surface of the virtual sphere and the region M2 is a surface region defined by a plurality of projection lines from the atom X without contacting a surface surrounding a virtual compound YE having the same structure as the compound Y except that the atom X is not present, and
(c) evaluating 1−(A₂/A₁) to calculate the protection coefficient of the atom X.
